(19) United States
(12) Patent Application Publication
(10) Pub. No.: US 2026/0013320 A1
(43) Pub. Date: Jan. 8, 2026

(54) LIGHT EMITTING ELEMENT, FUSED POLYCYCLIC COMPOUND FOR THE LIGHT EMITTING ELEMENT, AND ELECTRONIC APPARATUS INCLUDING THE LIGHT EMITTING ELEMENT

(71) Applicant: Samsung Display Co., Ltd., Yongin-si (KR)

(72) Inventors: MinJae SUNG, Yongin-si (KR); MUN-KI SIM, Yongin-si (KR); TAEIL KIM, Yongin-si (KR); SUN YOUNG PAK, Yongin-si (KR); JUNHA PARK, Yongin-si (KR); Chihyun RYOO, Yongin-si (KR); Giwoong HAN, Yongin-si (KR)

(21) Appl. No.: 19/255,742

(22) Filed: Jun. 30, 2025

(30) Foreign Application Priority Data
Jul. 2, 2024 (KR) 10-2024-0086877

(51) Int. Cl. H10K 50/11; H10K 59/38; H10K 85/30; H10K 85/60; H10K 102/00

(52) U.S. Cl. CPC H10K 50/11; H10K 59/38; H10K 85/346; H10K 85/626; H10K 85/633; H10K 85/654; H10K 85/6572; H10K 85/658; H10K 2102/331

(57) ABSTRACT

A light emitting element includes a first electrode, a second electrode on the first electrode, and an emission layer between the first electrode and the second electrode and including a first compound represented by Formula 1. In addition, a fused polycyclic compound represented by Formula 1 and an electronic apparatus including the light emitting element are provided.

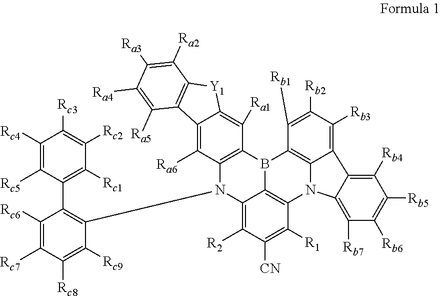

### CROSS-REFERENCE TO RELATED APPLICATION

The present application claims priority to and the benefit of Korean Patent Application No. 10-2024-0086877, filed on Jul. 2, 2024, in the Korean Intellectual Property Office, the entire content of which is incorporated herein by reference.

### BACKGROUND

### 1. Field

One or more embodiments of the present disclosure relate to a light emitting element, a fused polycyclic compound for the light emitting element, and an electronic apparatus including the light emitting element.

### 2. Description of the Related Art

An electronic apparatus may include a display device that displays an image. Recently, significant research and development efforts on organic electroluminescence display devices as image display devices have been conducted. The organic electroluminescence display device is a display device including a self-luminescent type (kind) light emitting element in which holes and electrons injected separately from a first electrode and a second electrode recombine in an emission layer. This recombination causes a light emitting material in the emission layer to emit light, thereby achieving display (e.g., display of images).

In the application of a light emitting element to a display device, increasing emission efficiency and lifespan of the light emitting element is desired or required. Therefore, the development of materials for the light emitting element, which stably achieve these requirements, has been consistently required, desired, and pursued.

### SUMMARY

One or more aspects of embodiments of the present disclosure are directed toward a light emitting element having improved emission efficiency and lifespan, and an electronic apparatus including the same.

One or more aspects of embodiments of the present disclosure are directed toward a fused polycyclic compound which is a material for a light emitting element that improves emission efficiency and lifespan of the light emitting element.

Additional aspects will be set forth in part in the description which follows and, in part, will be apparent from the description, or may be learned by practice of the presented embodiments.

According to one or more embodiments of the present disclosure, a light emitting element includes a first electrode, a second electrode on (e.g., arranged on) the first electrode, and an emission layer between (e.g., arranged between) the first electrode and the second electrode and including a first compound represented by Formula 1.

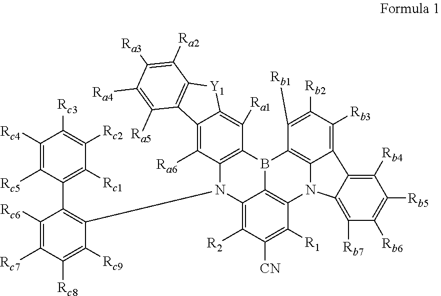

In Formula 1, Y₁ may be NR₃, O, or S, R₁ to R₃ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms, and Rₐ₁ to Rₐ₆, R_{b1} to R_{b7}, and R_{c1} to R_{c9} may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring.

In one or more embodiments, the emission layer may further include at least one selected from among a second compound represented by Formula HT-1, a third compound represented by Formula ET-1, and a fourth compound represented by Formula D-1.

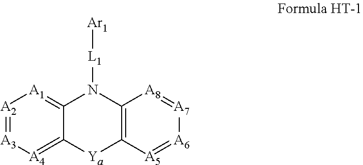

In Formula HT-1, A₁ to A₈ may each independently be N or CR₅₁, L₁ may be a direct linkage, a substituted or unsubstituted arylene group of 6 to 30 ring-forming carbon atoms, or a substituted or unsubstituted heteroarylene group of 2 to 30 ring-forming carbon atoms, Yₐ may be a direct linkage, CR₅₂R₅₃, or SiR₅₄R₅₅, Ar₁ may be a substituted or unsubstituted aryl group of 6 to 30 ring-forming carbon atoms or a substituted or unsubstituted heteroaryl group of 2 to 30 ring-forming carbon atoms, and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group or 2 to 60 ring-forming carbon atoms, and/or combined with an adjacent group to form a ring.

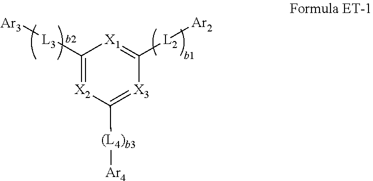

In Formula ET-1, at least one selected from among X₁ to X₃ may be N, and the remainder are CR₅₆, R₅₆ may be a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group or 2 to 60 ring-forming carbon atoms, b1 to b3 may each independently be an integer of 0 to 10, Ar₂ to Ar₄ may each independently be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group or 2 to 30 ring-forming carbon atoms, and L₂ to L₄ may each independently be a direct linkage, a substituted or unsubstituted arylene group of 6 to 30 ring-forming carbon atoms, or a substituted or unsubstituted heteroarylene group or 2 to 30 ring-forming carbon atoms.

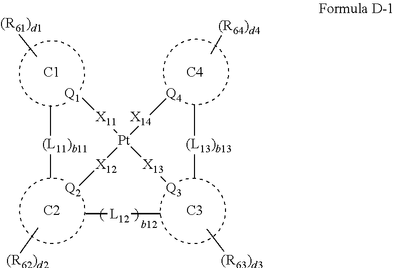

In Formula D-1, Q₁ to Q₄ may each independently be C or N, C1 to C4 may each independently be a substituted or unsubstituted hydrocarbon ring of 5 to 30 ring-forming carbon atoms, a substituted or unsubstituted aryl group of 6 to 30 ring-forming carbon atoms, or a substituted or unsubstituted heterocycle of 2 to 30 ring-forming carbon atoms, X₁₁ to X₁₄ may each independently be a direct linkage or *—O—*, L₁₁ to L₁₃ may each independently be a direct linkage,

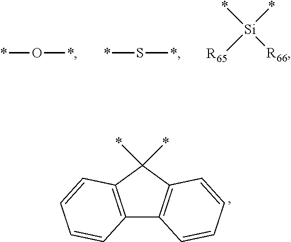

a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, b11 to b13 may each independently be 0 or 1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and d1 to d4 may each independently be an integer of 0 to 4.

In one or more embodiments, the first compound represented by Formula 1 may be represented by any one selected from among Formula 1-1 to Formula 1-3.

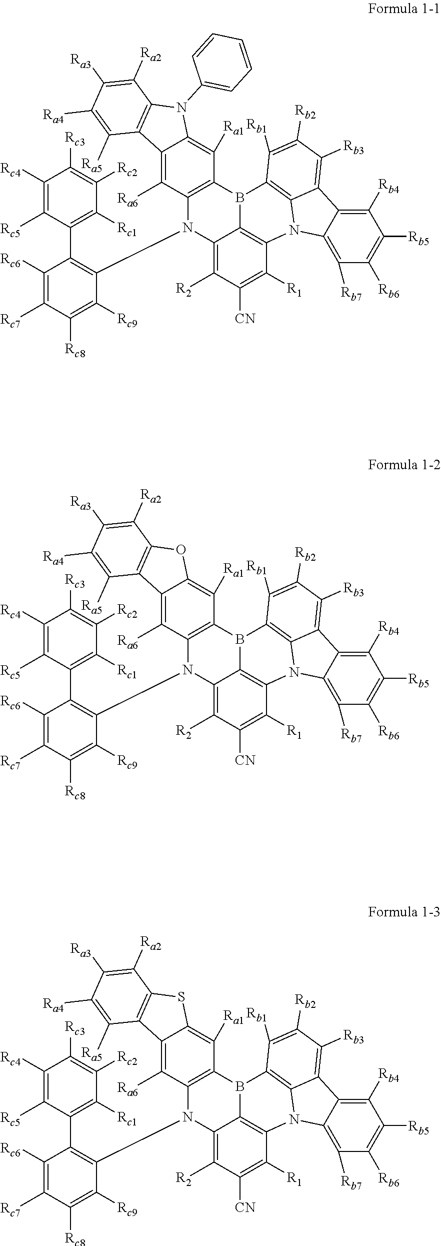

In Formula 1-1 to Formula 1-3, R₁, R₂, Rₐ₁ to R^{a6}, R_{b1} to R_{b7}, and R_{c1} to R^{c9} may each independently be the same as defined in Formula 1.

In one or more embodiments, the first compound represented by Formula 1 may be represented by Formula 1-A1.

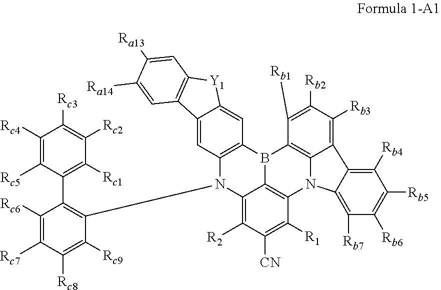

In Formula 1-A1, Rₐ₁₃ and Rₐ₁₄ may each independently be a hydrogen atom, a deuterium atom, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms. In Formula 1-A1, Y₁, R₁, R₂, R_{b1} to R_{b7}, and R_{c1} to R_{c9} may each independently be the same as defined in Formula 1.

In one or more embodiments, the first compound represented by Formula 1 may be represented by Formula 1-A2 or Formula 1-A3.

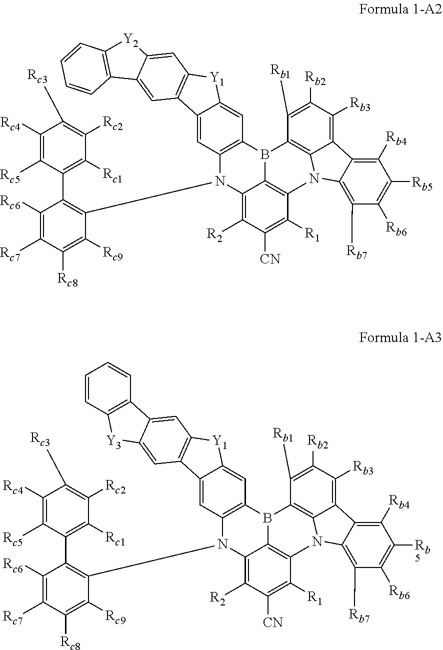

In Formula 1-A2 and Formula 1-A3, Y₂ and Y₃ may each independently be CR₄R₅, O, or S, R₄ and R₅ may each independently be a hydrogen atom, a deuterium atom, a substituted or unsubstituted alkyl group of 1 to 30 carbon atoms, or a substituted or unsubstituted aryl group of 6 to 30 ring-forming carbon atoms. In Formula 1-A2 and Formula 1-A3, Y₁, R₁, R₂, R_{b1} to R_{b7}, and R_{c1} to R_{c9} may each independently be the same as defined in Formula 1.

In one or more embodiments, the first compound represented by Formula 1 may be represented by Formula 1-B1 or Formula 1-B2.

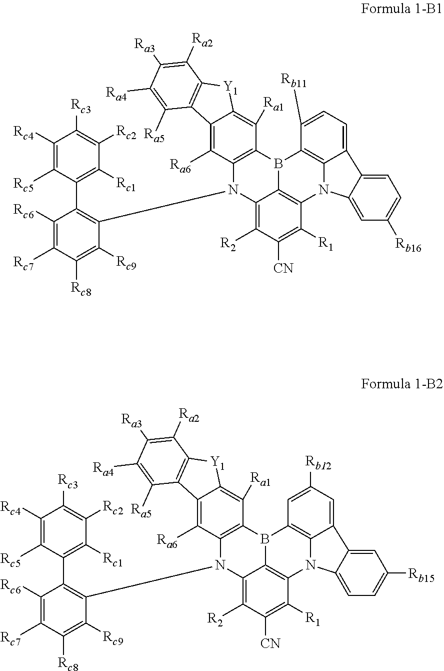

In Formula 1-B31 and Formula 1-132, R_{b11}, R_{b12}, R_{b15}, and R_{b16} may each independently be a hydrogen atom, a deuterium atom, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms. In Formula 1-1B1 and Formula 1-1B2, Y₁, R₁, R₂, Rₐ₁ to Rₐ₆, and R_{c1} to R_{c9} may each independently be the same as defined in Formula 1.

In one or more embodiments, the first compound represented by Formula 1 may be represented by any one selected from among Formula 1-B3 to Formula 1-B8.

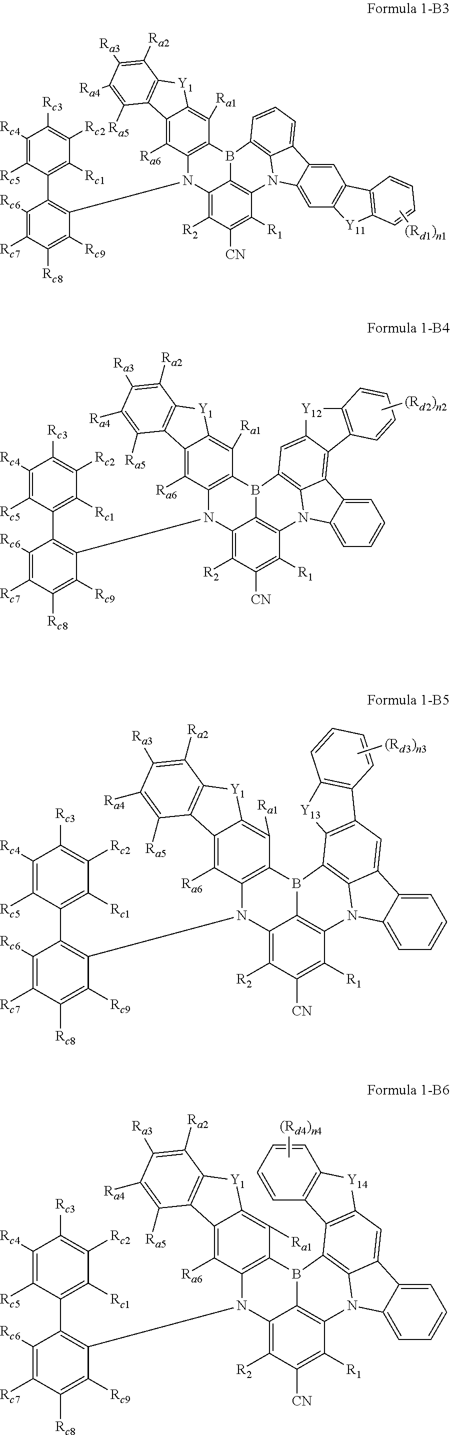

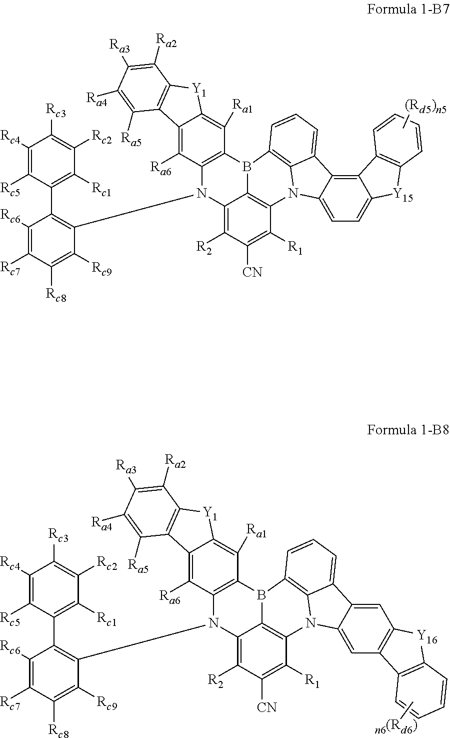

In Formula 1-1B3 to Formula 1-1B8, Y₁₁ to Y₁₆ may each independently be CR₁₁R₁₂, NR₁₃, O, or S, n1 to n6 may each independently be an integer of 0 to 4, R₁₁ to R₁₃ and R_{d1} to R_{d6} may each independently be a hydrogen atom, a deuterium atom, or a substituted or unsubstituted aryl group of 6 to 60 ring-forming carbon atoms. In Formula 1-B3 to Formula 1-B8, Y₁, R₁, R₂, Rₐ₁ to Rₐ₆, and R_{c1} to R_{c9} may each independently be the same as defined in Formula 1.

In one or more embodiments, in Formula 1, at least one selected from among R_{b1} to R_{b7} may be combined with an adjacent group to form a fused ring, and the fused ring may be a substituted or unsubstituted aryl group of 6 to 30 ring-forming carbon atoms or a substituted or unsubstituted heteroaryl group including N, O, or S as a ring-forming atom and having 2 to 30 ring-forming carbon atoms.

In one or more embodiments, in Formula 1, a biphenyl moiety including R_{c1} to R_{c9} may be represented by any one selected from among RC-1 to RC-18.

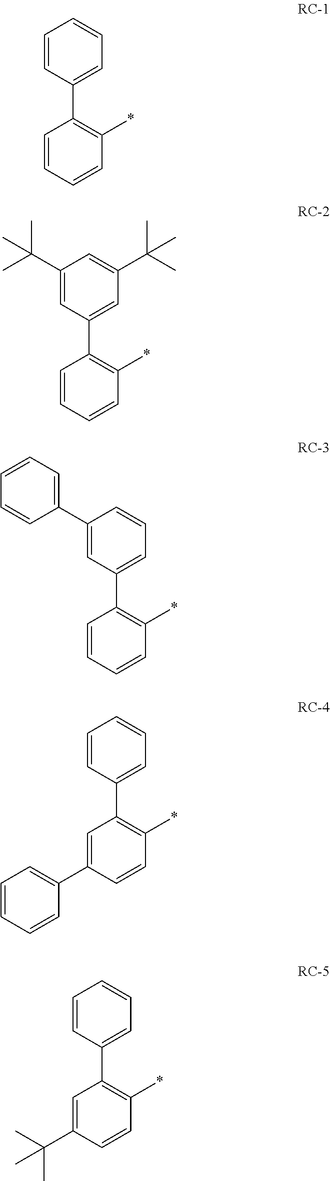

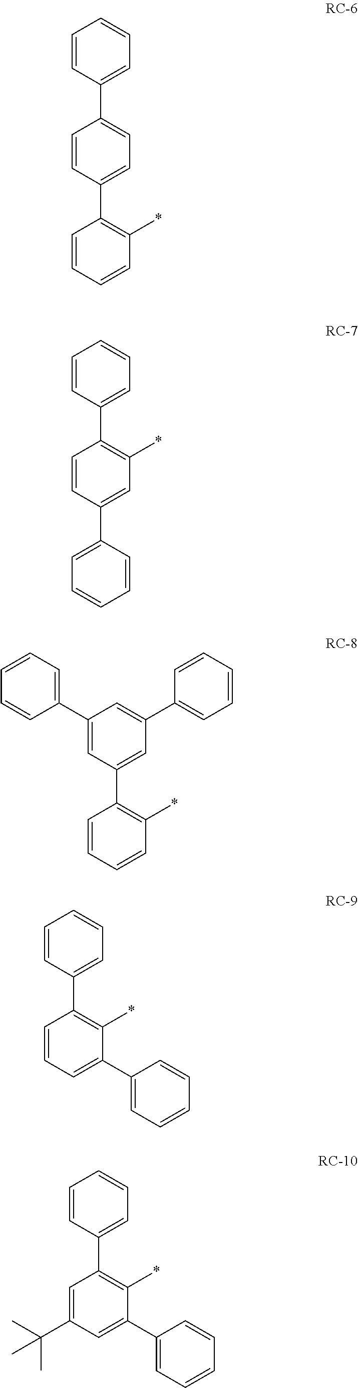 [SMILES: *c1ccccc1-c1ccc(-c2ccccc2)cc1 ; *c1cc(-c2ccccc2)ccc1-c1ccccc1 ; *c1ccccc1-c1cc(-c2ccccc2)cc(-c2ccccc2)c1 ; *c1c(-c2ccccc2)cccc1-c1ccccc1 ; *c1c(-c2ccccc2)cc(C(C)(C)C)cc1-c1ccccc1]

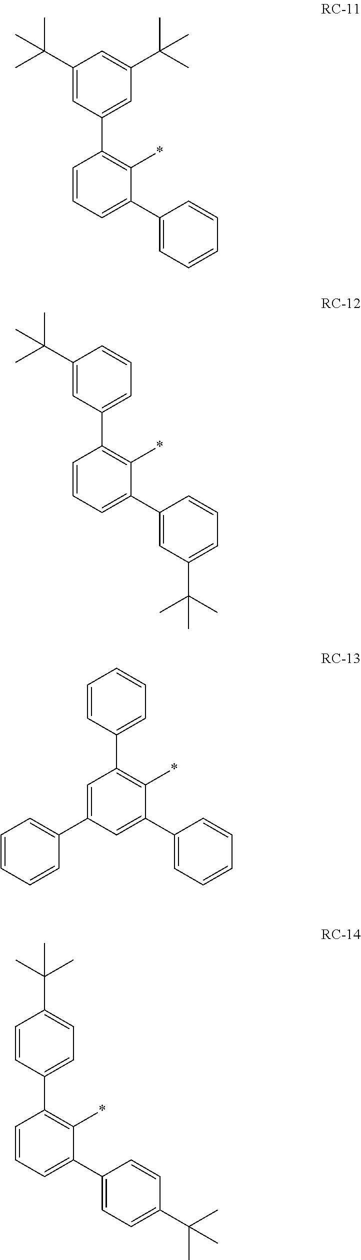 [SMILES: *c1c(-c2ccccc2)cccc1-c1cc(C(C)(C)C)cc(C(C)(C)C)c1 ; *c1c(-c2cccc(C(C)(C)C)c2)cccc1-c1cccc(C(C)(C)C)c1 ; *c1c(-c2ccccc2)cc(-c2ccccc2)cc1-c1ccccc1 ; *c1c(-c2ccc(C(C)(C)C)cc2)cccc1-c1ccc(C(C)(C)C)cc1]

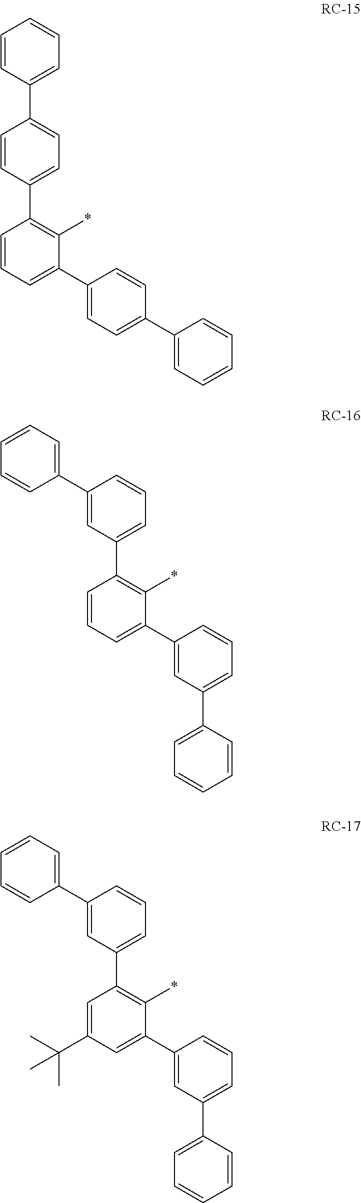 [SMILES: *c1c(-c2ccc(-c3ccccc3)cc2)cccc1-c1ccc(-c2ccccc2)cc1 ; *c1c(-c2cccc(-c3ccccc3)c2)cccc1-c1cccc(-c2ccccc2)c1 ; *c1c(-c2cccc(-c3ccccc3)c2)cc(C(C)(C)C)cc1-c1cccc(-c2ccccc2)c1]

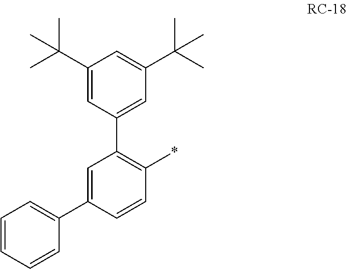 [SMILES: *c1ccc(-c2ccccc2)cc1-c1cc(C(C)(C)C)cc(C(C)(C)C)c1]

In one or more embodiments, in Formula 1, R_{c1} to R_{c9} may each independently be a hydrogen atom, a deuterium atom, a substituted or unsubstituted t-butyl group, a substituted or unsubstituted phenyl group, or a substituted or unsubstituted biphenyl group.

According to one or more embodiments of the present disclosure, there is provided the fused polycyclic compound represented by Formula 1.

According to one or more embodiments of the present disclosure, a display device includes a base layer, a circuit layer on (e.g., arranged on) the base layer, and a display element layer on (e.g., arranged on) the circuit layer and including a light emitting element, wherein the light emitting element includes a first electrode, a second electrode on (e.g., arranged on) the first electrode, and an emission layer between (e.g., arranged between) the first electrode and the second electrode and including the fused polycyclic compound represented by Formula 1.

In one or more embodiments, the light emitting element may include a first light emitting element configured to emit red light, a second light emitting element configured to emit green light, and a third light emitting element configured to emit blue light, and the second light emitting element may include the fused polycyclic compound.

In one or more embodiments, the display device may further include a light control layer on (e.g., arranged on) the display element layer and including a quantum dot.

### BRIEF DESCRIPTION OF DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. Above and/or other aspects of the disclosure should become apparent and appreciated from the following description of embodiments taken in conjunction with the accompanying drawings. In the drawings:

FIG. 1 is a plan view showing a display device according to one or more embodiments of the present disclosure;

FIG. 2 is a cross-sectional view showing a portion corresponding to the line I-I′ of FIG. 1 according to one or more embodiments of the present disclosure;

FIG. 3 is a cross-sectional view schematically showing a light emitting element of one or more embodiments of the present disclosure;

FIG. 4 is a cross-sectional view schematically showing a light emitting element of one or more embodiments of the present disclosure;

FIG. 5 is a cross-sectional view schematically showing a light emitting element of one or more embodiments of the present disclosure;

FIG. 6 is a cross-sectional view schematically showing a light emitting element of one or more embodiments of the present disclosure;

FIG. 7 is a cross-sectional view showing a display device according to one or more embodiments;

FIG. 8 is a cross-sectional view showing a display device according to one or more embodiments of the present disclosure;

FIG. 9 is a cross-sectional view showing a display device according to one or more embodiments of the present disclosure;

FIG. 10 is a cross-sectional view showing a display device according to one or more embodiments; and

FIG. 11 is a diagram showing an interior of a vehicle in which the display device of one or more embodiments is arranged;

FIG. 12 is a perspective view showing an electronic apparatus according to one or more embodiments of the present disclosure;

FIG. 13 is an exploded perspective view showing an electronic apparatus according to one or more embodiments of the present disclosure;

FIG. 14 is a block diagram of an electronic apparatus according to one or more embodiments of the present disclosure;

FIG. 15 is a diagram showing an electronic apparatus according to one or more embodiments of the present disclosure; and

FIG. 16 is a diagram showing an electronic apparatus according to one or more embodiments of the present disclosure.

### DETAILED DESCRIPTION

The accompanying drawings are included to provide a further understanding of the disclosure, and are incorporated in and constitute a part of this disclosure. The present disclosure may, however, be embodied in different forms and should not be construed as limited to any embodiment set forth herein. Rather, these embodiments are provided so that this disclosure will be thorough and complete, and will fully convey the scope of the disclosure to those skilled in the art.

In this disclosure, it will be understood that if (e.g., when) an element (or a region, a layer, a portion, and/or the like) is referred to as being “on”, “connected to” or “coupled to” another element, it may be directly arranged on, connected or coupled to the other element, or intervening elements may be arranged therebetween. In contrast, “directly on” may refer to that there are no additional layers, films, regions, plates, and/or the like, between a layer, a film, a region, a plate, and/or the like and the other part. For example, “directly on” may refer to two layers or two members are arranged without utilizing an additional member such as an adhesive member therebetween.

Like reference numerals or symbols refer to like elements throughout the disclosure, and duplicative descriptions thereof may not be provided for conciseness. In the drawings, the thickness, the ratio, and the size of an element may be exaggerated for effective description of the technical contents. As used herein, the term “and/or” or “or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b, or c,” “at least one selected from a, b, and c,” “at least one selected from among a to c,” and/or the like, may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

It will be understood that, although the terms “first,” “second,” and/or the like may be used herein to describe one or more suitable elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed herein could be termed a second element, component, region, layer, or section, respectively, without departing from the scope of the disclosure. Similarly, a second element, component, region, layer, or section may be termed a first element, component, region, layer, or section, respectively. As used herein, the singular forms, “a,” “an,” “me,” and “the” are intended to include the plural forms as well, unless the context clearly indicates otherwise. Further, the utilization of “may” when describing embodiments of the present disclosure refers to “one or more embodiments of the present disclosure”.

Also, as used herein, terms of “below,” “on lower side,” “above,” “on upper side,” and/or the like may be used to describe the relationships of elements illustrated in the drawings. These terms have relative concepts and are described on the basis of the directions indicated in the drawings.

It will be further understood that the terms “comprise(s)/comprising,” “include(s)/including,” and/or “have(has)/having,” if (e.g., when) used in this disclosure, specify the presence of stated features, integers, steps, operations, elements, components, and/or groups thereof, but do not preclude the presence or addition of one or more other features, integers, steps, operations, elements, components, and/or groups thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Unless otherwise defined, all terms (including technical and scientific terms) used herein have the same meaning as commonly understood by one of ordinary skill in the art to which this disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the present disclosure, the term “substituted or unsubstituted” may refer to substituted or unsubstituted with at least one substituent selected from among the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the present disclosure, the phrase “bonded to an adjacent group to form a ring” may refer to that a group is bonded to an adjacent group to form a substituted or unsubstituted hydrocarbon ring or a substituted or unsubstituted heterocycle. The hydrocarbon ring includes an aliphatic hydrocarbon ring and/or an aromatic hydrocarbon ring. The heterocycle includes an aliphatic heterocycle and/or an aromatic heterocycle. The hydrocarbon ring and the heterocycle may each be monocyclic or polycyclic. In addition, the rings formed by being bonded to each other may be connected to another ring to form a spiro structure.

In the present disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the present disclosure, examples of a halogen may include fluorine, chlorine, bromine, or iodine.

In the present disclosure, an alkyl group may be linear or branched. The number of carbons in the alkyl group may be 1 to 60, 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but embodiments of the present disclosure are not limited thereto.

In the present disclosure, a cycloalkyl group may refer to a cyclic alkyl group. The number of carbons in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, an adamantyl group, a 1-adamantyl group, a 2-adamantyl group, an isobornyl group, a bicycloheptyl group, and/or the like, but embodiments of the present disclosure are not limited thereto.

In the present disclosure, an alkenyl group refers to a hydrocarbon group including at least one carbon-carbon double bond in the middle or terminal of an alkyl group having 2 or more carbon atoms. The alkenyl group may be linear or branched. The number of carbon atoms in the alkenyl group is not specifically limited, for example, may be 2 to 60, 2 to 30, 2 to 20, or 2 to 10. Examples of the alkenyl group may include a vinyl group, a 1-butenyl group, a 1-pentenyl group, a 1,3-butadienyl group, a styrenyl group, a styryl vinyl group, and/or the like, but embodiments of the present disclosure are not limited thereto.

In the present disclosure, an alkynyl group refers to a hydrocarbon group including at least one carbon-carbon triple bond in the middle or terminal of an alkyl group having 2 or more carbon atoms. The alkynyl group may be linear or branched. Although the number of carbon atoms in the alkynyl group is not specifically limited, it may be 2 to 30, 2 to 20, or 2 to 10. Examples of the alkynyl group may include an ethynyl group, a propynyl group, and/or the like, but embodiments of the present disclosure are not limited thereto.

In the present disclosure, a hydrocarbon ring group refers to any functional group or substituent derived from an aliphatic hydrocarbon ring. The hydrocarbon ring group may be a saturated hydrocarbon ring group having 5 to 20 ring-forming carbon atoms.

In the present disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but embodiments of the present disclosure are not limited thereto.

In the present disclosure, a fluorenyl group may be substituted, and two substituents may be bonded to each other to form a spiro structure. Examples of the substituted fluorenyl group are as follows. However, embodiments of the present disclosure are not limited thereto.

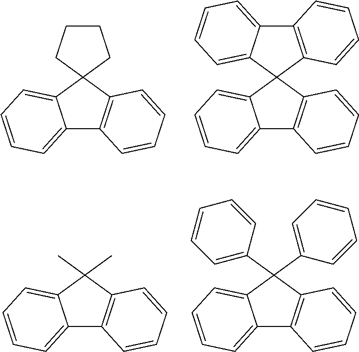

A heterocyclic group as used herein refers to any functional group or substituent derived from a ring containing at least one of B, O, N, P, Si, or S as a heteroatom. The heterocyclic group may include an aliphatic heterocyclic group and/or an aromatic heterocyclic group. The aromatic heterocyclic group may be a heteroaryl group. The aliphatic heterocycle and the aromatic heterocycle may each be monocyclic or polycyclic.

In the present disclosure, the heterocyclic group may contain at least one of B, O, N, P, Si, or S as a heteroatom. If (e.g., when) the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 60, 2 to 30, 2 to 20, or 2 to 10.

In the present disclosure, an aliphatic heterocyclic group may include at least one of B, O, N, P, Si, or S as a heteroatom. The number of ring-forming carbon atoms in the aliphatic heterocyclic group may be 2 to 60, 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but embodiments of the present disclosure are not limited thereto.

In the present disclosure, the heteroaryl group may contain at least one of B, O, N, P, Si, or S as a heteroatom. If the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but embodiments of the present disclosure are not limited thereto.

In the present disclosure, the above description of the aryl group may be applied to an arylene group except that the arylene group is a divalent group. The above description of the heteroaryl group may be applied to a heteroarylene group except that the heteroarylene group is a divalent group.

In the present disclosure, a silyl group may include an alkylsilyl group and/or an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but embodiments of the present disclosure are not limited thereto.

In the present disclosure, the number of carbon atoms in a carbonyl group is not specifically limited, for example, may be 1 to 40, 1 to 30, or 1 to 20. For example, the carbonyl group may have the following structures, but embodiments of the present disclosure are not limited thereto.

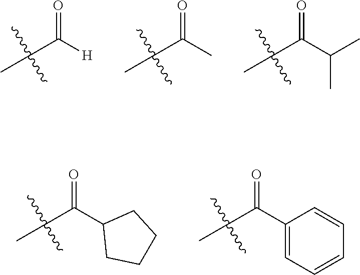

In the present disclosure, the number of carbon atoms in a sulfinyl group or a sulfonyl group is not particularly limited, for example, may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, a thio group may include an alkylthio group and/or an arylthio group. The thio group may refer to that a sulfur atom is bonded to the alkyl group or the aryl group defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, and a naphthylthio group, but embodiments of the present disclosure are not limited thereto.

In the present disclosure, an oxy group may refer to that an oxygen atom is bonded to the alkyl group or the aryl group defined above. The oxy group may include an alkoxy group and/or an aryl oxy group. The alkoxy group may be a linear chain, a branched chain, or a ring. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, and/or the like, but embodiments of the present disclosure are not limited thereto.

A boron group as used herein may refer to that a boron atom is bonded to the alkyl group or the aryl group defined above. The boron group includes an alkyl boron group and/or an aryl boron group. Examples of the boron group may include a dimethylboron group, a diethylboron group, a t-butylmethylboron group, a diphenylboron group, a phenylboron group, and/or the like, but embodiments of the present disclosure are not limited thereto.

In the present disclosure, the number of carbon atoms in an amine group is not specifically limited, for example, may be 1 to 50, 1 to 30, or 1 to 20. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, and/or the like, but embodiments of the present disclosure are not limited thereto. In the present disclosure, the term “amine group” is used interchangeably with the term “amino group.”

In the present disclosure, the alkyl group among an alkylthio group, an alkylsulfoxy group, an alkylaryl group, an alkylamino group, an alkyl boron group, an alkyl silyl group, and an alkyl amine group may be the same as the examples of the alkyl group described above.

In the present disclosure, the aryl group among an aryloxy group, an arylthio group, an arylsulfoxy group, an arylamino group, an arylboron group, an arylsilyl group, an arylamine group may be the same as the examples of the aryl group described above.

In the present disclosure, a direct linkage may refer to a single bond. In the disclosure,

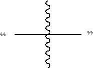

and “ [symbol] ” each refer to a position to be connected.

Hereinafter, embodiments of the disclosure will be described in more detail with reference to the accompanying drawings.

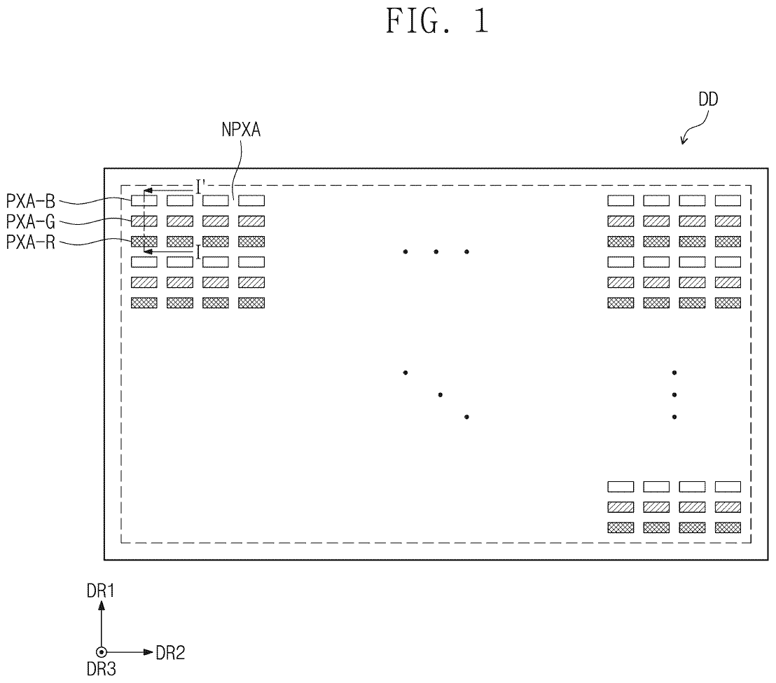

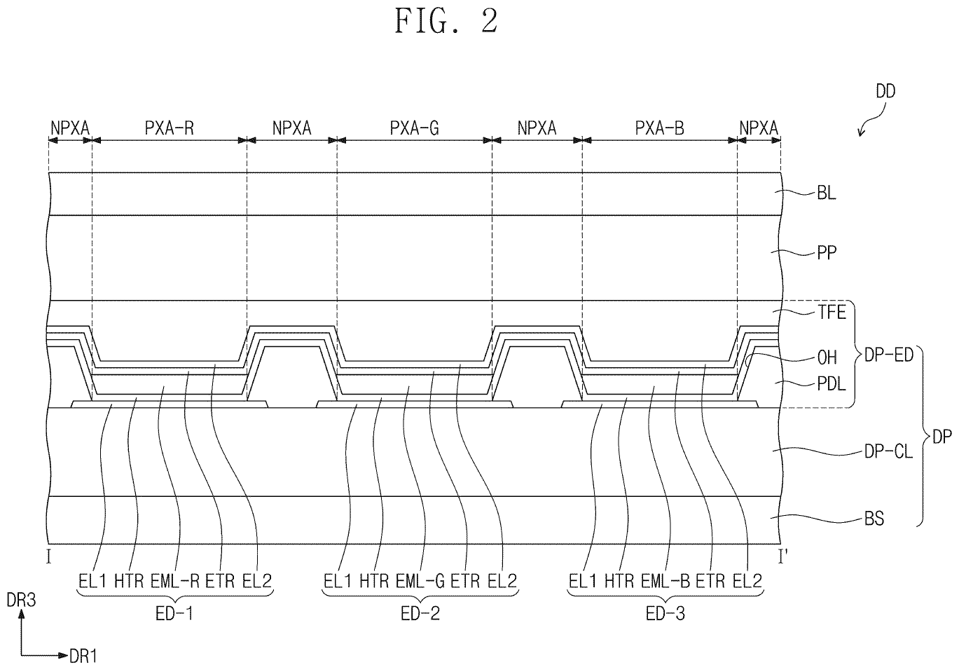

FIG. 1 is a plan view illustrating a display device DD according to one or more embodiments of the present disclosure. FIG. 2 is a cross-sectional view of the display device DD according to one or more embodiments of the present disclosure. FIG. 2 is a cross-sectional view illustrating a part taken along the line I-I′ of the display device DD of FIG. 1.

The display device DD may include a display panel DP and an optical layer PP arranged on the display panel DP. The display panel DP may include light emitting elements ED-1, ED-2, and ED-3. The display device DD may include a plurality of light emitting elements ED-1, ED-2, and ED-3. The optical layer PP may be arranged on the display panel DP to control reflected light in the display panel DP due to external light. The optical layer PP may include, for example, a polarization layer and/or a color filter layer. In one or more embodiments, the optical layer PP may not be provided in the display device DD.

A base substrate BL may be arranged on the optical layer PP. The base substrate BL may be a member which provides a base surface on which the optical layer PP arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

The display device DD according to one or more embodiments may further include a filling layer. The filling layer may be arranged between a display element layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and a display element layer DP-ED. The display element layer DP-ED may include a pixel defining film PDL, the light emitting elements ED-1, ED-2, and ED-3 arranged between respective portions of the pixel defining film PDL, and an encapsulation layer TFE arranged on the light emitting elements ED-1, ED-2, and ED-3.

The base layer BS may be a member which provides a base surface on which the display element layer DP-ED is arranged. The base layer BS may be a glass substrate, a metal substrate, a plastic substrate, and/or the like. However, embodiments of the present disclosure are not limited thereto, and the base layer BS may be an inorganic layer, an organic layer, or a composite material layer.

In one or more embodiments, the circuit layer DP-CL may be arranged on the base layer BS, and the circuit layer DP-CL may include a plurality of transistors. Each of the transistors may include a control electrode, an input electrode, and an output electrode. For example, in one or more embodiments, the circuit layer DP-CL may include switching transistor(s) and driving transistor(s) for driving the light emitting elements ED-1, ED-2, and ED-3 of the display element layer DP-ED.

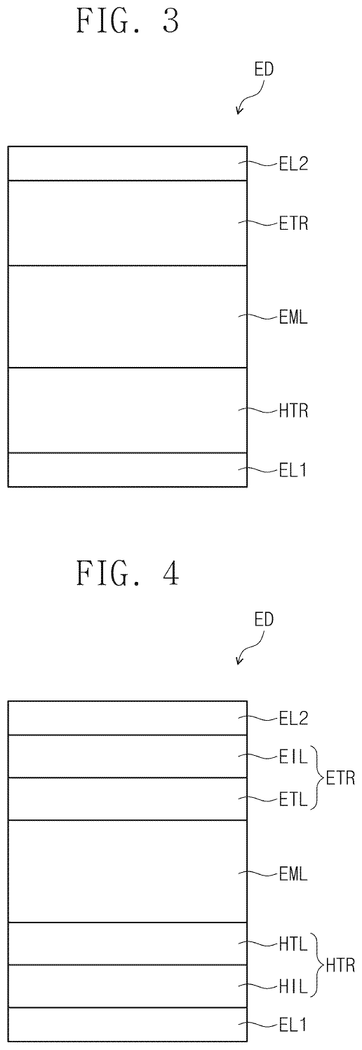

Each of the light emitting elements ED-1, ED-2, and ED-3 may have a structure of one of light emitting elements ED of embodiments according to FIGS. 3 to 6, which will be described in more detail later. Each of the light emitting elements ED-1, ED-2, and ED-3 may include a first electrode EL1, a hole transport region HTR, respective emission layers EML-R, EML-G, and EML-B, an electron transport region ETR, and a second electrode EL2.

FIG. 2 illustrates one or more embodiments in which the respective emission layers EML-R, EML-G, and EML-B of the light emitting elements ED-1, ED-2, and ED-3 are arranged in openings OH defined in the pixel defining film PDL, and the hole transport region HTR, the electron transport region ETR, and the second electrode EL2 are each provided as a common layer across the entire light emitting elements ED-1, ED-2, and ED-3. However, embodiments of the present disclosure are not limited thereto, for example, in one or more embodiments, the hole transport region HTR and the electron transport region ETR may each be provided by being patterned inside the openings OH defined in the pixel defining film PDL. For example, in one or more embodiments, the hole transport region HTR, the respective emission layers EML-R, EML-G, and EML-B, and the electron transport region ETR of the light emitting elements ED-1, ED-2, and ED-3 may be provided by being patterned in an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed by laminating one layer or a plurality of layers. The encapsulation layer TFE may include at least one insulation layer. The encapsulation layer TFE according to one or more embodiments may include at least one inorganic film (hereinafter, an encapsulation-inorganic film). The encapsulation layer TFE according to one or more embodiments may include at least one organic film (hereinafter, an encapsulation-organic film) and at least one encapsulation-inorganic film.

The encapsulation-inorganic film protects the display element layer DP-ED from moisture/oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, and/or the like, but embodiments of the present disclosure are not particularly limited thereto. In one or more embodiments, the encapsulation-organic film may include an acrylic-based compound, an epoxy-based compound, and/or the like. In one or more embodiments, the encapsulation-organic film may include a photopolymerizable organic material, but embodiments of the present disclosure are not particularly limited thereto.

The encapsulation layer TFE may be arranged on the second electrode EL2 and may be arranged filling the opening OH.

Referring to FIG. 1 and FIG. 2, the display device DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced and/or apart (e.g., spaced apart or separated) from one another on a plane (e.g., a plan view).

Each of the light emitting regions PXA-R, PXA-G, and PXA-B may be a region divided by the pixel defining film PDL. The non-light emitting areas NPXA may be areas between adjacent light emitting regions PXA-R, PXA-G, and PXA-B, which correspond to the pixel defining film PDL. In one or more embodiments, the light emitting regions PXA-R, PXA-G, and PXA-B may respectively correspond to pixels. The pixel defining film PDL may divide the light emitting elements ED-1, ED-2, and ED-3. The respective emission layers EML-R, EML-G, and EML-B of the light emitting elements ED-1, ED-2, and ED-3 may be arranged in openings OH defined in the pixel defining film PDL and separated from one another.

The light emitting regions PXA-R, PXA-G, and PXA-B may be divided into a plurality of groups according to the color of light generated from the light emitting elements ED-1, ED-2, and ED-3. In the display device DD of one or more embodiments illustrated in FIG. 1 and FIG. 2, three light emitting regions PXA-R, PXA-G, and PXA-B, which emit red light, green light, and blue light, respectively, are exemplarily illustrated. For example, the display device DD of one or more embodiments may include a red light emitting region PXA-R, a green light emitting region PXA-G, and a blue light emitting region PXA-B that are separated from one another.

In the display device DD according to one or more embodiments, the plurality of light emitting elements ED-1, ED-2, and ED-3 may be to emit light beams having wavelengths different from one another. For example, in one or more embodiments, the display device DD may include a first light emitting element ED-1 that emits red light, a second light emitting element ED-2 that emits green light, and a third light emitting element ED-3 that emits blue light. For example, in one or more embodiments, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, embodiments of the present disclosure are not limited thereto, and the first to third light emitting elements ED-1, ED-2, and ED-3 may be to emit light beams in substantially the same wavelength range or at least one light emitting element may be to emit a light beam in a wavelength range different from the others. For example, in one or more embodiments, the first to third light emitting elements ED-1, ED-2, and ED-3 may all emit blue light.

The light emitting regions PXA-R, PXA-G, and PXA-B in the display device DD according to one or more embodiments may be arranged in a stripe form. Referring to FIG. 1, a plurality of red light emitting regions PXA-R may be arranged with each other along a second direction axis DR2, a plurality of green light emitting regions PXA-G may be arranged with each other along the second direction axis DR2, and a plurality of blue light emitting regions PXA-B may be arranged with each other along the second direction axis DR2. In addition, the red light emitting region PXA-R, the green light emitting region PXA-G, and the blue light emitting region PXA-B may be alternately arranged in this order along a first direction axis DR1.

FIG. 1 and FIG. 2 illustrate that all the light emitting regions PXA-R, PXA-G, and PXA-B have similar area, but embodiments of the present disclosure are not limited thereto. Thus, the light emitting regions PXA-R, PXA-G, and PXA-B may have different areas from one another according to the wavelength range of the emitted light. In this regard, the areas of the light emitting regions PXA-R, PXA-G, and PXA-B may refer to areas when viewed on a plane defined by the first direction axis DR1 and the second direction axis DR2 (e.g., the areas in a plan view).

In one or more embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality desired or required in the display device DD. For example, in one or more embodiments, the arrangement form of the light emitting regions PXA-R, PXA-G, and PXA-B may be a pentile (PENTILE®) arrangement form (for example, an RGBG matrix, an RGBG structure, or an RGBG matrix structure) or a diamond (Diamond Pixel™) arrangement form (e.g., a display (e.g., an OLED display) containing red, blue, and green (RGB) light-emitting regions arranged in the shape of diamonds). PENTILE® is a duly registered trademark of Samsung Display Co., Ltd. Diamond Pixel™ is a trademark of Samsung Display Co., Ltd.

In one or more embodiments, the areas of the light emitting regions PXA-R, PXA-G, and PXA-B may be different from one another. For example, in one or more embodiments, the area of the green light emitting region PXA-G may be smaller than that of the blue light emitting region PXA-B, but embodiments of the present disclosure are not limited thereto.

Hereinafter, FIG. 3 to FIG. 6 are each a cross-sectional view schematically showing a light emitting element according to one or more embodiments of the present disclosure. The light emitting element ED of one or more embodiments may include a first electrode EL1, a hole transport region HTR, an emission layer EML, an electron transport region ETR, and a second electrode EL2 stacked in order (e.g., in the stated order).

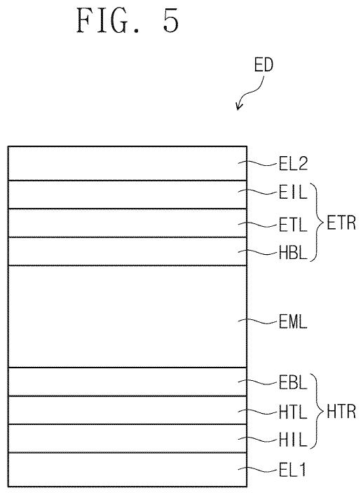

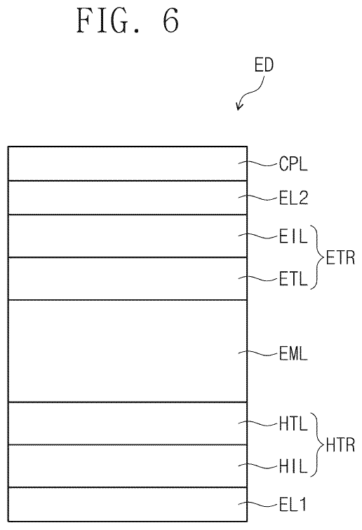

Compared with FIG. 3, FIG. 4 illustrates a cross-sectional view of a light emitting element ED of one or more embodiments, in which a hole transport region HTR includes a hole injection layer HIL and a hole transport layer HTL, and an electron transport region ETR includes an electron injection layer EIL and an electron transport layer ETL. In addition, compared with FIG. 3, FIG. 5 illustrates a cross-sectional view of a light emitting element ED of one or more embodiments, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In one or more embodiments, the hole injection layer HIL may not be provided in the hole transport region HTR. Compared with FIG. 4, FIG. 6 illustrates a cross-sectional view of a light emitting element ED of one or more embodiments including a capping layer CPL arranged on a second electrode EL2.

The first electrode EL1 has conductivity (e.g., is a conductor). The first electrode EL1 may be formed of a metal material, a metal alloy, and/or a conductive compound. The first electrode EL1 may be an anode or a cathode. However, embodiments of the present disclosure are not limited thereto. In one or more embodiments, the first electrode EL1 may be a pixel electrode. The first electrode EL1 may be a transmissive electrode, a transflective electrode, or a reflective electrode. The first electrode EL1 may include at least one selected from among silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), a compound of two or more selected therefrom, a mixture of two or more selected therefrom, or an oxide thereof.

If (e.g., when) the first electrode EL1 is a transmissive electrode, the first electrode EL1 may include a transparent metal oxide such as indium tin oxide (ITO), indium zinc oxide (IZO), zinc oxide (ZnO), and/or indium tin zinc oxide (ITZO). If (e.g., when) the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In one or more embodiments, the first electrode EL1 may have a multilayer structure including a reflective film or a transflective film formed of one or more of the above-described materials, and a transparent conductive film formed of ITO, IZO, ZnO, ITZO, and/or the like. For example, in one or more embodiments, the first electrode EL1 may have a three-layer structure of ITO/Ag/ITO, but embodiments of the present disclosure are not limited thereto. In one or more embodiments, the first electrode EL1 may include one of the above-described metal materials, one or more combinations of at least two metal materials of the above-described metal materials, any oxide of the above-described metal materials, and/or the like. A thickness of the first electrode EL1 may be from about 700 ångströms (Å) to about 10,000 Å. For example, in one or more embodiments, the thickness of the first electrode EL1 may be from about 1,000 Å to about 3,000 Å.

The hole transport region HTR may be provided on the first electrode EL1. The hole transport region HTR may include at least one of a hole injection layer HIL, a hole transport layer HTL, a buffer layer or an emission-auxiliary layer, or an electron blocking layer EBL. A thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, in one or more embodiments, the hole transport region HTR may have a single layer structure of a hole injection layer HIL or a hole transport layer HTL, or may have a single layer structure formed of a hole injection material and/or a hole transport material. In one or more embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order (e.g., in the stated order) from the first electrode EL1, but embodiments of the present disclosure are not limited thereto.

The hole transport region HTR may be formed using one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the hole transport region HTR may include a compound represented by Formula H-1:

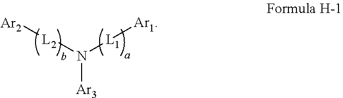

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer of 0 to 10. In one or more embodiments, if (e.g., when) a or b is an integer of 2 or greater, a plurality of L₁'s and/or a plurality of L₂'s may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In addition, in Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In one or more embodiments, the compound represented by Formula H-1 may be a monoamine compound. In one or more embodiments, the compound represented by Formula H-1 may be a diamine compound in which at least one selected from among Ar₁ to Ar₃ includes an amine group as a substituent. In one or more embodiments, the compound represented by Formula H-1 may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-1 may be any one selected from among compounds in Compound Group H. However, the compounds listed in Compound Group H are mere examples, and the compounds represented by Formula H-1 are not limited to those represented in Compound Group H:

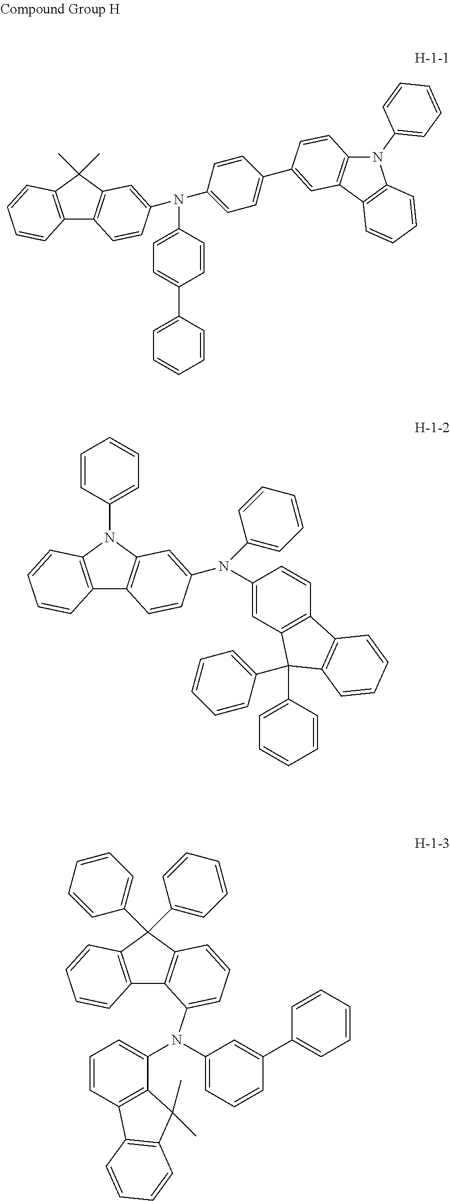 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

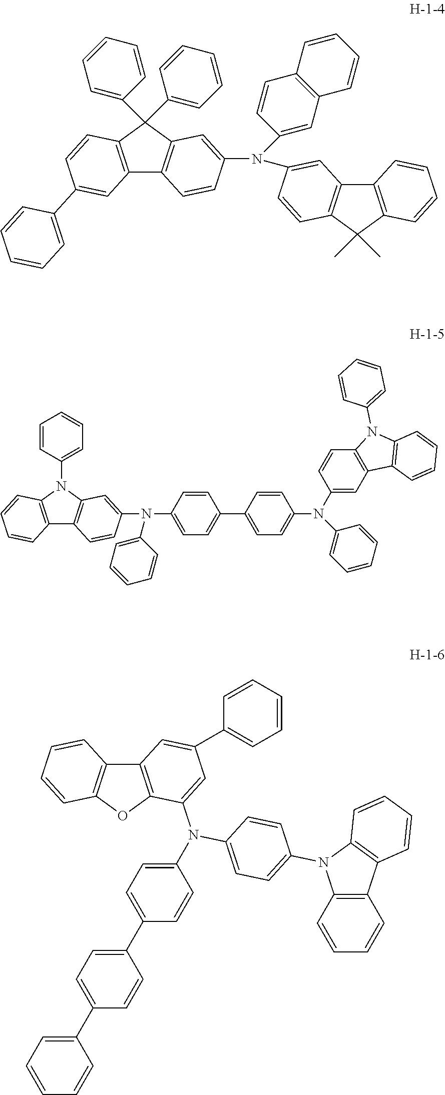 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

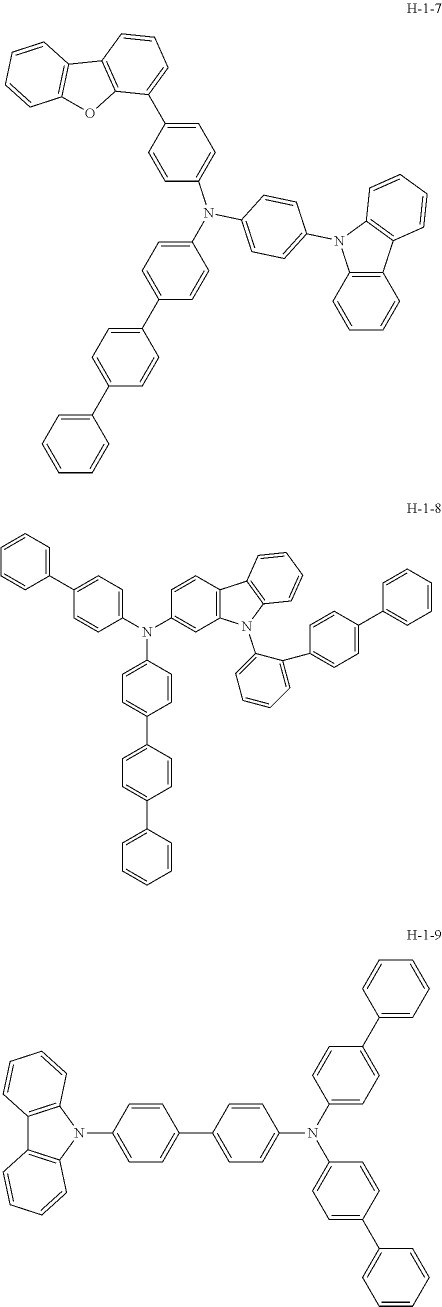 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

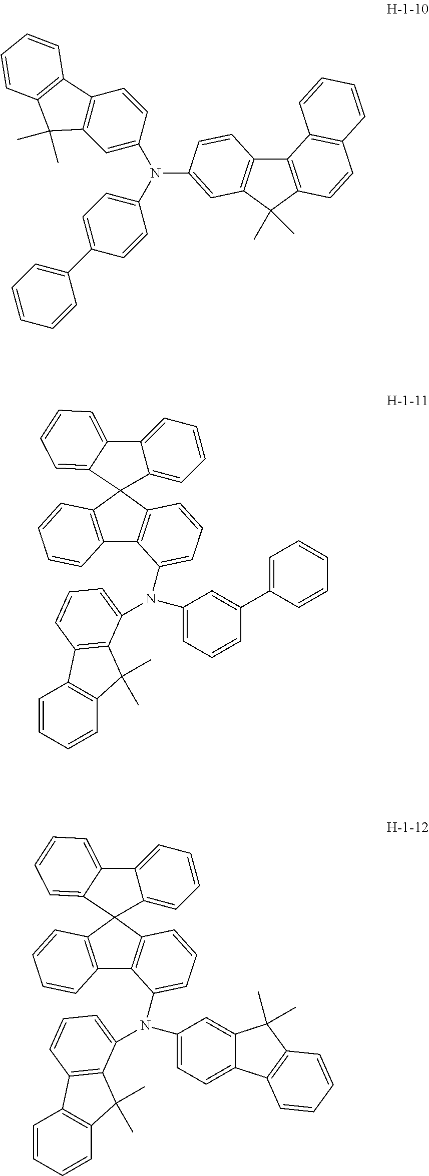 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21]

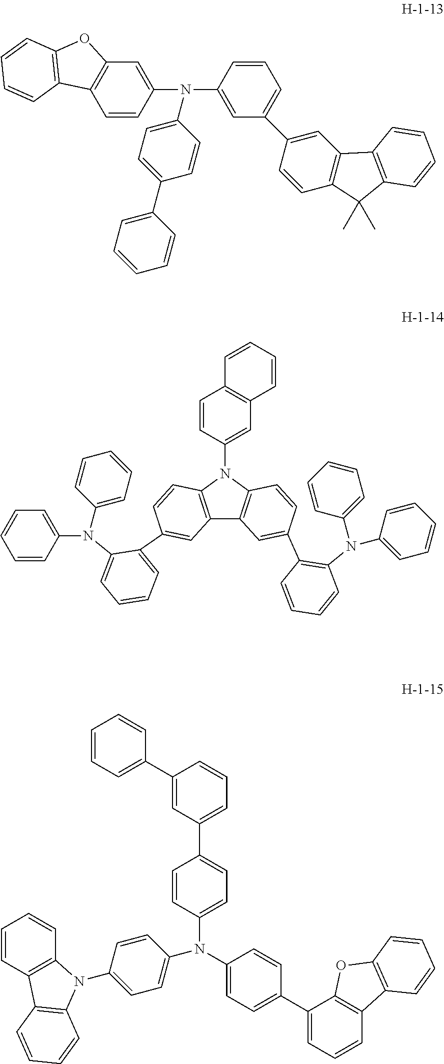 [SMILES: CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

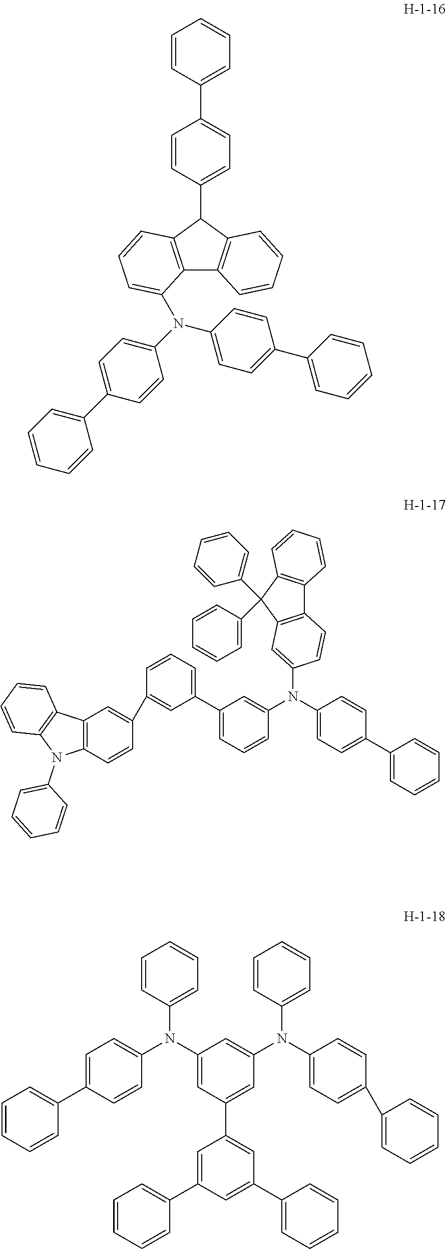 [SMILES: c1ccc(-c2ccc(C3c4ccccc4-c4c3cccc4N(c3ccc(-c4ccccc4)cc3)c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

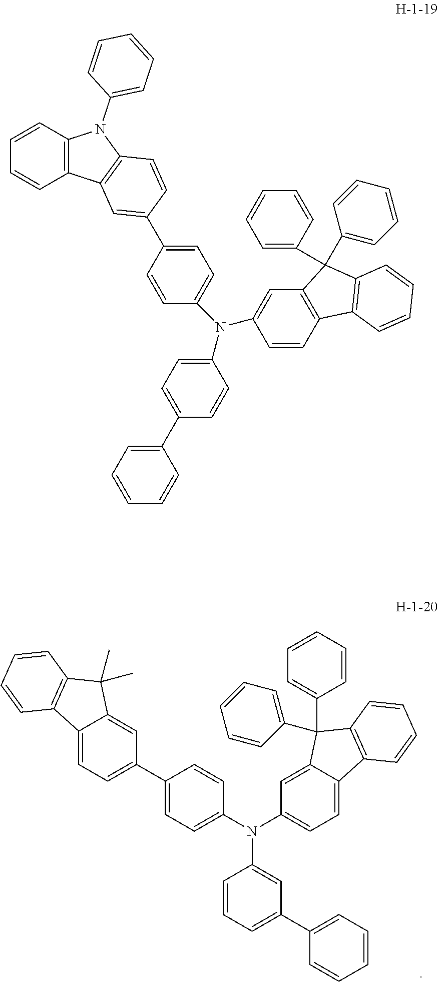 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; CC1(C)c2ccccc2-c2ccc(-c3ccc(N(c4cccc(-c5ccccc5)c4)c4ccc5c(c4)C(c4ccccc4)(c4ccccc4)c4ccccc4-5)cc3)cc21]

In one or more embodiments, the hole transport region HTR may include one or more selected from among a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalen-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HAT-CN), and/or the like.

In one or more embodiments, the hole transport region HTR may include one or more selected from among a carbazole-based derivative such as N-phenyl carbazole and/or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) and/or 4,4′,4″-tris(N-carbazolyl)triphenylamine (TCTA), N,N′-di(naphthalen-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), and/or the like.

In one or more embodiments, the hole transport region HTR may include one or more selected from among 9-(4-tert-butylphenyl)-3,6-bis(trphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

The hole transport region HTR may include one or more of the above-described compounds of the hole transport region in at least one of a hole injection layer HIL, a hole transport layer HTL, or an electron blocking layer EBL.

A thickness of the hole transport region HTR may be from about 100 Å to about 10,000 Å, for example, from about 100 Å to about 5,000 Å. If (e.g., when) the hole transport region HTR includes a hole injection layer HIL, the hole injection layer HIL may have, for example, a thickness of about 30 Å to about 1,000 Å. If (e.g., when) the hole transport region HTR includes a hole transport layer HTL, the hole transport layer HTL may have a thickness of about 30 Å to about 1,000 Å. For example, if (e.g., when) the hole transport region HTR includes an electron blocking layer EBL, the electron blocking layer EBL may have a thickness of about 10 Å to about 1,000 Å. If (e.g., when) the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

In one or more embodiments, the hole transport region HTR may further include a charge generating material to increase conductivity (e.g., electric conductivity) in addition to the above-described materials. The charge generating material may be dispersed uniformly (e.g., substantially uniformly) or non-uniformly in the hole transport region HTR. The charge generating material may be, for example, a p-dopant. The p-dopant may include at least one of a halogenated metal compound (e.g., a metal halide), a quinone derivative, a metal oxide, or a cyano group-containing compound, but embodiments of the present disclosure are not limited thereto. For example, in one or more embodiments, the p-dopant may include a metal halide such as CuI and/or RbI, a quinone derivative such as tetracyanoquinodimethane (TCNQ) and/or 2,3,5,6-tetrafluoro-7,7,8,8-tetracyanoquinodimethane (F4-TCNQ), a metal oxide such as tungsten oxide and/or molybdenum oxide, a cyano group-containing compound such as dipyrazino[2,3-f: 2′,3′-h]quinoxaline-2,3,6,7,10,11-hexacarbonitrile (HAT-CN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but embodiments of the present disclosure are not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be included in the hole transport region HTR may be used as a material to be included in the buffer layer. The electron blocking layer EBL is a layer that serves to prevent or reduce electron injection from the electron transport region ETR to the hole transport region HTR.

In one or more embodiments, the emission layer EML may include the first compound of one or more embodiments. The emission layer EML according to one or more embodiments may further include at least one selected from among second to fourth compounds. The second compound may include a fused ring with three rings including a nitrogen atom as a ring-forming atom. The third compound may include a hexagonal (e.g., 6-membered) ring group including at least one nitrogen atom as a ring-forming atom. The fourth compound may include an organometallic complex. The second to fourth compounds will be explained in more detail, later.

In the disclosure, the first compound may be referred to as a fused polycyclic compound of one or more embodiments. The fused polycyclic compound of one or more embodiments may include a fused ring with nine rings, including two nitrogen atoms, one boron atom and a fused heteroatom as ring-forming atoms, as a central structure (e.g., core structure). The fused heteroatom may be a nitrogen atom, an oxygen atom, or a sulfur atom. In addition, the fused polycyclic compound of one or more embodiments may include a biphenyl moiety bonded to the nitrogen atom of the central structure and a cyano group bonded at the para position of a benzene ring with respect to the boron atom. Accordingly, the fused polycyclic compound of one or more embodiments may show excellent or suitable material stability and may contribute to the reduction of the driving voltage of a light emitting element ED and the improvement of efficiency and lifespan of the light emitting element ED.

The light emitting element ED of one or more embodiments may include the fused polycyclic compound of one or more embodiments. The fused polycyclic compound of one or more embodiments may be represented by Formula 1.

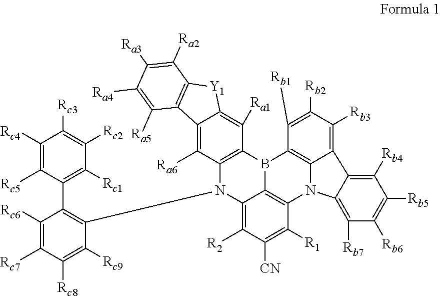

In Formula 1, Y₁ may be NR₃, O, or S. For example, in one or more embodiments, Y₁ may be NPh or O. In these embodiments, Ph refers to an unsubstituted phenyl group.

R₁ to R₃ may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms. For example, in one or more embodiments, R₁ and R₂ may each independently be hydrogen or deuterium.

Rₐ₁ to Rₐ₆, R_{b1} to R_{b7}, and R_{c1} to R_{c9} may each independently be a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring.

For example, in one or more embodiments, any one selected from among Rₐ₁ to Rₐ₆ may be a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, and the remainder may each independently be hydrogen or deuterium. In one or more embodiments, adjacent two groups selected from among Rₐ₁ to Rₐ₆ may be combined with each other to form a ring. However, the above are examples, and embodiments of the disclosure are not limited thereto.

For example, in one or more embodiments, any two selected from among R_{b1} to R_{b7} may be substituted or unsubstituted alkyl groups of 1 to 60 carbon atoms, substituted or unsubstituted aryl groups of 6 to 60 ring-forming carbon atoms, or substituted or unsubstituted heteroaryl groups of 2 to 60 ring-forming carbon atoms, and the remainder may each independently be hydrogen or deuterium. In one or more embodiments, adjacent two groups selected from among R_{b1} to R_{b7} may be combined with each other to form a ring.

In one or more embodiments, at least one selected from among R_{b1} to R_{b7} may be combined with an adjacent group to form a fused ring. The fused ring may be fused with a benzene ring including R_{b1} to R_{b3} and/or a benzene ring including R_{b4} to R_{b7}. The fused ring may be a substituted or unsubstituted aryl group of 6 to 30 ring-forming carbon atoms or a substituted or unsubstituted heteroaryl group including N, O, or S as a ring-forming atom and having 2 to 30 ring-forming carbon atoms. For example, if (e.g., when) the fused ring is a heteroaryl group, the fused ring may be substituted or unsubstituted, include N, O, or S as a ring-forming atom, and have 2 to 30 ring-forming carbon atoms.

For example, in one or more embodiments, R_{c1} to R_{c9} may each independently be a hydrogen atom, a deuterium atom, a substituted or unsubstituted t-butyl group, a substituted or unsubstituted phenyl group, or a substituted or unsubstituted biphenyl group. In Formula 1, a biphenyl moiety including R_{c1} to R_{c9} may be represented b an one selected from among RC-1 to RC-18.

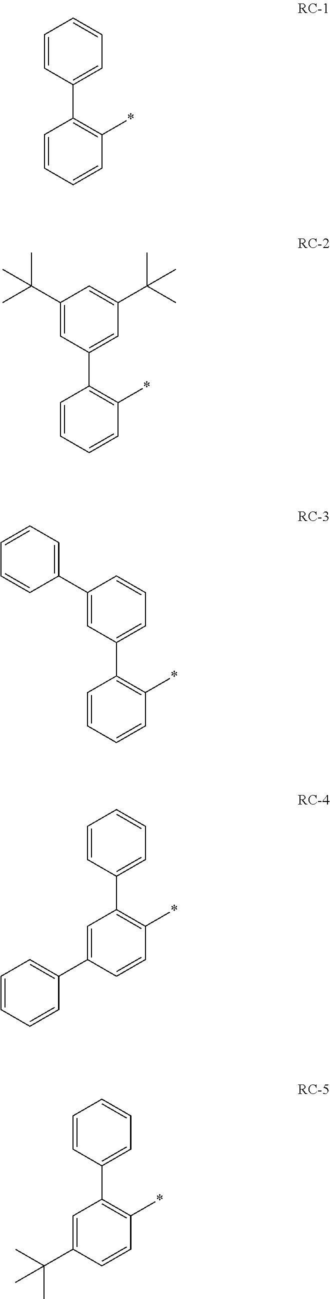

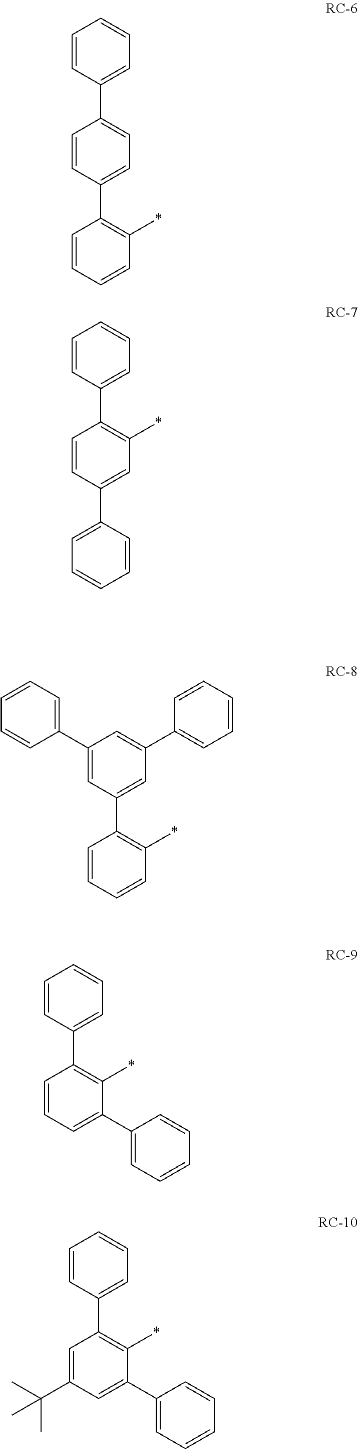

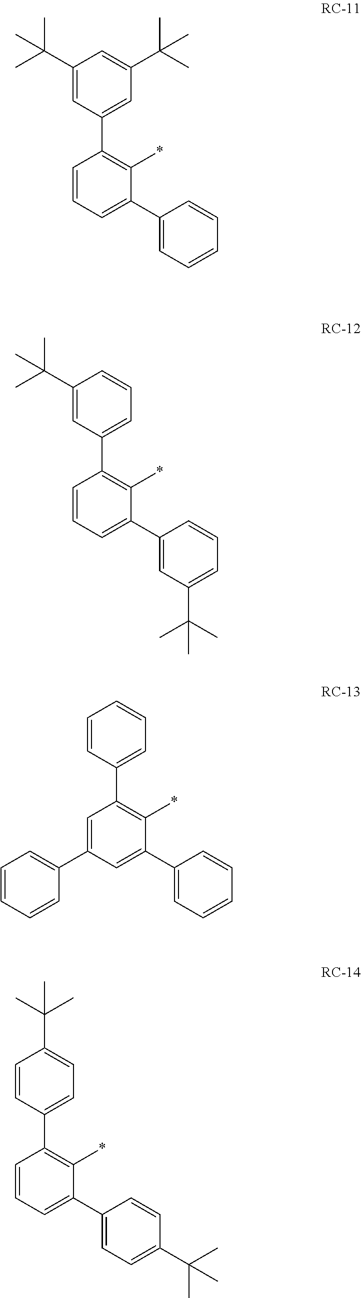 [SMILES: *c1c(-c2ccccc2)cccc1-c1cc(C(C)(C)C)cc(C(C)(C)C)c1 ; *c1c(-c2cccc(C(C)(C)C)c2)cccc1-c1cccc(C(C)(C)C)c1 ; *c1c(-c2ccccc2)cc(-c2ccccc2)cc1-c1ccccc1 ; *c1c(-c2ccc(C(C)(C)C)cc2)cccc1-c1ccc(C(C)(C)C)cc1]

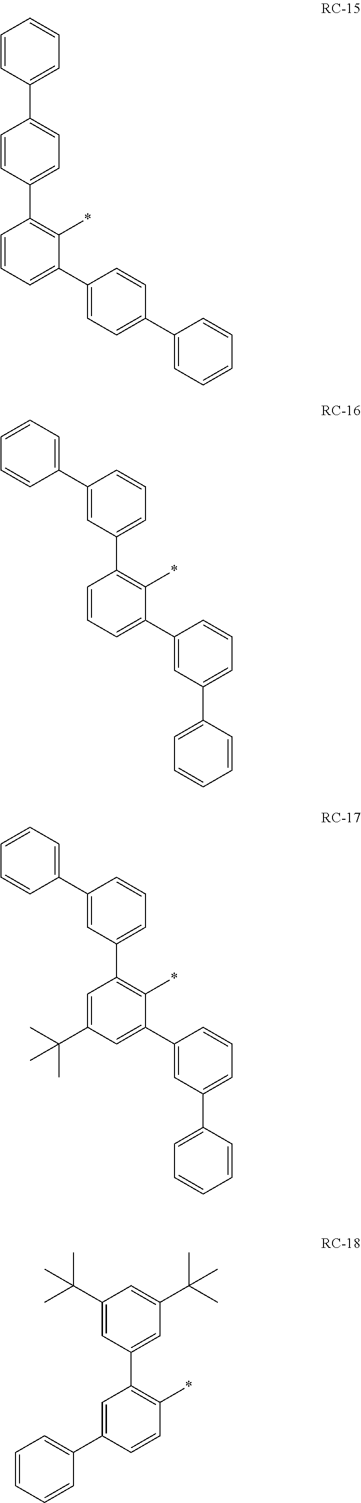 [SMILES: *c1c(-c2ccc(-c3ccccc3)cc2)cccc1-c1ccc(-c2ccccc2)cc1 ; *c1c(-c2cccc(-c3ccccc3)c2)cccc1-c1cccc(-c2ccccc2)c1 ; *c1c(-c2cccc(-c3ccccc3)c2)cc(C(C)(C)C)cc1-c1cccc(-c2ccccc2)c1 ; *c1ccc(-c2ccccc2)cc1-c1cc(C(C)(C)C)cc(C(C)(C)C)c1]

In the fused polycyclic compound of one or more embodiments, any one selected from among R₁ to R₃, Rₐ₁ to Rₐ₆, R_{b1} to R_{b7}, and R_{c1} to R_{c9} may be deuterium or may include a substituent that is substituted with deuterium.

In one or more embodiments, the fused polycyclic compound represented by Formula 1 may be represented by any one selected from among Formula 1-1 to Formula 1-3. Formula 1-1 to Formula 1-3 may each represent Formula 1 where Y₁ is specified.

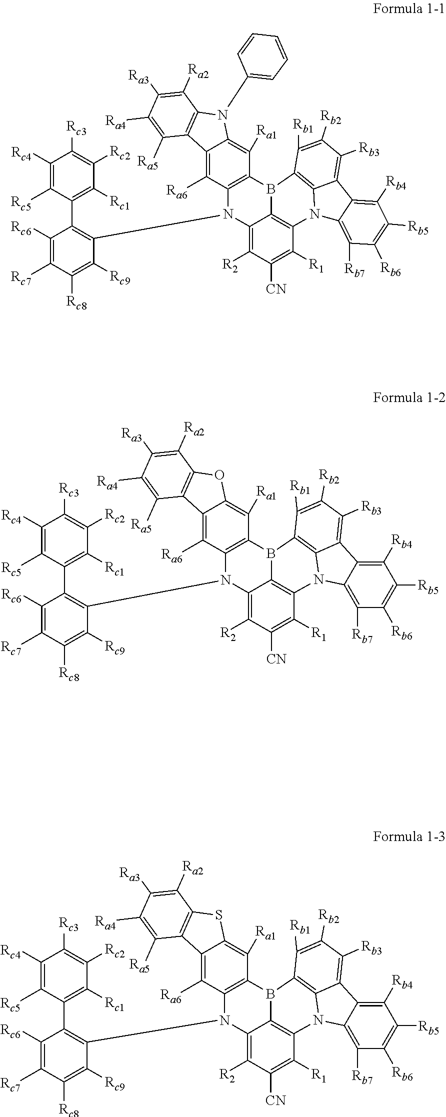

Formula 1-1 may represent Formula 1 where Yⱼ is NR₃, and R₃ is an unsubstituted phenyl group. Formula 1-2 may represent Formula 1 where Y_{J} is 0. Formula 1-3 may represent Formula 1 where Yⱼ is S. In Formula 1-1 to Formula 1-3, the same contents explained in Formula 1 may be applied for R₁, R₂, Rₐ₁ to Rₐ₆, R_{b1} to R_{b7}, and R_{c1} to R_{c9}. In other words, in Formula 1-1 to Formula 1-3, R₁, R₂, Rₐ₁ to Rₐ₆, R_{b1} to R_{b7}, and R_{c1} to R_{c9} may each independently be the same as defined in Formula 1.

In one or more embodiments, the fused polycyclic compound represented by Formula 1 may be represented by Formula 1-A1. Formula 1-A1 may represent Formula 1 where Rₐ₁, Rₐ₂, Rₐ₅, and Rₐ₆ are each hydrogen.

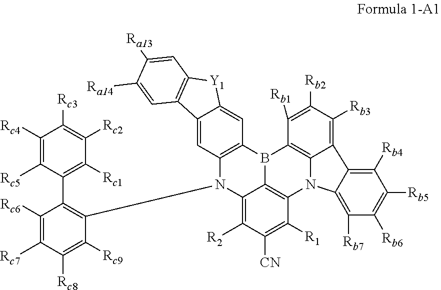

In Formula 1-A1, the same contents explained in Formula 1 may be applied for Y₁, R₁, R₂, R_{b1} to R_{b7}, and R_{c1} to R_{c9}. In other words, in Formula 1-A1, Y₁, R₁, R₂, R_{b1} to R_{b7}, and R_{c1} to R_{c9} may each independently be the same as defined in Formula 1. Rₐ₁₃ and Rₐ₁₄ may each independently be a hydrogen atom, a deuterium atom, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms. For example, in one or more embodiments, any one selected from among Rₐ₁₃ and Rₐ₁₄ may be a hydrogen atom, and the remainder may be a substituted or unsubstituted t-butyl group, a substituted or unsubstituted phenyl group, a substituted or unsubstituted biphenyl group, or a substituted or unsubstituted carbazole group.

In one or more embodiments, the fused polycyclic compound represented by Formula 1 may be represented by Formula 1-A2 or Formula 1-A3. Formula 1-A2 and Formula 1-A3 may each represent Formula 1 where Rₐ₁, Rₐ₂, Rₐ₅, and Rₐ₆ are each a hydrogen atom, and Rₐ₃ and Rₐ₄ are combined with each other to form a ring.

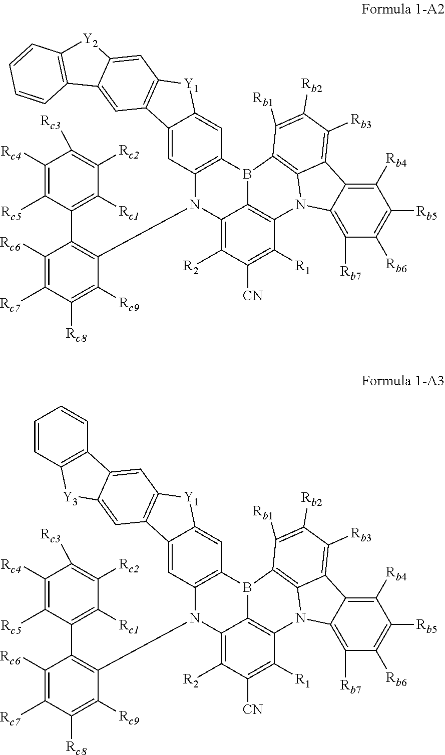

In Formula 1-A2 and Formula 1-A3, the same contents explained in Formula may be applied for Y₁, R₁, R₂, R_{b1} to R_{b7}, and R_{c1} to R_{c9}. In other words, in Formula 1-A2 and Formula 1-A3, Y₁, R₁, R₂, R_{b1} to R_{b7}, and R_{c1} to R_{c9} may each independently be the same as defined in Formula 1. Y₂ and Y₃ may each independently be CR₄R₅, O, or S. R₄ and R₅ may each independently be a hydrogen atom, a deuterium atom, a substituted or unsubstituted alkyl group of 1 to 30 carbon atoms, or a substituted or unsubstituted aryl group of 6 to 30 ring-forming carbon atoms. For example, in one or more embodiments, R₄ and R₅ may each independently be a substituted or unsubstituted phenyl group.

In one or more embodiments, the fused polycyclic compound represented by Formula 1 may be represented by Formula 1-B1 or Formula 1-B2. Formula 1-B1 may represent Formula 1 where R_{b2} to R_{b5} and R_{b7} are each hydrogen. Formula 1-B2 may represent Formula 1 where R_{b1}, R_{b3}, R_{b4}, R_{b6}, and R_{b7} are each hydrogen.

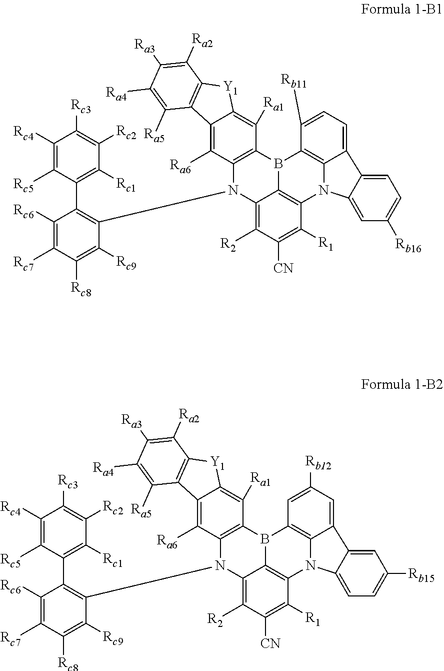

In Formula 1-B1 and Formula 1-B2, the contents explained in Formula 1 may be applied for Y₁, R₁, R₂, Rₐ₁ to Rₐ₆, and R_{c1} to R_{c9}. In other words, in Formula 1-B1 and Formula 1-B2, Y₁, R₁, R₂, Rₐ₁ to Rₐ₆, and Roi to Rog may each independently be the same as defined in Formula 1. R_{b11}, R_{b12}, R_{b15}, and R_{b16} may each independently be a hydrogen atom, a deuterium atom, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms. For example, in one or more embodiments, R_{b11}, R_{b12}, R_{b15}, and R_{b16} may each independently be a hydrogen atom, a deuterium atom, a substituted or unsubstituted t-butyl group, a substituted or unsubstituted phenyl group, or a substituted or unsubstituted biphenyl group.

In one or more embodiments, the fused polycyclic compound represented by Formula 1 may be represented by any one selected from among Formula 1-B3 to Formula 1-B8. Formula 1B-3 to Formula 1-B38 may represent embodiments in which at least one selected from among R_{b1} to R_{b7} is combined with an adjacent group to form a fused ring. Formula 1-B3 to Formula 1-B8 may each represent Formula 1 where adjacent two groups selected from among R_{b1} to R_{b7} are combined with each other to form a ring.

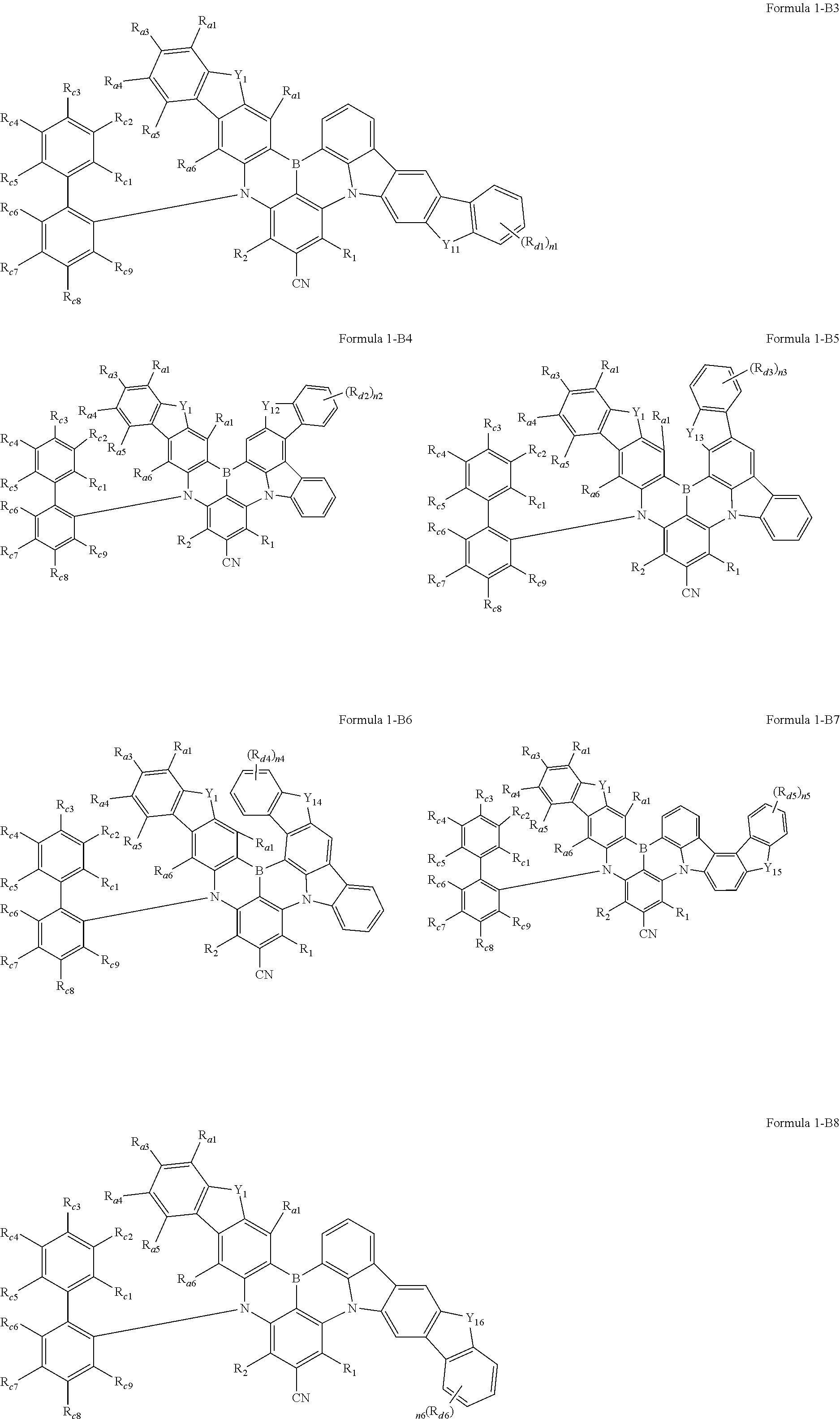

In Formula 1-B3 to Formula 1-B8, the same contents explained in Formula 1 may be applied for Y₁, R₁, R₂, Rₐ₁ to Rₐ₆, and R_{c1} to R_{c9}. In other words, in Formula 1-B3 to Formula 1-B8, Y₁, R₁, R₂, Rₐ₁ to Rₐ₆, and R_{c1} to R_{c9} may each independently be the same as defined in Formula 1.

In Formula 1-B3 to Formula 1-B8, Y₁₁ to Y₁₆ may each independently be CR₁₁R₁₂, NR₁₃, O, or S. R₁₁ to R₁₃ and R_{d1} to R_{d6} may each independently be a hydrogen atom, a deuterium atom, or a substituted or unsubstituted aryl group of 6 to 60 ring-forming carbon atoms. For example, in one or more embodiments, R₁₁ to R₁₃ may each independently be a substituted or unsubstituted phenyl group. R_{d1} to R_{d5} may each independently be a hydrogen atom, a deuterium atom, or a substituted or unsubstituted phenyl group.

In Formula 1-B3 to Formula 1-B8, n1 to n6 may each independently be an integer of 0 to 4. If (e.g., when) n1 is an integer of 2 or greater, multiple R_{d}1's may be the same, or at least one thereof may be different. An embodiment in which n1 is 4, and four R_{d1}'s are each a hydrogen atom, may be the same as an embodiment in which n1 is 0. If (e.g., when) n2 is an integer of 2 or greater, multiple R_{d2}'s may be the same, or at least one thereof may be different. An embodiment in which n2 is 4, and four R_{d2}'s are each a hydrogen atom, may be the same as an embodiment in which n2 is 0. If (e.g., when) n3 is an integer of 2 or greater, multiple R_{d3}'s may be the same, or at least one thereof may be different. An embodiment in which n3 is 4, and four R_{d3}'s are each a hydrogen atom, may be the same as an embodiment in which n3 is 0. If (e.g., when) n4 is an integer of 2 or greater, multiple R_{d4}'s may be the same, or at least one thereof may be different. An embodiment in which n4 is 4, and four R_{d4}'s are each a hydrogen atom, may be the same as an embodiment in which n4 is 0. If (e.g., when) n5 is an integer of 2 or greater, multiple R_{d}s's may be the same, or at least one thereof may be different. An embodiment in which n5 is 4, and four R_{d5}'s are each a hydrogen atom, may be the same as an embodiment in which n5 is 0. If (e.g., when) n6 is an integer of 2 or greater, multiple R_{d6}'s may be the same, or at least one thereof may be different. An embodiment in which n6 is 4, and four R_{d6}'s are each a hydrogen atom, may be the same as an embodiment in which n6 is 0.

The fused polycyclic compound represented by Formula 1 may be any one selected from among compounds in Compound Group 1. The fused polycyclic compound of one or more embodiments may be represented by any one selected from among the compounds in Compound Group 1. The light emitting element ED of one or more embodiments may include at least one selected from among the compounds of Compound Group 1.

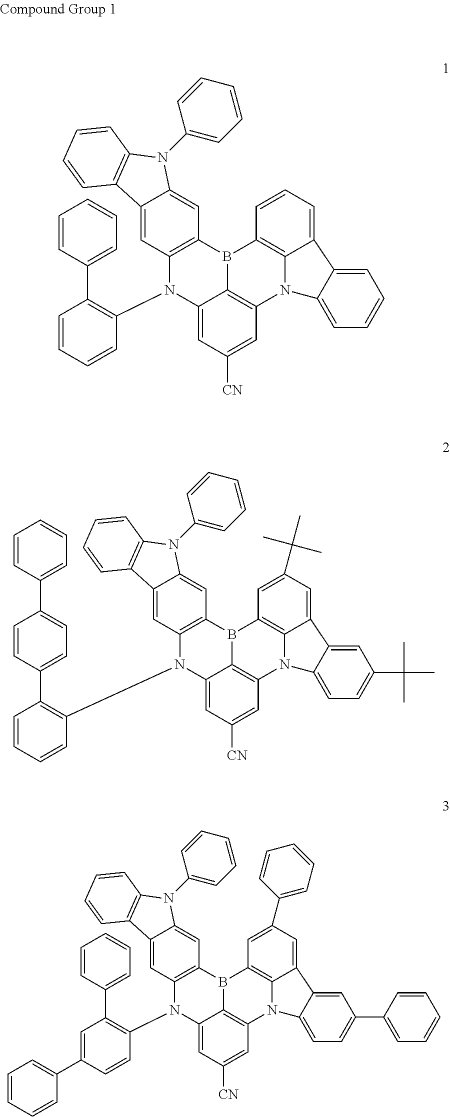 [SMILES: N#Cc1cc2c3c(c1)-n1c4ccccc4c4cccc(c41)B3c1cc3c(cc1N2c1ccccc1-c1ccccc1)c1ccccc1n3-c1ccccc1 ; CC(C)(C)c1ccc2c(c1)c1cc(C(C)(C)C)cc3c1n2-c1cc(C#N)cc2c1B3c1cc3c(cc1N2c1ccccc1-c1ccc(-c2ccccc2)cc1)c1ccccc1n3-c1ccccc1 ; N#Cc1cc2c3c(c1)-n1c4ccc(-c5ccccc5)cc4c4cc(-c5ccccc5)cc(c41)B3c1cc3c(cc1N2c1ccc(-c2ccccc2)cc1-c1ccccc1)c1ccccc1n3-c1ccccc1]

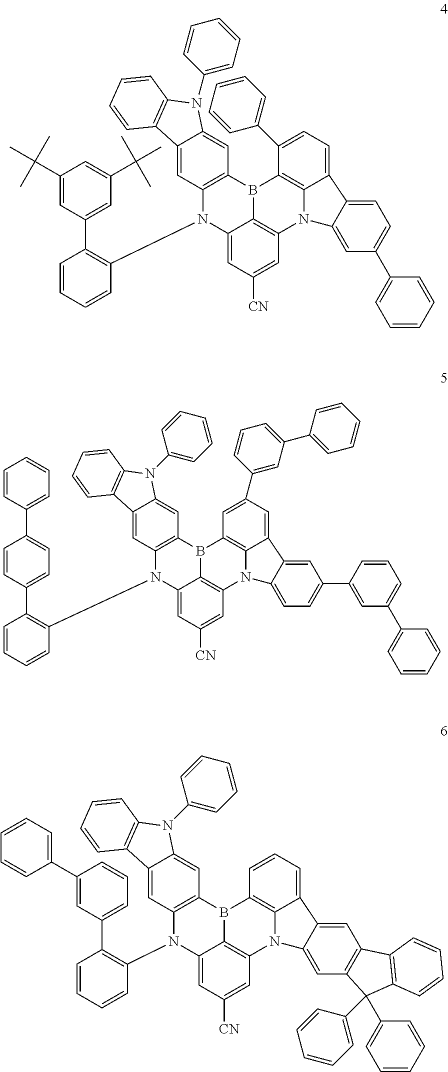 [SMILES: CC(C)(C)c1cc(-c2ccccc2N2c3cc4c5ccccc5n(-c5ccccc5)c4cc3B3c4c2cc(C#N)cc4-n2c4cc(-c5ccccc5)ccc4c4ccc(-c5ccccc5)c3c42)cc(C(C)(C)C)c1 ; N#Cc1cc2c3c(c1)-n1c4ccc(-c5cccc(-c6ccccc6)c5)cc4c4cc(-c5cccc(-c6ccccc6)c5)cc(c41)B3c1cc3c(cc1N2c1ccccc1-c1ccc(-c2ccccc2)cc1)c1ccccc1n3-c1ccccc1 ; N#Cc1cc2c3c(c1)-n1c4cc5c(cc4c4cccc(c41)B3c1cc3c(cc1N2c1ccccc1-c1cccc(-c2ccccc2)c1)c1ccccc1n3-c1ccccc1)-c1ccccc1C5(c1ccccc1)c1ccccc1]

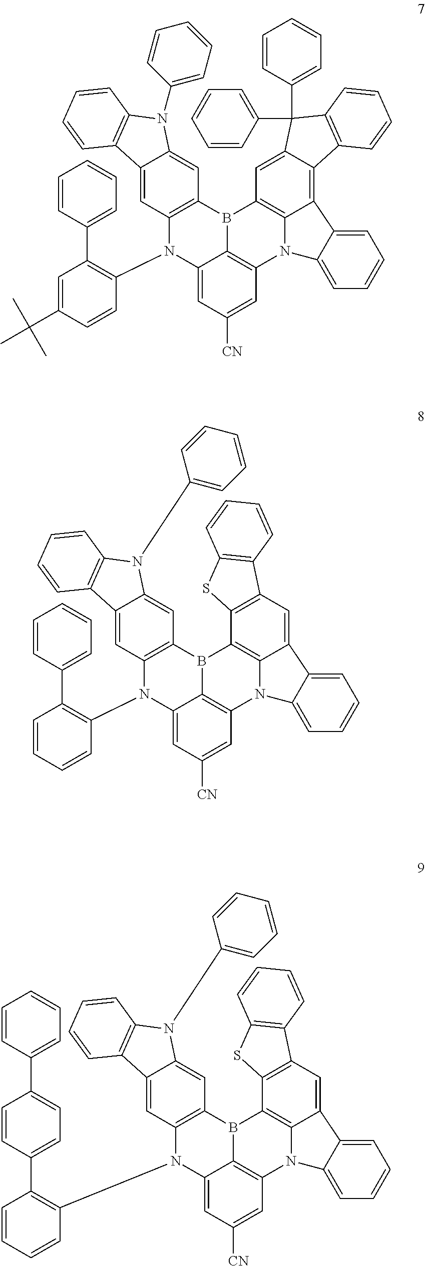 [SMILES: CC(C)(C)c1ccc(N2c3cc4c5ccccc5n(-c5ccccc5)c4cc3B3c4c2cc(C#N)cc4-n2c4ccccc4c4c5c(cc3c42)C(c2ccccc2)(c2ccccc2)c2ccccc2-5)c(-c2ccccc2)c1 ; N#Cc1cc2c3c(c1)-n1c4ccccc4c4cc5c(sc6ccccc65)c(c41)B3c1cc3c(cc1N2c1ccccc1-c1ccccc1)c1ccccc1n3-c1ccccc1 ; N#Cc1cc2c3c(c1)-n1c4ccccc4c4cc5c(sc6ccccc65)c(c41)B3c1cc3c(cc1N2c1ccccc1-c1ccc(-c2ccccc2)cc1)c1ccccc1n3-c1ccccc1]

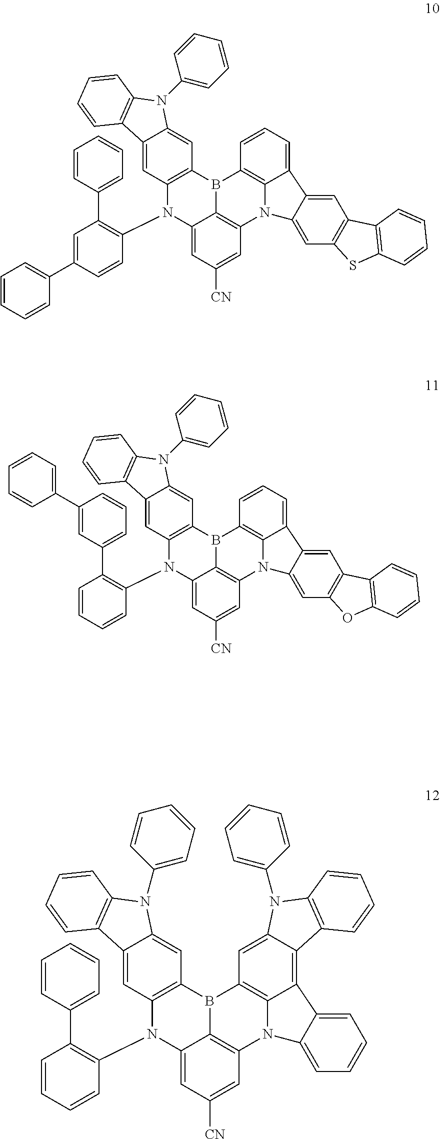 [SMILES: N#Cc1cc2c3c(c1)-n1c4cc5sc6ccccc6c5cc4c4cccc(c41)B3c1cc3c(cc1N2c1ccc(-c2ccccc2)cc1-c1ccccc1)c1ccccc1n3-c1ccccc1 ; N#Cc1cc2c3c(c1)-n1c4cc5oc6ccccc6c5cc4c4cccc(c41)B3c1cc3c(cc1N2c1ccccc1-c1cccc(-c2ccccc2)c1)c1ccccc1n3-c1ccccc1 ; N#Cc1cc2c3c(c1)-n1c4ccccc4c4c5c6ccccc6n(-c6ccccc6)c5cc(c41)B3c1cc3c(cc1N2c1ccccc1-c1ccccc1)c1ccccc1n3-c1ccccc1]

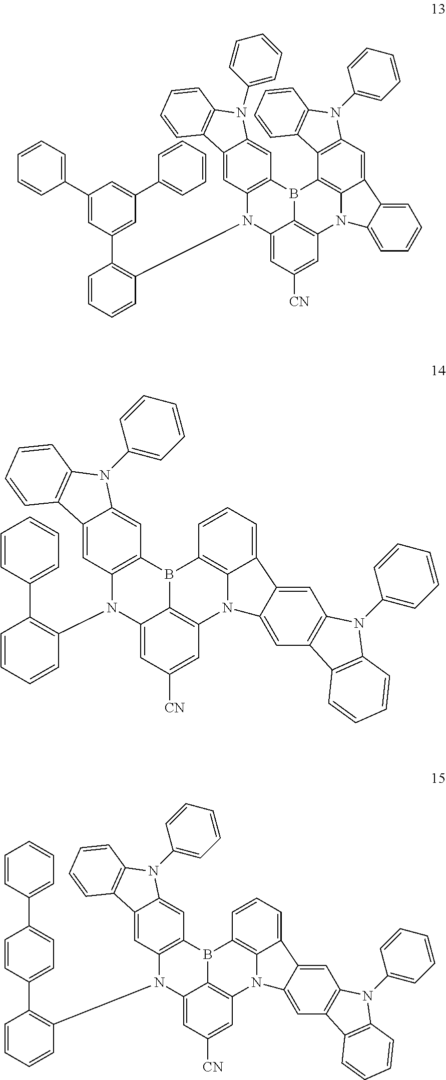 [SMILES: N#Cc1cc2c3c(c1)-n1c4ccccc4c4cc5c(c(c41)B3c1cc3c(cc1N2c1ccccc1-c1cc(-c2ccccc2)cc(-c2ccccc2)c1)c1ccccc1n3-c1ccccc1)c1ccccc1n5-c1ccccc1 ; N#Cc1cc2c3c(c1)-n1c4cc5c6ccccc6n(-c6ccccc6)c5cc4c4cccc(c41)B3c1cc3c(cc1N2c1ccccc1-c1ccccc1)c1ccccc1n3-c1ccccc1 ; N#Cc1cc2c3c(c1)-n1c4cc5c6ccccc6n(-c6ccccc6)c5cc4c4cccc(c41)B3c1cc3c(cc1N2c1ccccc1-c1ccc(-c2ccccc2)cc1)c1ccccc1n3-c1ccccc1]

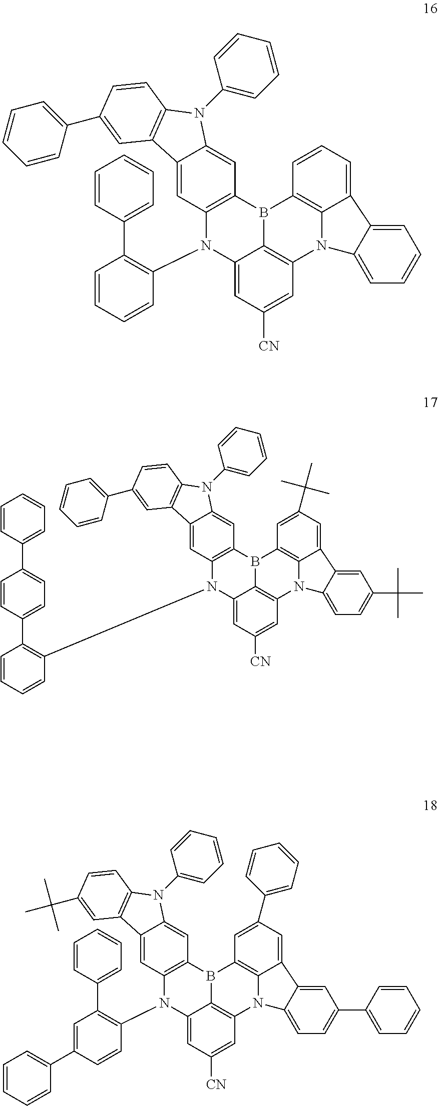 [SMILES: N#Cc1cc2c3c(c1)-n1c4ccccc4c4cccc(c41)B3c1cc3c(cc1N2c1ccccc1-c1ccccc1)c1cc(-c2ccccc2)ccc1n3-c1ccccc1 ; CC(C)(C)c1ccc2c(c1)c1cc(C(C)(C)C)cc3c1n2-c1cc(C#N)cc2c1B3c1cc3c(cc1N2c1ccccc1-c1ccc(-c2ccccc2)cc1)c1cc(-c2ccccc2)ccc1n3-c1ccccc1 ; CC(C)(C)c1ccc2c(c1)c1cc3c(cc1n2-c1ccccc1)B1c2c(cc(C#N)cc2-n2c4ccc(-c5ccccc5)cc4c4cc(-c5ccccc5)cc1c42)N3c1ccc(-c2ccccc2)cc1-c1ccccc1]

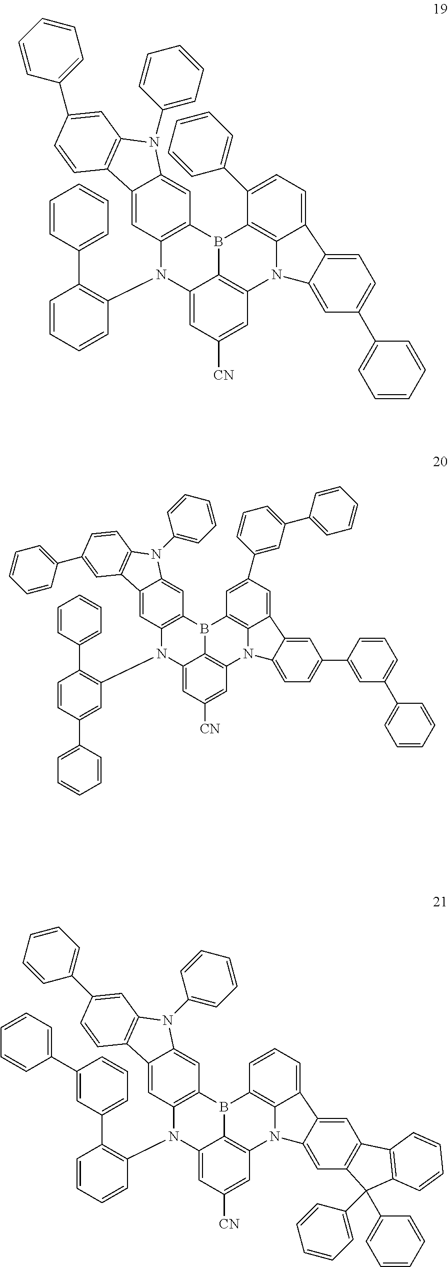 [SMILES: N#Cc1cc2c3c(c1)-n1c4cc(-c5ccccc5)ccc4c4ccc(-c5ccccc5)c(c41)B3c1cc3c(cc1N2c1ccccc1-c1ccccc1)c1ccc(-c2ccccc2)cc1n3-c1ccccc1 ; N#Cc1cc2c3c(c1)-n1c4ccc(-c5cccc(-c6ccccc6)c5)cc4c4cc(-c5cccc(-c6ccccc6)c5)cc(c41)B3c1cc3c(cc1N2c1cc(-c2ccccc2)ccc1-c1ccccc1)c1cc(-c2ccccc2)ccc1n3-c1ccccc1 ; N#Cc1cc2c3c(c1)-n1c4cc5c(cc4c4cccc(c41)B3c1cc3c(cc1N2c1ccccc1-c1cccc(-c2ccccc2)c1)c1ccc(-c2ccccc2)cc1n3-c1ccccc1)-c1ccccc1C5(c1ccccc1)c1ccccc1]

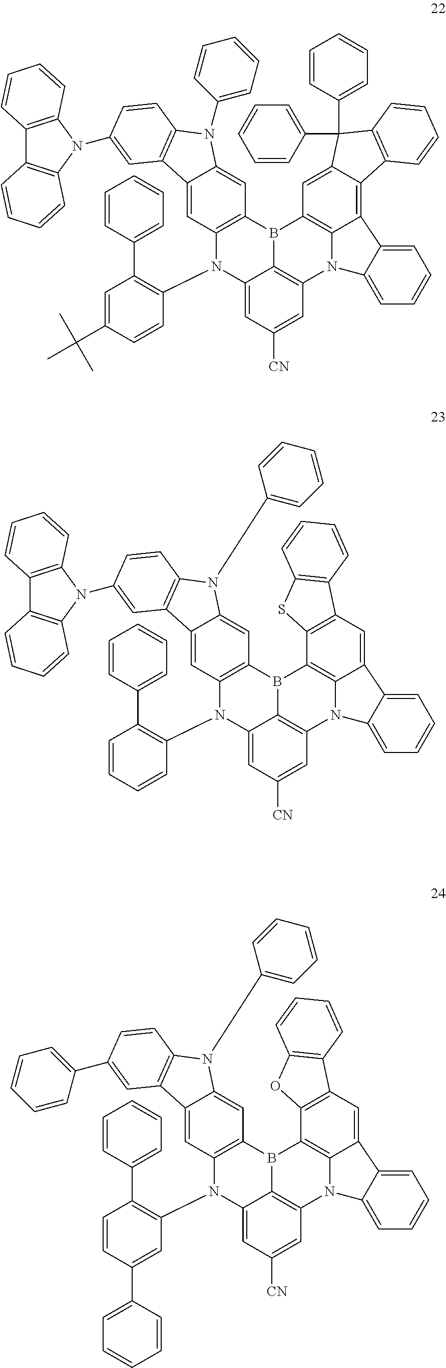 [SMILES: CC(C)(C)c1ccc(N2c3cc4c5cc(-n6c7ccccc7c7ccccc76)ccc5n(-c5ccccc5)c4cc3B3c4c2cc(C#N)cc4-n2c4ccccc4c4c5c(cc3c42)C(c2ccccc2)(c2ccccc2)c2ccccc2-5)c(-c2ccccc2)c1 ; N#Cc1cc2c3c(c1)-n1c4ccccc4c4cc5c(sc6ccccc65)c(c41)B3c1cc3c(cc1N2c1ccccc1-c1ccccc1)c1cc(-n2c4ccccc4c4ccccc42)ccc1n3-c1ccccc1 ; N#Cc1cc2c3c(c1)-n1c4ccccc4c4cc5c(oc6ccccc65)c(c41)B3c1cc3c(cc1N2c1cc(-c2ccccc2)ccc1-c1ccccc1)c1cc(-c2ccccc2)ccc1n3-c1ccccc1]

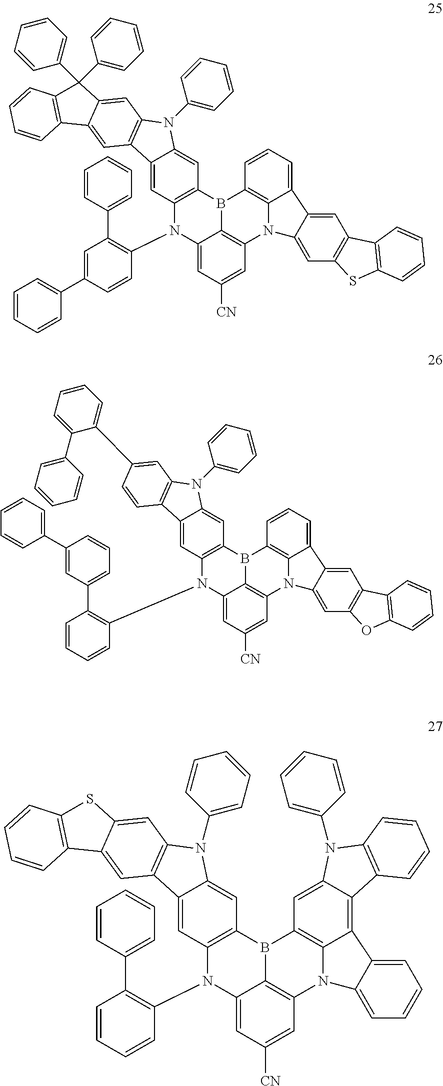 [SMILES: N#Cc1cc2c3c(c1)-n1c4cc5sc6ccccc6c5cc4c4cccc(c41)B3c1cc3c(cc1N2c1ccc(-c2ccccc2)cc1-c1ccccc1)c1cc2c(cc1n3-c1ccccc1)C(c1ccccc1)(c1ccccc1)c1ccccc1-2 ; N#Cc1cc2c3c(c1)-n1c4cc5oc6ccccc6c5cc4c4cccc(c41)B3c1cc3c(cc1N2c1ccccc1-c1cccc(-c2ccccc2)c1)c1ccc(-c2ccccc2-c2ccccc2)cc1n3-c1ccccc1 ; N#Cc1cc2c3c(c1)-n1c4ccccc4c4c5c6ccccc6n(-c6ccccc6)c5cc(c41)B3c1cc3c(cc1N2c1ccccc1-c1ccccc1)c1cc2c(cc1n3-c1ccccc1)sc1ccccc12]

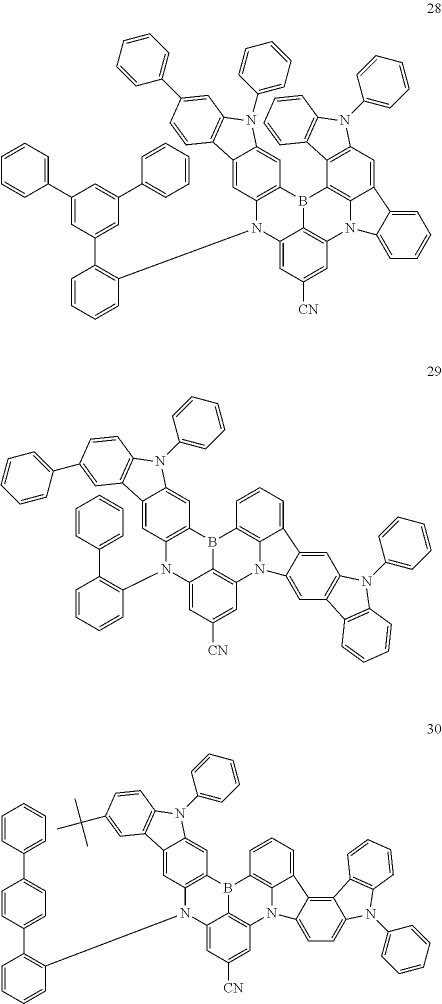 [SMILES: N#Cc1cc2c3c(c1)-n1c4ccccc4c4cc5c(c(c41)B3c1cc3c(cc1N2c1ccccc1-c1cc(-c2ccccc2)cc(-c2ccccc2)c1)c1ccc(-c2ccccc2)cc1n3-c1ccccc1)c1ccccc1n5-c1ccccc1 ; N#Cc1cc2c3c(c1)-n1c4cc5c6ccccc6n(-c6ccccc6)c5cc4c4cccc(c41)B3c1cc3c(cc1N2c1ccccc1-c1ccccc1)c1cc(-c2ccccc2)ccc1n3-c1ccccc1 ; CC(C)(C)c1ccc2c(c1)c1cc3c(cc1n2-c1ccccc1)B1c2c(cc(C#N)cc2-n2c4ccc5c(c6ccccc6n5-c5ccccc5)c4c4cccc1c42)N3c1ccccc1-c1ccc(-c2ccccc2)cc1]

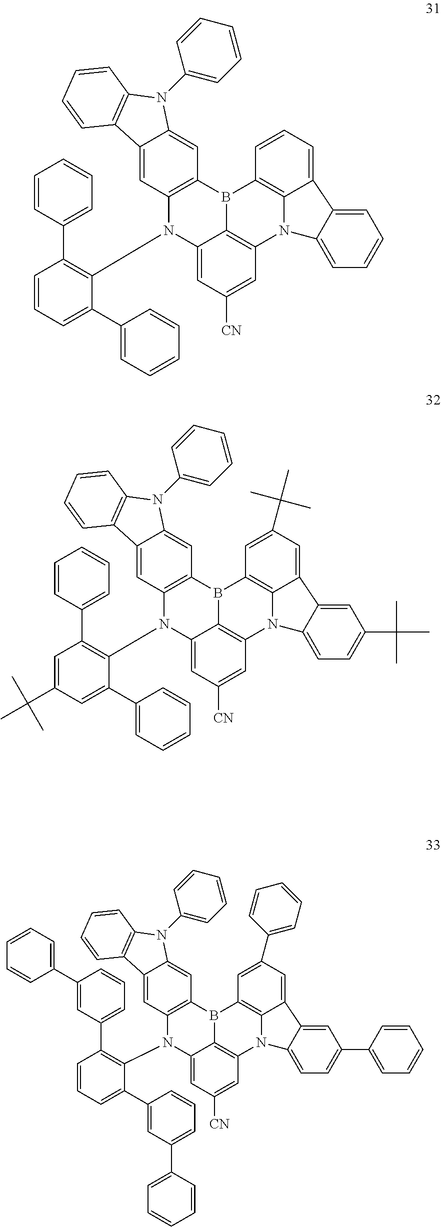 [SMILES: N#Cc1cc2c3c(c1)-n1c4ccccc4c4cccc(c41)B3c1cc3c(cc1N2c1c(-c2ccccc2)cccc1-c1ccccc1)c1ccccc1n3-c1ccccc1 ; CC(C)(C)c1cc(-c2ccccc2)c(N2c3cc4c5ccccc5n(-c5ccccc5)c4cc3B3c4c2cc(C#N)cc4-n2c4ccc(C(C)(C)C)cc4c4cc(C(C)(C)C)cc3c42)c(-c2ccccc2)c1 ; N#Cc1cc2c3c(c1)-n1c4ccc(-c5ccccc5)cc4c4cc(-c5ccccc5)cc(c41)B3c1cc3c(cc1N2c1c(-c2cccc(-c4ccccc4)c2)cccc1-c1cccc(-c2ccccc2)c1)c1ccccc1n3-c1ccccc1]

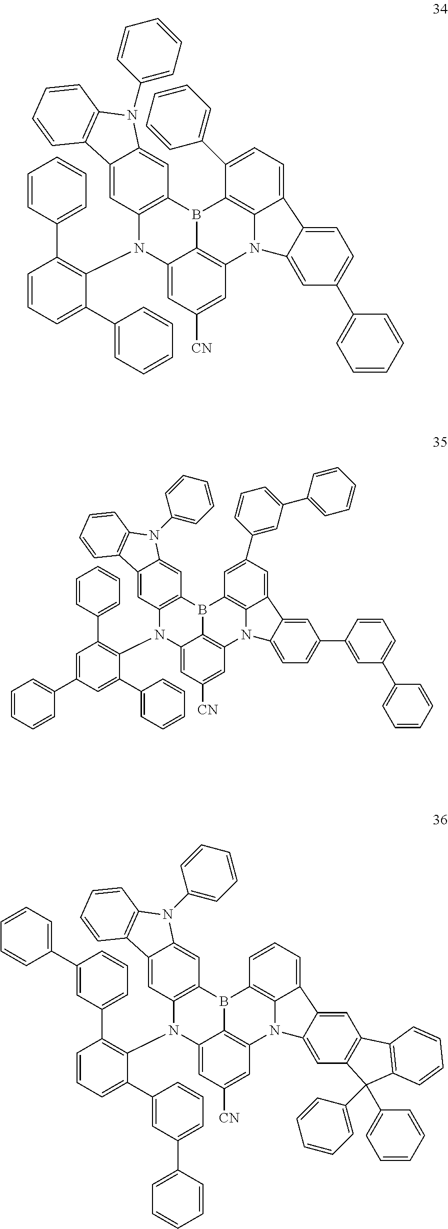 [SMILES: N#Cc1cc2c3c(c1)-n1c4cc(-c5ccccc5)ccc4c4ccc(-c5ccccc5)c(c41)B3c1cc3c(cc1N2c1c(-c2ccccc2)cccc1-c1ccccc1)c1ccccc1n3-c1ccccc1 ; N#Cc1cc2c3c(c1)-n1c4ccc(-c5cccc(-c6ccccc6)c5)cc4c4cc(-c5cccc(-c6ccccc6)c5)cc(c41)B3c1cc3c(cc1N2c1c(-c2ccccc2)cc(-c2ccccc2)cc1-c1ccccc1)c1ccccc1n3-c1ccccc1 ; N#Cc1cc2c3c(c1)-n1c4cc5c(cc4c4cccc(c41)B3c1cc3c(cc1N2c1c(-c2cccc(-c4ccccc4)c2)cccc1-c1cccc(-c2ccccc2)c1)c1ccccc1n3-c1ccccc1)-c1ccccc1C5(c1ccccc1)c1ccccc1]

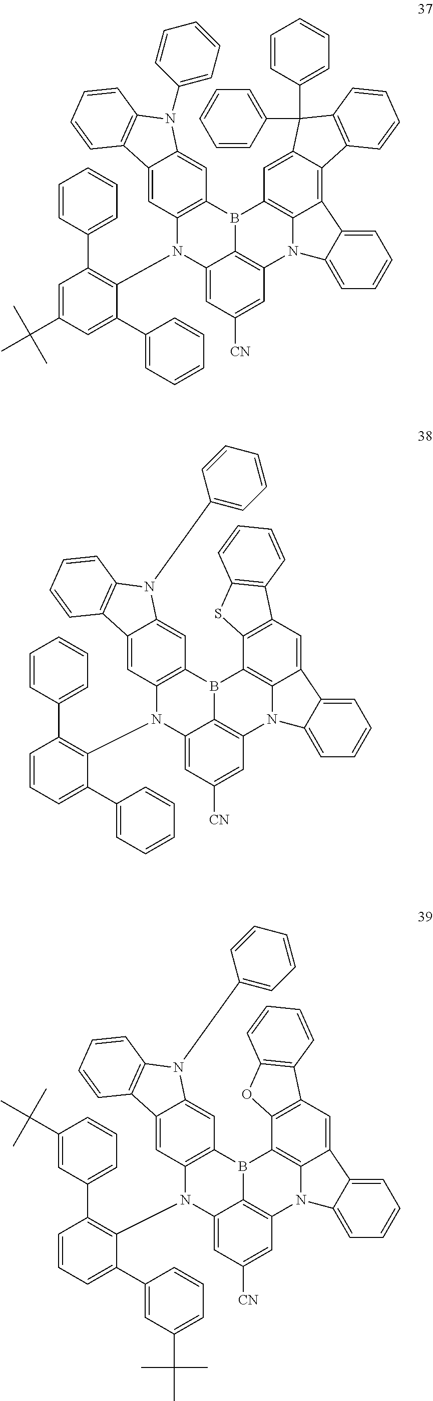 [SMILES: CC(C)(C)c1cc(-c2ccccc2)c(N2c3cc4c5ccccc5n(-c5ccccc5)c4cc3B3c4c2cc(C#N)cc4-n2c4ccccc4c4c5c(cc3c42)C(c2ccccc2)(c2ccccc2)c2ccccc2-5)c(-c2ccccc2)c1 ; N#Cc1cc2c3c(c1)-n1c4ccccc4c4cc5c(sc6ccccc65)c(c41)B3c1cc3c(cc1N2c1c(-c2ccccc2)cccc1-c1ccccc1)c1ccccc1n3-c1ccccc1 ; CC(C)(C)c1cccc(-c2cccc(-c3cccc(C(C)(C)C)c3)c2N2c3cc4c5ccccc5n(-c5ccccc5)c4cc3B3c4c2cc(C#N)cc4-n2c4ccccc4c4cc5c(oc6ccccc65)c3c42)c1]

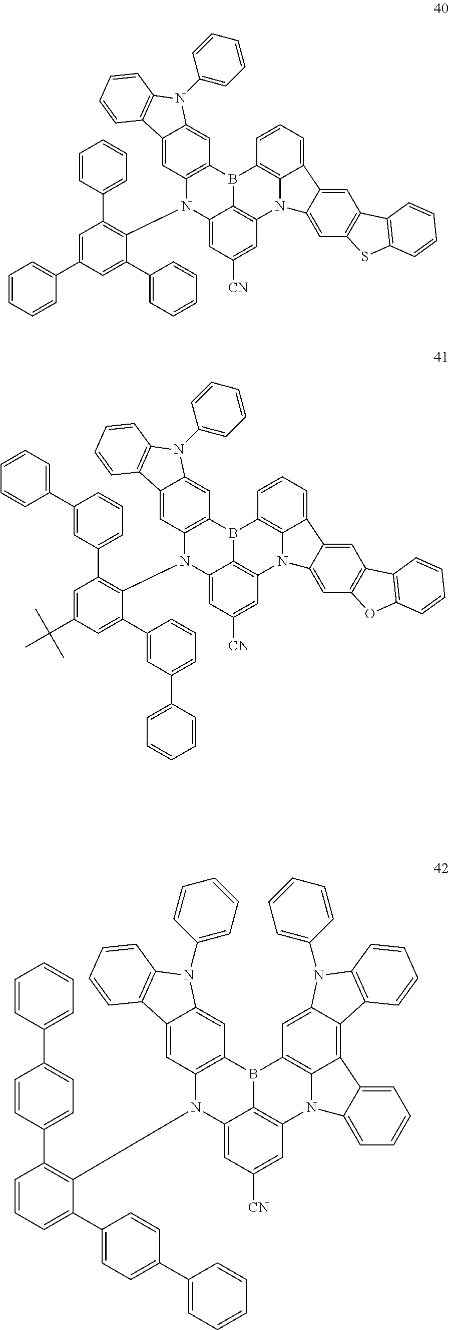 [SMILES: N#Cc1cc2c3c(c1)-n1c4cc5sc6ccccc6c5cc4c4cccc(c41)B3c1cc3c(cc1N2c1c(-c2ccccc2)cc(-c2ccccc2)cc1-c1ccccc1)c1ccccc1n3-c1ccccc1 ; CC(C)(C)c1cc(-c2cccc(-c3ccccc3)c2)c(N2c3cc4c5ccccc5n(-c5ccccc5)c4cc3B3c4c2cc(C#N)cc4-n2c4cc5oc6ccccc6c5cc4c4cccc3c42)c(-c2cccc(-c3ccccc3)c2)c1 ; N#Cc1cc2c3c(c1)-n1c4ccccc4c4c5c6ccccc6n(-c6ccccc6)c5cc(c41)B3c1cc3c(cc1N2c1c(-c2ccc(-c4ccccc4)cc2)cccc1-c1ccc(-c2ccccc2)cc1)c1ccccc1n3-c1ccccc1]

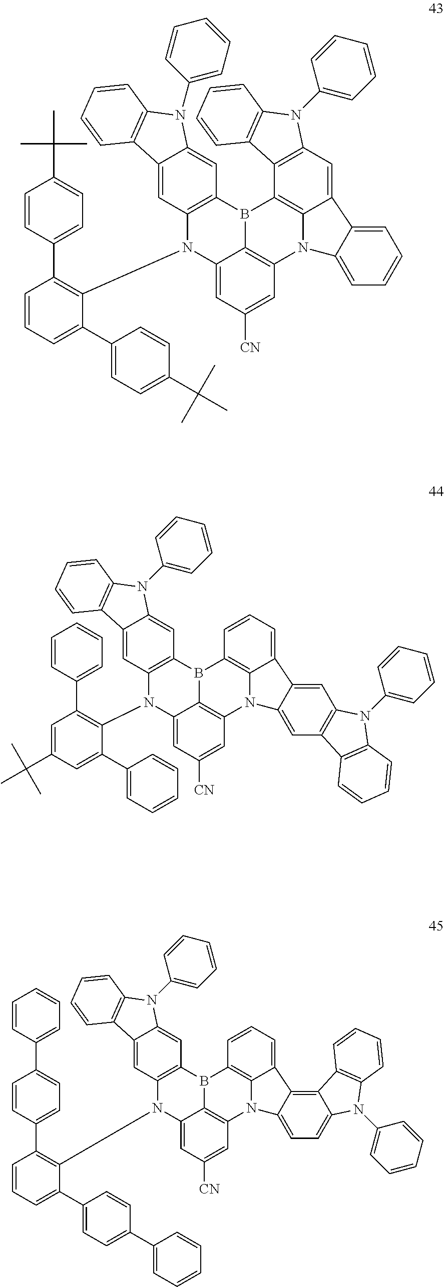 [SMILES: CC(C)(C)c1ccc(-c2cccc(-c3ccc(C(C)(C)C)cc3)c2N2c3cc4c5ccccc5n(-c5ccccc5)c4cc3B3c4c2cc(C#N)cc4-n2c4ccccc4c4cc5c(c3c42)c2ccccc2n5-c2ccccc2)cc1 ; CC(C)(C)c1cc(-c2ccccc2)c(N2c3cc4c5ccccc5n(-c5ccccc5)c4cc3B3c4c2cc(C#N)cc4-n2c4cc5c6ccccc6n(-c6ccccc6)c5cc4c4cccc3c42)c(-c2ccccc2)c1 ; N#Cc1cc2c3c(c1)-n1c4ccc5c(c6ccccc6n5-c5ccccc5)c4c4cccc(c41)B3c1cc3c(cc1N2c1c(-c2ccc(-c4ccccc4)cc2)cccc1-c1ccc(-c2ccccc2)cc1)c1ccccc1n3-c1ccccc1]

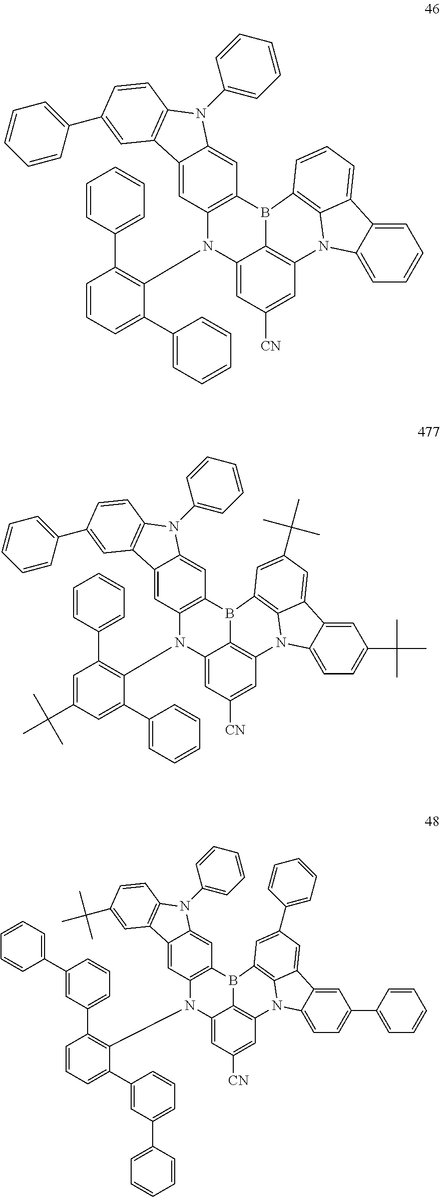 [SMILES: N#Cc1cc2c3c(c1)-n1c4ccccc4c4cccc(c41)B3c1cc3c(cc1N2c1c(-c2ccccc2)cccc1-c1ccccc1)c1cc(-c2ccccc2)ccc1n3-c1ccccc1 ; CC(C)(C)c1cc(-c2ccccc2)c(N2c3cc4c5cc(-c6ccccc6)ccc5n(-c5ccccc5)c4cc3B3c4c2cc(C#N)cc4-n2c4ccc(C(C)(C)C)cc4c4cc(C(C)(C)C)cc3c42)c(-c2ccccc2)c1 ; CC(C)(C)c1ccc2c(c1)c1cc3c(cc1n2-c1ccccc1)B1c2c(cc(C#N)cc2-n2c4ccc(-c5ccccc5)cc4c4cc(-c5ccccc5)cc1c42)N3c1c(-c2cccc(-c3ccccc3)c2)cccc1-c1cccc(-c2ccccc2)c1]

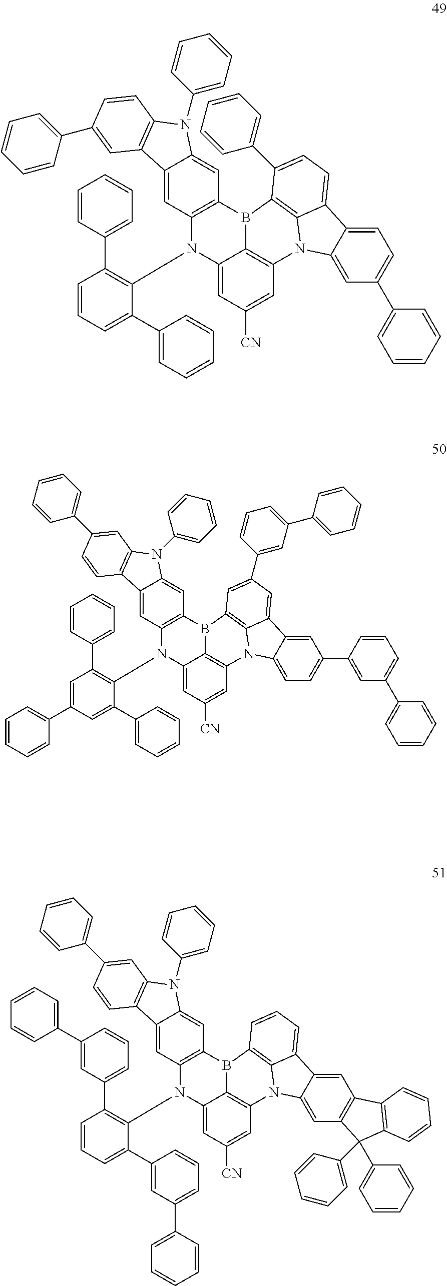 [SMILES: N#Cc1cc2c3c(c1)-n1c4cc(-c5ccccc5)ccc4c4ccc(-c5ccccc5)c(c41)B3c1cc3c(cc1N2c1c(-c2ccccc2)cccc1-c1ccccc1)c1cc(-c2ccccc2)ccc1n3-c1ccccc1 ; N#Cc1cc2c3c(c1)-n1c4ccc(-c5cccc(-c6ccccc6)c5)cc4c4cc(-c5cccc(-c6ccccc6)c5)cc(c41)B3c1cc3c(cc1N2c1c(-c2ccccc2)cc(-c2ccccc2)cc1-c1ccccc1)c1ccc(-c2ccccc2)cc1n3-c1ccccc1 ; N#Cc1cc2c3c(c1)-n1c4cc5c(cc4c4cccc(c41)B3c1cc3c(cc1N2c1c(-c2cccc(-c4ccccc4)c2)cccc1-c1cccc(-c2ccccc2)c1)c1ccc(-c2ccccc2)cc1n3-c1ccccc1)-c1ccccc1C5(c1ccccc1)c1ccccc1]

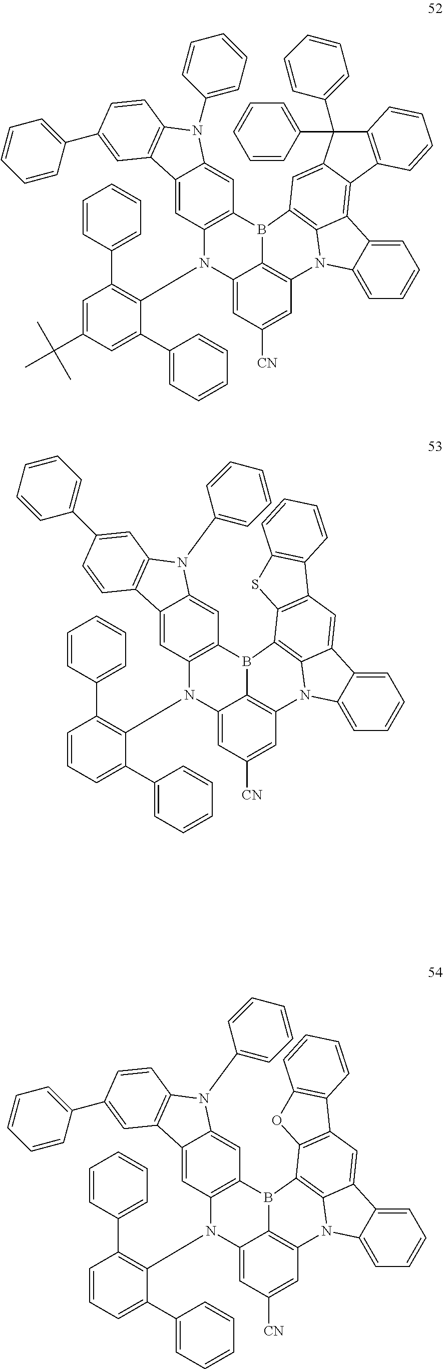 [SMILES: CC(C)(C)c1cc(-c2ccccc2)c(N2c3cc4c5cc(-c6ccccc6)ccc5n(-c5ccccc5)c4cc3B3c4c2cc(C#N)cc4-n2c4ccccc4c4c5c(cc3c42)C(c2ccccc2)(c2ccccc2)c2ccccc2-5)c(-c2ccccc2)c1 ; N#Cc1cc2c3c(c1)-n1c4ccccc4c4cc5c(sc6ccccc65)c(c41)B3c1cc3c(cc1N2c1c(-c2ccccc2)cccc1-c1ccccc1)c1ccc(-c2ccccc2)cc1n3-c1ccccc1 ; N#Cc1cc2c3c(c1)-n1c4ccccc4c4cc5c(oc6ccccc65)c(c41)B3c1cc3c(cc1N2c1c(-c2ccccc2)cccc1-c1ccccc1)c1cc(-c2ccccc2)ccc1n3-c1ccccc1]

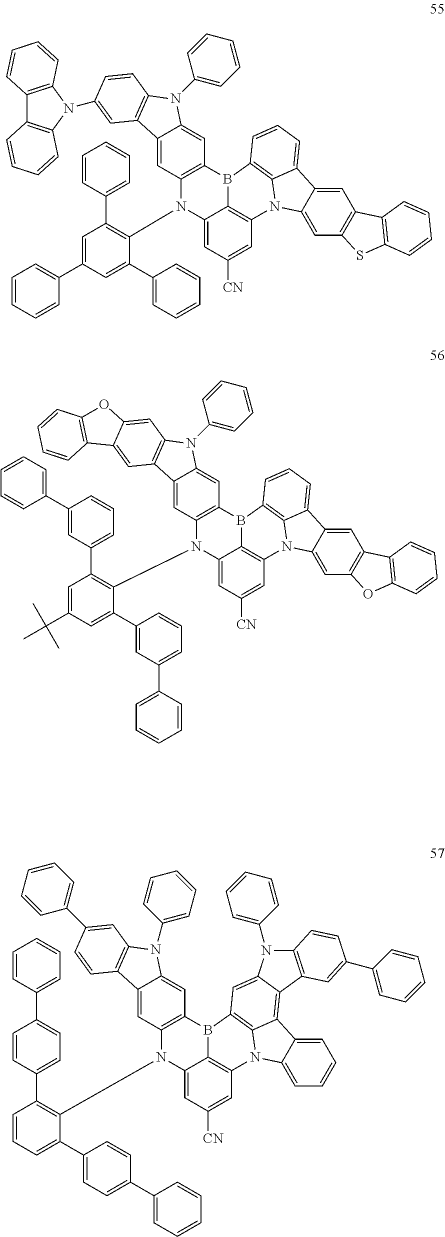 [SMILES: N#Cc1cc2c3c(c1)-n1c4cc5sc6ccccc6c5cc4c4cccc(c41)B3c1cc3c(cc1N2c1c(-c2ccccc2)cc(-c2ccccc2)cc1-c1ccccc1)c1cc(-n2c4ccccc4c4ccccc42)ccc1n3-c1ccccc1 ; CC(C)(C)c1cc(-c2cccc(-c3ccccc3)c2)c(N2c3cc4c5cc6c(cc5n(-c5ccccc5)c4cc3B3c4c2cc(C#N)cc4-n2c4cc5oc7ccccc7c5cc4c4cccc3c42)oc2ccccc26)c(-c2cccc(-c3ccccc3)c2)c1 ; N#Cc1cc2c3c(c1)-n1c4ccccc4c4c5c6cc(-c7ccccc7)ccc6n(-c6ccccc6)c5cc(c41)B3c1cc3c(cc1N2c1c(-c2ccc(-c4ccccc4)cc2)cccc1-c1ccc(-c2ccccc2)cc1)c1ccc(-c2ccccc2)cc1n3-c1ccccc1]

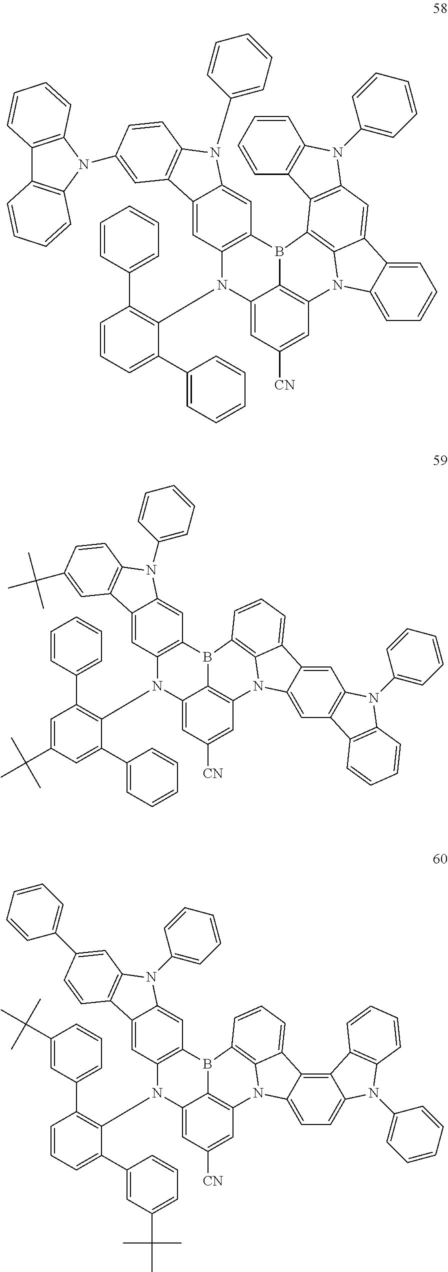 [SMILES: N#Cc1cc2c3c(c1)-n1c4ccccc4c4cc5c(c(c41)B3c1cc3c(cc1N2c1c(-c2ccccc2)cccc1-c1ccccc1)c1cc(-n2c4ccccc4c4ccccc42)ccc1n3-c1ccccc1)c1ccccc1n5-c1ccccc1 ; CC(C)(C)c1cc(-c2ccccc2)c(N2c3cc4c5cc(C(C)(C)C)ccc5n(-c5ccccc5)c4cc3B3c4c2cc(C#N)cc4-n2c4cc5c6ccccc6n(-c6ccccc6)c5cc4c4cccc3c42)c(-c2ccccc2)c1 ; CC(C)(C)c1cccc(-c2cccc(-c3cccc(C(C)(C)C)c3)c2N2c3cc4c5ccc(-c6ccccc6)cc5n(-c5ccccc5)c4cc3B3c4c2cc(C#N)cc4-n2c4ccc5c(c6ccccc6n5-c5ccccc5)c4c4cccc3c42)c1]

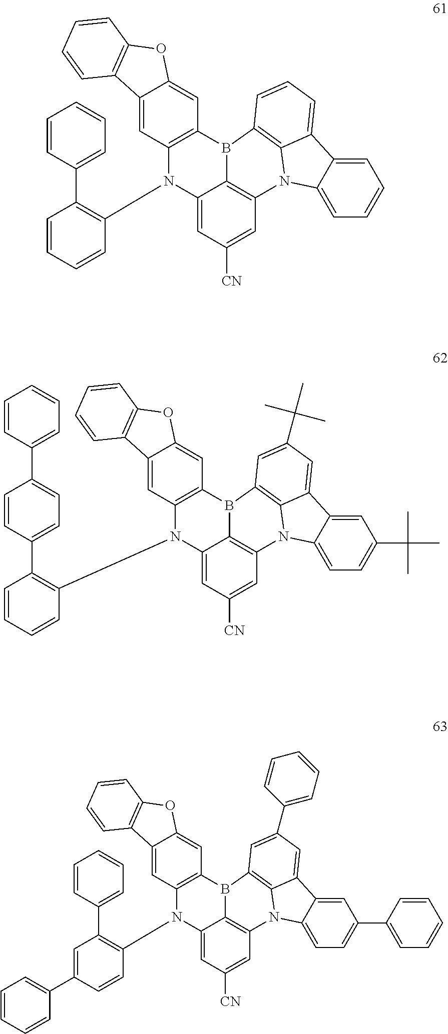 [SMILES: N#Cc1cc2c3c(c1)-n1c4ccccc4c4cccc(c41)B3c1cc3oc4ccccc4c3cc1N2c1ccccc1-c1ccccc1 ; CC(C)(C)c1ccc2c(c1)c1cc(C(C)(C)C)cc3c1n2-c1cc(C#N)cc2c1B3c1cc3oc4ccccc4c3cc1N2c1ccccc1-c1ccc(-c2ccccc2)cc1 ; N#Cc1cc2c3c(c1)-n1c4ccc(-c5ccccc5)cc4c4cc(-c5ccccc5)cc(c41)B3c1cc3oc4ccccc4c3cc1N2c1ccc(-c2ccccc2)cc1-c1ccccc1]

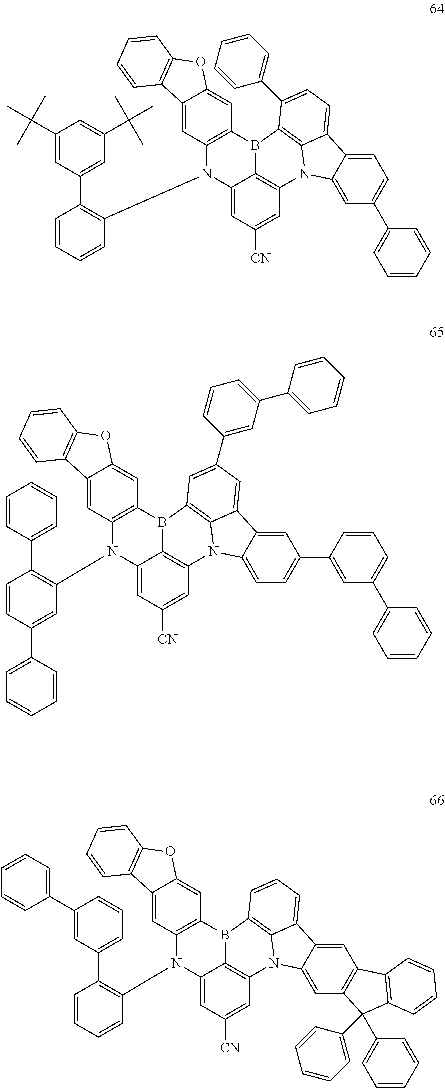 [SMILES: CC(C)(C)c1cc(-c2ccccc2N2c3cc4c(cc3B3c5c2cc(C#N)cc5-n2c5cc(-c6ccccc6)ccc5c5ccc(-c6ccccc6)c3c52)oc2ccccc24)cc(C(C)(C)C)c1 ; N#Cc1cc2c3c(c1)-n1c4ccc(-c5cccc(-c6ccccc6)c5)cc4c4cc(-c5cccc(-c6ccccc6)c5)cc(c41)B3c1cc3oc4ccccc4c3cc1N2c1cc(-c2ccccc2)ccc1-c1ccccc1 ; N#Cc1cc2c3c(c1)-n1c4cc5c(cc4c4cccc(c41)B3c1cc3oc4ccccc4c3cc1N2c1ccccc1-c1cccc(-c2ccccc2)c1)-c1ccccc1C5(c1ccccc1)c1ccccc1]

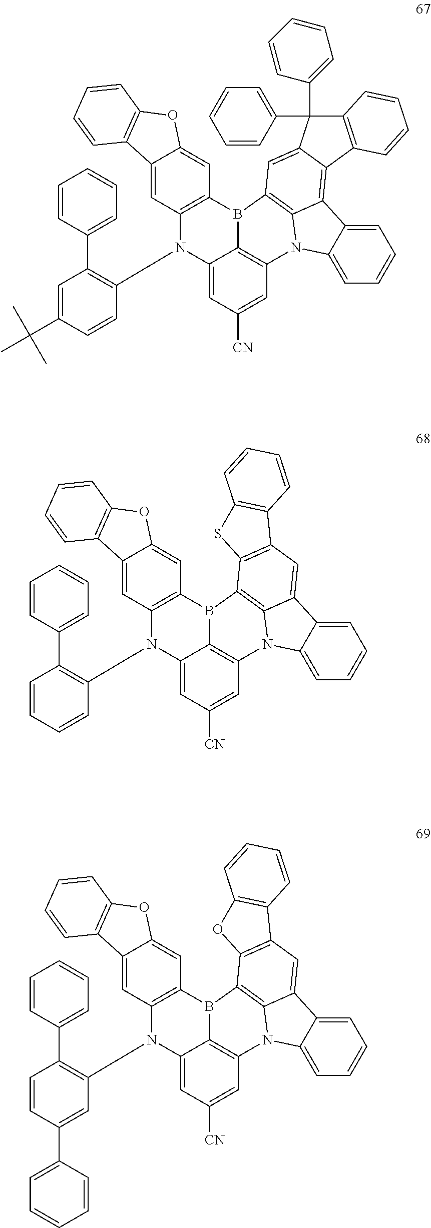 [SMILES: CC(C)(C)c1ccc(N2c3cc4c(cc3B3c5c2cc(C#N)cc5-n2c5ccccc5c5c6c(cc3c52)C(c2ccccc2)(c2ccccc2)c2ccccc2-6)oc2ccccc24)c(-c2ccccc2)c1 ; N#Cc1cc2c3c(c1)-n1c4ccccc4c4cc5c(sc6ccccc65)c(c41)B3c1cc3oc4ccccc4c3cc1N2c1ccccc1-c1ccccc1 ; N#Cc1cc2c3c(c1)-n1c4ccccc4c4cc5c(oc6ccccc65)c(c41)B3c1cc3oc4ccccc4c3cc1N2c1cc(-c2ccccc2)ccc1-c1ccccc1]

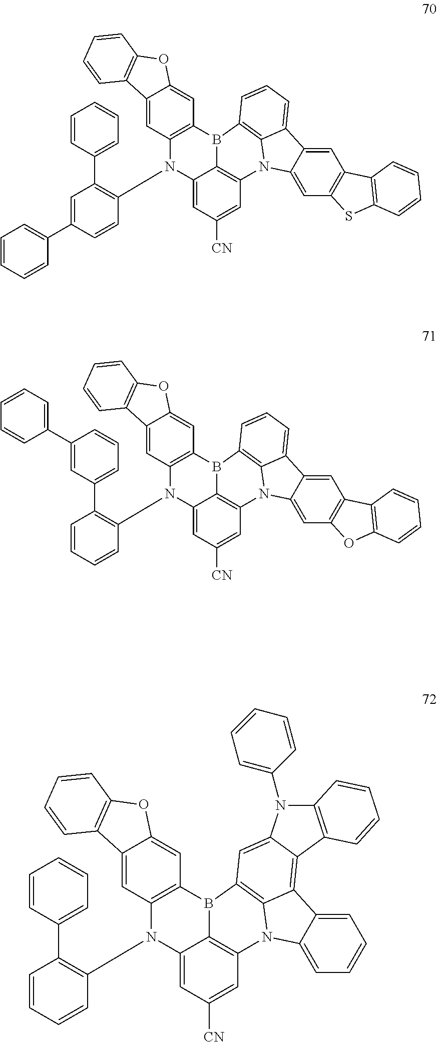 [SMILES: N#Cc1cc2c3c(c1)-n1c4cc5sc6ccccc6c5cc4c4cccc(c41)B3c1cc3oc4ccccc4c3cc1N2c1ccc(-c2ccccc2)cc1-c1ccccc1 ; N#Cc1cc2c3c(c1)-n1c4cc5oc6ccccc6c5cc4c4cccc(c41)B3c1cc3oc4ccccc4c3cc1N2c1ccccc1-c1cccc(-c2ccccc2)c1 ; N#Cc1cc2c3c(c1)-n1c4ccccc4c4c5c6ccccc6n(-c6ccccc6)c5cc(c41)B3c1cc3oc4ccccc4c3cc1N2c1ccccc1-c1ccccc1]

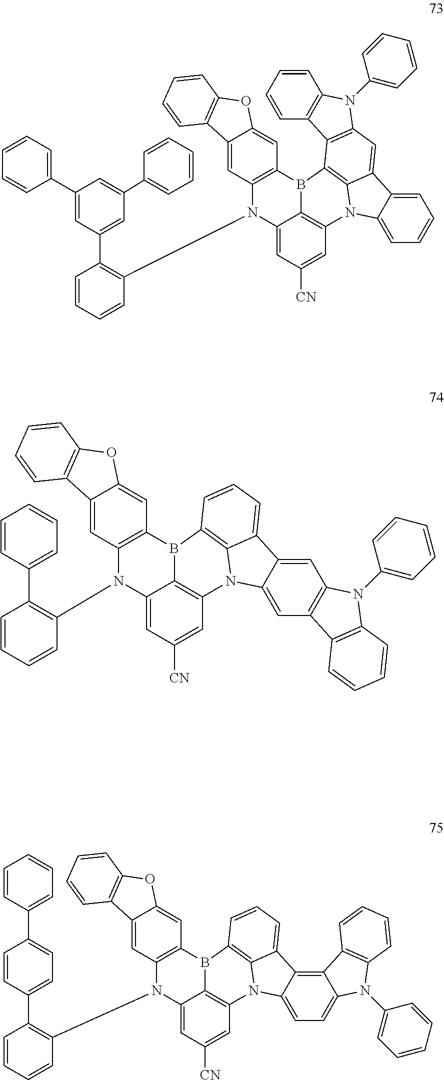 [SMILES: N#Cc1cc2c3c(c1)-n1c4ccccc4c4cc5c(c(c41)B3c1cc3oc4ccccc4c3cc1N2c1ccccc1-c1cc(-c2ccccc2)cc(-c2ccccc2)c1)c1ccccc1n5-c1ccccc1 ; N#Cc1cc2c3c(c1)-n1c4cc5c6ccccc6n(-c6ccccc6)c5cc4c4cccc(c41)B3c1cc3oc4ccccc4c3cc1N2c1ccccc1-c1ccccc1 ; N#Cc1cc2c3c(c1)-n1c4ccc5c(c6ccccc6n5-c5ccccc5)c4c4cccc(c41)B3c1cc3oc4ccccc4c3cc1N2c1ccccc1-c1ccc(-c2ccccc2)cc1]

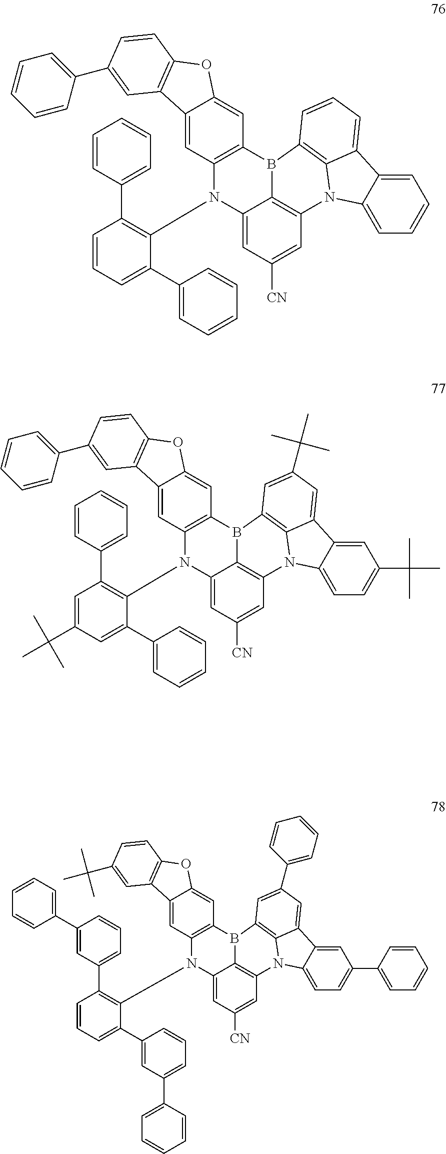 [SMILES: N#Cc1cc2c3c(c1)-n1c4ccccc4c4cccc(c41)B3c1cc3oc4ccc(-c5ccccc5)cc4c3cc1N2c1c(-c2ccccc2)cccc1-c1ccccc1 ; CC(C)(C)c1cc(-c2ccccc2)c(N2c3cc4c(cc3B3c5c2cc(C#N)cc5-n2c5ccc(C(C)(C)C)cc5c5cc(C(C)(C)C)cc3c52)oc2ccc(-c3ccccc3)cc24)c(-c2ccccc2)c1 ; CC(C)(C)c1ccc2oc3cc4c(cc3c2c1)N(c1c(-c2cccc(-c3ccccc3)c2)cccc1-c1cccc(-c2ccccc2)c1)c1cc(C#N)cc2c1B4c1cc(-c3ccccc3)cc3c4cc(-c5ccccc5)ccc4n-2c13]

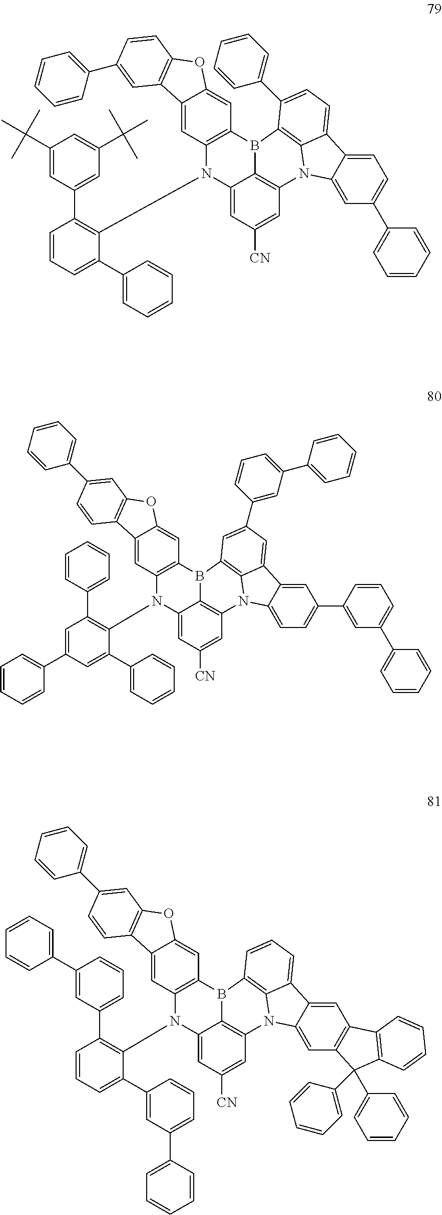 [SMILES: CC(C)(C)c1cc(-c2cccc(-c3ccccc3)c2N2c3cc4c(cc3B3c5c2cc(C#N)cc5-n2c5cc(-c6ccccc6)ccc5c5ccc(-c6ccccc6)c3c52)oc2ccc(-c3ccccc3)cc24)cc(C(C)(C)C)c1 ; N#Cc1cc2c3c(c1)-n1c4ccc(-c5cccc(-c6ccccc6)c5)cc4c4cc(-c5cccc(-c6ccccc6)c5)cc(c41)B3c1cc3oc4cc(-c5ccccc5)ccc4c3cc1N2c1c(-c2ccccc2)cc(-c2ccccc2)cc1-c1ccccc1 ; N#Cc1cc2c3c(c1)-n1c4cc5c(cc4c4cccc(c41)B3c1cc3oc4cc(-c6ccccc6)ccc4c3cc1N2c1c(-c2cccc(-c3ccccc3)c2)cccc1-c1cccc(-c2ccccc2)c1)-c1ccccc1C5(c1ccccc1)c1ccccc1]

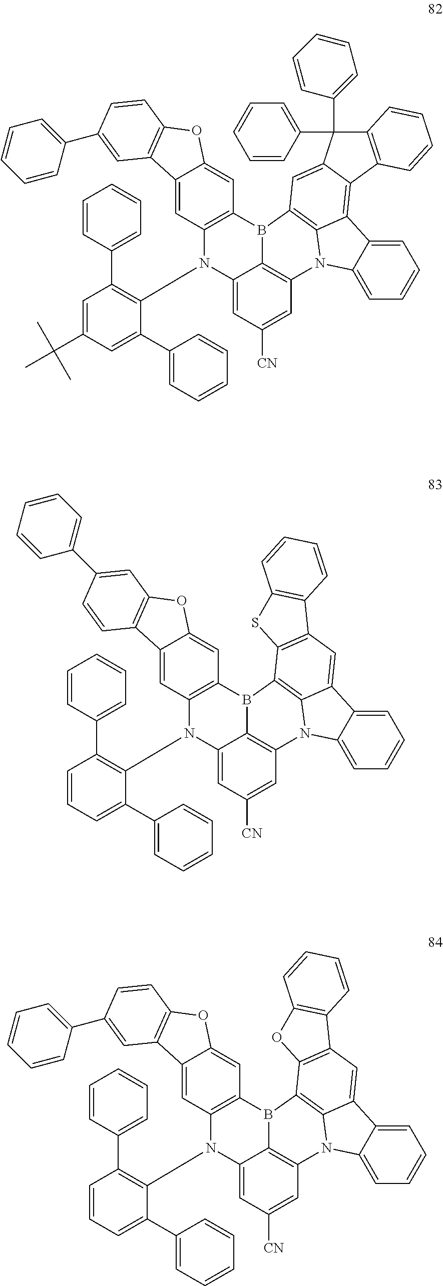 [SMILES: CC(C)(C)c1cc(-c2ccccc2)c(N2c3cc4c(cc3B3c5c2cc(C#N)cc5-n2c5ccccc5c5c6c(cc3c52)C(c2ccccc2)(c2ccccc2)c2ccccc2-6)oc2ccc(-c3ccccc3)cc24)c(-c2ccccc2)c1 ; N#Cc1cc2c3c(c1)-n1c4ccccc4c4cc5c(sc6ccccc65)c(c41)B3c1cc3oc4cc(-c5ccccc5)ccc4c3cc1N2c1c(-c2ccccc2)cccc1-c1ccccc1 ; N#Cc1cc2c3c(c1)-n1c4ccccc4c4cc5c(oc6ccccc65)c(c41)B3c1cc3oc4ccc(-c5ccccc5)cc4c3cc1N2c1c(-c2ccccc2)cccc1-c1ccccc1]

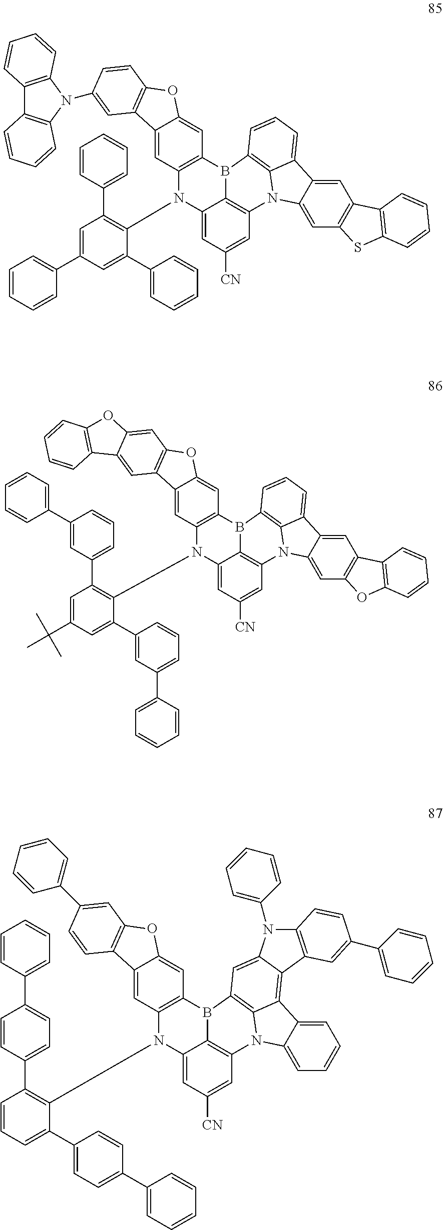 [SMILES: N#Cc1cc2c3c(c1)-n1c4cc5sc6ccccc6c5cc4c4cccc(c41)B3c1cc3oc4ccc(-n5c6ccccc6c6ccccc65)cc4c3cc1N2c1c(-c2ccccc2)cc(-c2ccccc2)cc1-c1ccccc1 ; CC(C)(C)c1cc(-c2cccc(-c3ccccc3)c2)c(N2c3cc4c(cc3B3c5c2cc(C#N)cc5-n2c5cc6oc7ccccc7c6cc5c5cccc3c52)oc2cc3oc5ccccc5c3cc24)c(-c2cccc(-c3ccccc3)c2)c1 ; N#Cc1cc2c3c(c1)-n1c4ccccc4c4c5c6cc(-c7ccccc7)ccc6n(-c6ccccc6)c5cc(c41)B3c1cc3oc4cc(-c5ccccc5)ccc4c3cc1N2c1c(-c2ccc(-c3ccccc3)cc2)cccc1-c1ccc(-c2ccccc2)cc1]

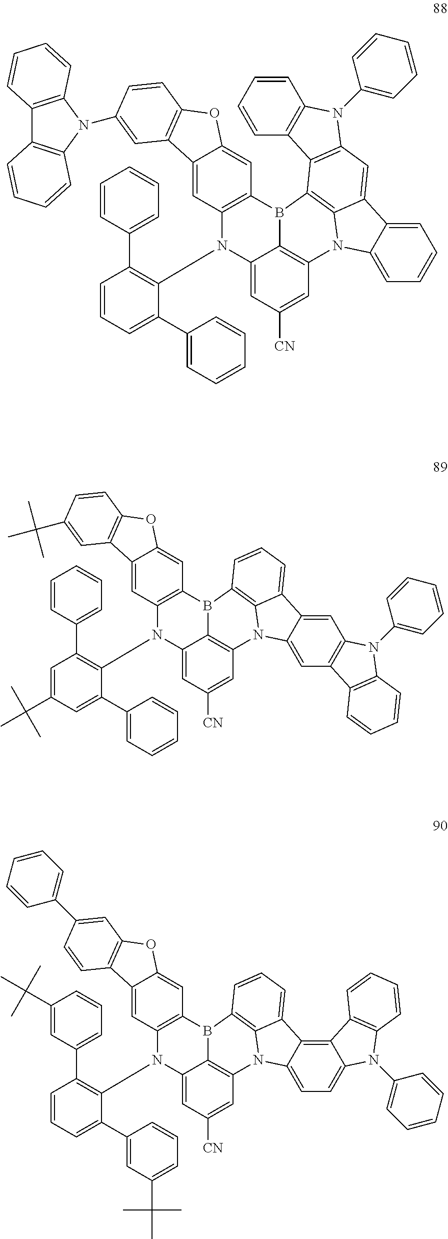 [SMILES: N#Cc1cc2c3c(c1)-n1c4ccccc4c4cc5c(c(c41)B3c1cc3oc4ccc(-n6c7ccccc7c7ccccc76)cc4c3cc1N2c1c(-c2ccccc2)cccc1-c1ccccc1)c1ccccc1n5-c1ccccc1 ; CC(C)(C)c1cc(-c2ccccc2)c(N2c3cc4c(cc3B3c5c2cc(C#N)cc5-n2c5cc6c7ccccc7n(-c7ccccc7)c6cc5c5cccc3c52)oc2ccc(C(C)(C)C)cc24)c(-c2ccccc2)c1 ; CC(C)(C)c1cccc(-c2cccc(-c3cccc(C(C)(C)C)c3)c2N2c3cc4c(cc3B3c5c2cc(C#N)cc5-n2c5ccc6c(c7ccccc7n6-c6ccccc6)c5c5cccc3c52)oc2cc(-c3ccccc3)ccc24)c1]

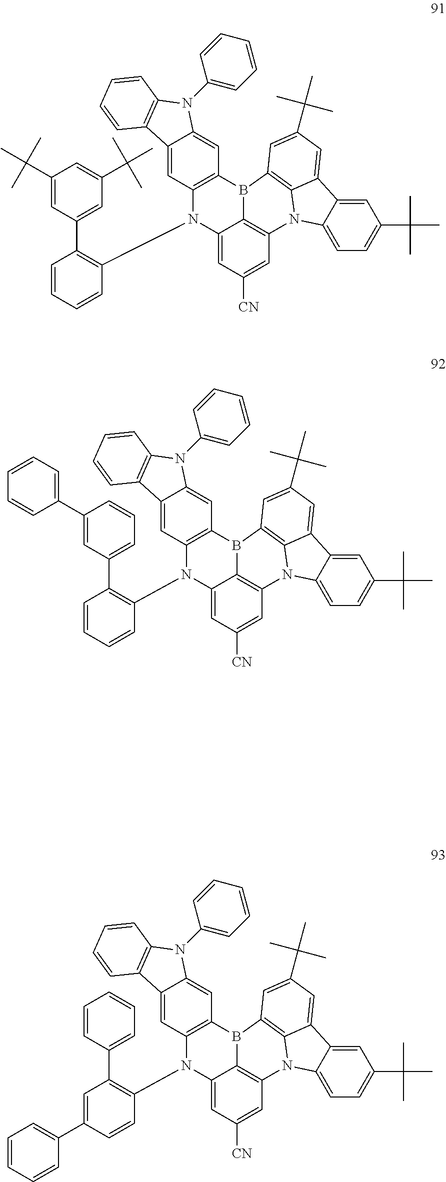 [SMILES: CC(C)(C)c1cc(-c2ccccc2N2c3cc4c5ccccc5n(-c5ccccc5)c4cc3B3c4c2cc(C#N)cc4-n2c4ccc(C(C)(C)C)cc4c4cc(C(C)(C)C)cc3c42)cc(C(C)(C)C)c1 ; CC(C)(C)c1ccc2c(c1)c1cc(C(C)(C)C)cc3c1n2-c1cc(C#N)cc2c1B3c1cc3c(cc1N2c1ccccc1-c1cccc(-c2ccccc2)c1)c1ccccc1n3-c1ccccc1 ; CC(C)(C)c1ccc2c(c1)c1cc(C(C)(C)C)cc3c1n2-c1cc(C#N)cc2c1B3c1cc3c(cc1N2c1ccc(-c2ccccc2)cc1-c1ccccc1)c1ccccc1n3-c1ccccc1]

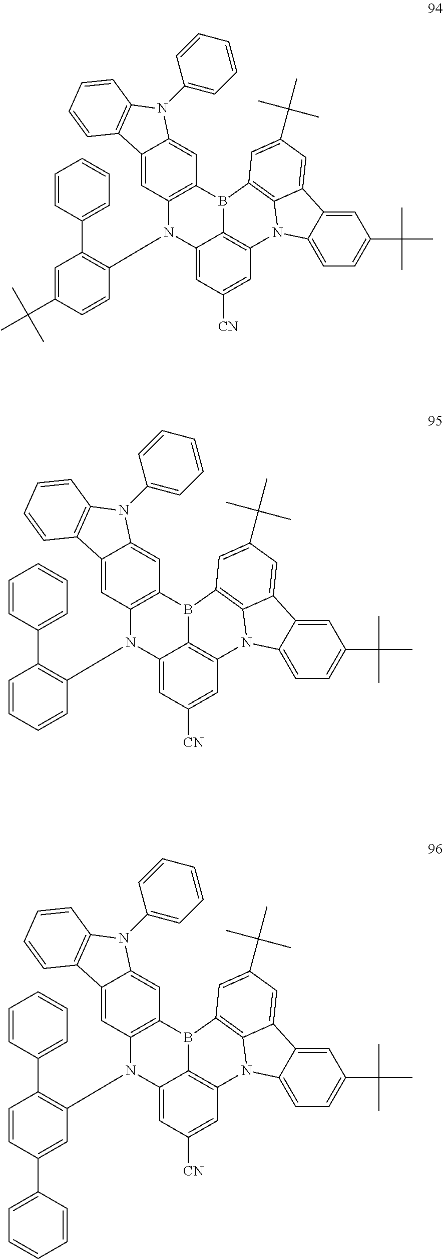 [SMILES: CC(C)(C)c1ccc(N2c3cc4c5ccccc5n(-c5ccccc5)c4cc3B3c4c2cc(C#N)cc4-n2c4ccc(C(C)(C)C)cc4c4cc(C(C)(C)C)cc3c42)c(-c2ccccc2)c1 ; CC(C)(C)c1ccc2c(c1)c1cc(C(C)(C)C)cc3c1n2-c1cc(C#N)cc2c1B3c1cc3c(cc1N2c1ccccc1-c1ccccc1)c1ccccc1n3-c1ccccc1 ; CC(C)(C)c1ccc2c(c1)c1cc(C(C)(C)C)cc3c1n2-c1cc(C#N)cc2c1B3c1cc3c(cc1N2c1cc(-c2ccccc2)ccc1-c1ccccc1)c1ccccc1n3-c1ccccc1]

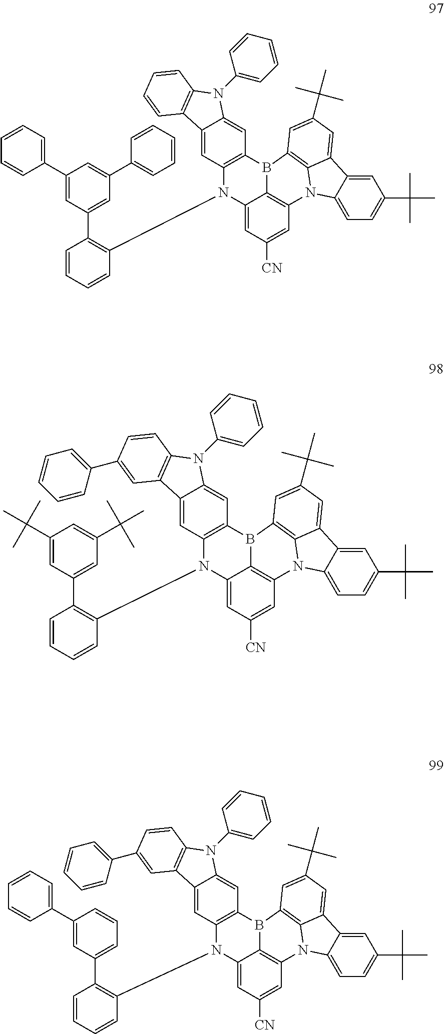

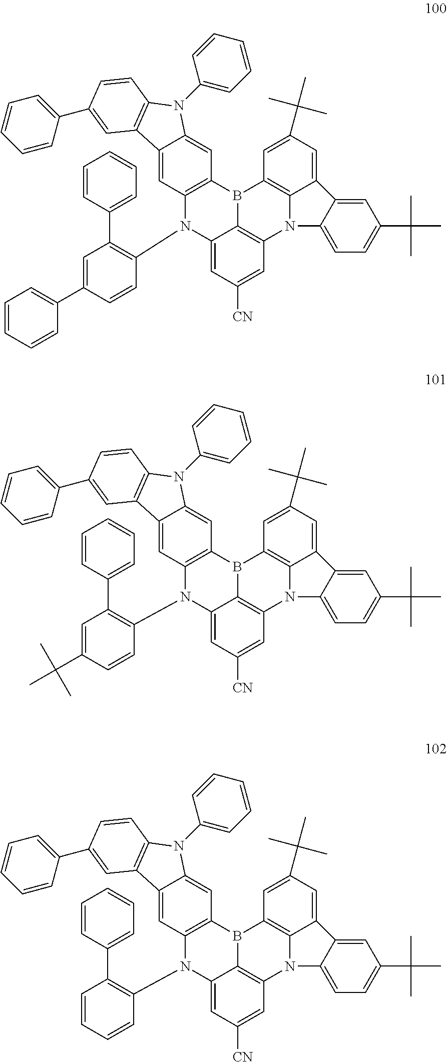 [SMILES: CC(C)(C)c1ccc2c(c1)c1cc(C(C)(C)C)cc3c1n2-c1cc(C#N)cc2c1B3c1cc3c(cc1N2c1ccc(-c2ccccc2)cc1-c1ccccc1)c1cc(-c2ccccc2)ccc1n3-c1ccccc1 ; CC(C)(C)c1ccc(N2c3cc4c5cc(-c6ccccc6)ccc5n(-c5ccccc5)c4cc3B3c4c2cc(C#N)cc4-n2c4ccc(C(C)(C)C)cc4c4cc(C(C)(C)C)cc3c42)c(-c2ccccc2)c1 ; CC(C)(C)c1ccc2c(c1)c1cc(C(C)(C)C)cc3c1n2-c1cc(C#N)cc2c1B3c1cc3c(cc1N2c1ccccc1-c1ccccc1)c1cc(-c2ccccc2)ccc1n3-c1ccccc1]

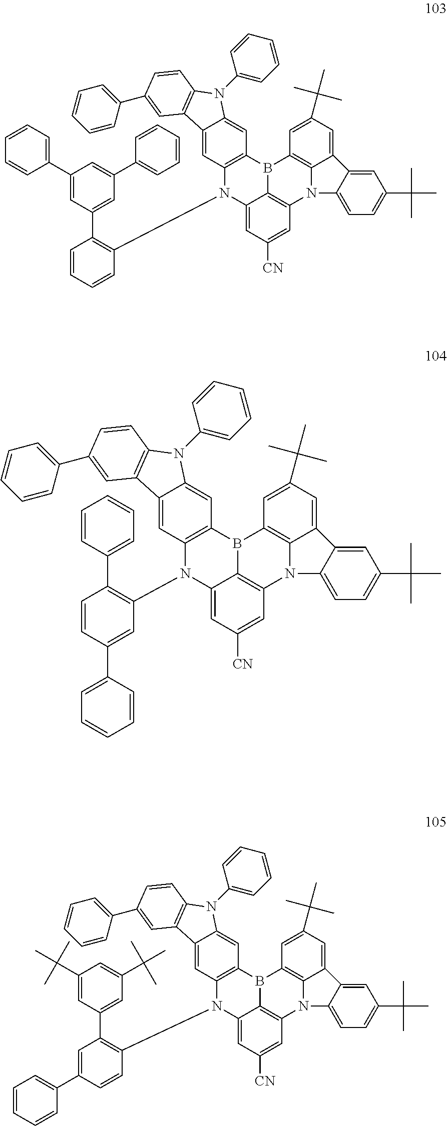 [SMILES: CC(C)(C)c1ccc2c(c1)c1cc(C(C)(C)C)cc3c1n2-c1cc(C#N)cc2c1B3c1cc3c(cc1N2c1ccccc1-c1cc(-c2ccccc2)cc(-c2ccccc2)c1)c1cc(-c2ccccc2)ccc1n3-c1ccccc1 ; CC(C)(C)c1ccc2c(c1)c1cc(C(C)(C)C)cc3c1n2-c1cc(C#N)cc2c1B3c1cc3c(cc1N2c1cc(-c2ccccc2)ccc1-c1ccccc1)c1cc(-c2ccccc2)ccc1n3-c1ccccc1 ; CC(C)(C)c1cc(-c2cc(-c3ccccc3)ccc2N2c3cc4c5cc(-c6ccccc6)ccc5n(-c5ccccc5)c4cc3B3c4c2cc(C#N)cc4-n2c4ccc(C(C)(C)C)cc4c4cc(C(C)(C)C)cc3c42)cc(C(C)(C)C)c1]

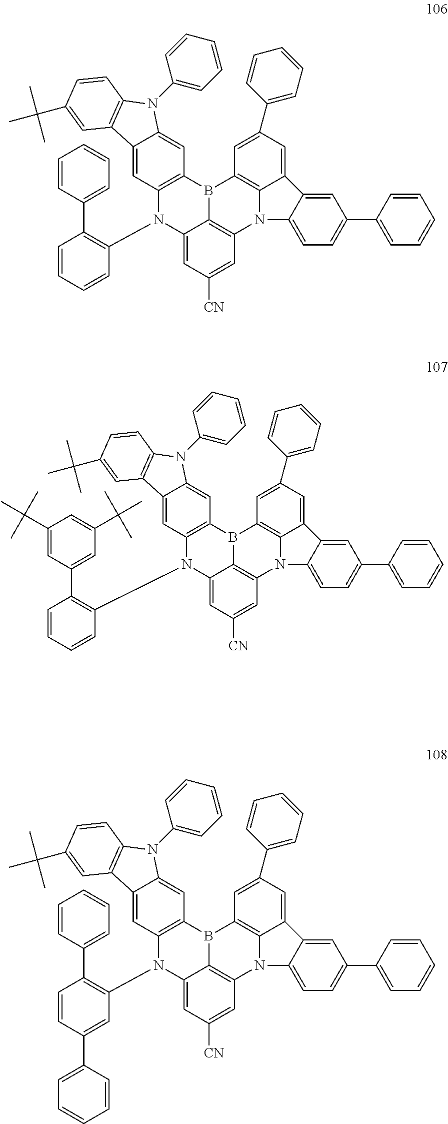 [SMILES: CC(C)(C)c1ccc2c(c1)c1cc3c(cc1n2-c1ccccc1)B1c2c(cc(C#N)cc2-n2c4ccc(-c5ccccc5)cc4c4cc(-c5ccccc5)cc1c42)N3c1ccccc1-c1ccccc1 ; CC(C)(C)c1cc(-c2ccccc2N2c3cc4c5cc(C(C)(C)C)ccc5n(-c5ccccc5)c4cc3B3c4c2cc(C#N)cc4-n2c4ccc(-c5ccccc5)cc4c4cc(-c5ccccc5)cc3c42)cc(C(C)(C)C)c1 ; CC(C)(C)c1ccc2c(c1)c1cc3c(cc1n2-c1ccccc1)B1c2c(cc(C#N)cc2-n2c4ccc(-c5ccccc5)cc4c4cc(-c5ccccc5)cc1c42)N3c1cc(-c2ccccc2)ccc1-c1ccccc1]

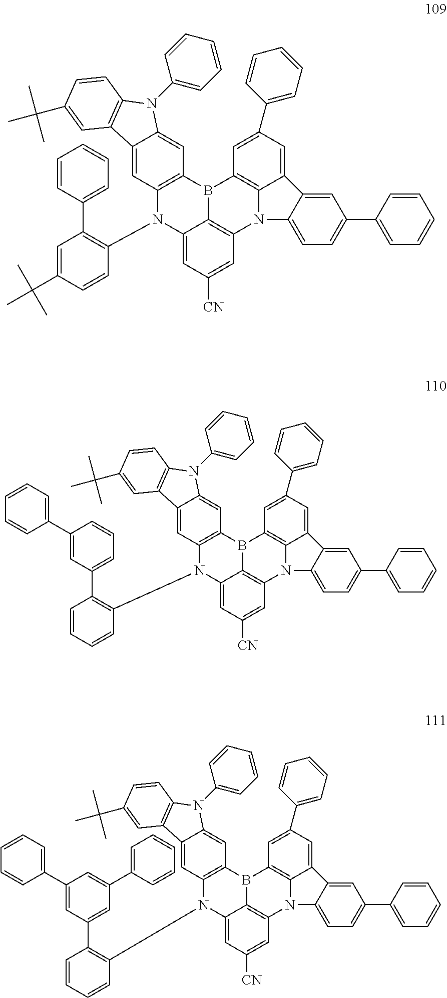

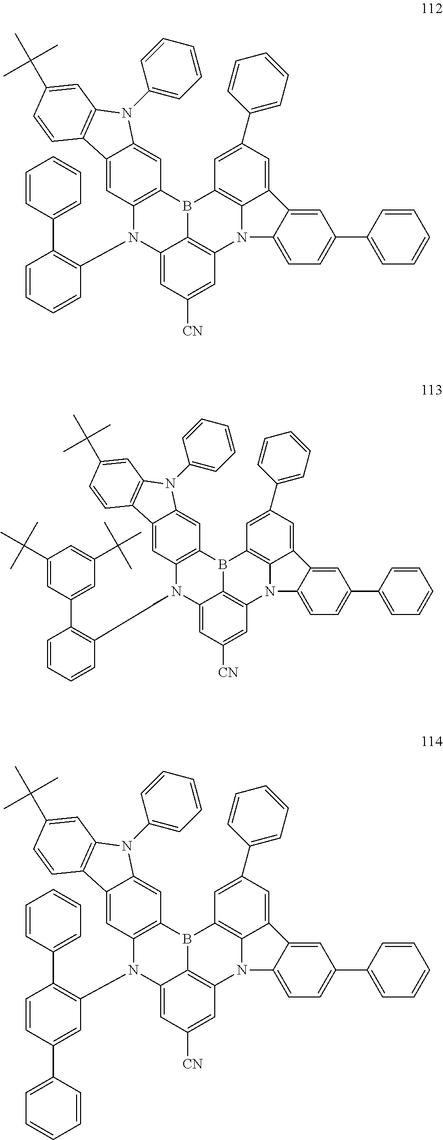

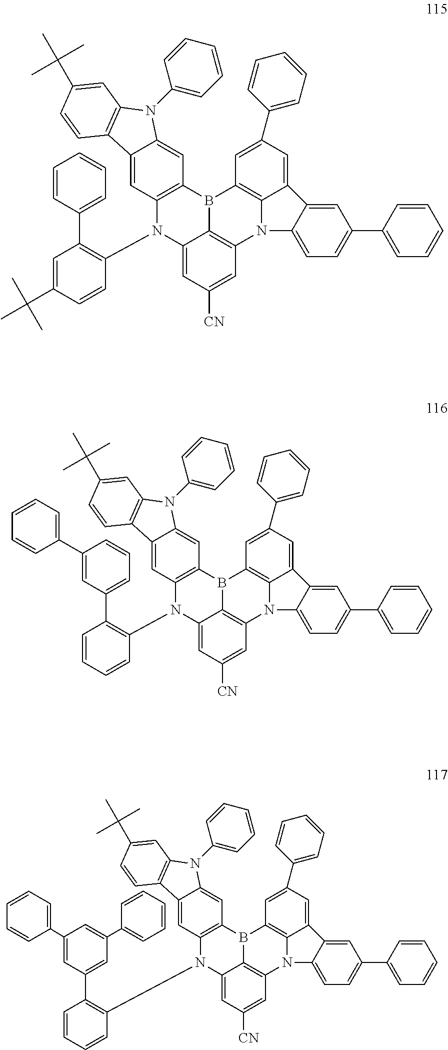 [SMILES: CC(C)(C)c1ccc(N2c3cc4c5ccc(C(C)(C)C)cc5n(-c5ccccc5)c4cc3B3c4c2cc(C#N)cc4-n2c4ccc(-c5ccccc5)cc4c4cc(-c5ccccc5)cc3c42)c(-c2ccccc2)c1 ; CC(C)(C)c1ccc2c3cc4c(cc3n(-c3ccccc3)c2c1)B1c2c(cc(C#N)cc2-n2c3ccc(-c5ccccc5)cc3c3cc(-c5ccccc5)cc1c32)N4c1ccccc1-c1cccc(-c2ccccc2)c1 ; CC(C)(C)c1ccc2c3cc4c(cc3n(-c3ccccc3)c2c1)B1c2c(cc(C#N)cc2-n2c3ccc(-c5ccccc5)cc3c3cc(-c5ccccc5)cc1c32)N4c1ccccc1-c1cc(-c2ccccc2)cc(-c2ccccc2)c1]

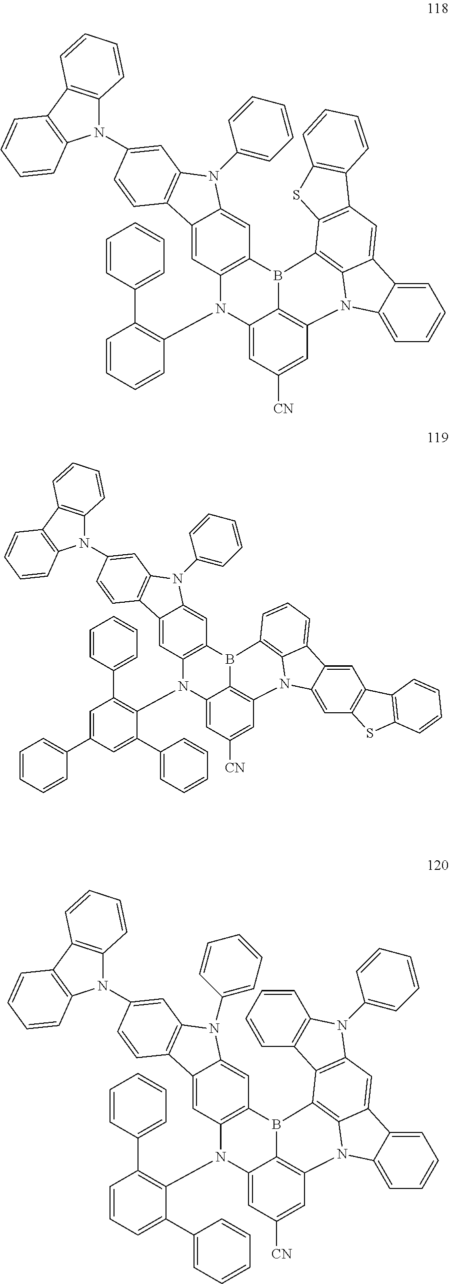 [SMILES: N#Cc1cc2c3c(c1)-n1c4ccccc4c4cc5c(sc6ccccc65)c(c41)B3c1cc3c(cc1N2c1ccccc1-c1ccccc1)c1ccc(-n2c4ccccc4c4ccccc42)cc1n3-c1ccccc1 ; N#Cc1cc2c3c(c1)-n1c4cc5sc6ccccc6c5cc4c4cccc(c41)B3c1cc3c(cc1N2c1c(-c2ccccc2)cc(-c2ccccc2)cc1-c1ccccc1)c1ccc(-n2c4ccccc4c4ccccc42)cc1n3-c1ccccc1 ; N#Cc1cc2c3c(c1)-n1c4ccccc4c4cc5c(c(c41)B3c1cc3c(cc1N2c1c(-c2ccccc2)cccc1-c1ccccc1)c1ccc(-n2c4ccccc4c4ccccc42)cc1n3-c1ccccc1)c1ccccc1n5-c1ccccc1]

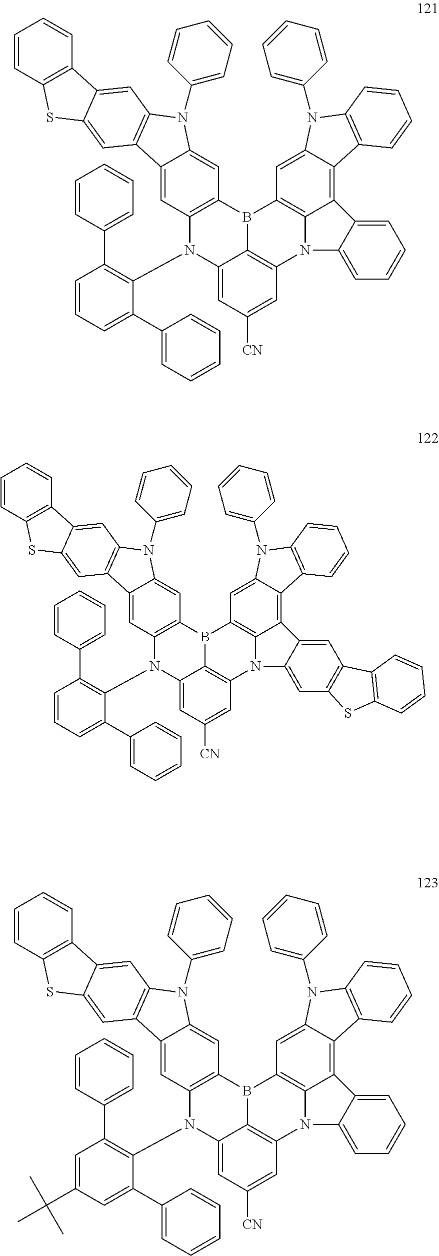 [SMILES: N#Cc1cc2c3c(c1)-n1c4ccccc4c4c5c6ccccc6n(-c6ccccc6)c5cc(c41)B3c1cc3c(cc1N2c1c(-c2ccccc2)cccc1-c1ccccc1)c1cc2sc4ccccc4c2cc1n3-c1ccccc1 ; N#Cc1cc2c3c(c1)-n1c4cc5sc6ccccc6c5cc4c4c5c6ccccc6n(-c6ccccc6)c5cc(c41)B3c1cc3c(cc1N2c1c(-c2ccccc2)cccc1-c1ccccc1)c1cc2sc4ccccc4c2cc1n3-c1ccccc1 ; CC(C)(C)c1cc(-c2ccccc2)c(N2c3cc4c5cc6sc7ccccc7c6cc5n(-c5ccccc5)c4cc3B3c4c2cc(C#N)cc4-n2c4ccccc4c4c5c6ccccc6n(-c6ccccc6)c5cc3c42)c(-c2ccccc2)c1]

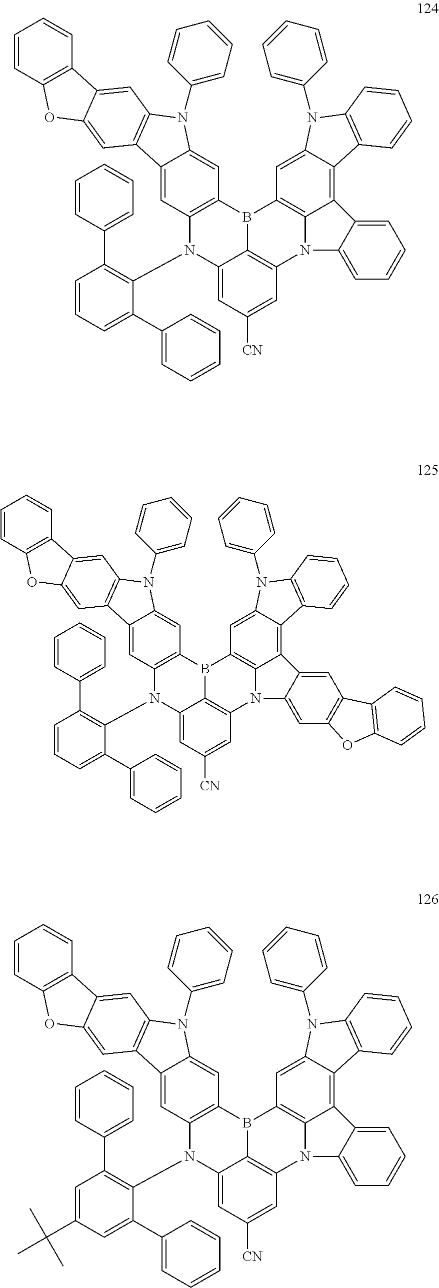 [SMILES: N#Cc1cc2c3c(c1)-n1c4ccccc4c4c5c6ccccc6n(-c6ccccc6)c5cc(c41)B3c1cc3c(cc1N2c1c(-c2ccccc2)cccc1-c1ccccc1)c1cc2oc4ccccc4c2cc1n3-c1ccccc1 ; N#Cc1cc2c3c(c1)-n1c4cc5oc6ccccc6c5cc4c4c5c6ccccc6n(-c6ccccc6)c5cc(c41)B3c1cc3c(cc1N2c1c(-c2ccccc2)cccc1-c1ccccc1)c1cc2oc4ccccc4c2cc1n3-c1ccccc1 ; CC(C)(C)c1cc(-c2ccccc2)c(N2c3cc4c5cc6oc7ccccc7c6cc5n(-c5ccccc5)c4cc3B3c4c2cc(C#N)cc4-n2c4ccccc4c4c5c6ccccc6n(-c6ccccc6)c5cc3c42)c(-c2ccccc2)c1]

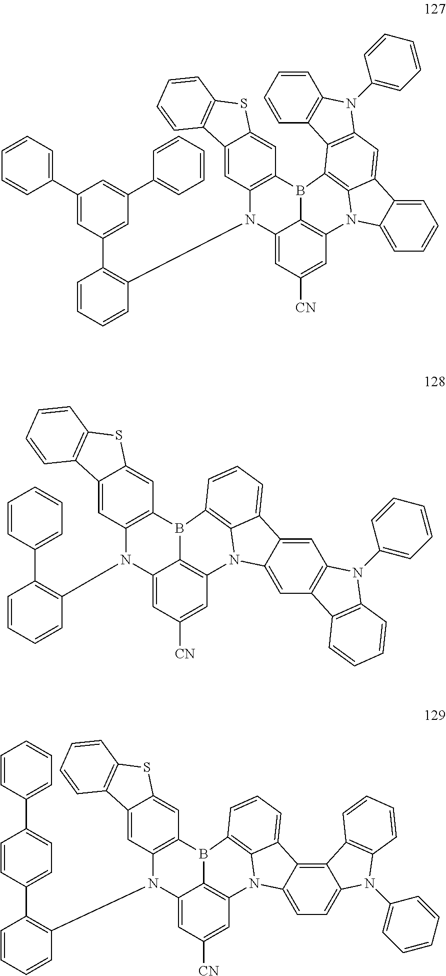 [SMILES: N#Cc1cc2c3c(c1)-n1c4ccccc4c4cc5c(c(c41)B3c1cc3sc4ccccc4c3cc1N2c1ccccc1-c1cc(-c2ccccc2)cc(-c2ccccc2)c1)c1ccccc1n5-c1ccccc1 ; N#Cc1cc2c3c(c1)-n1c4cc5c6ccccc6n(-c6ccccc6)c5cc4c4cccc(c41)B3c1cc3sc4ccccc4c3cc1N2c1ccccc1-c1ccccc1 ; N#Cc1cc2c3c(c1)-n1c4ccc5c(c6ccccc6n5-c5ccccc5)c4c4cccc(c41)B3c1cc3sc4ccccc4c3cc1N2c1ccccc1-c1ccc(-c2ccccc2)cc1]

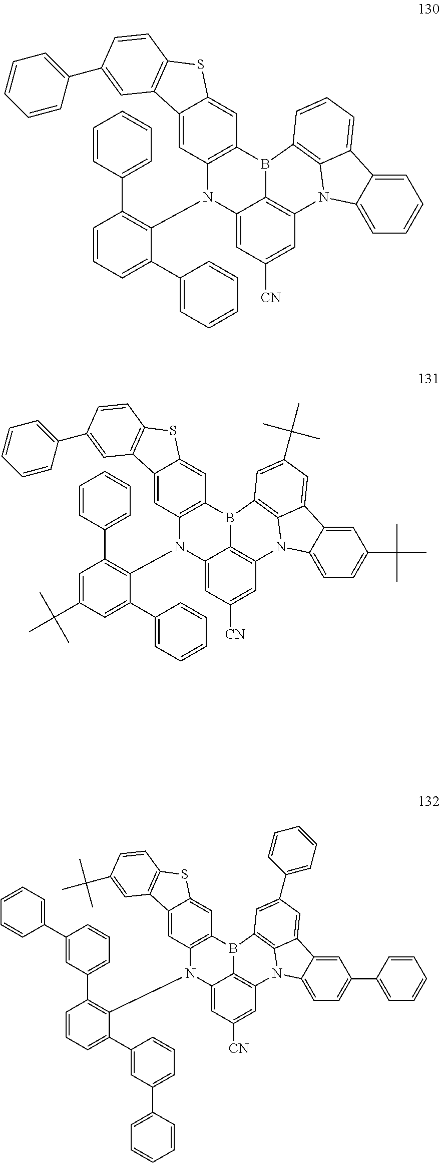 [SMILES: N#Cc1cc2c3c(c1)-n1c4ccccc4c4cccc(c41)B3c1cc3sc4ccc(-c5ccccc5)cc4c3cc1N2c1c(-c2ccccc2)cccc1-c1ccccc1 ; CC(C)(C)c1cc(-c2ccccc2)c(N2c3cc4c(cc3B3c5c2cc(C#N)cc5-n2c5ccc(C(C)(C)C)cc5c5cc(C(C)(C)C)cc3c52)sc2ccc(-c3ccccc3)cc24)c(-c2ccccc2)c1 ; CC(C)(C)c1ccc2sc3cc4c(cc3c2c1)N(c1c(-c2cccc(-c3ccccc3)c2)cccc1-c1cccc(-c2ccccc2)c1)c1cc(C#N)cc2c1B4c1cc(-c3ccccc3)cc3c4cc(-c5ccccc5)ccc4n-2c13]

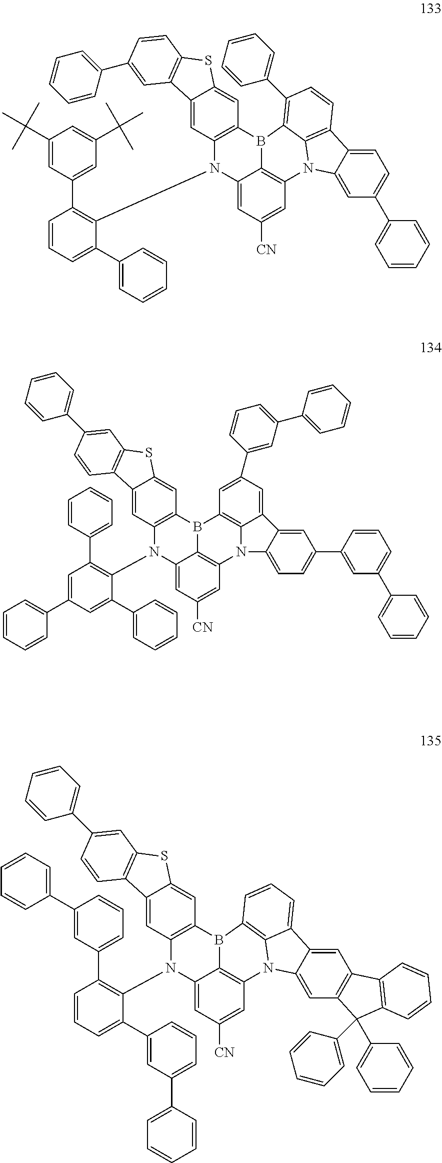 [SMILES: CC(C)(C)c1cc(-c2cccc(-c3ccccc3)c2N2c3cc4c(cc3B3c5c2cc(C#N)cc5-n2c5cc(-c6ccccc6)ccc5c5ccc(-c6ccccc6)c3c52)sc2ccc(-c3ccccc3)cc24)cc(C(C)(C)C)c1 ; N#Cc1cc2c3c(c1)-n1c4ccc(-c5cccc(-c6ccccc6)c5)cc4c4cc(-c5cccc(-c6ccccc6)c5)cc(c41)B3c1cc3sc4cc(-c5ccccc5)ccc4c3cc1N2c1c(-c2ccccc2)cc(-c2ccccc2)cc1-c1ccccc1 ; N#Cc1cc2c3c(c1)-n1c4cc5c(cc4c4cccc(c41)B3c1cc3sc4cc(-c6ccccc6)ccc4c3cc1N2c1c(-c2cccc(-c3ccccc3)c2)cccc1-c1cccc(-c2ccccc2)c1)-c1ccccc1C5(c1ccccc1)c1ccccc1]

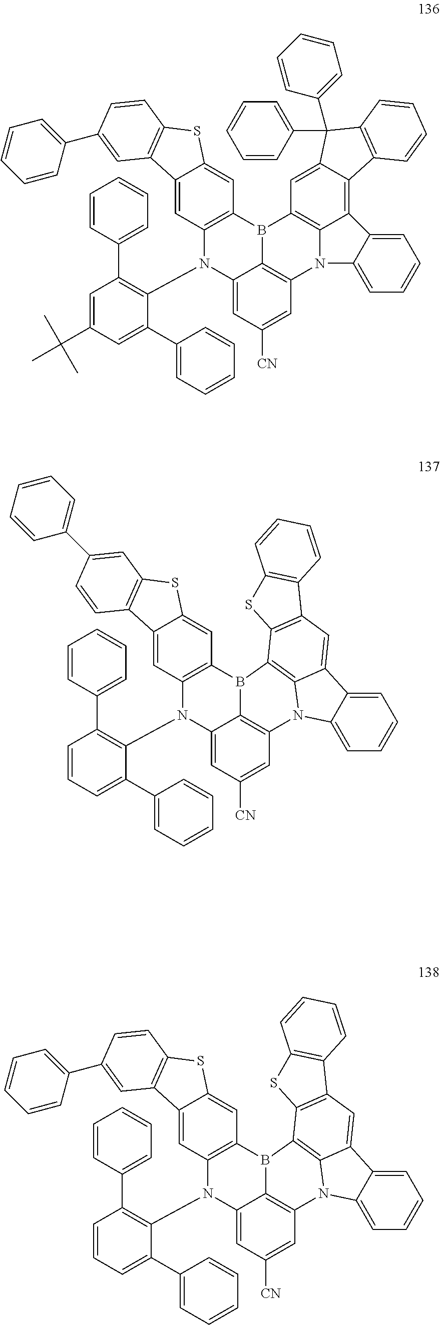 [SMILES: CC(C)(C)c1cc(-c2ccccc2)c(N2c3cc4c(cc3B3c5c2cc(C#N)cc5-n2c5ccccc5c5c6c(cc3c52)C(c2ccccc2)(c2ccccc2)c2ccccc2-6)sc2ccc(-c3ccccc3)cc24)c(-c2ccccc2)c1 ; N#Cc1cc2c3c(c1)-n1c4ccccc4c4cc5c(sc6ccccc65)c(c41)B3c1cc3sc4cc(-c5ccccc5)ccc4c3cc1N2c1c(-c2ccccc2)cccc1-c1ccccc1 ; N#Cc1cc2c3c(c1)-n1c4ccccc4c4cc5c(sc6ccccc65)c(c41)B3c1cc3sc4ccc(-c5ccccc5)cc4c3cc1N2c1c(-c2ccccc2)cccc1-c1ccccc1]

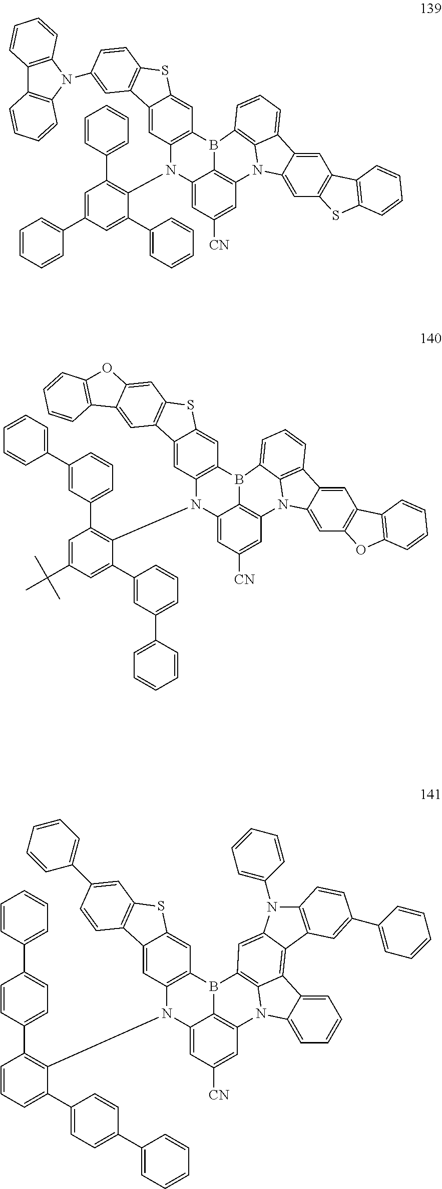 [SMILES: N#Cc1cc2c3c(c1)-n1c4cc5sc6ccccc6c5cc4c4cccc(c41)B3c1cc3sc4ccc(-n5c6ccccc6c6ccccc65)cc4c3cc1N2c1c(-c2ccccc2)cc(-c2ccccc2)cc1-c1ccccc1 ; CC(C)(C)c1cc(-c2cccc(-c3ccccc3)c2)c(N2c3cc4c(cc3B3c5c2cc(C#N)cc5-n2c5cc6oc7ccccc7c6cc5c5cccc3c52)sc2cc3oc5ccccc5c3cc24)c(-c2cccc(-c3ccccc3)c2)c1 ; N#Cc1cc2c3c(c1)-n1c4ccccc4c4c5c6cc(-c7ccccc7)ccc6n(-c6ccccc6)c5cc(c41)B3c1cc3sc4cc(-c5ccccc5)ccc4c3cc1N2c1c(-c2ccc(-c3ccccc3)cc2)cccc1-c1ccc(-c2ccccc2)cc1]

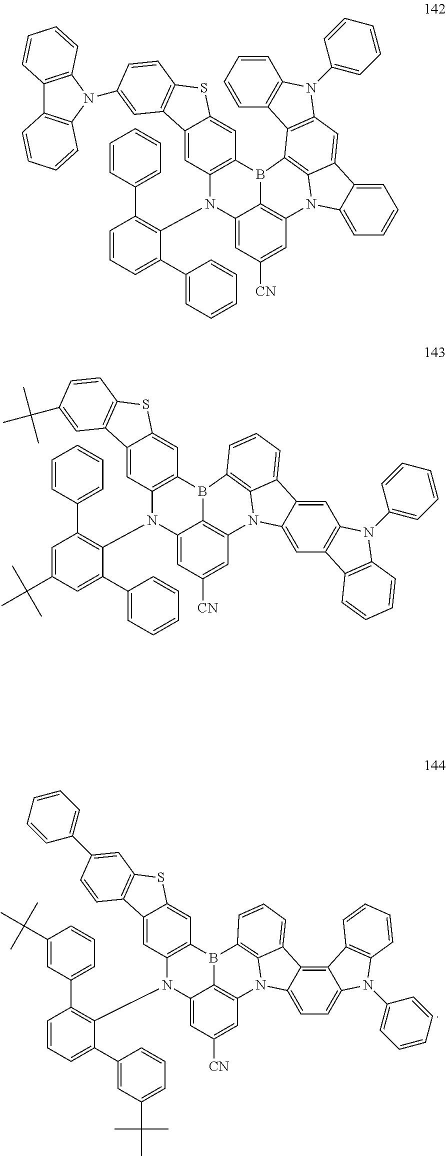 [SMILES: N#Cc1cc2c3c(c1)-n1c4ccccc4c4cc5c(c(c41)B3c1cc3sc4ccc(-n6c7ccccc7c7ccccc76)cc4c3cc1N2c1c(-c2ccccc2)cccc1-c1ccccc1)c1ccccc1n5-c1ccccc1 ; CC(C)(C)c1cc(-c2ccccc2)c(N2c3cc4c(cc3B3c5c2cc(C#N)cc5-n2c5cc6c7ccccc7n(-c7ccccc7)c6cc5c5cccc3c52)sc2ccc(C(C)(C)C)cc24)c(-c2ccccc2)c1 ; CC(C)(C)c1cccc(-c2cccc(-c3cccc(C(C)(C)C)c3)c2N2c3cc4c(cc3B3c5c2cc(C#N)cc5-n2c5ccc6c(c7ccccc7n6-c6ccccc6)c5c5cccc3c52)sc2cc(-c3ccccc3)ccc24)c1]

The light emitting element ED including the fused polycyclic compound of one or more embodiments may be to emit green light. The second light emitting element ED-2 (FIG. 2) emitting green light may include the fused polycyclic compound of one or more embodiments.

The emission layer EML may include the fused polycyclic compound of one or more embodiments as a dopant. The fused polycyclic compound of one or more embodiments may be a delayed fluorescence material. The fused polycyclic compound of one or more embodiments may be a thermally activated delayed fluorescence (TADF) material. The fused polycyclic compound of one or more embodiments may be to emit light through the transformation (e.g., up-conversion) of triplet excitons into singlet excitons by a reverse inter system crossing (RISC) mechanism.

The fused polycyclic compound of one or more embodiments may include a fused ring with nine rings, including two nitrogen atoms, one boron atom and a fused heteroatom as ring-forming atoms, as a central structure. The fused heteroatom may be a nitrogen atom, an oxygen atom, or a sulfur atom. The fused heteroatom may correspond to Y₁ of the Formula 1. In addition, the fused polycyclic compound of one or more embodiments may include a biphenyl moiety combined with (e.g., bonded to) the nitrogen atom (one among the two nitrogen atoms) of the central structure and a cyano group combined (e.g., bonded) at the para position of a benzene ring with respect to the boron atom. The biphenyl moiety may correspond to the biphenyl moiety including R_{c1} to R_{c9} in Formula 1. The central structure included in the fused polycyclic compound of one or more embodiments may be represented by Formula Z1. In Formula Z1, the same contents explained in Formula 1 may be applied for Y₁. In Formula Z1, N^{c} is indicated by alphabet letter ‘c’ in the nitrogen atom for the convenience of explanation. N^{c} is the nitrogen atom binding biphenyl moiety including R_{c1} to R_{c9} in Formula 1.

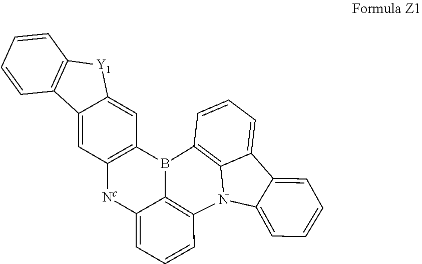

The boron atom that is a ring-forming atom, includes a vacant p-orbital, and a compound including a boron atom exhibits electron-deficient properties due to the vacant p-orbital, and is easy to form a bond with a nucleophile. In this regard, a ring group containing the boron atom may be transformed into a tetrahedral structure; as a result, deterioration of a light emitting element including the compound may occur. In addition, a general compound containing a boron atom and used as a light emitting material may have a plate-like structure, and the compound having a plate-like structure may enhance intermolecular interaction. Intermolecular interactions that cause intermolecular aggregation, intermolecular excimer formation, and intermolecular exciplex formation induce the deterioration of the efficiency and lifespan of a light emitting element.

The fused polycyclic compound of one or more embodiments includes a biphenyl moiety, and the biphenyl moiety may increase an intermolecular distance, thereby preventing or reducing (or minimizing) intermolecular interaction and Dexter energy transfer. Because the Dexter energy transfer may be prevented or reduced, the concentration of triplet excitons may decrease, and thus a light emitting element ED including the fused polycyclic compound of one or more embodiments may show long-life characteristics.

Because the biphenyl moiety may prevent or reduce intermolecular aggregation, the purification of a fused polycyclic compound during synthesizing the fused polycyclic compound may become easy, thermal stability may increase in sublimation and purification stages during synthesis, and color purity may be improved during emitting light. Accordingly, a light emitting element ED including the fused polycyclic compound of one or more embodiments may show excellent or suitable emission efficiency.

The fused polycyclic compound of one or more embodiments includes a cyano group combined at the para position of a benzene ring with respect to the boron atom of the central structure, and the cyano group exhibits electron accepting properties and corresponds to a sterically bulky substituent. Accordingly, the fused polycyclic compound of one or more embodiments has a relatively small molecular weight compared to those containing a bulky substituent at the same position, and may exhibit excellent or suitable material stability and relatively simple synthesizing processes of a compound.

In one or more embodiments, the emission layer EML includes the fused polycyclic compound of one or more embodiments and may further include at least one selected from among second to fourth compounds. In one or more embodiments, the emission layer may include a second compound represented by Formula HT-1. For example, the second compound may be used as a hole transporting host material of the emission layer EML.

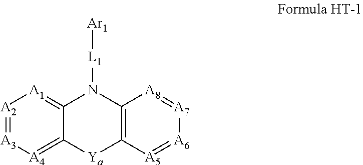

In Formula HT-1, A₁ to A₈ may each independently be N or CR₅₁. For example, in one or more embodiments, all of A₁ to A₈ may each be CR₅₁. In one or more embodiments, any one selected from among A₁ to A₈ may be N, and the rest may be CR₅₁.

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, in one or more embodiments, L₁ may be a direct linkage, a substituted or unsubstituted phenylene group, a substituted or unsubstituted divalent biphenyl group, a substituted or unsubstituted divalent carbazole group, and/or the like, but embodiments of the present disclosure are not limited thereto.

In Formula HT-1, Yₐ may be a direct linkage, CR₅₂R₅₃, or SiR₅₄R₅₅. That is, it may refer to that two 6-membered rings (e.g., two benzene rings) linked to the nitrogen atom in Formula HT-1 are linked via a direct linkage,

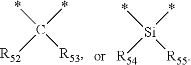

In Formula HT-1, if (e.g., when) Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, in one or more embodiments, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among R₅₁ to R₅₅ may be each independently bonded to an adjacent group to form a ring. For example, in one or more embodiments, R₅₁ to R₅₅ may each independently be hydrogen or deuterium. In one or more embodiments, R₅₁ to R₅₅ may each independently be an unsubstituted methyl group or an unsubstituted phenyl group.

In one or more embodiments, the second compound represented by Formula HT-1 may be any one selected from among compounds represented by Compound Group 2. The emission layer EML may include at least one selected from among the compounds represented by Compound Group 2 as a hole transporting host material.

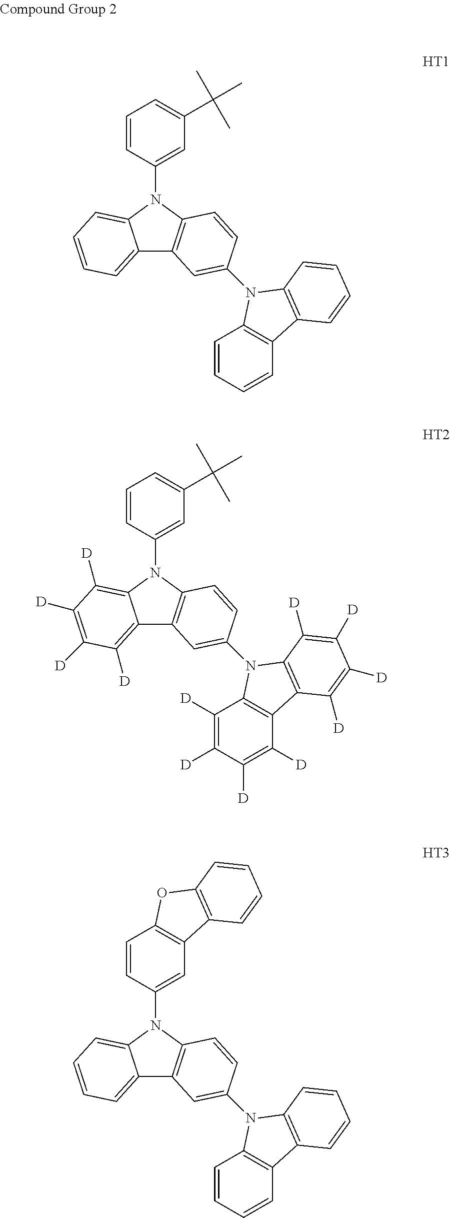 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

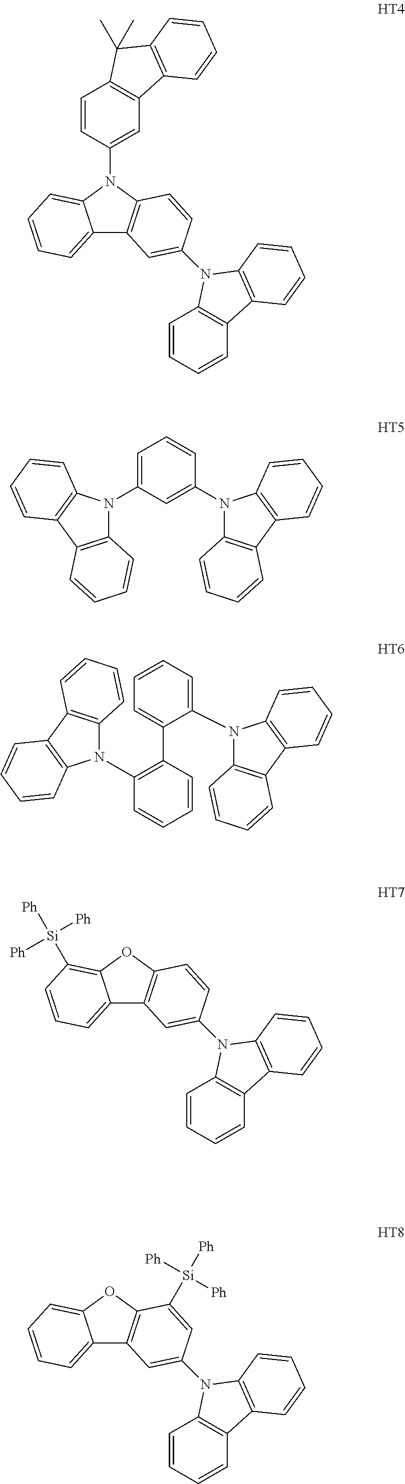 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

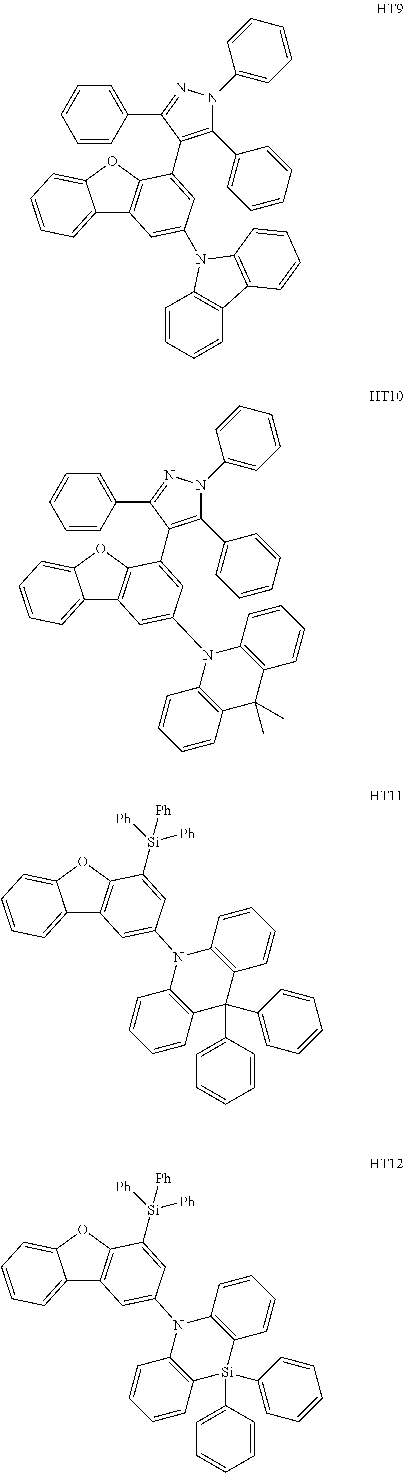 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

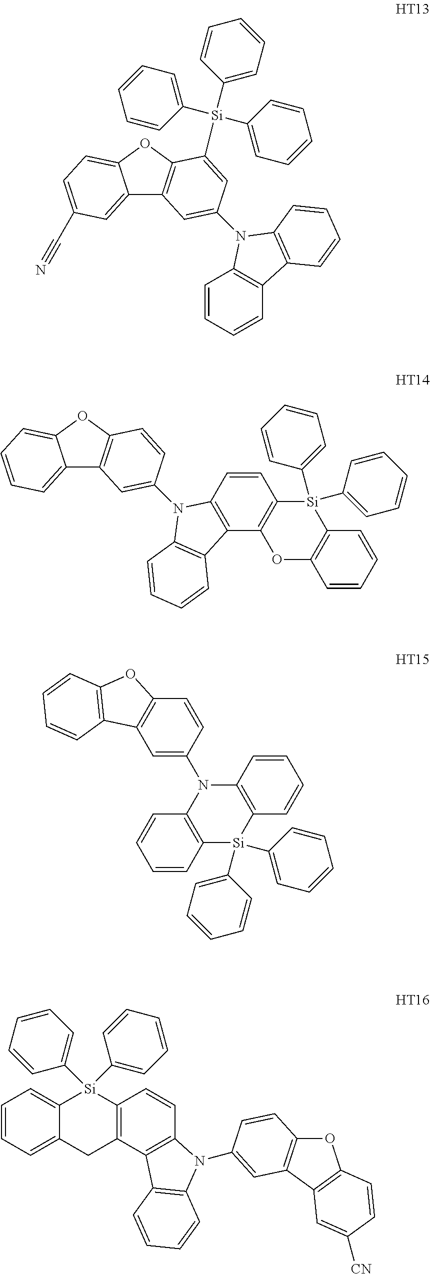 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4C6)cc3c2c1]

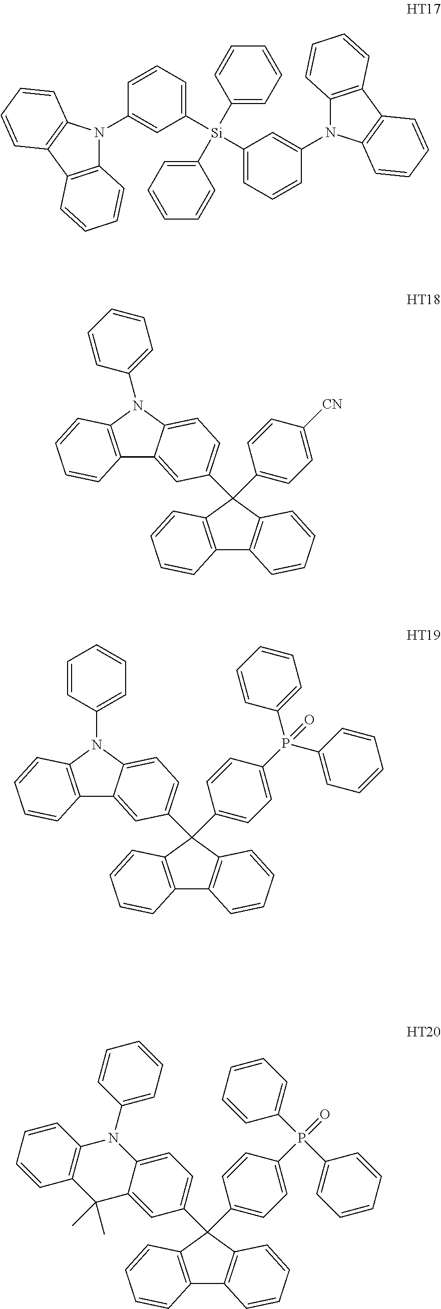 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

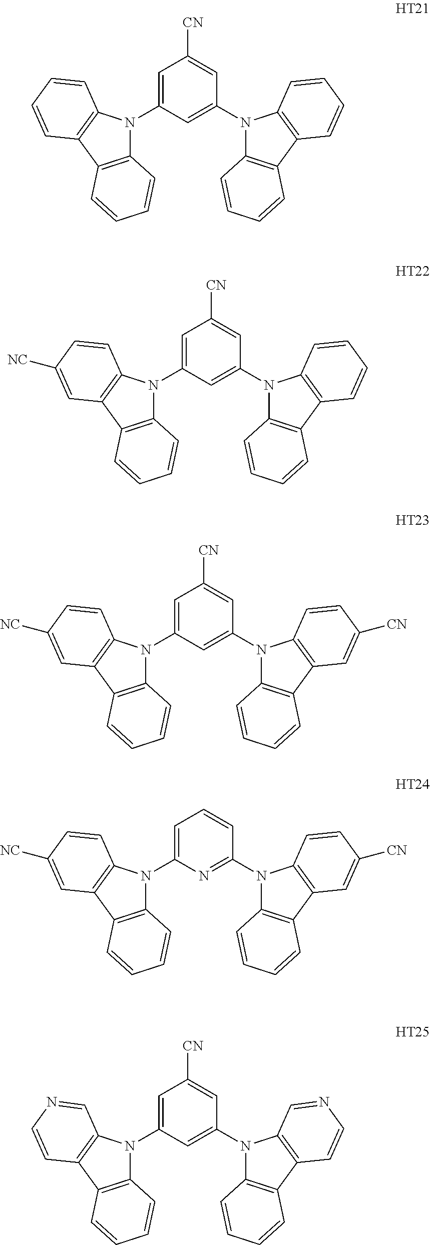 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1]

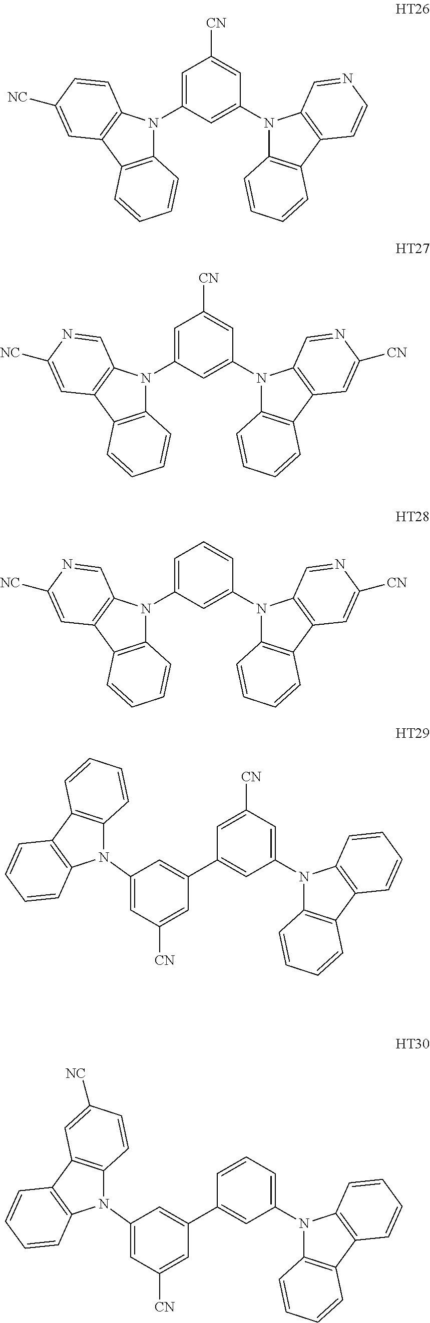 [SMILES: N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)c3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

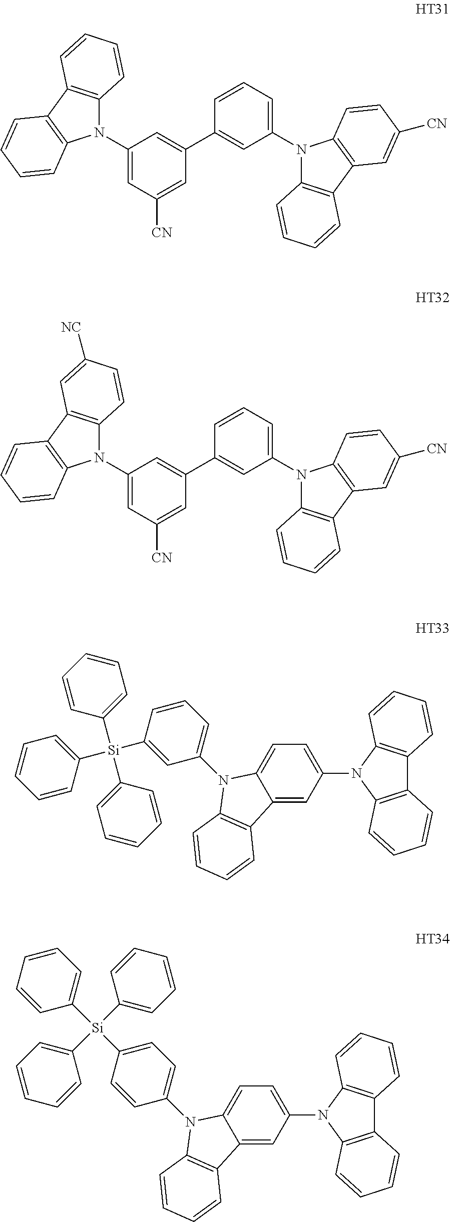 [SMILES: N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1]

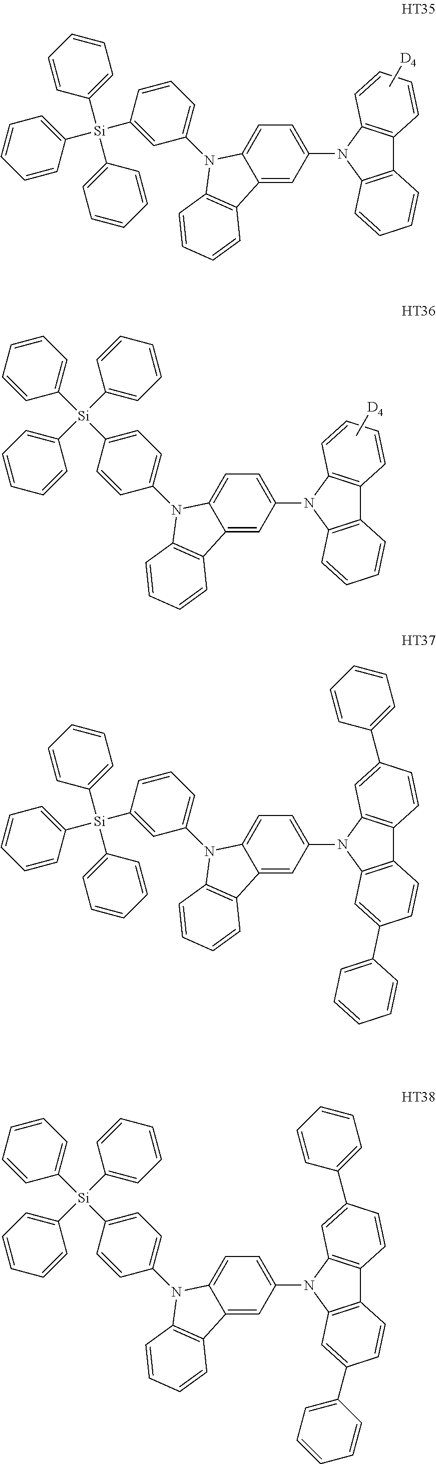

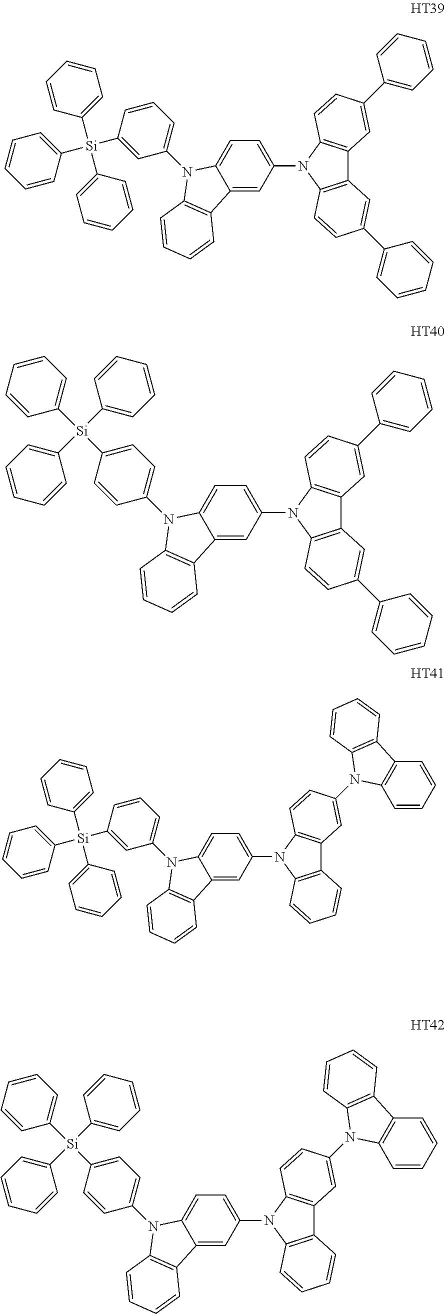 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

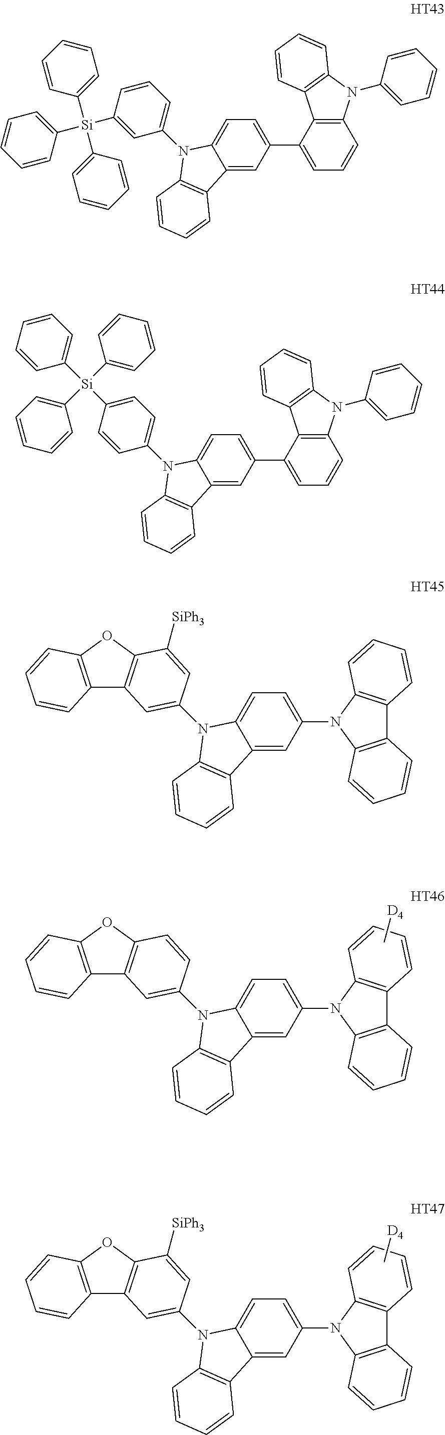

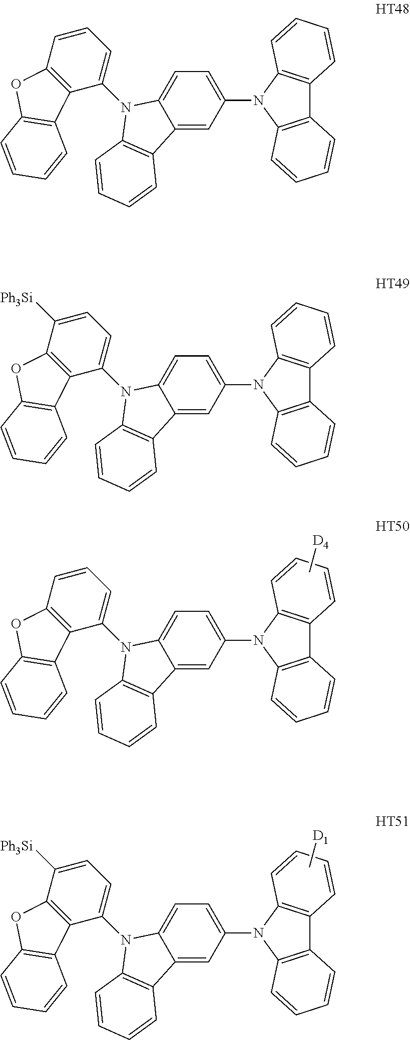

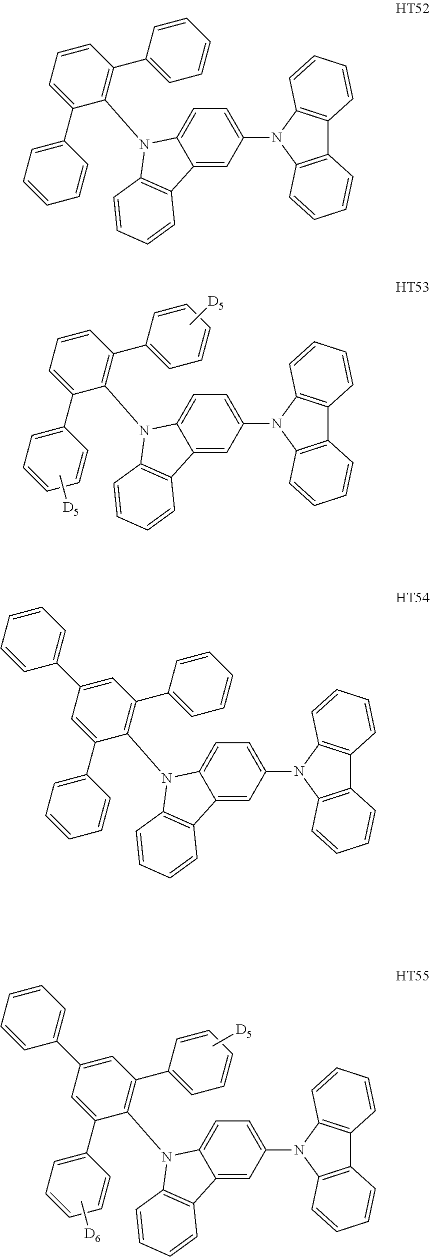

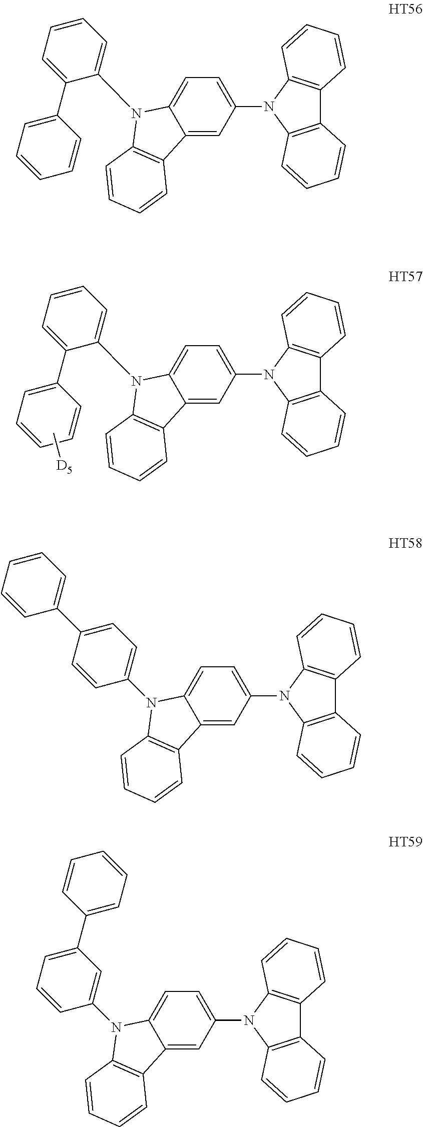

In embodiment compounds presented in Compound Group 2, “D” may refer to a deuterium atom, and “Ph” may refer to a substituted or unsubstituted phenyl group. For example, in embodiment compounds presented in Compound Group 2, “Ph” may refer to an unsubstituted phenyl group.

In one or more embodiments, the emission layer EML may include the third compound represented by Formula ET-1. For example, the third compound may be used as an electron transporting host material for the emission layer EML.

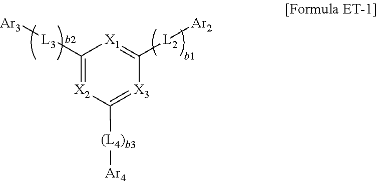

In Formula ET-1, at least one selected from among X₁ to X₃ may be N, and the rest are CR₅₆. For example, in one or more embodiments, any one selected from among X₁ to X₃ may be N, and the rest may each independently be CR₅₆. In these embodiments, the third compound represented by Formula ET-1 may include a pyridine moiety. In one or more embodiments, two selected from among X₁ to X₃ may be N, and the rest may be CR₅₆. In these embodiments, the third compound represented by Formula ET-1 may include a pyrimidine moiety. In one or more embodiments, X₁ to X₃ may all be N. In these embodiments, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer of 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in one or more embodiments, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) b1 to b3 are each an integer of 2 or greater, L₂'s to L₄'s may each independently be a substituted or unsubstituted arylene group having 6 to 30 ring-forming carbon atoms or a substituted or unsubstituted heteroarylene group having 2 to 30 ring-forming carbon atoms.

In one or more embodiments, the third compound may be any one selected from among compounds in Compound Group 3. The light emitting element ED of one or more embodiments may include any one selected from among the compounds in Compound Group 3.

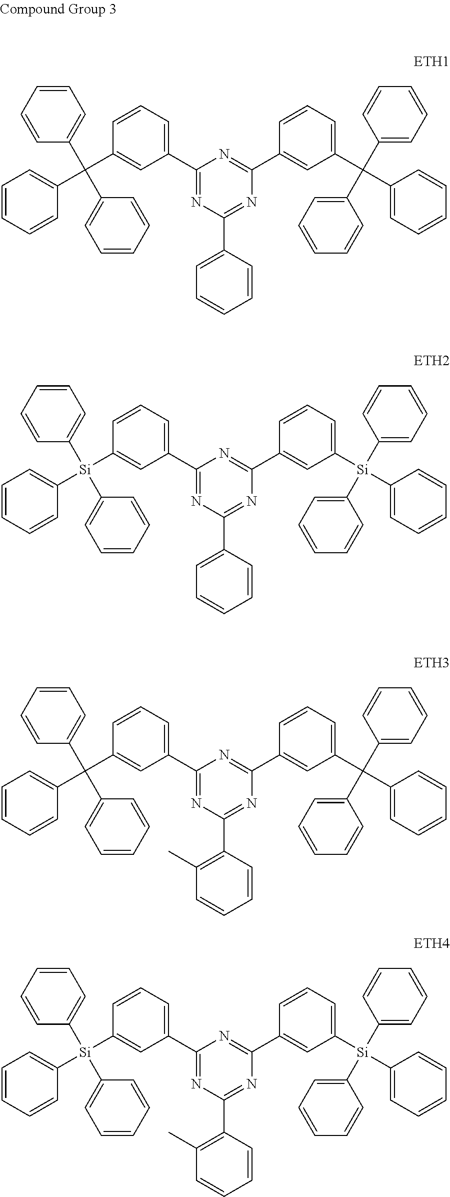 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

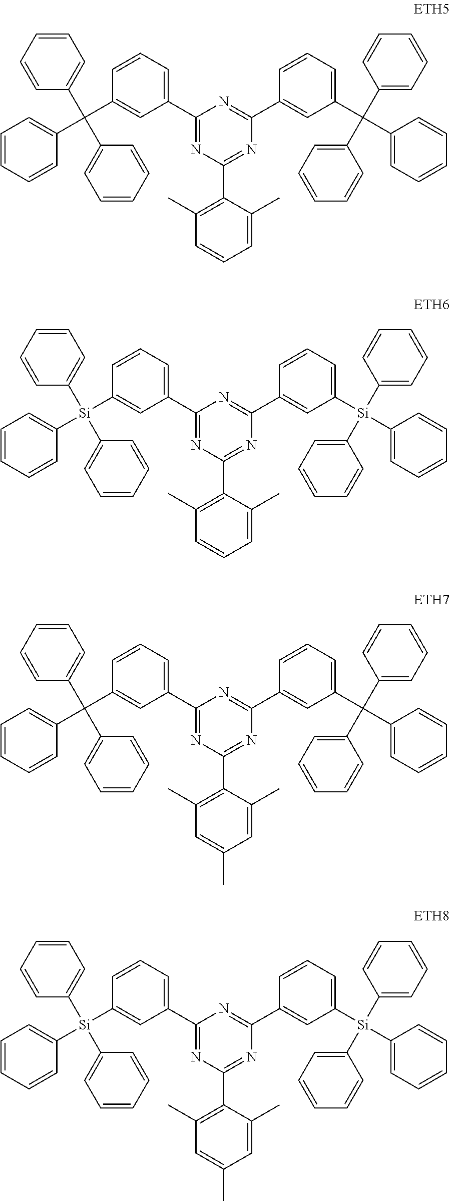 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

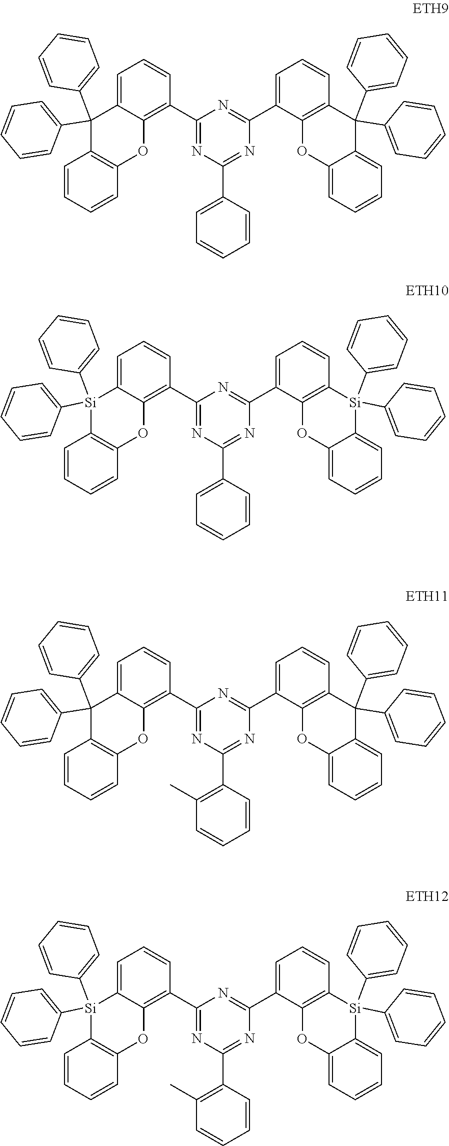 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

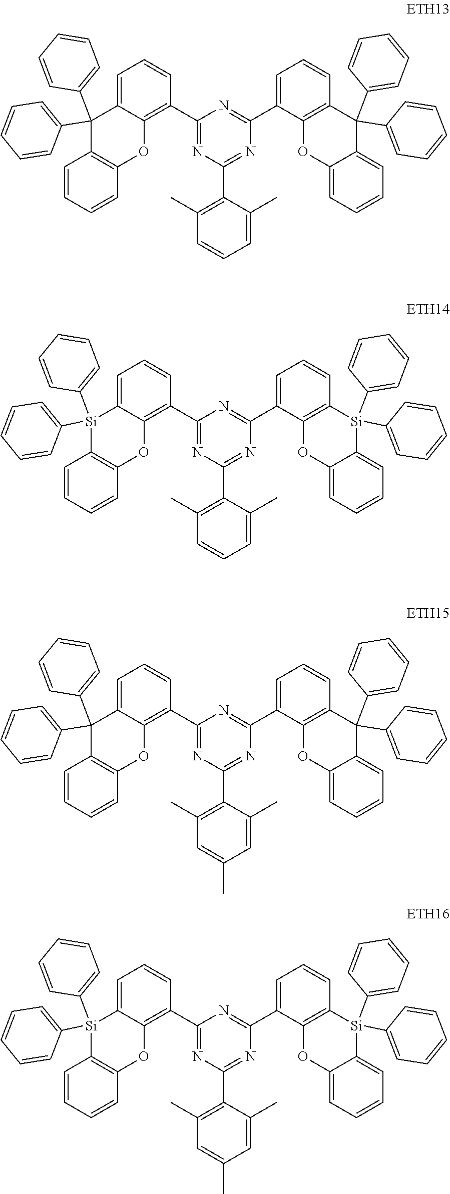 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

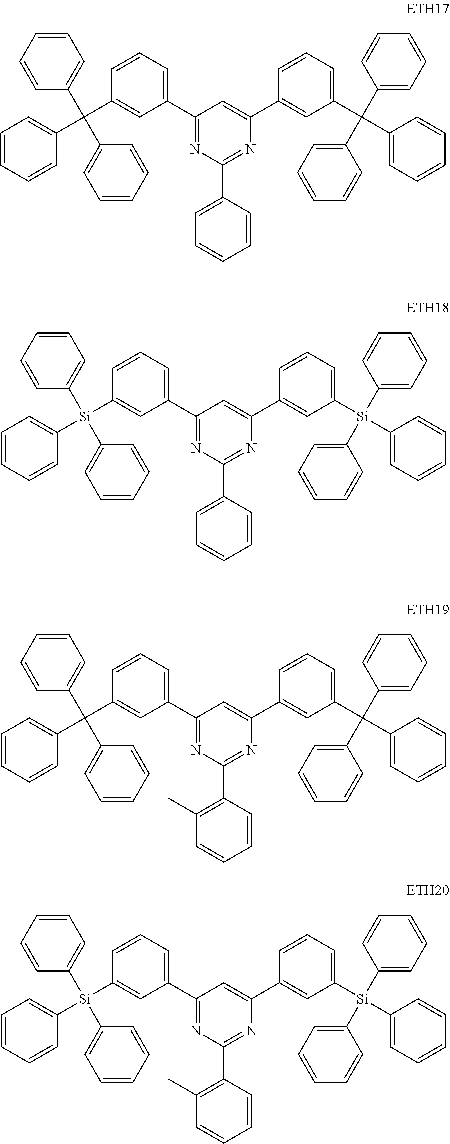 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

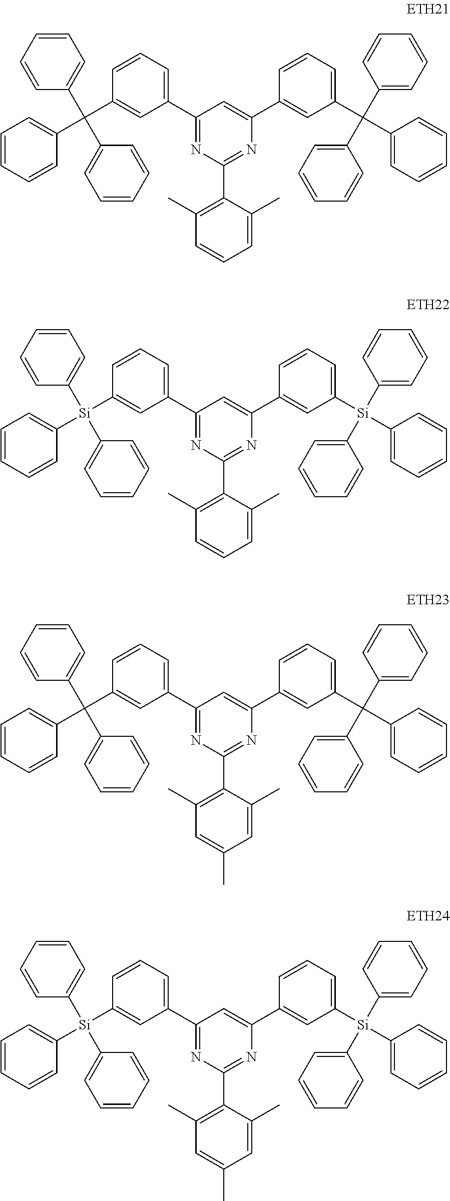 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

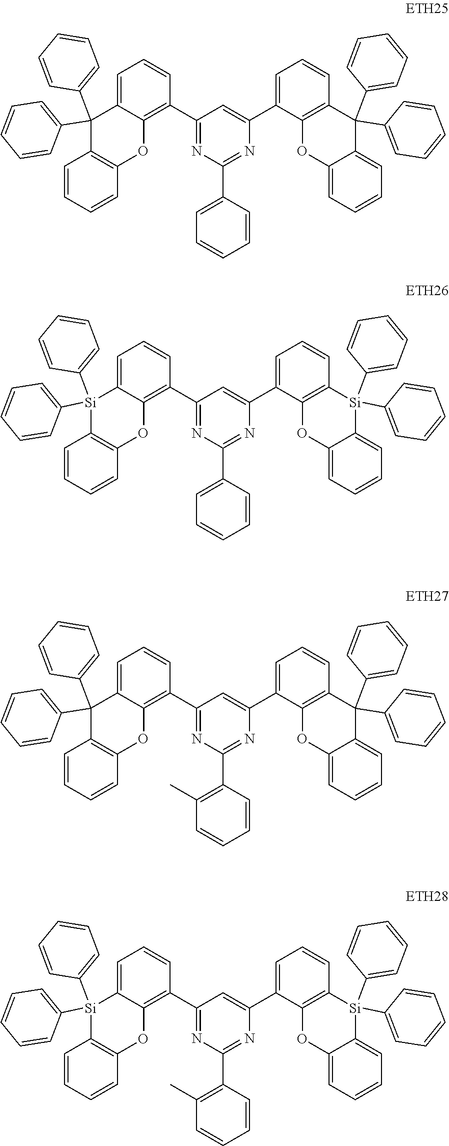 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

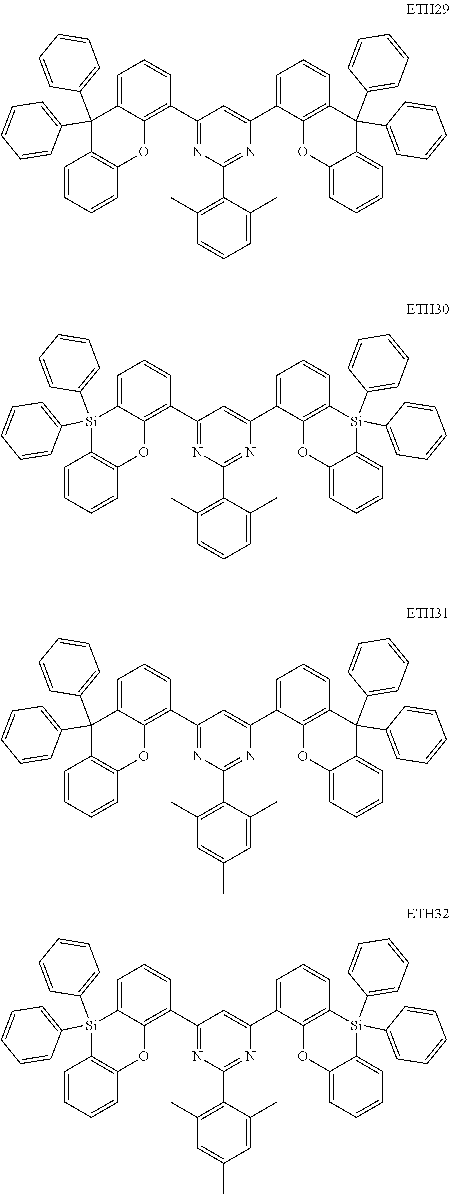 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

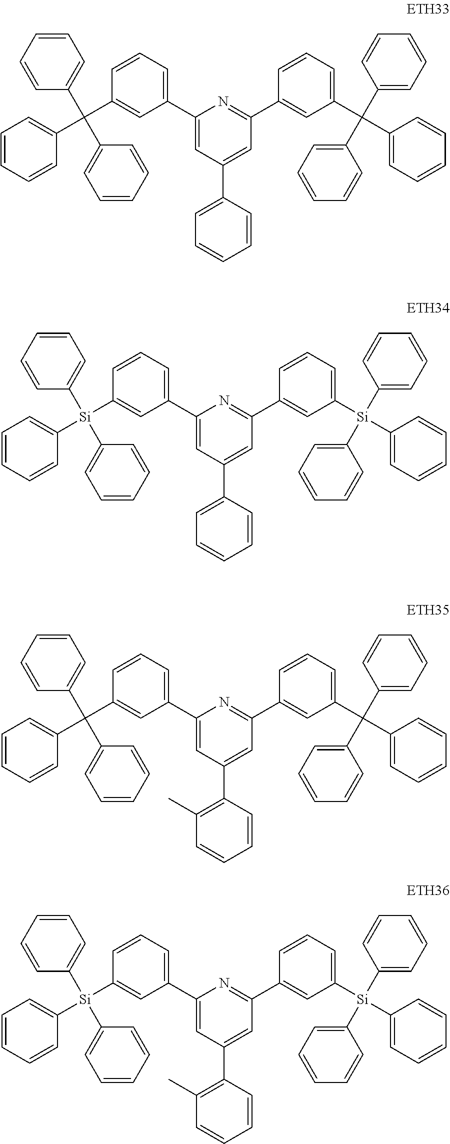 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

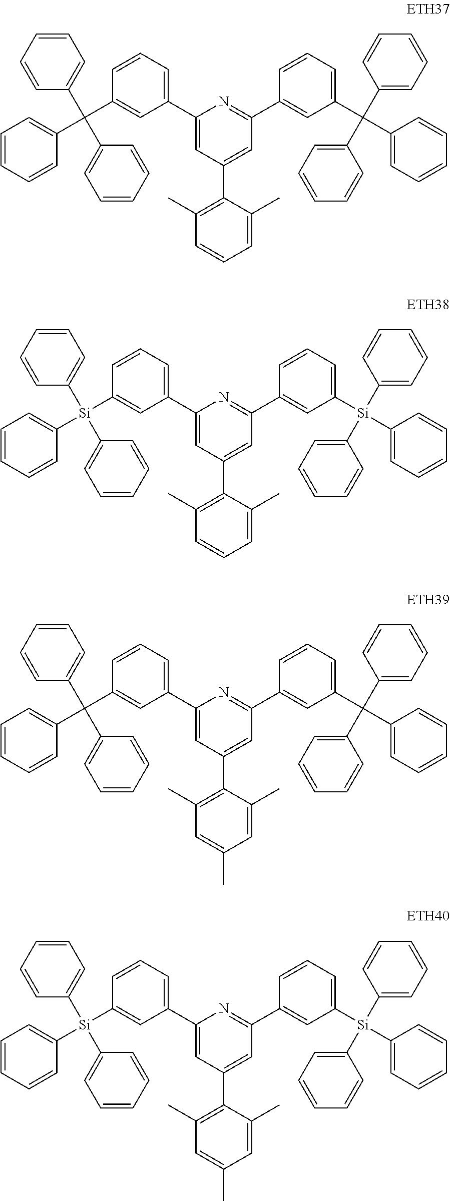 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

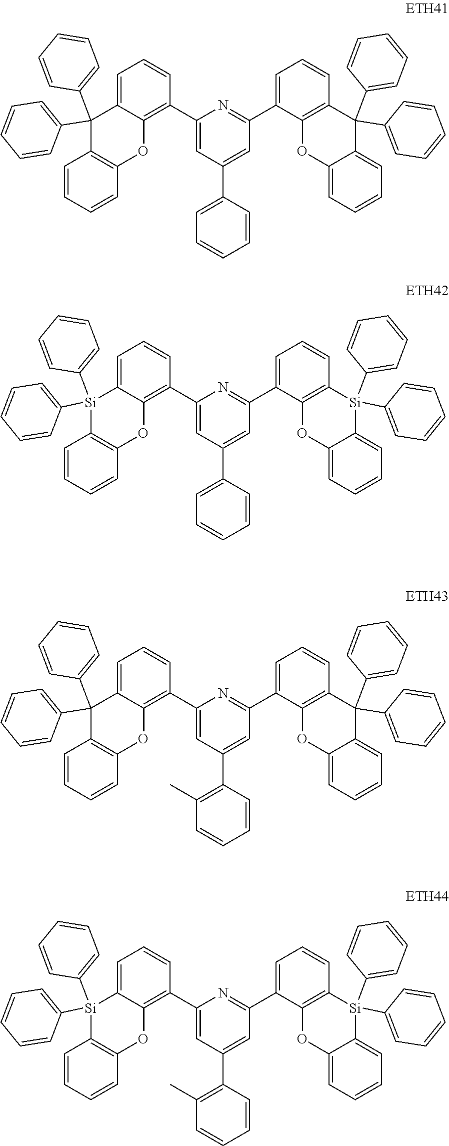 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

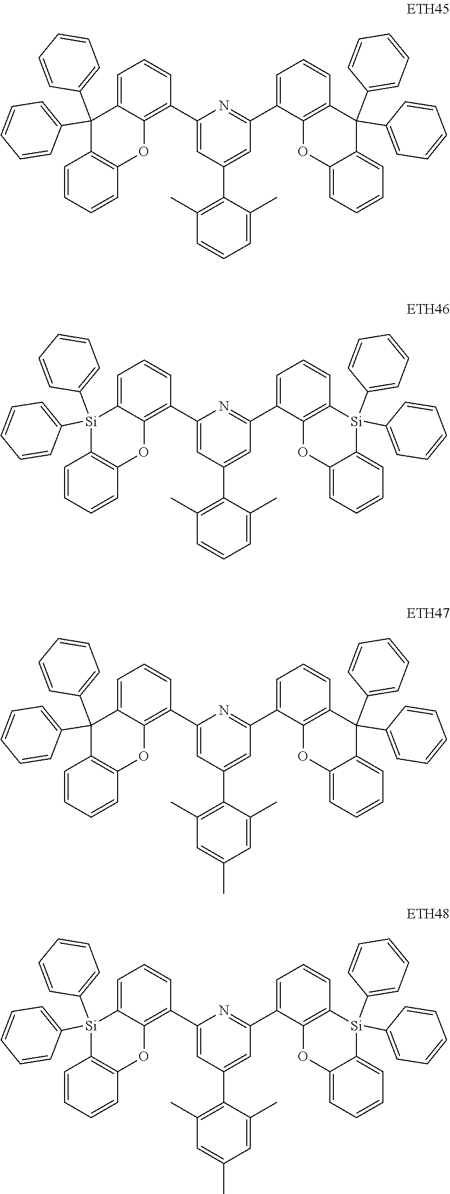 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

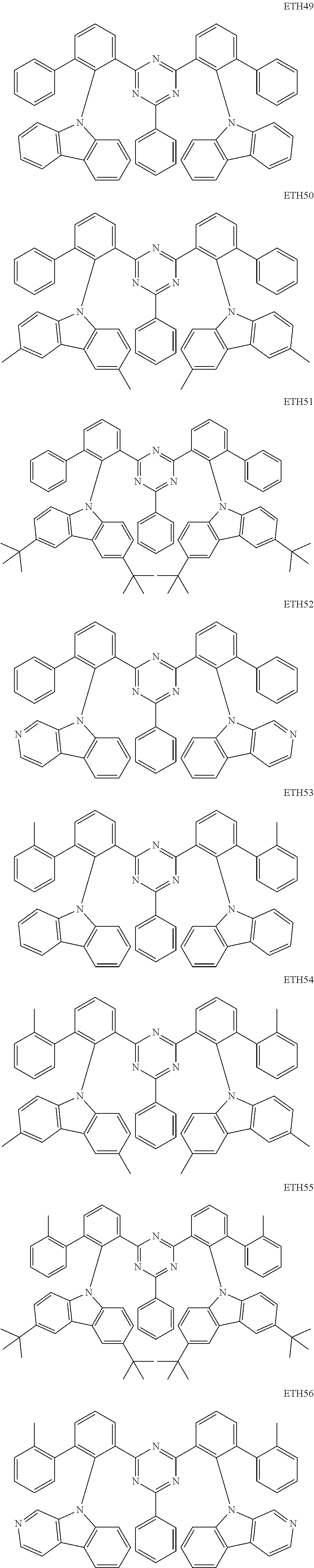

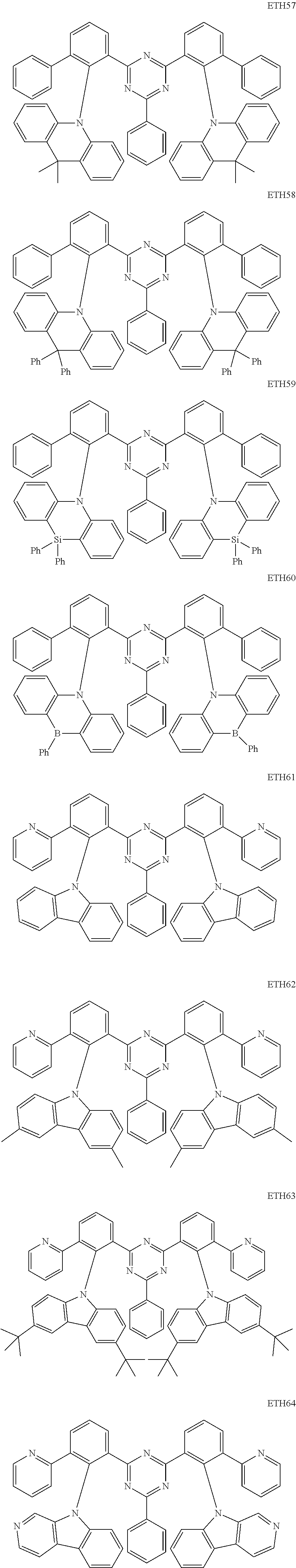

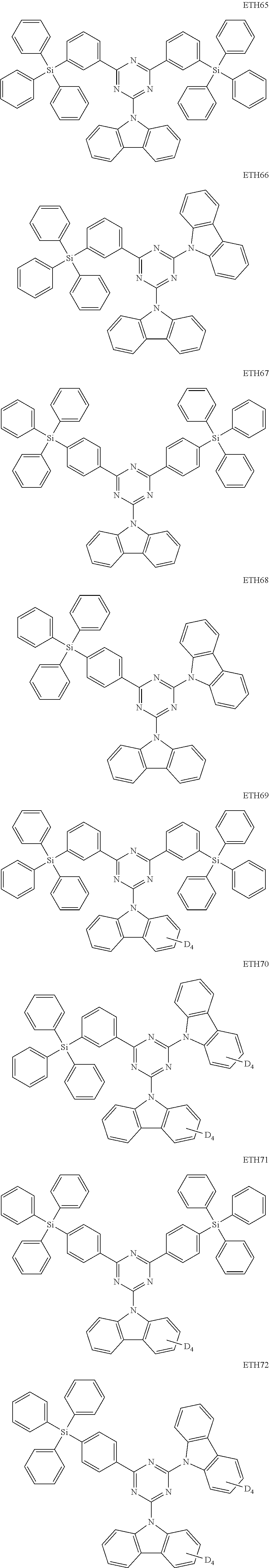

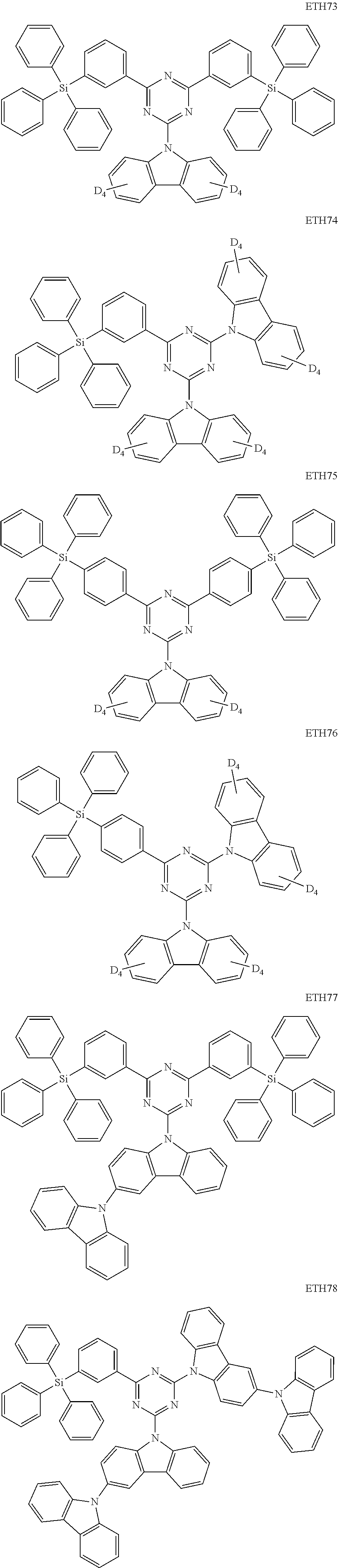

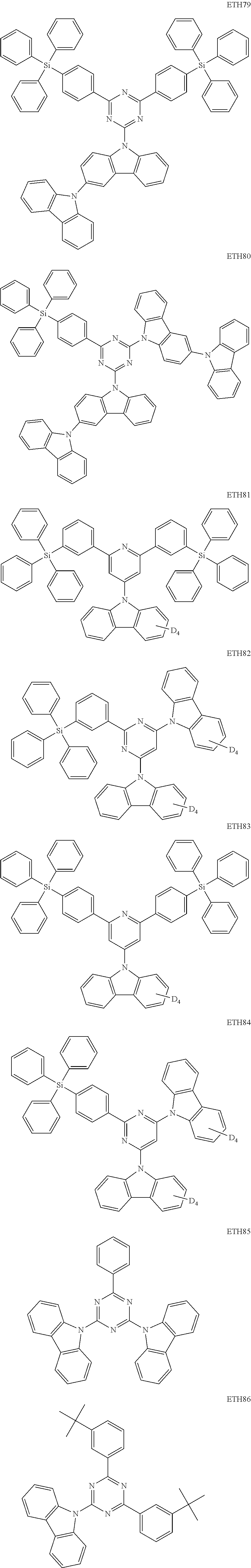

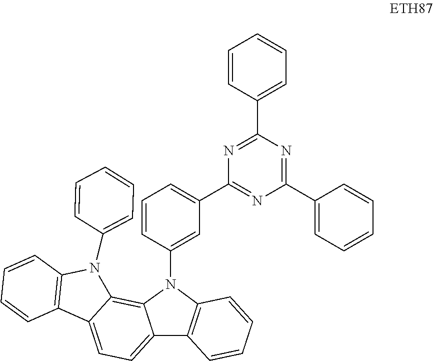 [SMILES: c1ccc(-c2nc(-c3ccccc3)nc(-c3cccc(-n4c5ccccc5c5ccc6c7ccccc7n(-c7ccccc7)c6c54)c3)n2)cc1]

In the embodiment compounds presented in Compound Group 3, “D” refers to a deuterium atom, and “Ph” refers to an unsubstituted phenyl group.

In one or more embodiments, the emission layer EML may include the second compound and the third compound, and the second compound and the third compound may form an exciplex. In the emission layer EML, an exciplex may be formed by the hole transporting host and the electron transporting host. In this regard, a triplet energy of the exciplex formed by the hole transporting host and the electron transporting host may correspond to a difference between a lowest unoccupied molecular orbital (LUMO) energy level of the electron transporting host and a highest occupied molecular orbital (HOMO) energy level of the hole transporting host.

For example, in one or more embodiments, an absolute value of the triplet energy (T1) of the exciplex formed by the hole transporting host and the electron transporting host may be about 2.4 eV to about 3.0 eV. In addition, the triplet energy of the exciplex may be a value smaller than an energy gap of each host material. The exciplex may have a triplet energy of about 3.0 eV or less that is an energy gap between the hole transporting host and the electron transporting host.

In one or more embodiments, the emission layer EML may include a fourth compound in addition to the first compound to the third compound as described above. The fourth compound may be used as a phosphorescent sensitizer of the emission layer EML. The energy may be transferred from the fourth compound to the first compound, thereby emitting light.

For example, in one or more embodiments, the emission layer EML may include, as the fourth compound, an organometallic complex containing platinum (Pt) as a central metal atom and ligands linked to the central metal atom. The emission layer EML in the light emitting element ED of one or more embodiments may include, as the fourth compound, a compound represented by Formula D-1:

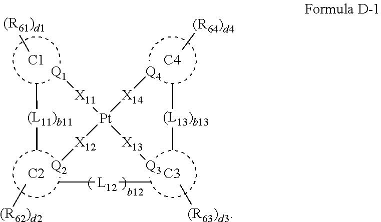

In Formula D-1, Q₁ to Q₄ may each independently be C or N. In Formula D-1, C1 to C4 may each independently be a substituted or unsubstituted hydrocarbon ring having 5 to 30 ring-forming carbon atoms, a substituted or unsubstituted aryl group having 6 to 30 ring-forming carbon atoms, or a substituted or unsubstituted heterocycle having 2 to 30 ring-forming carbon atoms,
X₁₁ to X₁₄ may each independently be a direct linkage, or *—O—*. For example, in one or more embodiments, any one selected from among X₁₁ to X₁₄ may be *—O—*, and the remainder may be a direct linkage.

In Formula D-1, L₁₁ to L₁₃ may each independently be a direct linkage,

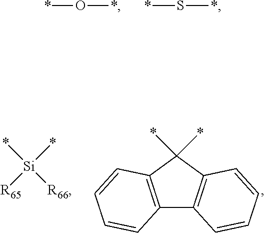

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “ [symbol] ” refers to a part linked to C1 to C4.

In Formula D-1, b11 to b13 may each independently be 0 or 1. If (e.g., when) b11 is 0, C1 and C2 may not be linked to each other. If (e.g., when) b12 is 0, C2 and C3 may not be linked to each other. If (e.g., when) b13 is 0, C3 and C4 may not be linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In one or more embodiments, one or more selected from among R₆₁ to R₆₆ may be independently bonded to an adjacent group to form a ring. In one or more embodiments, R₆₁ to R₆₆ may each independently be a substituted or unsubstituted methyl group or a substituted or unsubstituted t-butyl group.

In Formula D-1, d1 to d4 may each independently be an integer of 0 to 4. In Formula D-1, if (e.g., when) each of d1 to d4 is 0, the fourth compound may not be substituted with each of R₆₁ to R₆₄. The embodiment in which each of d1 to d4 is 4 and R₆₁'s to R₆₄'s are each hydrogen may be the same as the embodiment in which each of d1 to d4 is 0. When each of d1 to d4 is an integer of 2 or greater, a plurality of R₆₁'s to R₆₄'s may each be the same or at least one selected from among the plurality of R₆₁'s to R₆₄'s may be different from the others.

In Formula D-1, C1 to C4 may each independently be a substituted or unsubstituted hydrocarbon ring, a substituted or unsubstituted aryl group, or a substituted or unsubstituted heterocycle represented by any one selected from among C-1 to C-4:

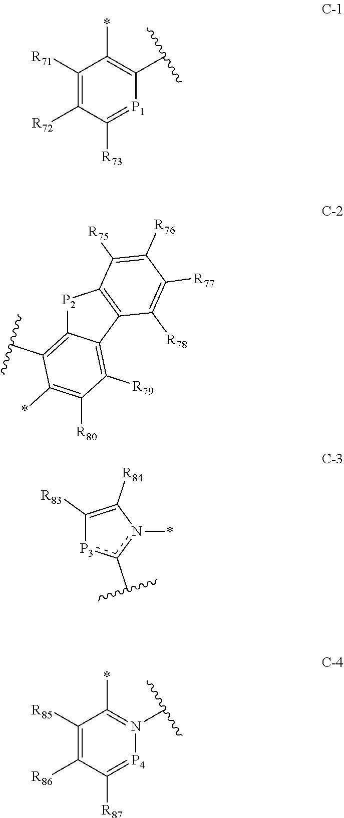

In C-1 to C-4, P₁ may be C—* or CR₇₄, P₂ may be N—* or NR₈₁, P₃ may be N—* or NRa₈₂, and P₄ may be C—* or CR₈₈. R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In addition, in C-1 to C-4,

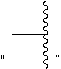

corresponds to a part linked to Pt that is a central metal atom, and “ [symbol] ” corresponds to a part linked to a neighboring cyclic group (C1 to C4) or an adjacent linker (L₁₁ to L₁₃).

The emission layer EML of one or more embodiments may include the first compound, which is a fused polycyclic compound represented by Formula 1, and at least one selected from among the second to fourth compounds. For example, in one or more embodiments, the emission layer EML may include the first compound, the second compound, and the third compound. In the emission layer EML, the second compound and the third compound may form an exciplex, and the energy may be transferred from the exciplex to the first compound, thereby emitting light.

In one or more embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In one or more embodiments, the fourth compound may be a sensitizer. The fourth compound included in the emission layer EML in the light emitting element ED of one or more embodiments may serve as a sensitizer to deliver energy from the host to the first compound that is a light emitting dopant. For example, in one or more embodiments, the fourth compound serving as an auxiliary dopant accelerates energy delivery to the first compound that is a light emitting dopant, thereby increasing the emission ratio of the first compound. Therefore, the emission layer EML of one or more embodiments may improve luminous efficiency. In addition, if (e.g., when) the energy delivery to the first compound is increased, an exciton formed in the emission layer EML is not accumulated inside the emission layer EML and instead emits light rapidly, and thus deterioration of the element may be reduced. Therefore, the service life of the light emitting element ED of one or more embodiments may increase.

The light emitting element ED of one or more embodiments may include all of the first compound, the second compound, the third compound, and the fourth compound, and the emission layer EML may include the combination of two host materials and two dopant materials. In the light emitting element ED of one or more embodiments, the emission layer EML may concurrently (e.g., simultaneously) include the second compound and the third compound, which are two different hosts, the first compound that emits a delayed fluorescence, and the fourth compound including an organometallic complex, thereby exhibiting excellent or suitable luminous efficiency characteristics.

In one or more embodiments, the fourth compound represented by Formula D-1 may be any one selected from among compounds represented in Compound Group 4. The emission layer EML may include at least one selected from among the compounds represented in Compound Group 4 as a sensitizer material.

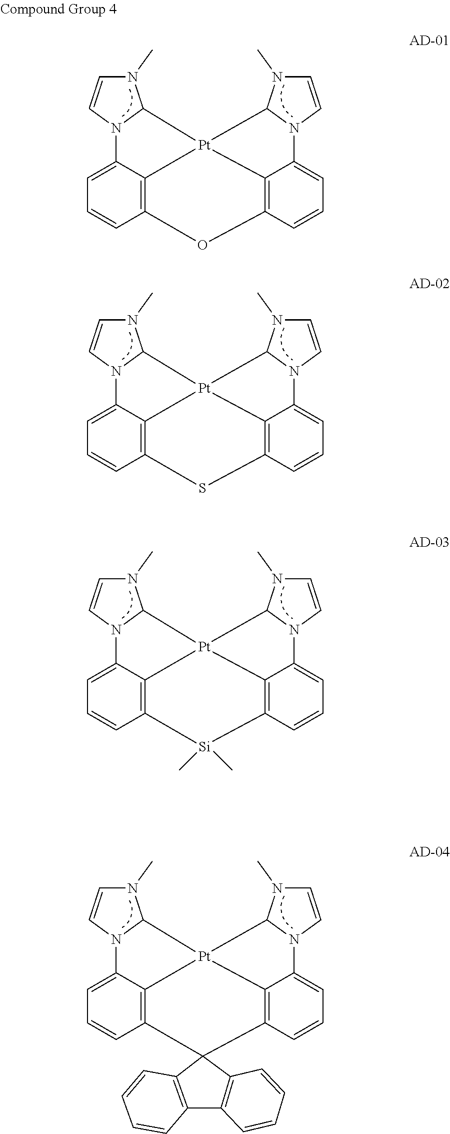

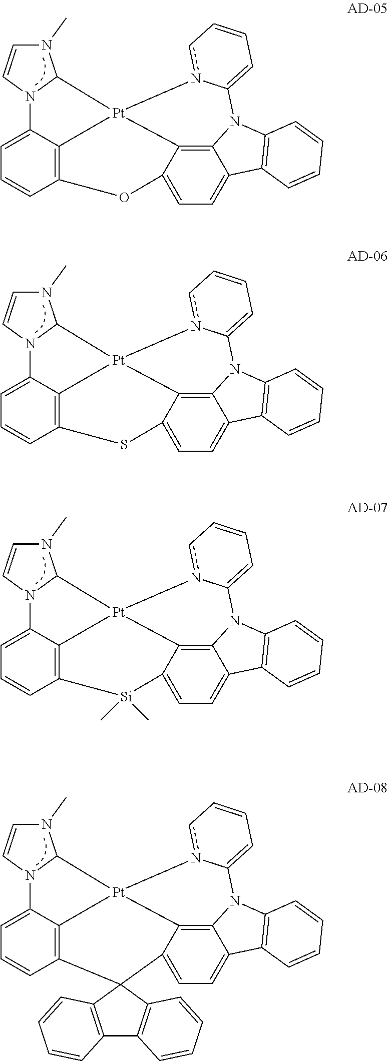

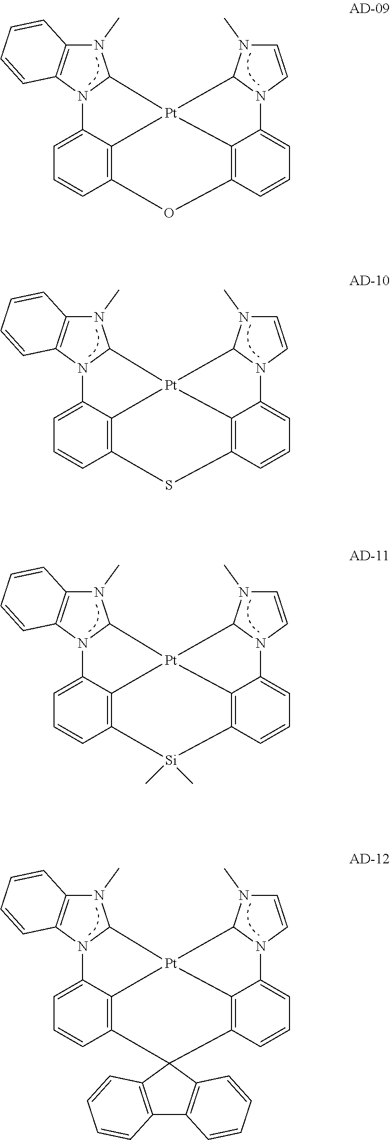

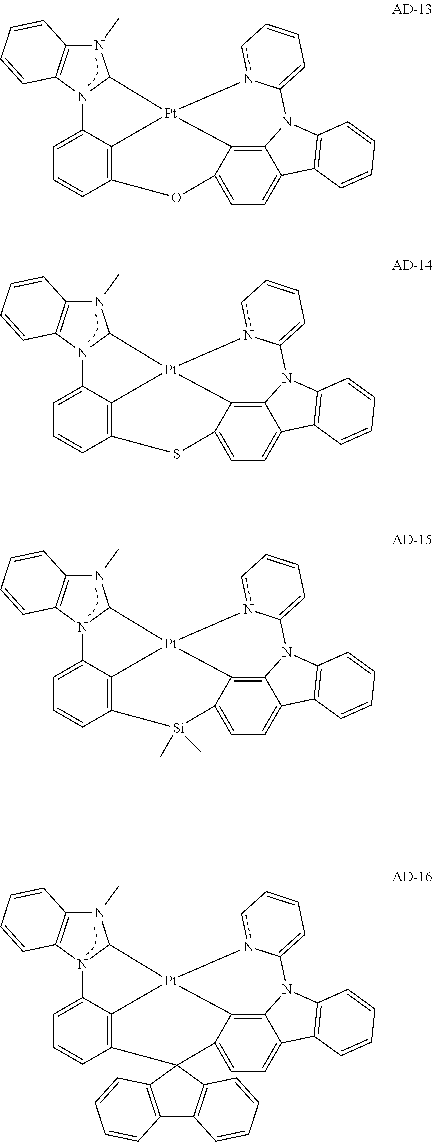

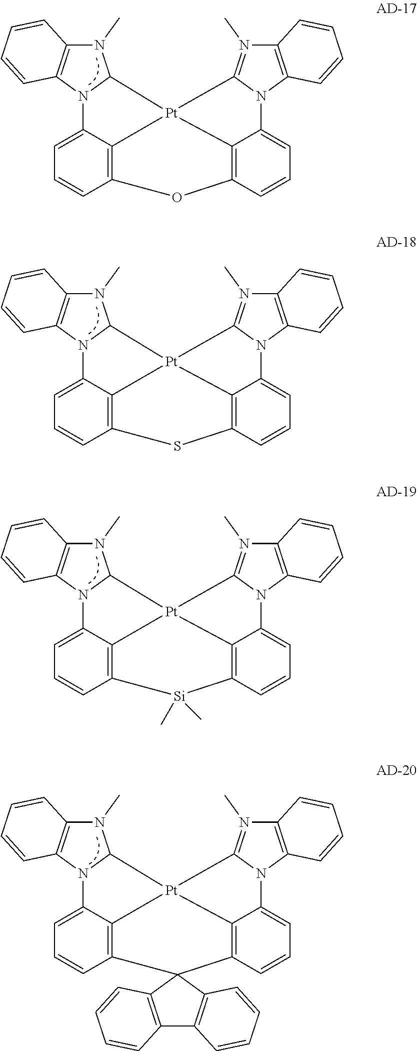

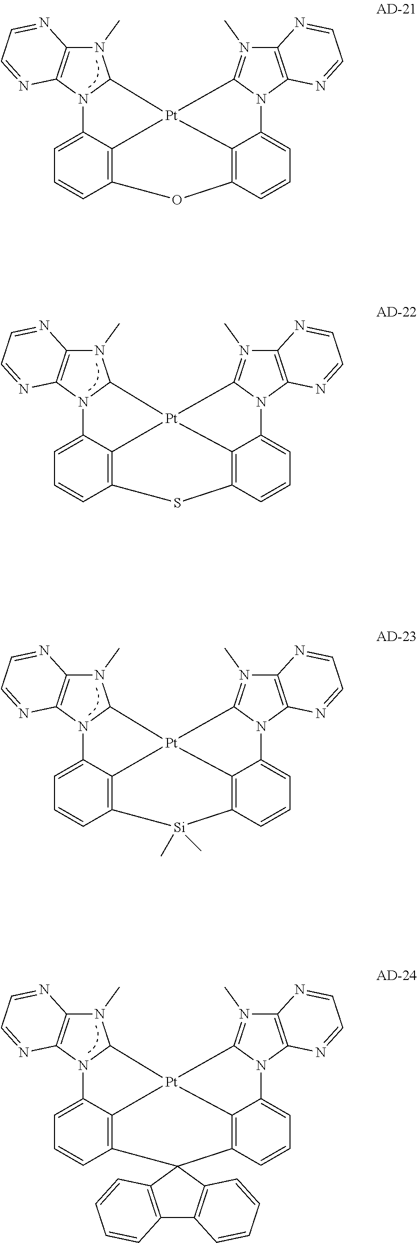

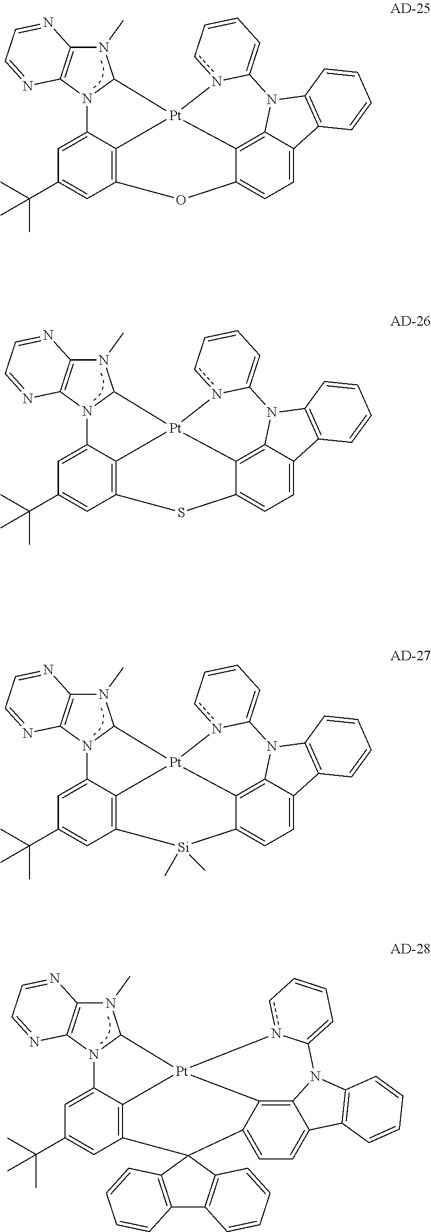

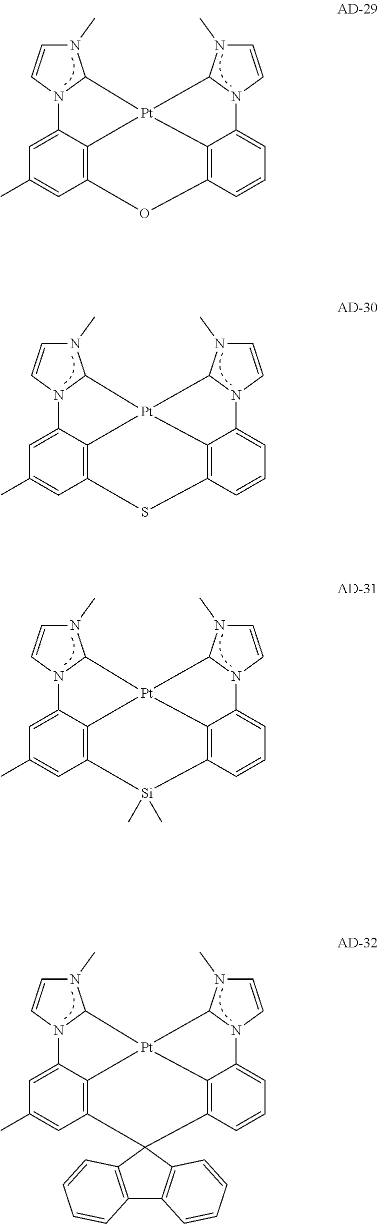

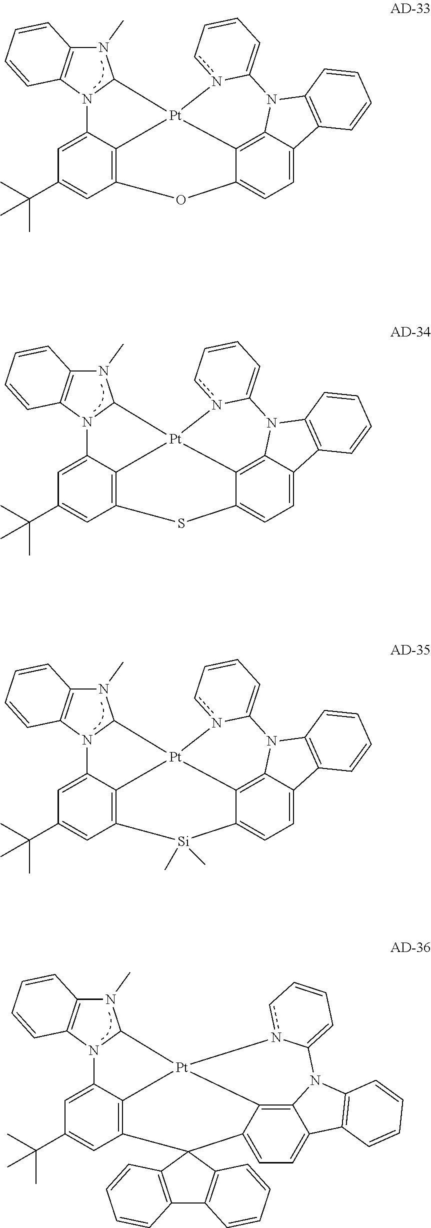

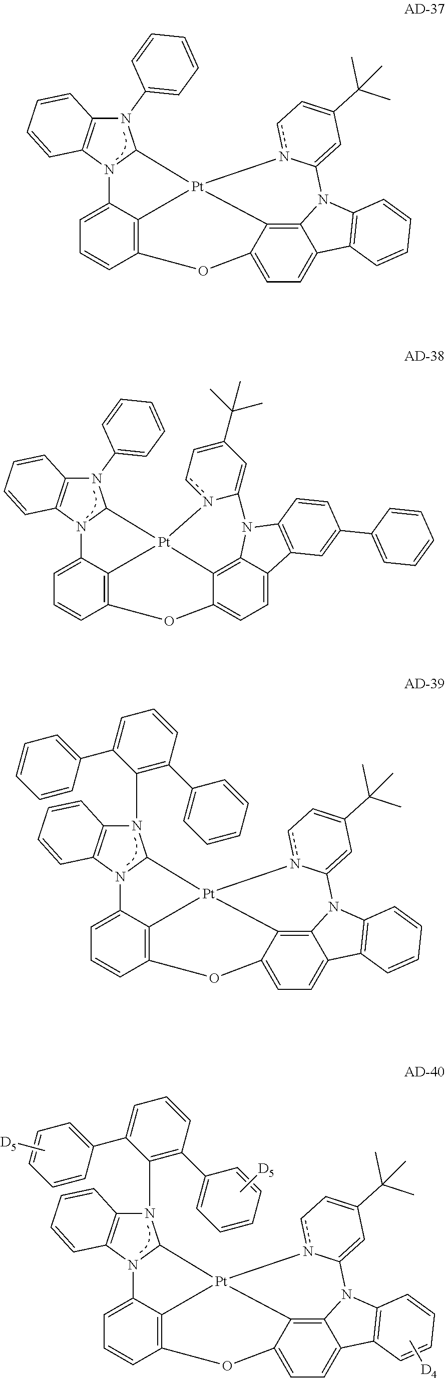

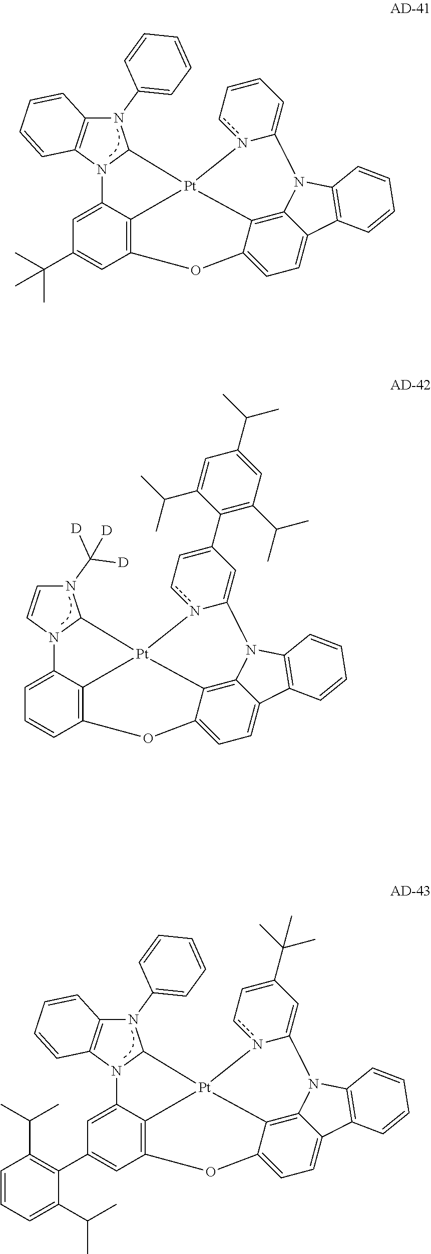

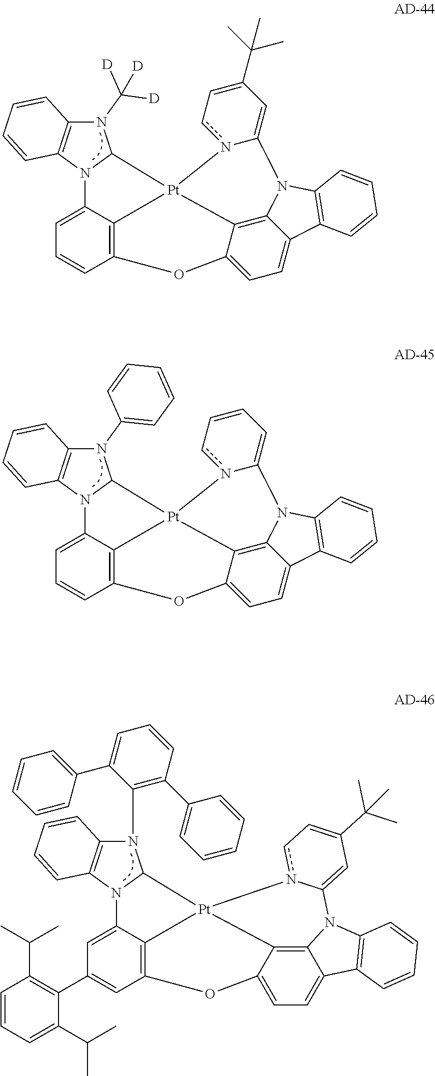

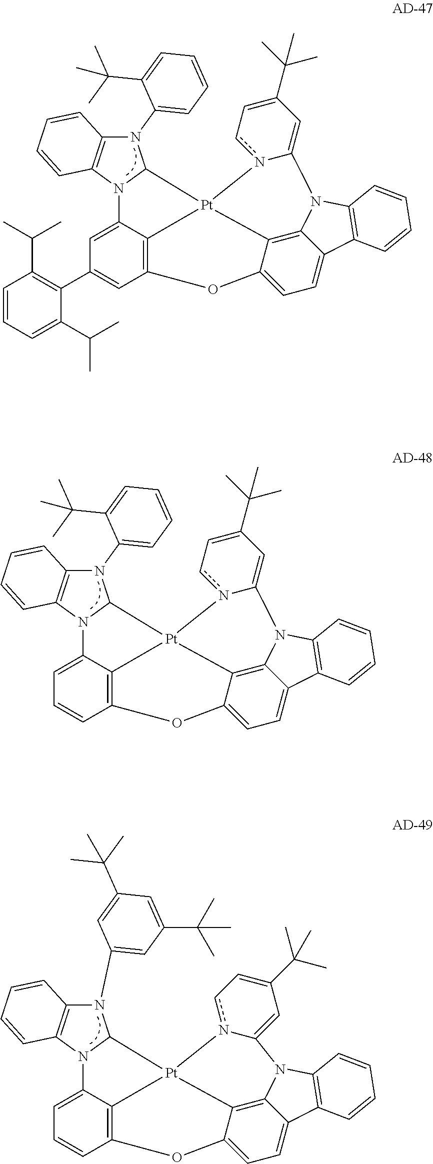

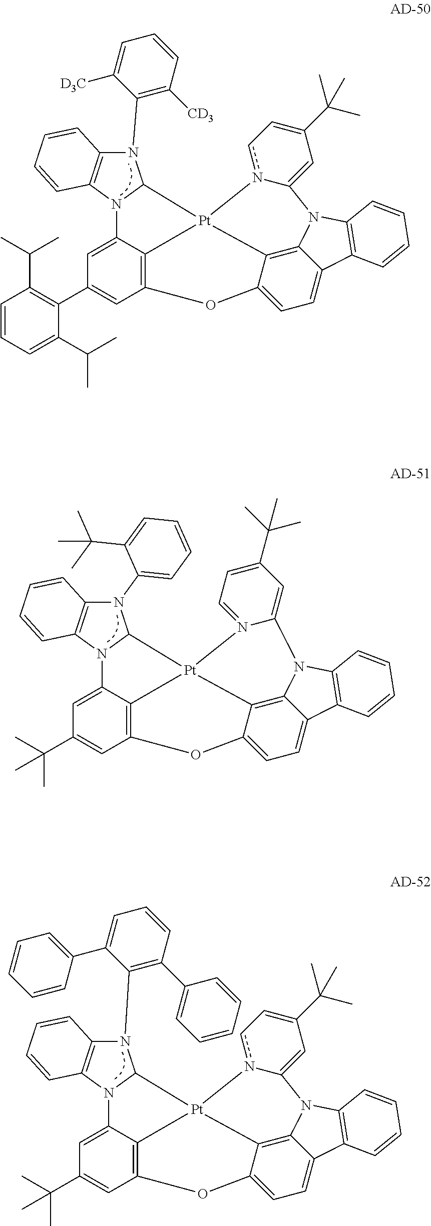

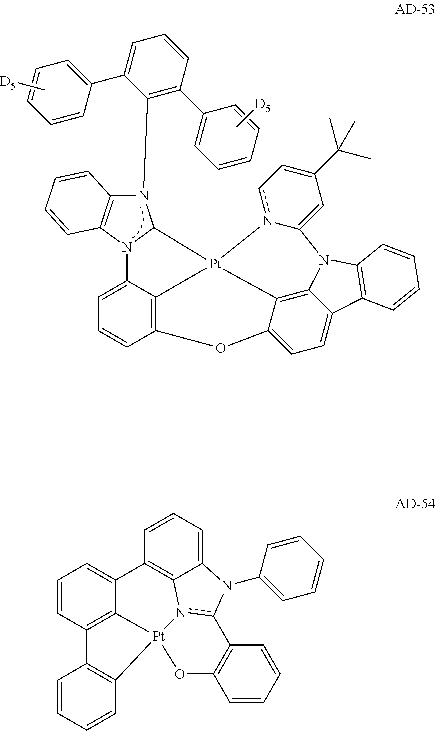

In the embodiment compounds presented in Compound Group 4, “D” refers to deuterium.

When the emission layer EML in the light emitting element ED of one or more embodiments includes all of the first compound, the second compound, and the third compound, with respect to a total weight of the first compound, the second compound, and the third compound, the content (e.g., amount) of the first compound may be about 0.1 wt % to about 5 wt %. However, embodiments of the present disclosure are not limited thereto. When the content (e.g., amount) of the first compound satisfy the above-described proportion, the energy transfer from the second compound and the third compound to the first compound may increase, and thus the luminous efficiency and element service life may increase.

The contents of the second compound and the third compound in the emission layer EML may be the rest excluding the weight of the first compound. For example, the contents of the second compound and the third compound in the emission layer EML may be about 65 wt % to about 95 wt % with respect to the total weight of the first compound, the second compound, and the third compound.

In the total weight of the second compound and the third compound, a weight ratio of the second compound to the third compound may be about 3:7 to about 7:3.

When the contents (e.g., amounts) of the second compound and the third compound satisfy the above-described ratio, a charge balance characteristic in the emission layer EML are improved, and thus the luminous efficiency and service life of the light emitting element may increase. When the contents of the second compound and the third compound deviate from the above-described ratio range, a charge balance in the emission layer EML is broken, and thus the luminous efficiency may be reduced, and the element may be easily deteriorated.

In one or more embodiments, when the emission layer EML includes the fourth compound, the content (e.g., amount) of the fourth compound in the emission layer EML may be about 10 wt % to about 30 wt % with respect to a total weight of the first compound, the second compound, the third compound, and the fourth compound. However, embodiments of the present disclosure are not limited thereto. When the content (e.g., amount) of the fourth compound satisfies the above-described content (e.g., amount), the energy delivery from the host to the first compound which is a light emitting dopant may be increased, thereby a luminous ratio may be improved, and thus the luminous efficiency of the emission layer EML may be improved. When the first compound, the second compound, the third compound, and the fourth compound included in the emission layer EML satisfy the above-described content (e.g., amount) ratio range, excellent or suitable luminous efficiency and long service life may be achieved.

The emission layer EML may be provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

In the light emitting element ED of one or more embodiments, the emission layer EML may include at least one of an anthracene derivative, a pyrene derivative, a fluoranthene derivative, a chrysene derivative, a dihydrobenzanthracene derivative, or a triphenylene derivative. For example, in one or more embodiments, the emission layer EML may include the anthracene derivative and/or the pyrene derivative.

In each light emitting element ED of embodiments illustrated in FIGS. 3 to 6, the emission layer EML may further include a suitable host and/or dopant besides the above-described host and dopant, for example, in one or more embodiments, the emission layer EML may include a compound represented by Formula E-1. The compound represented by Formula E-1 may be used as a fluorescent host material.

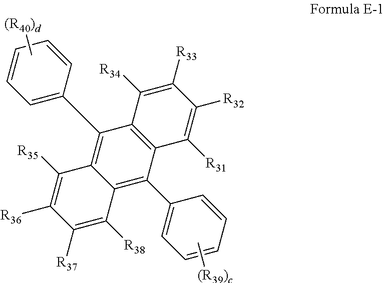

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, one or more selected from among R₃₁ to R₄₀ may be each independently bonded to an adjacent group to form a saturated hydrocarbon ring, an unsaturated hydrocarbon rnng, a saturated heterocycle, or an unsaturated heterocycle.

In Formula E-1, c and d may each independently be an integer of 0 to 5.

The Compound represented by Formula E-1 may be any one selected from among Compound E1 to Compound E21:

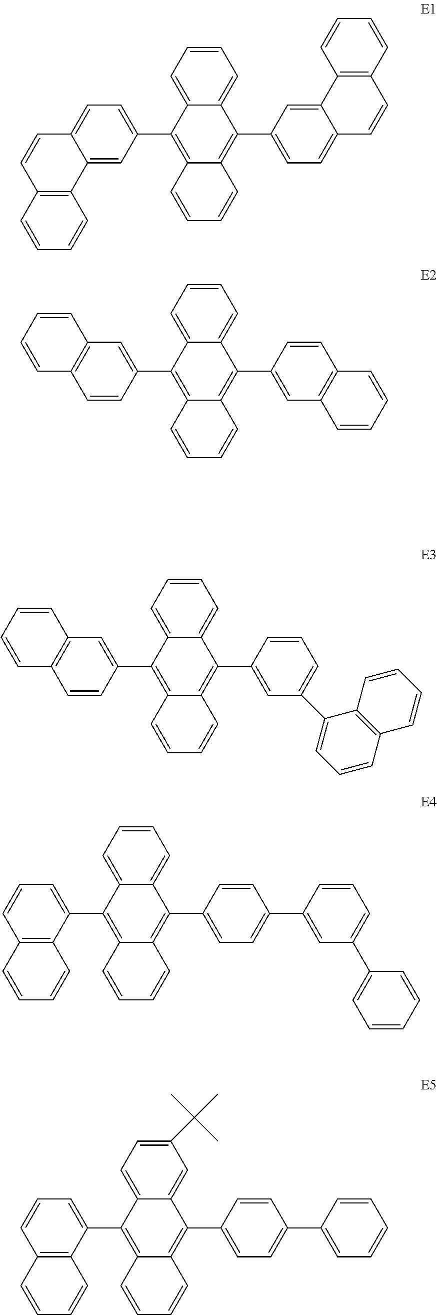

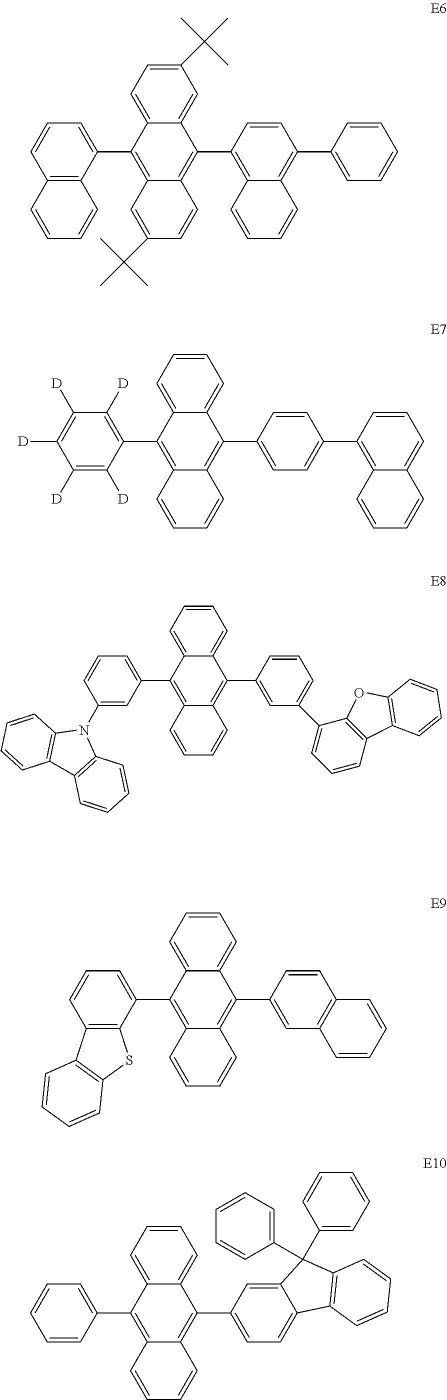

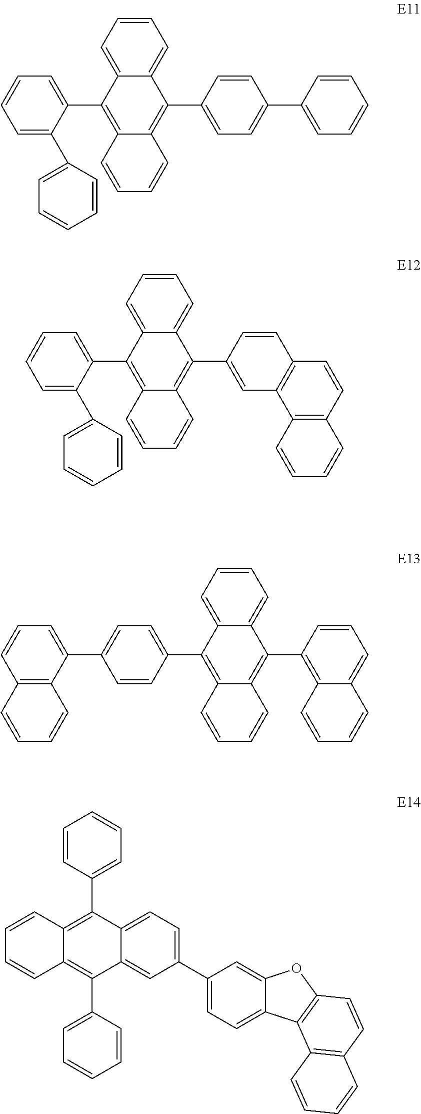

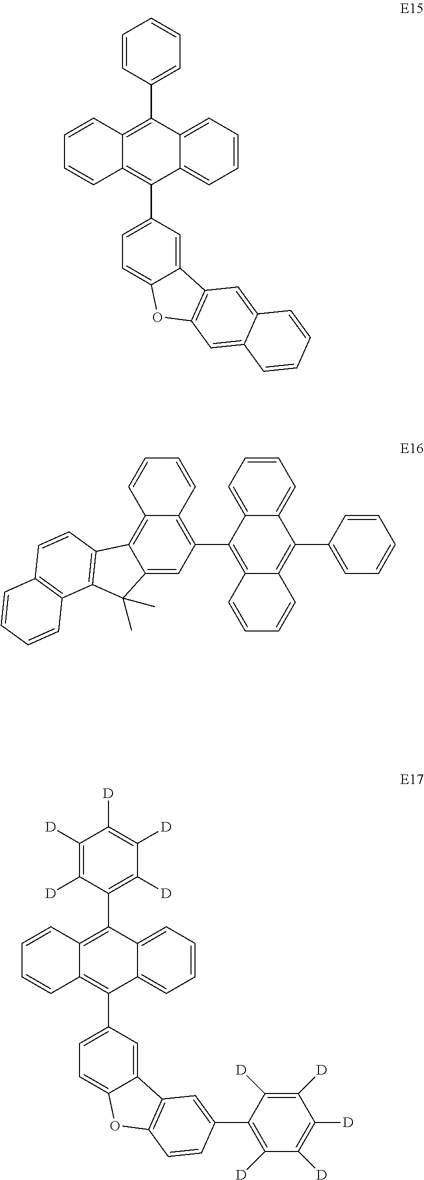

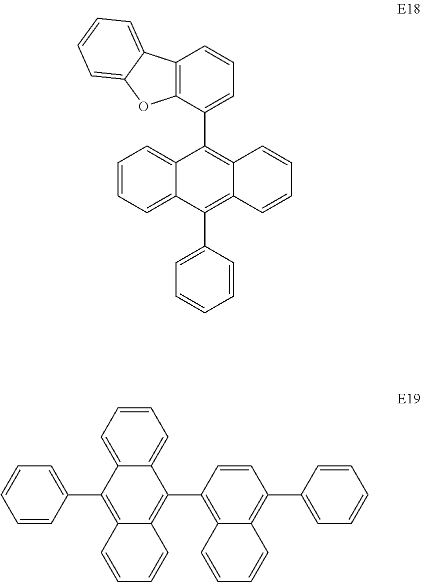

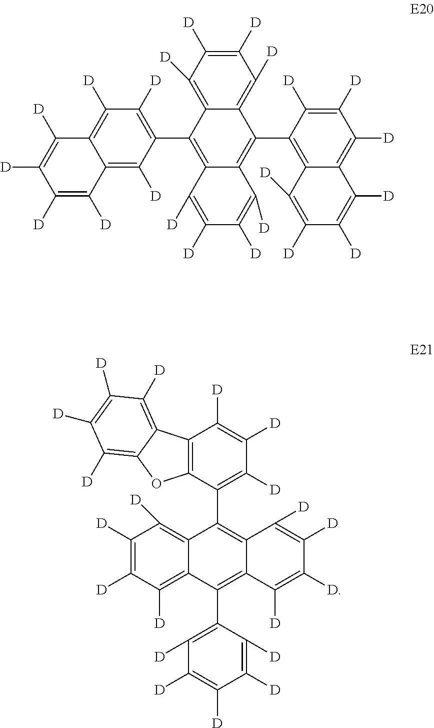

In one or more embodiments, the emission layer EML may include a compound represented by Formula E-2a or Formula E-2b. The compound represented by Formula E-2a or Formula E-2b may be used as a host material.

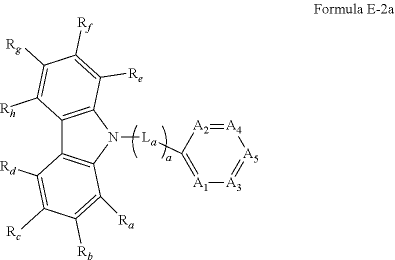

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a is an integer of 2 or greater, a plurality of Lₐ's may each independently be a substituted or unsubstituted arylene group having 6 to 30 ring-forming carbon atoms or a substituted or unsubstituted heteroarylene group having 2 to 30 ring-forming carbon atoms.

In addition, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In one or more embodiments, one or more selected from among Rₐ to R₁ may be each independently bonded to an adjacent group to form a hydrocarbon ring or a heterocycle containing N, O, S, and/or the like, as a ring-forming atom.

In one or more embodiments, in Formula E-2a, two or three selected from among A₁ to A₅ may be N, and the rest may be CRᵢ.

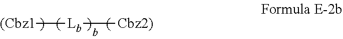

In Formula E-2b, Cbz1 and Cbz2 may each independently be an unsubstituted carbazole group or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, b may be an integer of 0 to 10, and if (e.g., when) b is an integer of 2 or greater, a plurality of L_{b}'s may each independently be a substituted or unsubstituted arylene group having 6 to 30 ring-forming carbon atoms or a substituted or unsubstituted heteroarylene group having 2 to 30 ring-forming carbon atoms.

The compound represented by Formula E-2a or Formula E-2b may be any one selected from among compounds of Compound Group E-2. However, the compounds listed in Compound Group E-2 are mere examples, and the compound represented by Formula E-2a or Formula E-2b is not limited to those represented in Compound Group E-2.

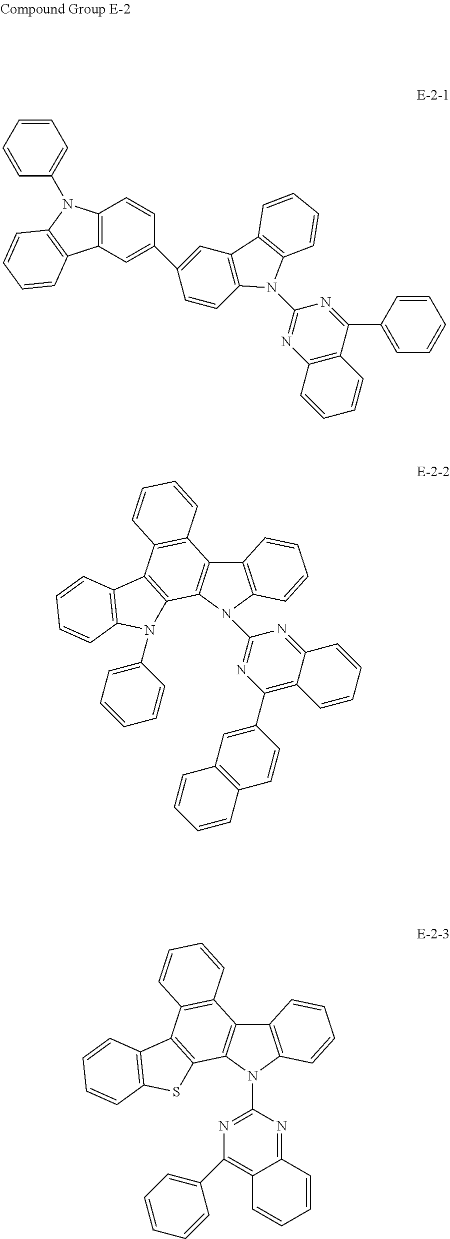 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

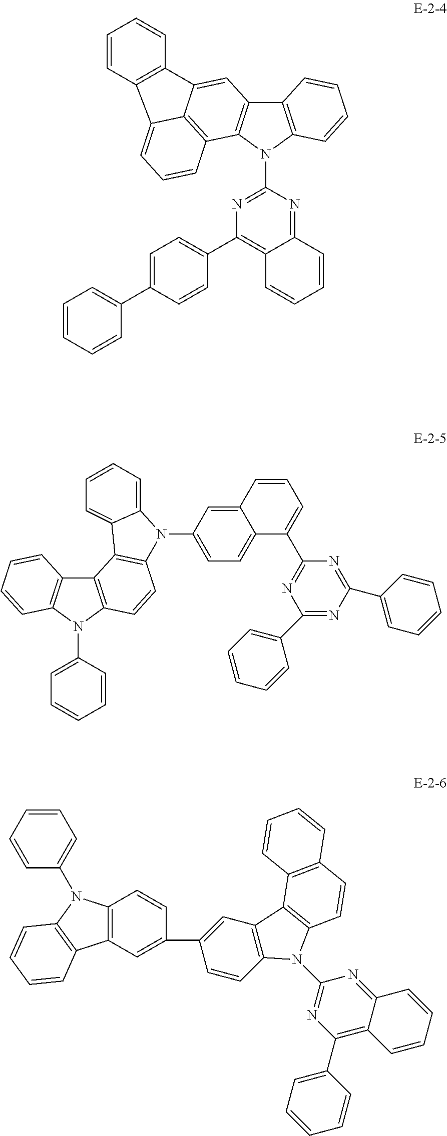 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

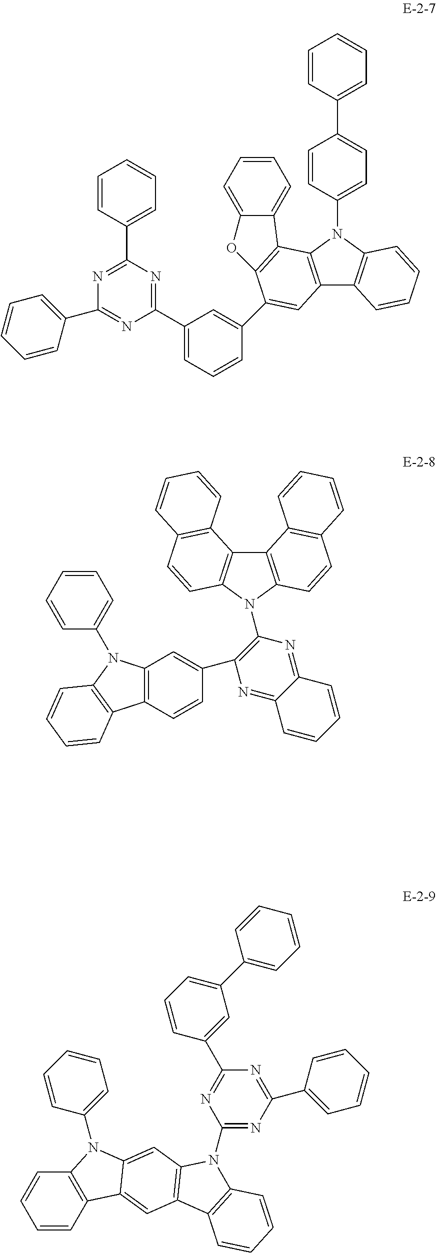 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

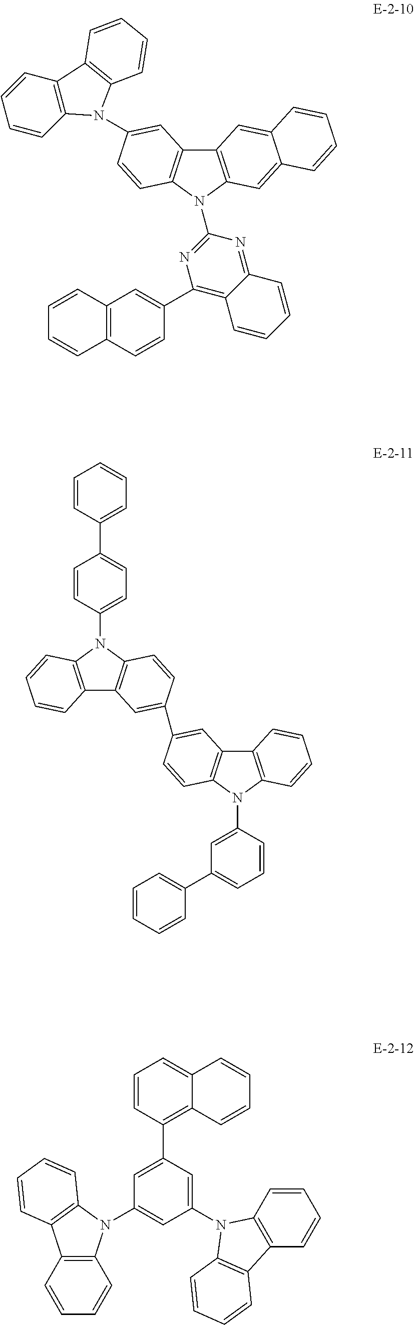 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

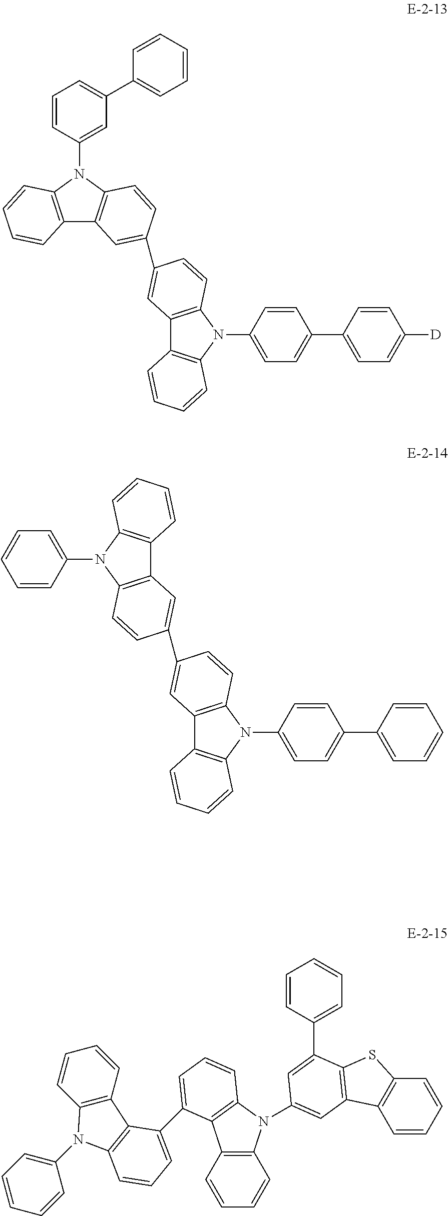 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

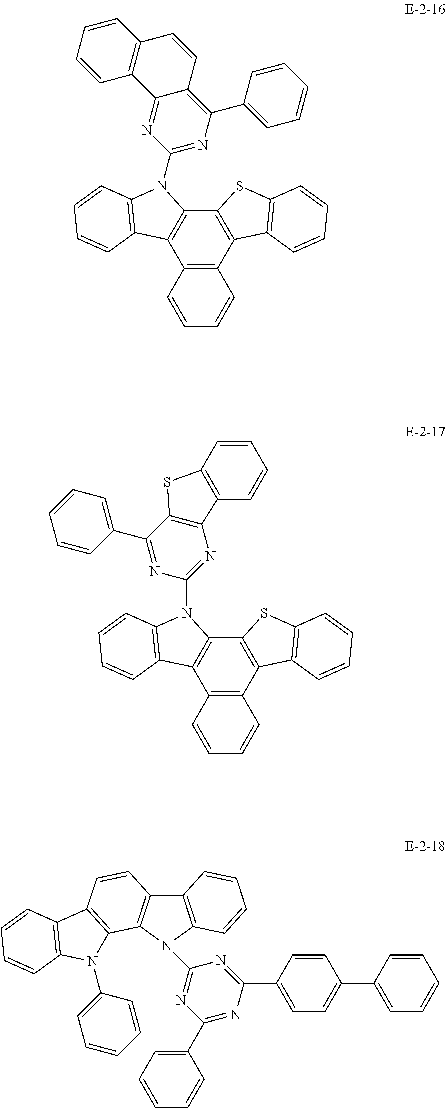 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

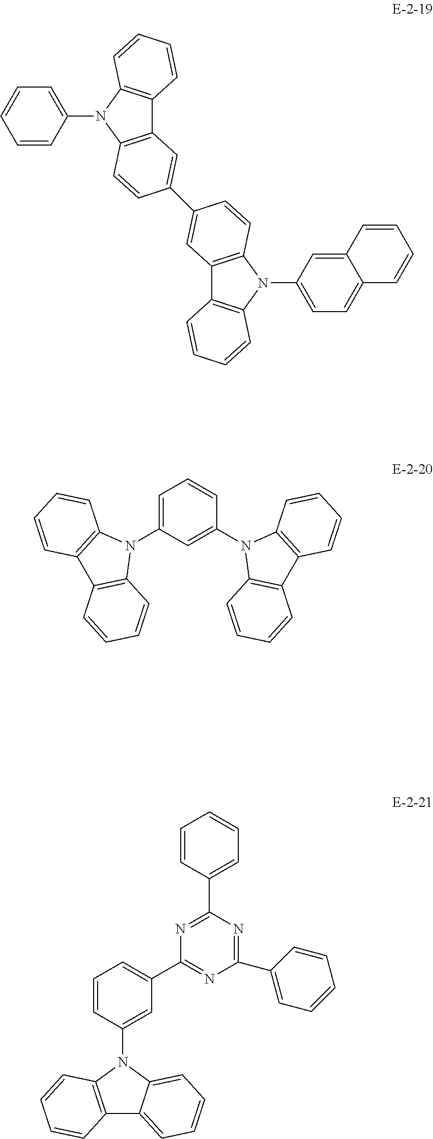 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

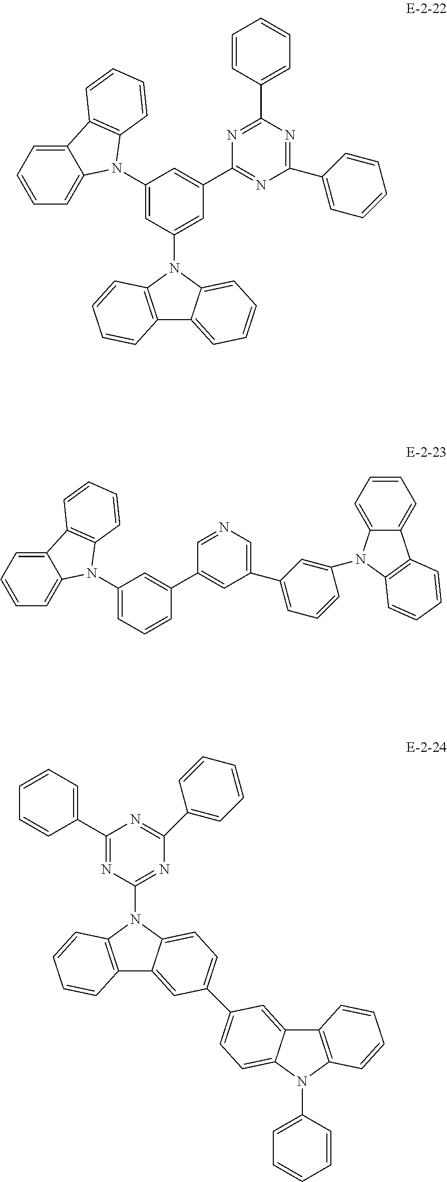 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazol-2-yl)benzene (TPBi). However, embodiments of the present disclosure are not limited thereto, for example, tis(8-hydroxyquinolinato)aluminum (Alq₃), 9,10-di(naphthalen-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(trphenylsilyl)benzene (UGH2), hexaphenylcyclotrisiloxane (DPSiO₃), octaphenylcyclotetrasiloxane (DPSiO₄), and/or the like, may be used as a host material.

In one or more embodiments, the emission layer EML may include a compound represented by Formula M-a. The compound represented by Formula M-a may be used as a phosphorescent dopant material.

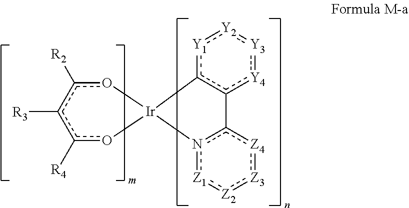

In Formula M-a, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. In Formula M-a, m is 0 or 1, and n is 2 or 3. In Formula M-a, if (e.g., when) m is 0, n is 3, and if (e.g., when) m is 1, n is 2.

The compound represented by Formula M-a may be used as a phosphorescent dopant.

The compound represented by Formula M-a may be any one selected from among Compound M-a1 to Compound M-a25. However, Compounds M-a1 to M-a25 are mere examples, and the compound represented by Formula M-a is not limited to those represented by Compounds M-a1 to M-a25.

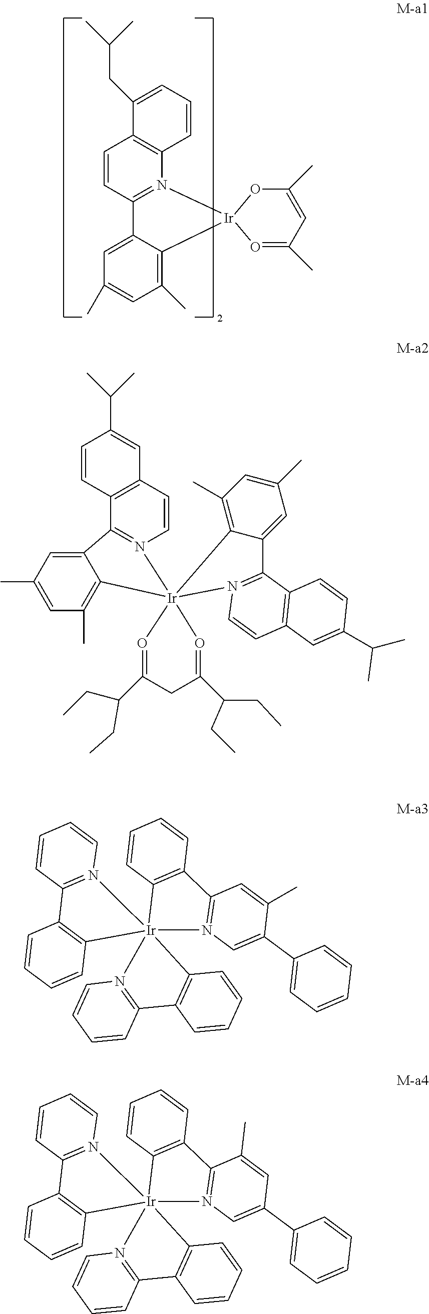

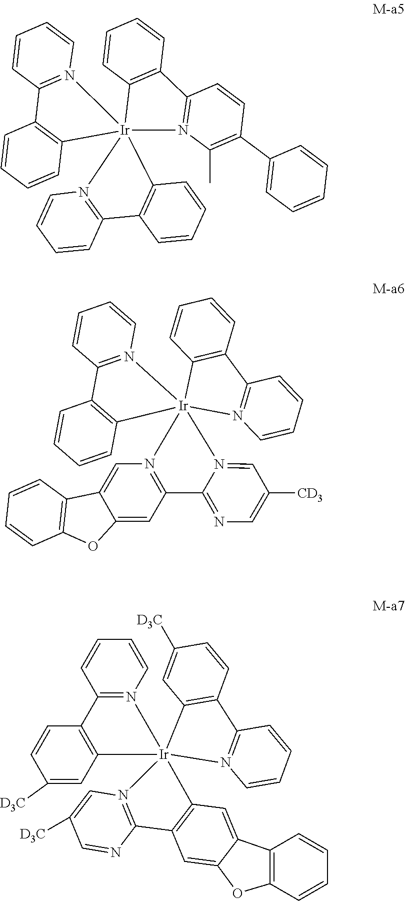

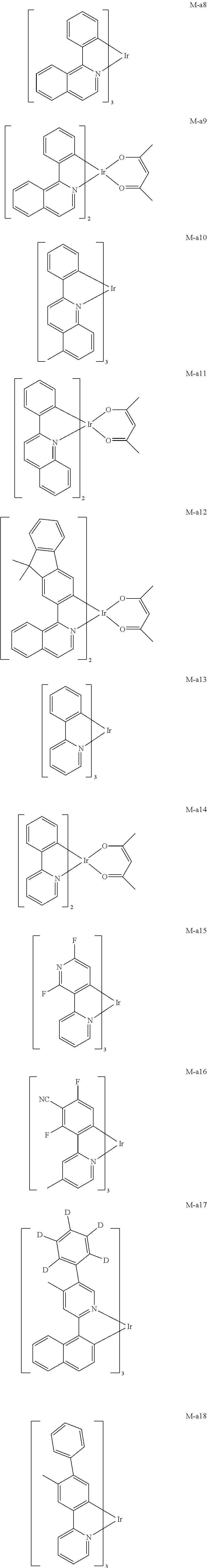

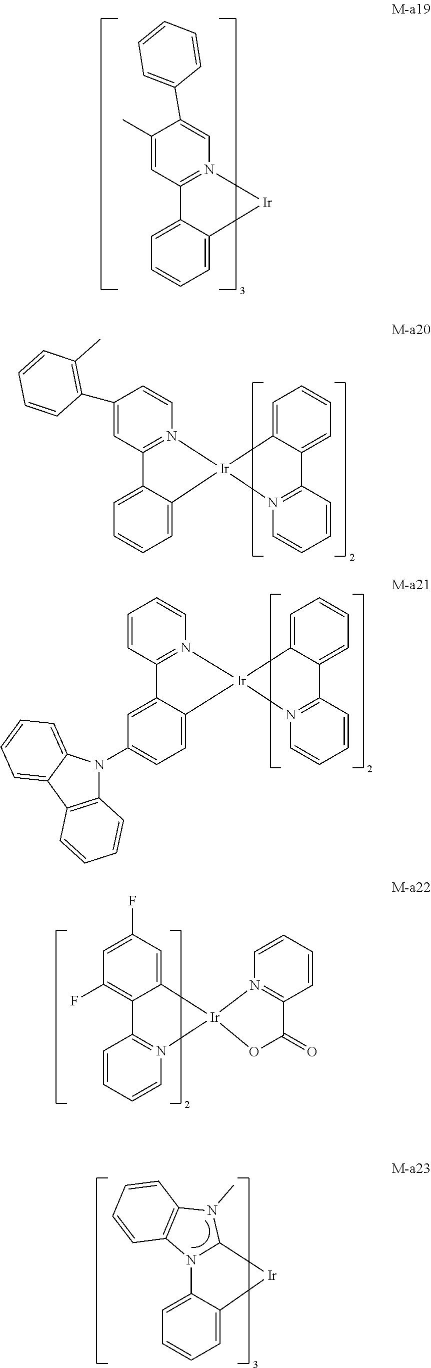

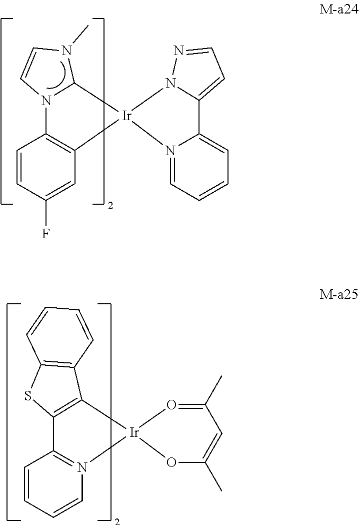

In one or more embodiments, the emission layer EML may include a compound represented by any one selected from among Formula F-a to Formula F-c. The compound represented by Formula F-a to Formula F-c may be used as a fluorescence dopant material.

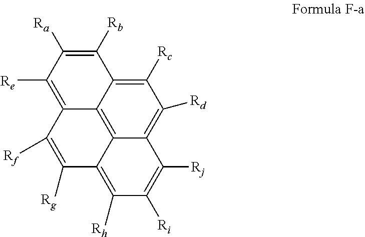

In Formula F-a, two selected from among Rₐ to Rⱼ may each independently be substituted with *—NAr₁Ar₂. The others, which are not substituted with A*—NAr₁Ar₂, among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₂, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, in one or more embodiments, at least one of Ar₁ or Ar₂ may be a heteroaryl group containing O or S as a ring-forming atom.

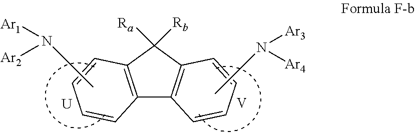

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring. Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms. In one or more embodiments, at least one selected from among Ar₁ to Ar₄ may be a heteroaryl group containing O or S as a ring-forming atom.

In Formula F-b, the number of rings represented by U and V may each independently be 0 or 1. For example, in Formula F-b, it refers to that if (e.g., when) the number of U or V is 1, one ring constitutes a part of a fused ring at a portion indicated by U or V, and if (e.g., when) the number of U or V is 0, a ring indicated by U or V does not exist. For example, if (e.g., when) the number of U is 0 and the number of V is 1, or if (e.g., when) the number of U is 1 and the number of V is 0, the fused ring having a fluorene core in Formula F-b may be a cyclic compound having four rings. In one or more embodiments, if (e.g., when) each number of U and V is 0, the fused ring in Formula F-b may be a cyclic compound having three rings. In one or more embodiments, if (e.g., when) each number of U and V is 1, the fused ring having a fluorene core in Formula F-b may be a cyclic compound having five rings.

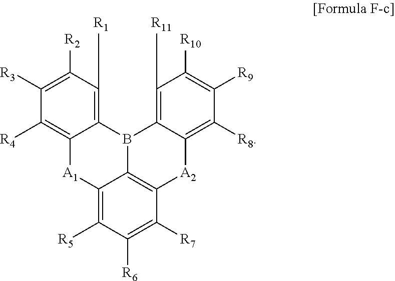

In Formula F-c, A₁ and A₂ may each independently be 0, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or may be bonded to an adjacent group to form a ring.

In one or more embodiments, in Formula F-c, A₁ and A₂ may each independently be bonded to substituents of an adjacent ring to form a fused ring. For example, if (e.g., when) A₁ and A₂ may each independently be NRₘ, in one or more embodiments, A₁ may be bonded to R₄ or R₅ to form a ring. In one or more embodiments, A₂ may be bonded to R₇ or R₈ to form a ring.

In one or more embodiments, the emission layer EML may further include, as a suitable dopant material, one or more selected from among styryl derivatives (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi)), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), and/or the like.

In one or more embodiments, the emission layer EML may further include a suitable phosphorescence dopant material. For example, a metal complex containing iridium (Ir), platinum (Pt), osmium (Os), aurum (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N, C2′)picolinate) (Flrpic), bis(2,4-difluorophenylpyridinato)-tetrakis(1-pyrazolyl)borate iridium(III) (Flr6), or platinum octaethyl porphyrin (PtOEP) may be used as a phosphorescent dopant. However, embodiments of the present disclosure are not limited thereto.

In one or more embodiments, the emission layer EML may include a quantum dot material. In one or more embodiments, the quantum dot may have a core/shell structure. The core of the quantum dot may be selected from among Group II-VI compounds, Group 1-II-VI compounds, Group II-IV-VI compounds, Group I-II-IV-VI compounds, Group II-IV-V compounds, Group III-VI compounds, Group 1-Ill-VI compounds, Group III-V compounds, Group III-II-V compounds, Group IV-VI compounds, Group IV elements, Group IV compounds, and/or one or more (e.g., any suitable) combinations thereof.

The Group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS, and mixtures thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

In one or more embodiments, the Group II-VI compound may further include Group I metals and/or Group IV elements. The Group 1-II-VI compound may be selected from among CuSnS and CuZnS, and the Group II-IV-VI compound may be selected from among ZnSnS and/or the like. The Group I-II-IV-VI compound may be selected from among a quaternary compound selected from the group consisting of Cu₂ZnSnS₂, Cu₂ZnSnS₄, Cu₂ZnSnSe₄, Ag₂ZnSnS₂, and mixtures thereof.

The Group II-IV-V compound may be selected from among a ternary compound selected from the group consisting of ZnSnP, ZnSnP₂, ZnSnAs₂, ZnGeP₂, ZnGeAs₂, CdSnP₂, CdGeP₂, and mixtures thereof.

The Group III-VI compound may include a binary compound such as GaS, Ga₂S₃, GaSe, Ga₂Se₃, GaTe, InTe, InS, InSe, In₂S₃, and/or In₂Se₃, a ternary compound such as InGaS₃ and/or InGaSe₃, or optional combinations thereof.

The Group 1-Ill-VI compound may be selected from among a ternary compound selected from the group consisting of AgInS, AgInS₂, CuInS, CuInS₂, AgGaS₂, CuGaS₂, CuGaO₂, AgGaO₂, AgAlO₂ and mixtures thereof, and/or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In one or more embodiments, the Group III-V compound may further include Group II metals. For example, InZnP, and/or the like, may be selected as a Group III-II-V compound.

The Group IV-VI compound may be selected from the group consisting of a binary compound selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary compound selected from the group consisting of SnPbSSe, SnPbSeTe, SnPbSTe, and mixtures thereof. The Group IV element may be selected from the group consisting of Si, Ge, and a (e.g., any suitable) mixture thereof. The Group IV compound may be a binary compound selected from the group consisting of SiC, SiGe, and a (e.g., any suitable) mixture thereof.

Each element included in a polynary compound such as the binary compound, the ternary compound, or the quaternary compound may be present at a substantially uniform concentration or at a non-uniform concentration in a particle. For example, the above chemical formulae refer to the types (kinds) of the elements included in the compound, and the atomic ratio in the compound may be different. For example, AgInGaS₂ may refer to AgInₓGa₁₋ₓS₂ (x is a real number between 0 to 1).

In one or more embodiments, the quantum dot may have a single structure in which the concentration of each element included in the quantum dot is substantially uniform, or a core-shell double structure. For example, a material included in the core and a material included in the shell may be different from each other.

The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. An interface between the core and the shell may have a concentration gradient in which the concentration of an element present in the shell is decreased toward the center.

In one or more embodiments, the quantum dot may have the above-described core-shell structure including a core including a nanocrystal and a shell wrapping the core. Examples of the shell of the quantum dot may include a metal or non-metal oxide, a semiconductor compound, and/or one or more (e.g., any suitable) combinations thereof.

For example, the metal or non-metal oxide for the shell may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but embodiments of the present disclosure are not limited thereto.

Also, the semiconductor compound suitable as a shell may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but embodiments of the present disclosure are not limited thereto.

Each element included in a polynary compound such as the binary compound or the ternary compound may be present at a substantially uniform concentration or non-uniform concentration in a particle. For example, the chemical formulae may refer to the types (kinds) of elements included, but the atomic ratio in the compound may be different, e.g., may vary.

The quantum dot may have a full width at half maximum (FWHM) of emission spectrum of about 45 nanometers (nm) or less, about 40 nm or less, or, about 30 nm or less. Within this range, color purity or color reproducibility of the quantum dot may be improved. In addition, light emitted via the quantum dot is emitted in all directions, and thus light viewing angle properties may be improved.

In addition, the shape of the quantum dot may be generally used shapes in the art, without specific limitation. For example, the shape of spherical nanoparticle, pyramidal nanoparticle, multi-arm nanoparticle, cubic nanoparticle, nanotube, nanowire, nanofiber, nanoplate, and/or the like, may be used.

By controlling the size of the quantum dot or by controlling the element ratio in the quantum dot compound, an energy band gap may be controlled or selected, and one or more suitable wavelength bands of light may be obtained from a quantum dot emission layer. Accordingly, by using the quantum dot (using quantum dots having different sizes or controlling an element ratio in a quantum dot compound differently), a light emitting element emitting one or more suitable wavelengths of light may be accomplished. For example, the size of the quantum dot and/or the element ratio in the quantum dot compound may be controlled or selected to enable the quantum dots to emit red, green, and/or blue light. In one or more embodiments, the quantum dots may be provided to combine one or more suitable emission colors to emit white light.

In each of the light emitting elements ED of embodiments illustrated in FIGS. 3 to 6, the electron transport region ETR may be provided on the emission layer EML. The electron transport region ETR may include at least one of a hole blocking layer HBL, an electron transport layer ETL, or an electron injection layer EIL, but embodiments of the present disclosure are not limited thereto.

The electron transport region ETR may have a single layer formed of a single material, a single layer formed of a plurality of different materials, or a multilayer structure including a plurality of layers formed of a plurality of different materials.

For example, in one or more embodiments, the electron transport region ETR may have a single layer structure of an electron injection layer EIL or an electron transport layer ETL, or may have a single layer structure formed of an electron injection material and/or an electron transport material. In one or more embodiments, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order (e.g., in the stated order) from the emission layer EML, but embodiments of the present disclosure are not limited thereto. The electron transport region ETR may have a thickness, for example, from about 1,000 Å to about 1,500 Å.

The electron transport region ETR may be formed using one or more suitable methods such as a vacuum deposition method, a spin coating method, a casting method, a Langmuir-Blodgett (LB) method, an inkjet printing method, a laser printing method, and/or a laser induced thermal imaging (LITI) method.

In one or more embodiments, the electron transport region ETR may include a compound represented by Formula ET-2:

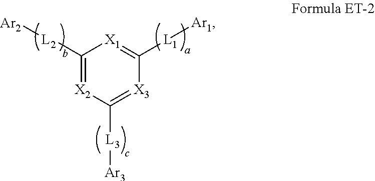

In Formula ET-2, at least one selected from among X₁ to X₃ may be N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer of 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a to c may each independently be an integer of 2 or greater, L₁'s to L₃'s may each independently be a substituted or unsubstituted arylene group having 6 to 30 ring-forming carbon atoms or a substituted or unsubstituted heteroarylene group having 2 to 30 ring-forming carbon atoms.

In one or more embodiments, the electron transport region ETR may include an anthracene-based compound. However, embodiments of the disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(biphenyl-4-yl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), beryllium bis(benzoquinolin-10-olate) (Bebq₂), 9,10-di(naphthalen-2-yl)anthracene (ADN), 1,3-bis[3,5-di(pyridin-3-yl)phenyl]benzene (BmPyPhB), and/or a (e.g., any suitable) mixture thereof.

In one or more embodiments, the electron transport region ETR may include at least one selected from among Compound ET1 to Compound ET38:

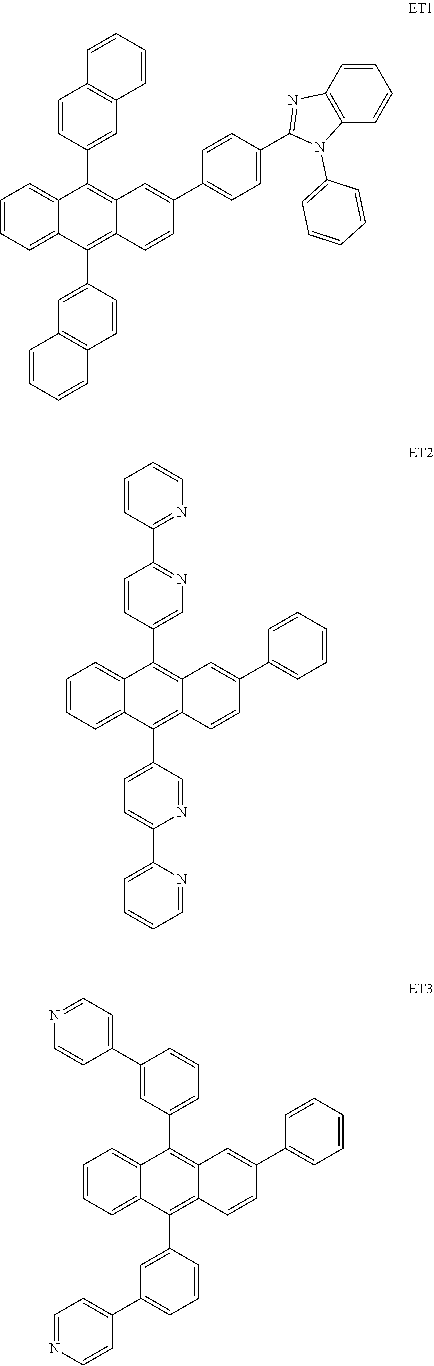 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

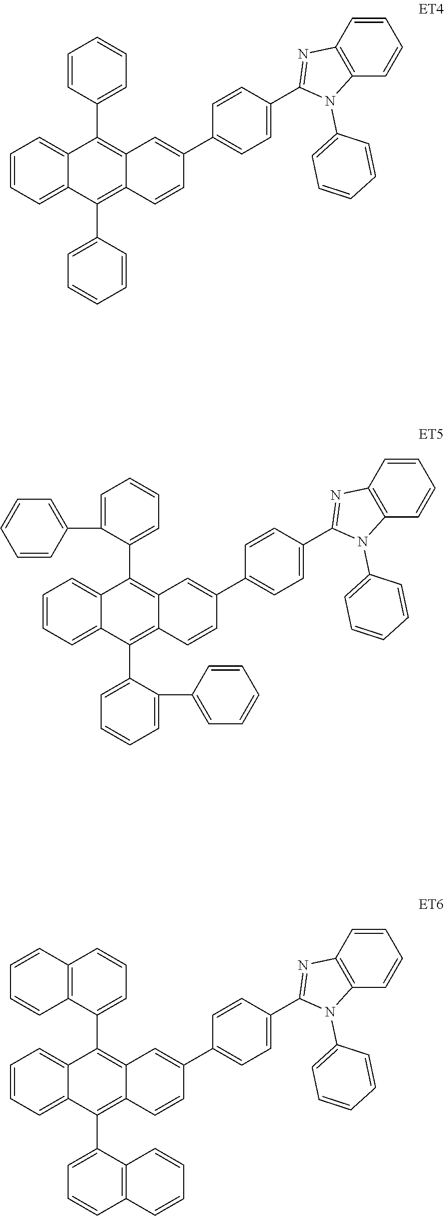 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

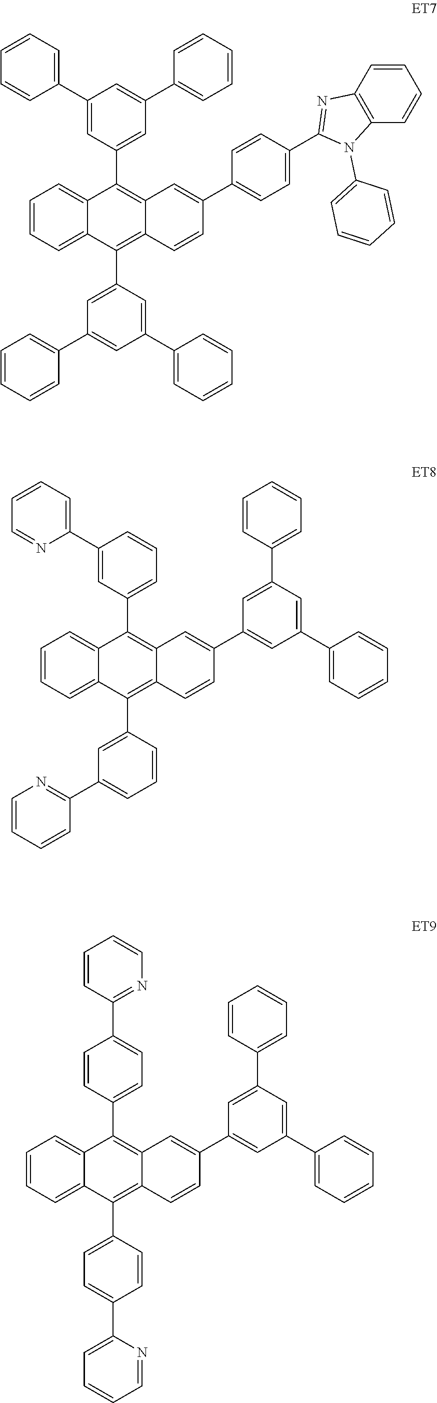 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

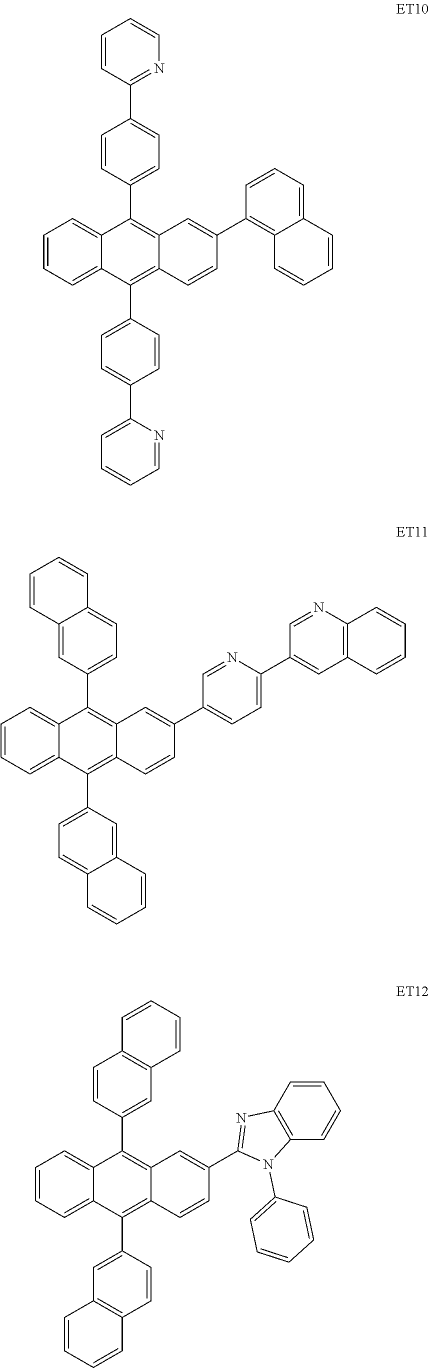 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

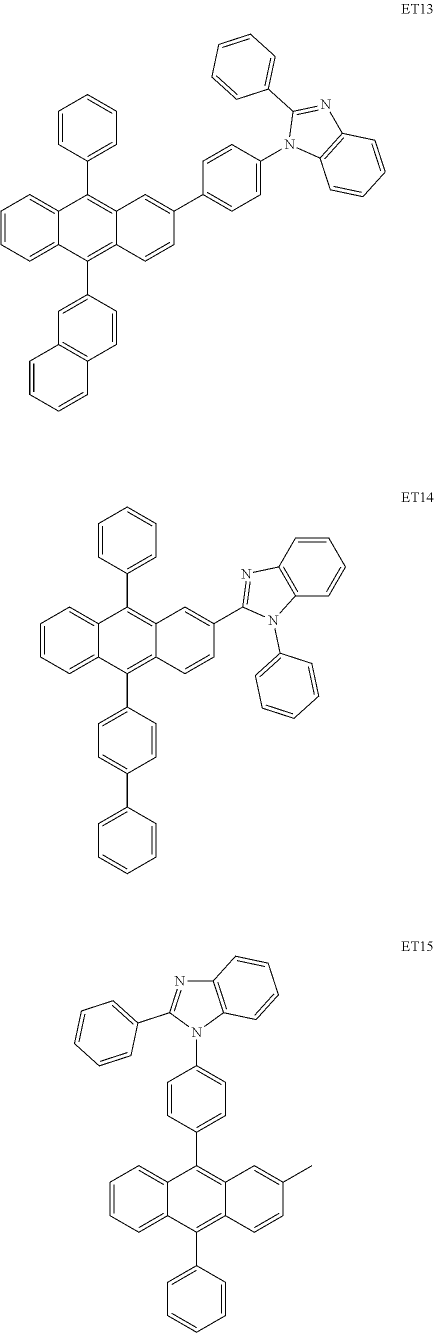 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

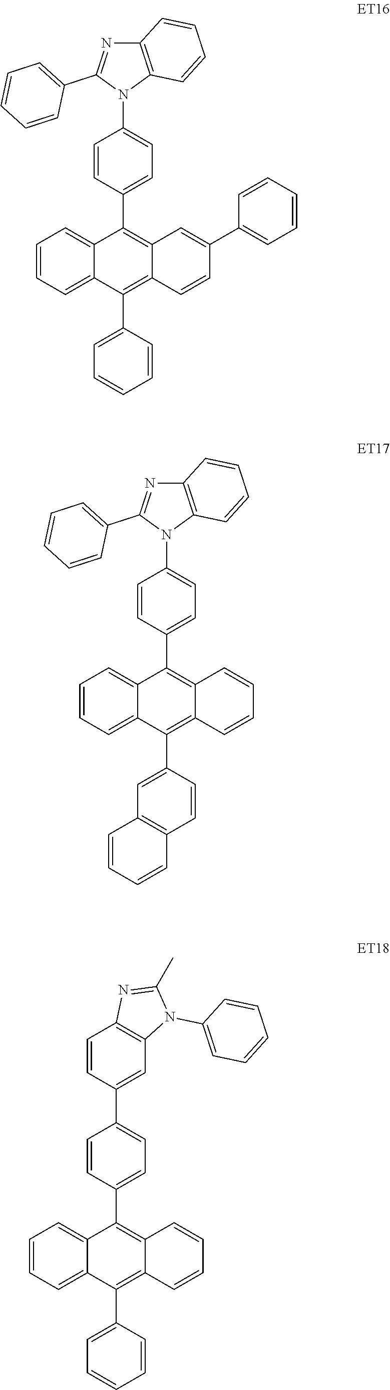 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

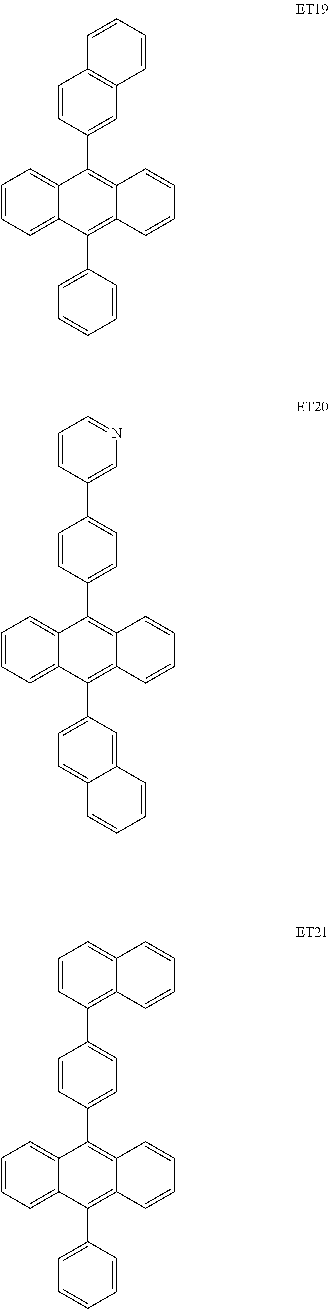

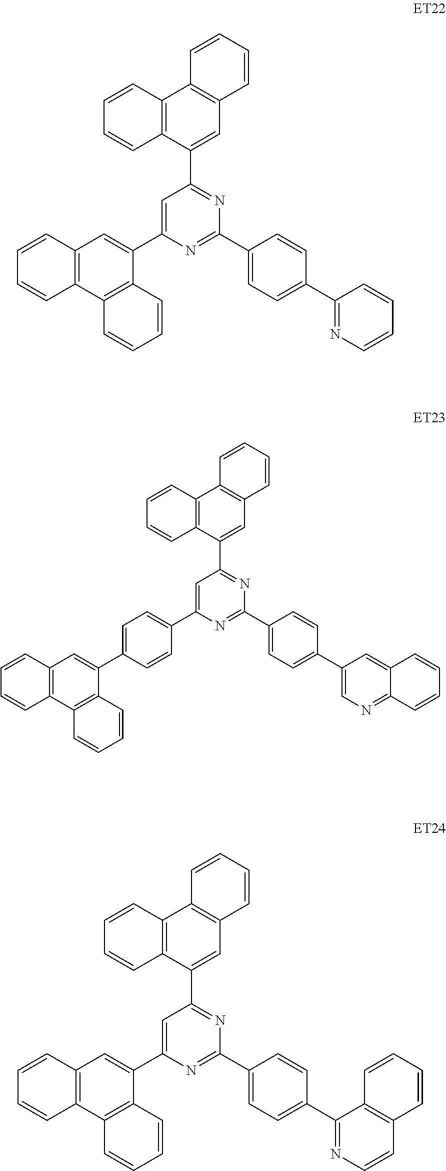 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

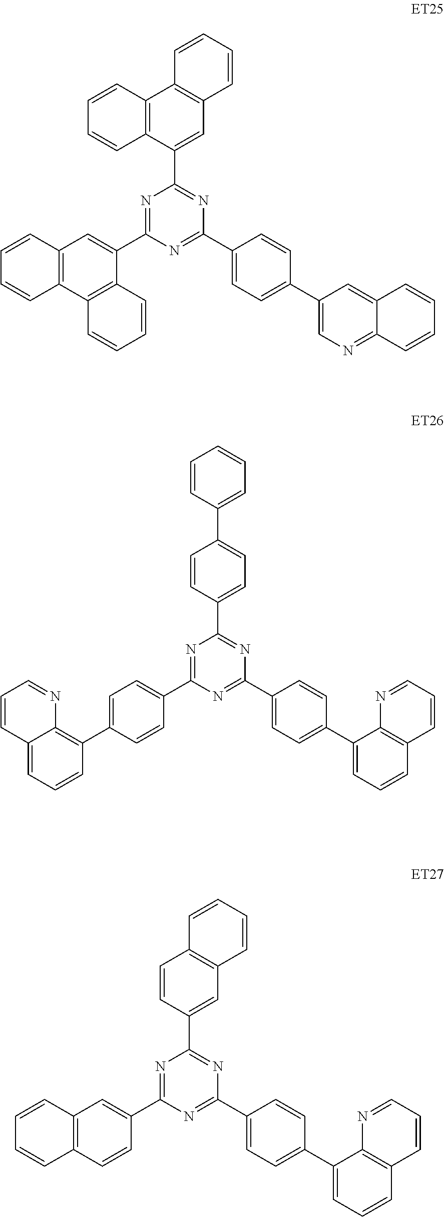 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

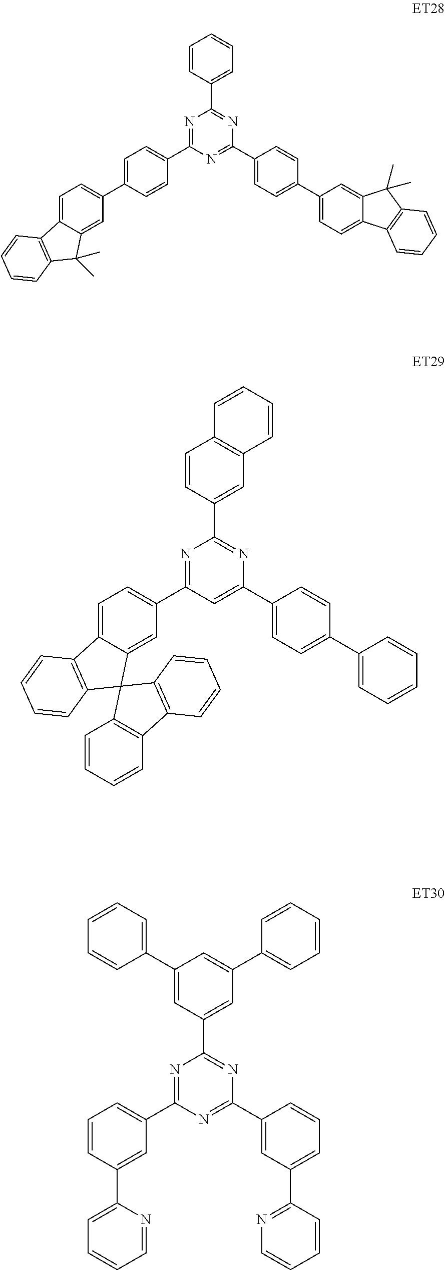 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

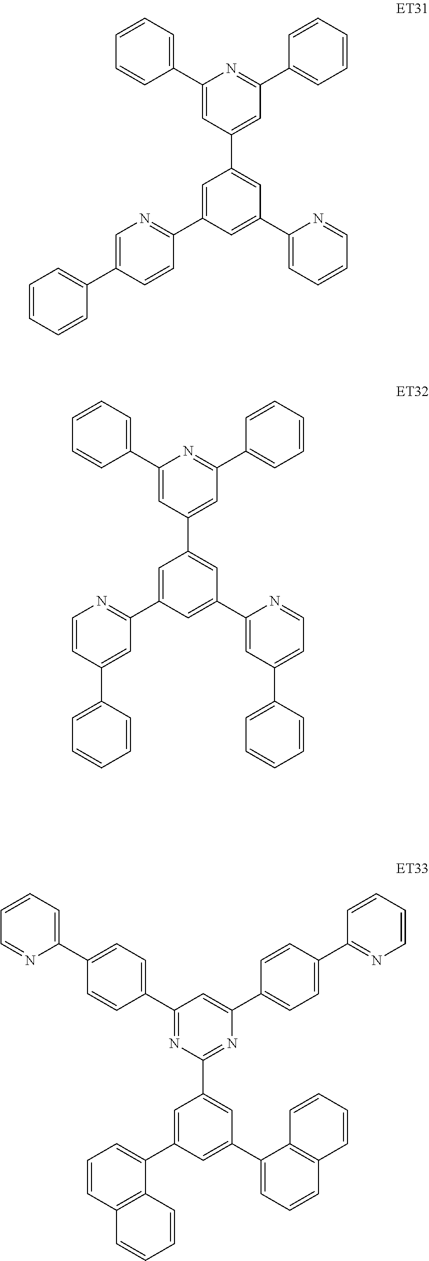 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

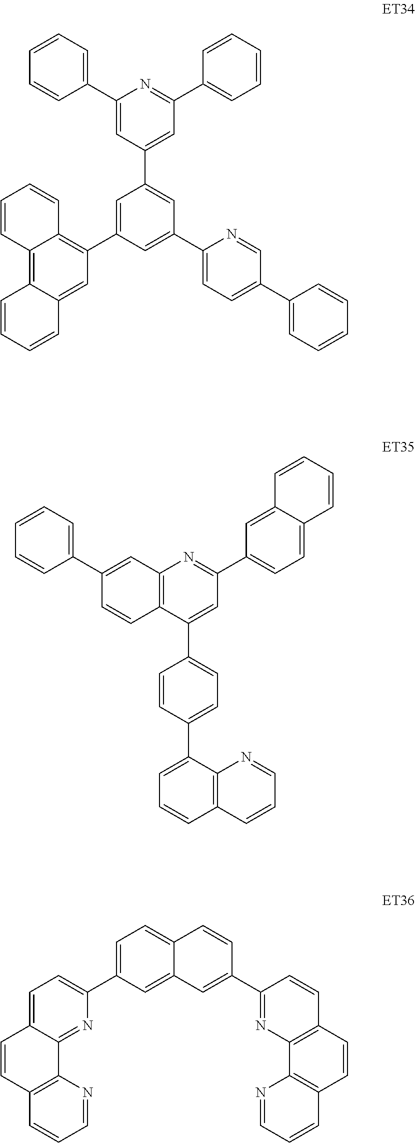 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

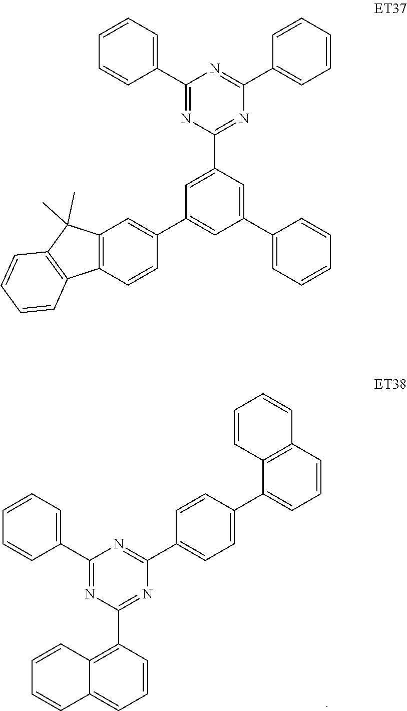 [SMILES: CC1(C)c2ccccc2-c2ccc(-c3cc(-c4ccccc4)cc(-c4nc(-c5ccccc5)nc(-c5ccccc5)n4)c3)cc21 ; c1ccc(-c2nc(-c3ccc(-c4cccc5ccccc45)cc3)nc(-c3cccc4ccccc34)n2)cc1]

In one or more embodiments, the electron transport region ETR may include a metal halide such as LiF, NaCl, CsF, RbCl, RbI, CuI, and/or KI, a lanthanide metal such as Yb, or a co-deposited material of the metal halide and the lanthanide metal. For example, in one or more embodiments, the electron transport region ETR may include KI:Yb, RbI:Yb, LiF:Yb, and/or the like, as a co-deposited material. In one or more embodiments, the electron transport region ETR may be formed using a metal oxide such as Li₂O and/or BaO, or 8-hydroxyquinolinolato lithium (Liq), and/or the like, but embodiments of the present disclosure are not limited thereto. The electron transport region ETR may also be formed of a mixture material of an electron transport material and an insulating organometallic salt. The organometallic salt may be a material having an energy band gap of about 4 eV or more. For example, the insulating organometallic salt may include, for example, one or more of a metal acetate, a metal benzoate, a metal acetoacetate, a metal acetylacetonate, or a metal stearate.

In one or more embodiments, the electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to one or more of the above-described materials, but embodiments of the present disclosure are not limited thereto.

The electron transport region ETR may include one or more of the above-described compounds of the electron transport region in at least one of an electron injection layer EIL, an electron transport layer ETL, or a hole blocking layer HBL.

If (e.g., when) the electron transport region ETR includes an electron transport layer ETL, the electron transport layer ETL may have a thickness of about 100 Å to about 1,000 Å, for example, about 150 Å to about 500 Å. If (e.g., when) the thickness of the electron transport layer ETL satisfies the aforementioned range, satisfactory electron transport characteristics may be obtained without a substantial increase in driving voltage. If (e.g., when) the electron transport region ETR includes an electron injection layer EIL, the electron injection layer EIL may have a thickness of about 1 Å to about 100 Å, for example, about 3 Å to about 90 Å. If (e.g., when) the thickness of the electron injection layer EIL satisfies the above-described range, satisfactory electron injection characteristics may be obtained without a substantial increase in driving voltage.

The second electrode EL2 may be provided on the electron transport region ETR. In one or more embodiments, the second electrode EL2 may be a common electrode. The second electrode EL2 may be a cathode or an anode, but embodiments of the disclosure are not limited thereto. For example, if (e.g., when) the first electrode EL1 is an anode, the second electrode EL2 may be a cathode, and if (e.g., when) the first electrode EL1 is a cathode, the second electrode EL2 may be an anode.

The second electrode EL2 may be a transmissive electrode, a transflective electrode, or a reflective electrode. If (e.g., when) the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), and/or the like.

If (e.g., when) the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In one or more embodiments, the second electrode EL2 may have a multilayer structure including a reflective film or a transflective film formed of one or more of the above-described materials, and a transparent conductive film formed of ITO, IZO, ZnO, ITZO, and/or the like. For example, in one or more embodiments, the second electrode EL2 may include one of the above-described metal materials, a (e.g., any suitable) combination of at least two metal materials of the above-described metal materials, an oxide of the above-described metal materials, and/or the like.

In one or more embodiments, the second electrode EL2 may be connected with an auxiliary electrode. If (e.g., when) the second electrode EL2 is connected with the auxiliary electrode, the resistance of the second electrode EL2 may be decreased.

In one or more embodiments, a capping layer CPL may further be arranged on the second electrode EL2 of the light emitting element ED of one or more embodiments. The capping layer CPL may include a multilayer or a single layer.

In one or more embodiments, the capping layer CPL may be an organic layer or an inorganic layer. For example, if (e.g., when) the capping layer CPL contains an inorganic material, the inorganic material may include an alkali metal compound (e.g., LiF), an alkaline earth metal compound (e.g., MgF₂), SiON, SiNₓ, SiO_{y}, and/or the like.

For example, in one or more embodiments, if (e.g., when) the capping layer CPL includes an organic material, the organic material may include a-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), and/or the like, or an epoxy resin, or acrylate such as methacrylate. However, embodiments of the present disclosure are not limited thereto, for example, in one or more embodiments, the capping layer CPL may include at least one selected from among Compounds P1 to P5:

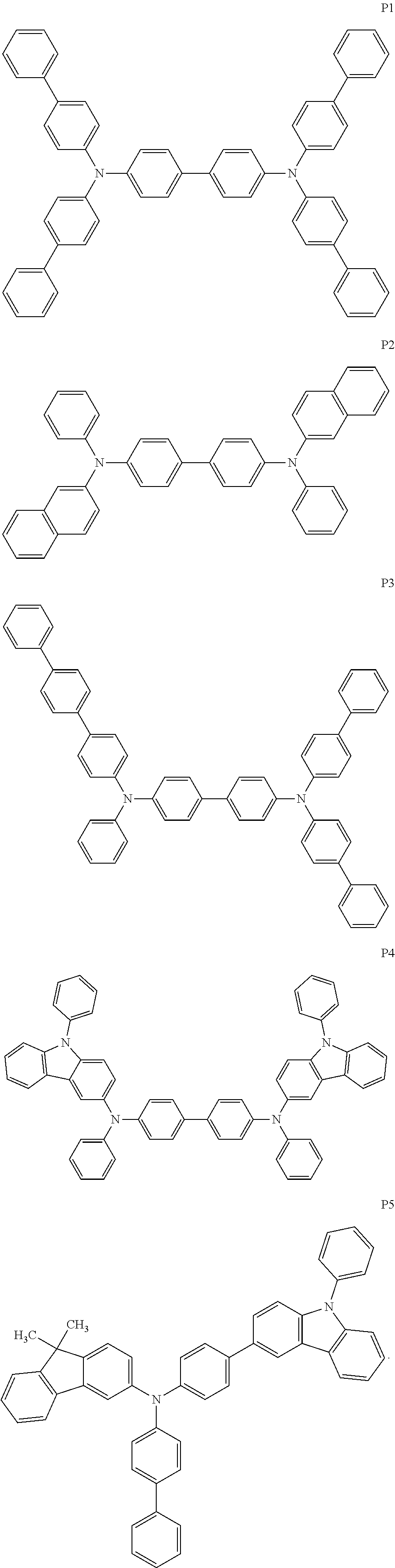 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the refractive index of the capping layer CPL may be about 1.6 or more. For example, in one or more embodiments, the refractive index of the capping layer CPL may be about 1.6 or more with respect to light in a wavelength range of about 550 nm to about 660 nm.

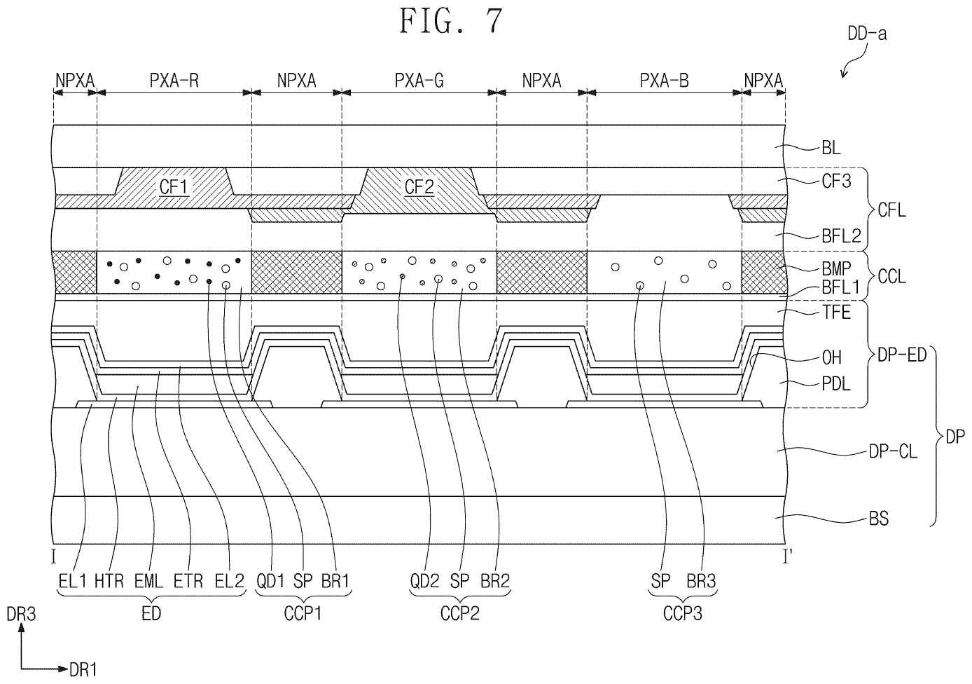

FIG. 7 to FIG. 10 are each a cross-sectional view of a display device according to one or more embodiments. Hereinafter, in the explanation on the display devices according to one or more embodiments of the present disclosure, referring to FIG. 7 to FIG. 10, the overlapping contents with those explained in FIG. 1 to FIG. 6 will not be explained again for conciseness, instead only different points will be explained mainly.

Referring to FIG. 7, a display device DD-a according to one or more embodiments may include a display panel DP including a display element layer DP-ED, a light control layer CCL arranged on the display panel DP, and a color filter layer CFL. In one or more embodiments as shown in FIG. 7, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR arranged on the first electrode EL1, an emission layer EML arranged on the hole transport region HTR, an electron transport region ETR arranged on the emission layer EML, and a second electrode EL2 arranged on the electron transport region ETR. In one or more embodiments, the same structure as any one of the light emitting elements ED of FIG. 3 to FIG. 6 may be applied to the structure of the light emitting element ED, shown in FIG. 7. The light emitting element ED shown in FIG. 7 may include the fused polycyclic compound of one or more embodiments of the present disclosure. The light emitting element ED including the fused polycyclic compound of one or more embodiments may show excellent or suitable emission efficiency and long-life characteristics.

Referring to FIG. 7, the emission layer EML may be arranged in an opening OH defined in a pixel defining film PDL. For example, the emission layer EML which is divided by the pixel defining film PDL and provided corresponding to each of light emitting regions PXA-R, PXA-G, and PXA-B may be to emit light in substantially the same wavelength range. In the display device DD-a of one or more embodiments, the emission layer EML may be to emit blue light. In one or more embodiments, the emission layer EML may be provided as a common layer across the entire light emitting regions PXA-R, PXA-G, and PXA-B.

The light control layer CCL may be arranged on the display panel DP. The light control layer CCL may include a light conversion body. The light conversion body may be a quantum dot, a phosphor, and/or the like. The light conversion body may be to emit provided light by converting the wavelength thereof. For example, the light control layer CCL may a layer containing a quantum dot or a layer containing a phosphor.

The light control layer CCL may include a plurality of light control parts CCP1, CCP2, and CCP3. The light control parts CCP1, CCP2, and CCP3 may be spaced and/or apart (e.g., spaced apart or separated) from one another.

Referring to FIG. 7, divided patterns BMP may be arranged between the light control parts CCP1, CCP2, and CCP3 which are spaced and/or apart (e.g., spaced apart or separated) from one another, but embodiments of the present disclosure are not limited thereto. FIG. 7 illustrates that the divided patterns BMP do not overlap the light control parts CCP1, CCP2, and CCP3, but, in one or more embodiments, at least a portion of the edges of the light control parts CCP1, CCP2, and CCP3 may overlap the divided patterns BMP.

The light control layer CCL may include a first light control part CCP1 containing a first quantum dot QD1 which converts first color light provided from the light emitting element ED into second color light, a second light control part CCP2 containing a second quantum dot QD2 which converts the first color light into third color light, and a third light control part CCP3 which transmits the first color light.

In one or more embodiments, the first light control part CCP1 may provide red light that is the second color light, and the second light control part CCP2 may provide green light that is the third color light. The third light control part CCP3 may provide blue light by transmitting the blue light that is the first color light provided from the light emitting element ED. For example, in one or more embodiments, the first quantum dot QD1 may be a red quantum dot to emit red light, and the second quantum dot QD2 may be a green quantum dot to emit green light. The same as described above on quantum dots may be applied with respect to the quantum dots QD1 and QD2.

In one or more embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but include the scatterer SP.

The scatterer SP may be inorganic particles. For example, the scatterer SP may include at least one of TiO₂, ZnO, Al₂O₃, SiO₂, or hollow sphere silica. In one or more embodiments, the scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 may respectively include base resins BR1, BR2, and BR3 in which the quantum dots QD1 and QD2 and the scatterer SP are dispersed accordingly. In one or more embodiments, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed accordingly, and may be formed of one or more suitable resin compositions, which may be generally referred to as a binder. For example, the base resins BR1, BR2, and BR3 may each independently be an acrylic-based resin, a urethane-based resin, a silicone-based resin, an epoxy-based resin, and/or the like. The base resins BR1, BR2, and BR3 may each be transparent resins. In one or more embodiments, the first base resin BR1, the second base resin BR2, and the third base resin BR3 may be the same as or different from one another.

In one or more embodiments, the light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may block the light control parts CCP1, CCP2, and CCP3 from being exposed to moisture/oxygen. In one or more embodiments, the barrier layer BFL1 may cover the light control parts CCP1, CCP2, and CCP3. In one or more embodiments, a barrier layer BFL2 may be provided between the light control parts CCP1, CCP2, and CCP3 and the color filter layer CFL.

The barrier layers BFL1 and BFL2 may each include at least one inorganic layer. For example, in one or more embodiments, the barrier layers BFL1 and BFL2 may each include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, and/or the like. In one or more embodiments, the barrier layers BFL1 and BFL2 may each independently further include an organic film. The barrier layers BFL1 and BFL2 may be each formed of a single layer or a plurality of layers.

In the display device DD-a of one or more embodiments, the color filter layer CFL may be arranged on the light control layer CCL. For example, in one or more embodiments, the color filter layer CFL may be directly arranged on the light control layer CCL. In these embodiments, the barrier layer BFL2 may not be provided.

The color filter layer CFL may include color filters CF1, CF2, and CF3. The color filter layer CFL may include a first filter CF1 configured to transmit the second color light, a second filter CF2 configured to transmit the third color light, and a third filter CF3 configured to transmit the first color light. For example, in one or more embodiments, the first filter CF1 may be a red filter, the second filter CF2 may be a green filter, and the third filter CF3 may be a blue filter. The filters CF1, CF2, and CF3 each may include a polymeric photosensitive resin and a pigment and/or a dye. The first filter CF1 may include a red pigment and/or a red dye, the second filter CF2 may include a green pigment and/or a green dye, and the third filter CF3 may include a blue pigment and/or a blue dye.

In one or more embodiments, the third filter CF3 may not include (e.g., may exclude) any pigment or dye. The third filter CF3 may include a polymeric photosensitive resin and may not include (e.g., may exclude) any pigment or dye. The third filter CF3 may be transparent. The third filter CF3 may be formed of a transparent photosensitive resin.

Furthermore, in one or more embodiments, the first filter CF1 and the second filter CF2 may each be a yellow filter. The first filter CF1 and the second filter CF2 may not be separated but be provided as one filter.

In one or more embodiments, the color filter layer CFL may further include a light shielding part. The light shielding part may be a black matrix. The light shielding part may include an organic light shielding material or an inorganic light shielding material containing a black pigment and/or a black dye. The light shielding part may prevent or reduce light leakage, and may separate boundaries between adjacent filters CF1, CF2, and CF3.

The first to third filters CF1, CF2, and CF3 may be arranged corresponding to the red light emitting region PXA-R, the green light emitting region PXA-G, and the blue light emitting region PXA-B, respectively.

In one or more embodiments, a base substrate BL may be arranged on the color filter layer CFL. The base substrate BL may be a member which provides a base surface on which the color filter layer CFL, the light control layer CCL, and/or the like are arranged. The base substrate BL may be a glass substrate, a metal substrate, a plastic substrate, and/or the like. However, embodiments of the present disclosure are not limited thereto, and the base substrate BL may be an inorganic layer, an organic layer, or a composite material layer. In one or more embodiments, the base substrate BL may not be provided.

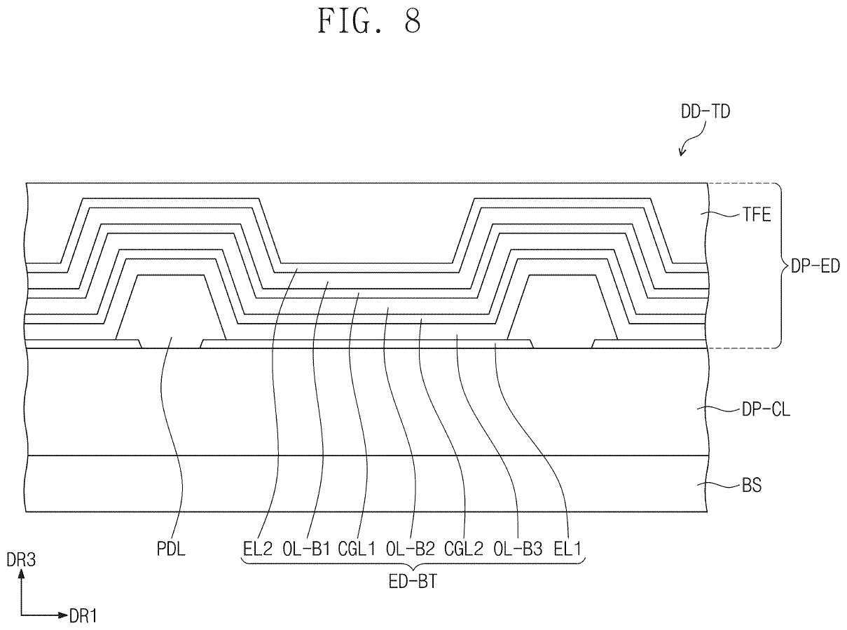

FIG. 8 is a cross-sectional view showing a portion of a display device according to one or more embodiments. In a display device DD-TD of one or more embodiments, a light emitting element ED-BT may include multiple light emitting structures OL-B1, OL-B2, and OL-B3. The light emitting element ED-BT may include oppositely arranged first electrode EL1 and second electrode EL2, and multiple light emitting structures OL-B1, OL-B2, and OL-B3, which are stacked in order in a thickness direction and provided between the first electrode EL1 and the second electrode EL2. Each of the light emitting structures OL-B1, OL-B2, and OL-B3 may include an emission layer EML (FIG. 7) and a hole transport region HTR and an electron transport region ETR arranged with the emission layer EML (FIG. 7) therebetween. For example, the light emitting element ED-BT included in the display device DD-TD of one or more embodiments may be a light emitting element with a tandem structure, including multiple emission layers.

At least one selected from among the light emitting structures OL-B1, OL-B2 and OL-B3 may include the fused polycyclic compound of one or more embodiments. The light emitting element ED-BT including the fused polycyclic compound of one or more embodiments may show excellent or suitable emission efficiency and long-life characteristics.

In one or more embodiments illustrated in FIG. 8, all light beams respectively emitted from the light emitting structures OL-B1, OL-B2, and OL-B3 may be blue light. However, embodiments of the present disclosure are not limited thereto, and the light beams respectively emitted from the light emitting structures OL-B1, OL-B2, and OL-B3 may have wavelength ranges different from one another. For example, in one or more embodiments, the light emitting element ED-BT including the plurality of light emitting structures OL-B1, OL-B2, and OL-B3 which emit light beams having wavelength ranges different from one another may be to emit white light (e.g., combined white light).

Charge generation layers CGL1 and CGL2 may be respectively arranged between two of the neighboring light emitting structures OL-B1, OL-B2, and OL-B3. The charge generation layers CGL1 and CGL2 may each include a p-type (kind) charge (e.g., P-charge) generation layer and/or an n-type (kind) charge (e.g., N-charge) generation layer.

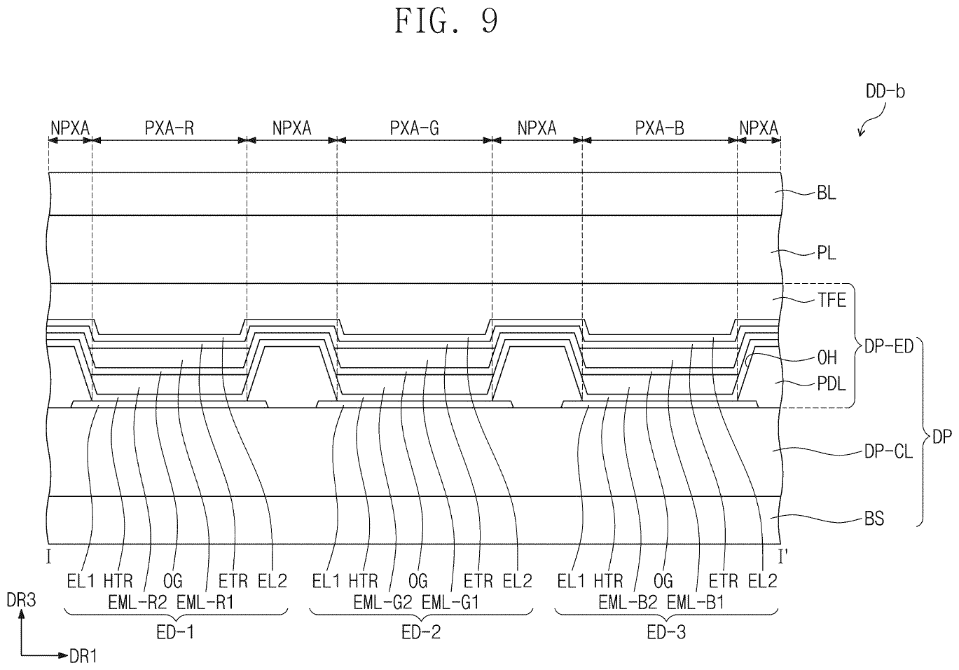

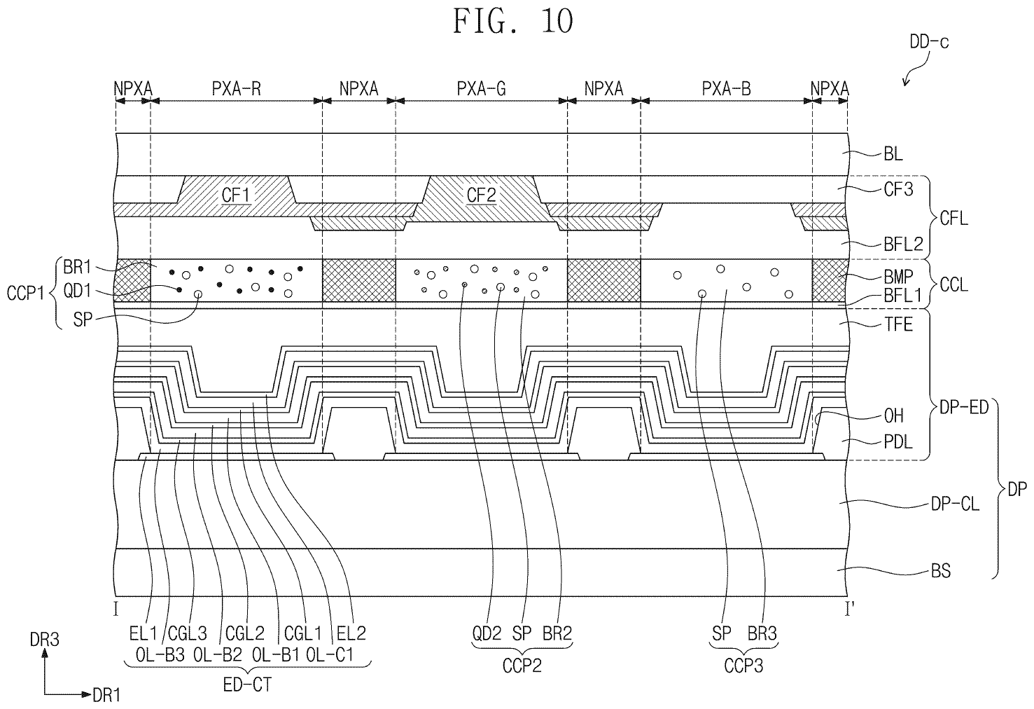

Referring to FIG. 9, a display device DD-b according to one or more embodiments may include light emitting elements ED-1, ED-2, and ED-3, in each of which two emission layers are stacked. Compared to the display device DD of one or more embodiments, shown in FIG. 2, the display device DD-b shown in FIG. 9 differs in that each of the first to third light emitting elements ED-1, ED-2, and ED-3 includes two emission layers stacked in a thickness direction. The two emission layers in each of the first to third light emitting elements ED-1, ED-2, and ED-3 may be to emit light having the same wavelength range.

In one or more embodiments, at least one selected from among the light emitting elements ED-1, ED-2, and ED-3 may include the fused polycyclic compound of one or more embodiments. The at least one selected from among the light emitting elements ED-1, ED-2, and ED-3, including the fused polycyclic compound of one or more embodiments, may show excellent or suitable emission efficiency.

In one or more embodiments, the first light emitting element ED-1 may include a first red emission layer EML-R1 and a second red emission layer EML-R2. The second light emitting element ED-2 may include a first green emission layer EML-G1 and a second green emission layer EML-G2. In addition, the third light emitting element ED-3 may include a first blue emission layer EML-B1 and a second blue emission layer EML-B2. An emission auxiliary part OG may be arranged between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. In one or more embodiments, the emission auxiliary part OG may include an electron transport region, a charge generation layer, and a hole transport region that are sequentially stacked (e.g., in the stated order). The emission auxiliary part OG may be provided as a common layer in the whole of the first to third light emitting elements ED-1, ED-2, and ED-3. However, embodiments of the present disclosure are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may each be arranged between the emission auxiliary part OG and the electron transport region ETR. The second red emission layer EML-R2, the second green emission layer EML-G2, and the second blue emission layer EML-B2 may each be arranged between the hole transport region HTR and the emission auxiliary part OG.

For example, in one or more embodiments, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2 that are sequentially stacked (e.g., in the stated order). The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2 that are sequentially stacked (e.g., in the stated order). The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2 that are sequentially stacked (e.g., in the stated order).

In one or more embodiments, an optical auxiliary layer PL may be arranged on the display element layer DP-ED. The optical auxiliary layer PL may include a polarizing layer. The optical auxiliary layer PL may be arranged on the display panel DP and control reflected light in the display panel DP due to external light. In one or more embodiments, the optical auxiliary layer PL may not be provided in the display device DD-b.

Different from FIG. 8 and FIG. 9, a display device DD-c in FIG. 10 is shown to include four light emitting structures OL-B1, OL-B2, OL-B3, and OL-C1. A light emitting element ED-CT may include oppositely arranged first electrode EL1 and second electrode EL2, and first to fourth light emitting structures OL-B1, OL-B2, OL-B3, and OL-C1 stacked in a thickness direction between the first electrode EL1 and the second electrode EL2. At least one selected from among the first to fourth light emitting structures OL-B1, OL-B2, OL-B3, and OL-C1 may include the fused polycyclic compound of one or more embodiments. The light emitting element ED-CT including the fused polycyclic compound of one or more embodiments may show excellent or suitable emission efficiency and long-life characteristics.

Charge generation layers CGL1, CGL2, and CGL3 may each be separately arranged between the first to fourth light emitting structures OL-B1, OL-B2, OL-B3, and OL-C1, accordingly. In one or more embodiments, among the four light emitting structures, the first to third light emitting structures OL-B1, OL-B2, and OL-B3 may be to emit blue light, and the fourth light emitting structure OL-C1 may be to emit green light. However, embodiments of the present disclosure are not limited thereto, and the first to fourth light emitting structures OL-B1, OL-B2, OL-B3, and OL-C1 may be to emit light beams in different wavelength regions.

The charge generation layers CGL1, CGL2, and CGL3 arranged between adjacent light emitting structures OL-B1, OL-B2, OL-B3, and OL-C1 may each independently include a p-type (kind) charge (e.g., P-charge) generation layer and/or an n-type (kind) charge (e.g., N-charge) generation layer.

In one or more embodiments, an electronic apparatus/device may include a display device including multiple light emitting elements and a control part controlling the display device. The electronic apparatus/device of one or more embodiments may be a device that is activated according to electrical signals. The electronic apparatus/device may include display devices of one or more suitable embodiments. For example, the electronic apparatus/devices may include large-size display devices such as televisions, monitors, and outside billboards, and/or medium- and small-size display devices such as personal computers, laptop computers, personal digital terminals, display apparatuses/devices for automobiles, game consoles, portable electronic devices, and cameras.

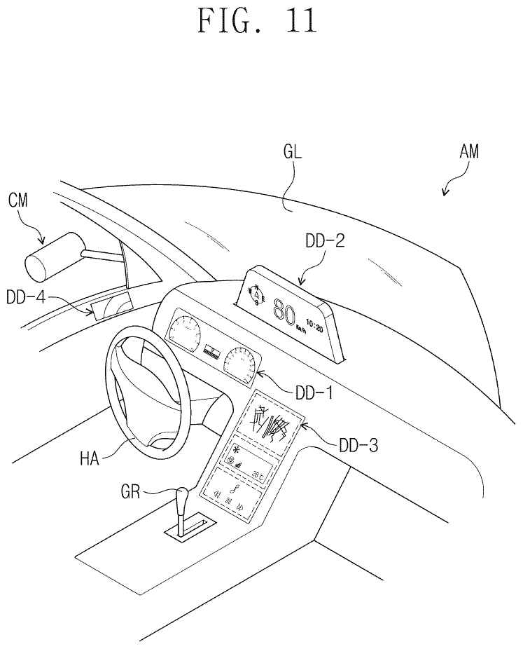

FIG. 11 is a diagram showing a vehicle AM in which first to fourth display devices DD-1, DD-2, DD-3, and DD-4 are arranged. At least one selected from among the first to fourth display devices DD-1, DD-2, DD-3, and DD-4 may include the same configurations as those of the display devices DD, DD-TD, DD-a, DD-b, and DD-c of embodiments, explained referring to FIGS. 1, 2, and 7 to 10.

In FIG. 11, a vehicle is shown as a vehicle AM, but this is an example, and the first to fourth display devices DD-1, DD-2, DD-3, and DD-4 may be arranged on other transport apparatuses such as bicycles, motorcycles, trains, ships, and/or airplanes. In one or more embodiments, at least one selected from among the first to fourth display devices DD-1, DD-2, DD-3, and DD-4 including the same configurations as those of the display devices DD, DD-TD, DD-a, DD-b, and DD-c may be introduced in personal computers, laptop computers, personal digital terminals, game consoles, portable electronic devices, televisions, monitors, external billboards, and/or the like. These are suggested as examples, and the display device may be introduced in other electronic apparatuses/devices as long as not deviated from the disclosure.

At least one selected from among the first to fourth display devices DD-1, DD-2, DD-3, and DD-4 may include the light emitting element ED, explained referring to FIG. 3 to FIG. 6. At least one selected from among the first to fourth display devices DD-1, DD-2, DD-3, and DD-4 may include the fused polycyclic compound of one or more embodiments. A display device including the fused polycyclic compound of one or more embodiments (at least one selected from among the first to fourth display devices DD-1, DD-2, DD-3, and DD-4) may show excellent or suitable display quality.

Referring to FIG. 11, the vehicle AM may include a steering wheel HA and a gear GR for driving the vehicle AM. In addition, the vehicle AM may include a front window GL arranged so as to face a driver.

The first display device DD-1 may be arranged in a first region overlapping the steering wheel HA. For example, the first display device DD-1 may be a digital cluster which displays first information of the vehicle AM. The first information may include a first scale which indicates a driving speed of the vehicle AM, a second scale which indicates an engine speed (that is, revolutions per minute (RPM)), an image which indicates a fuel state, and/or the like. The first scale and the second scale may be each indicated as a digital image.

The second display device DD-2 may be arranged in a second region opposite to (e.g., facing) a driver seat and overlapping the front window GL. The driver seat may be a seat in which the steering wheel HA faces. For example, the second display device DD-2 may be a head up display (HUD) which displays second information of the vehicle AM. The second display device DD-2 may be optically transparent. The second information may include digital numbers which indicate a driving speed, and may further include information such as the current time. In one or more embodiments, the second information of the second display device DD-2 may be projected to the front window GL to be displayed.

The third display device DD-3 may be arranged in a third region adjacent to the gear GR. For example, the third display device DD-3 may be arranged between the driver seat and a passenger seat and may be a center information display (CID) for the vehicle for displaying third information. The passenger seat may be a seat spaced and/or apart (e.g., spaced apart or separated) from the driver seat with the gear GR arranged therebetween. The third information may include information about traffic (e.g., navigation information), playing music or radio or a video (or an image), temperatures inside the vehicle AM, and/or the like.

The fourth display device DD-4 may be spaced and/or apart (e.g., spaced apart or separated) from the steering wheel HA and the gear GR, and may be arranged in a fourth region adjacent to a side of the vehicle AM. For example, the fourth display device DD-4 may be a digital side-view mirror which displays fourth information. The fourth display device DD-4 may display an image outside the vehicle AM taken by a camera module CM arranged outside the vehicle AM. The fourth information may include an image outside the vehicle AM.

The above-described first to fourth information may be examples, and the first to fourth display devices DD-1, DD-2, DD-3, and DD-4 may further display information about the inside and outside of the vehicle AM. The first to fourth information may include different information. However, embodiments of the present disclosure are not limited thereto, and a part of the first to fourth information may include the same information as one another.

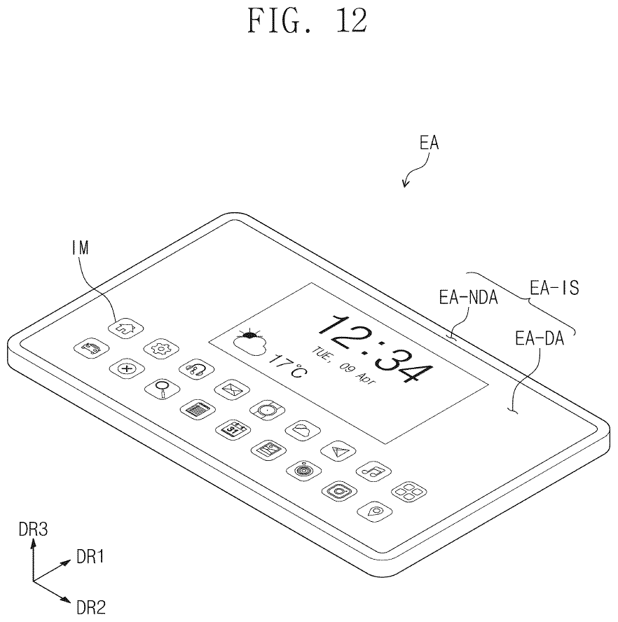

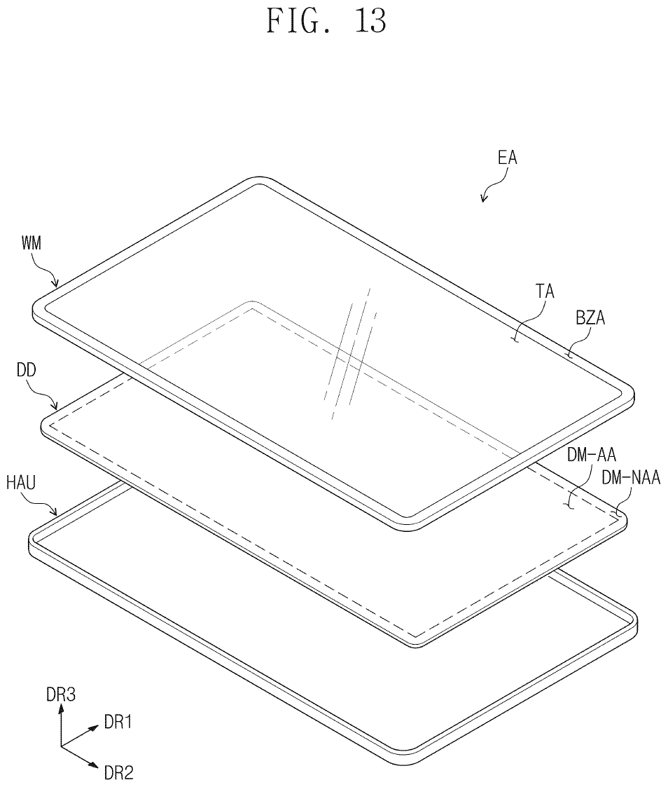

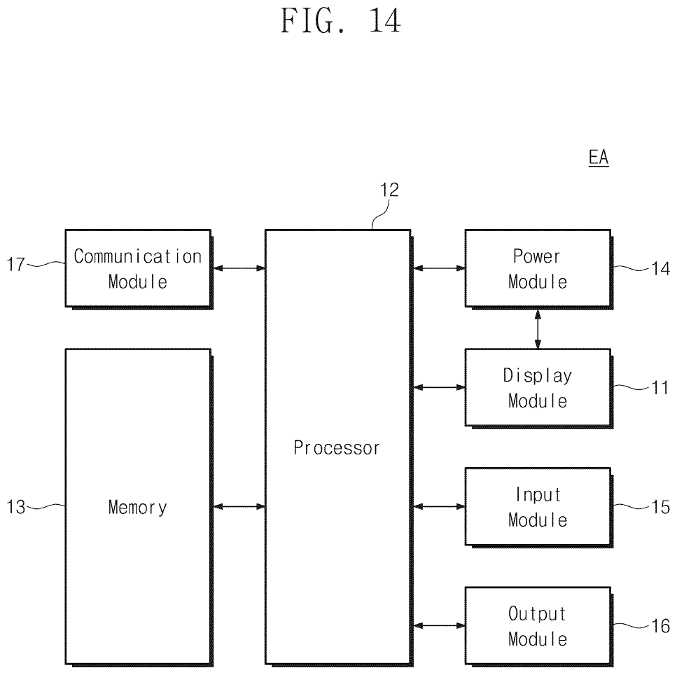

FIG. 12 is a perspective view showing an electronic apparatus of one or more embodiments of the present disclosure. FIG. 13 is an exploded perspective view showing an electronic apparatus of one or more embodiments.

The electronic apparatus EA may display an image IM through a display surface EA-IS. The image IM may include a dynamic image as well as a static image. The display surface EA-IS may be parallel to a plane defined by a first direction axis DR1 and a second direction axis DR2. FIG. 12 illustrates an electronic apparatus EA having a flat display surface EA-IS, but embodiments of the present disclosure are not limited thereto. For example, in one or more embodiments, the electronic apparatus EA may include a curved display surface or a three-dimensional display surface. The three-dimensional display surface may include a plurality of display areas indicating different directions from each other.

The display surface EA-IS may include a display area EA-DA and a non-display area EA-NDA. The electronic apparatus EA may display an image IM through the display area EA-DA.

The non-display area EA-NDA may have a set or predetermined color. The non-display area EA-NDA may be adjacent to the display area EA-DA. The non-display area EA-NDA may be around (e.g., surround) the display area EA-DA. Accordingly, the shape of the display area EA-DA may be substantially defined by the non-display area EA-NDA. However, FIG. 12 is a mere example, and the non-display area EA-NDA may be arranged adjacent to only one side of the display area EA-DA or may even not be provided.

Referring to FIG. 13, the electronic apparatus EA may include a display device DD. In addition, the electronic apparatus EA may further include a window member WM and a housing HAU.

The window member WM may cover the entire outer side of the electronic apparatus EA. The window member WM may include a transparent area TA and a bezel area BZA. The front surface of the window member WM including the transparent area TA and the bezel area BZA may correspond to the front surface of the electronic apparatus EA. The transparent area TA may correspond to the display area EA-DA of the electronic apparatus EA illustrated in FIG. 12, and the bezel area BZA may correspond to the non-display area EA-NDA of the electronic apparatus EA illustrated in FIG. 12.

The transparent area TA may be an optically transparent area. The bezel area BZA may be an area having a relatively low light transmittance compared to the transparent area TA. The bezel area BZA may have a set or predetermined color. The bezel area BZA may be adjacent to the transparent area TA and may be around (e.g., surround) the transparent area TA. The bezel area BZA may define the shape of the transparent area TA. However, embodiments of the present disclosure are not limited thereto, and the bezel area BZA may be arranged adjacent to only one side of the transparent area TA, or a portion thereof may not be provided.

The housing HAU may include a material having relatively high rigidity. For example, in one or more embodiments, the housing HAU may include a frame and/or a plate made of glass, plastic, or metal. The frames and/or plates may be provided in multiple pieces. The housing HAU may provide a set or predetermined receiving space. The display device DD may be accommodated in the receiving space and protected from external impact.

The display device DD may include the same configurations as those of at least one selected from among the display devices DD, DD-TD, DD-a, DD-b, and DD-c of one or more embodiments described with reference to FIGS. 1, 2, and 7 to 10. The display device DD may include the light emitting element ED described with reference to FIGS. 3 to 6. Accordingly, the electronic apparatus EA including the display device DD according to one or more embodiments may exhibit excellent or suitable reliability.

An active area DM-AA and a peripheral area DM-NAA may be defined in the display device DD. The active area DM-AA may overlap the display area EA-DA illustrated in FIG. 12, and the peripheral area DM-NAA may overlap the non-display area EA-NDA illustrated in FIG. 12.

The active area DM-AA may be an area activated according to an electrical signal. The peripheral area DM-NAA may be an area positioned adjacent to at least one side of the active area DM-AA. The active area DM-AA may include the non-light emitting area NPXA and light emitting areas PXA-R, PXA-G, and PXA-B, illustrated in FIG. 1. The peripheral area DM-NAA may be arranged to be around (e.g., surround) the active area DM-AA. However, embodiments of the present disclosure are not limited thereto, for example, in one or more embodiments, some of the peripheral areas DM-NAA may not be provided. A driving circuit and/or driving wiring for driving the active area DM-AA may be arranged in the peripheral area DM-NAA.

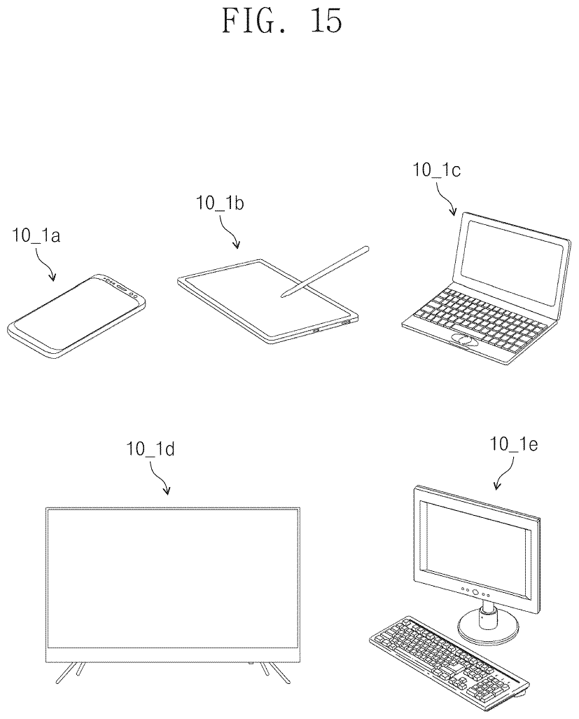

The electronic apparatus EA according to one or more embodiments includes the display device described above, and may further include a module or device having an additional function, in addition to the display device. FIG. 14 is a block diagram of an electronic apparatus according to one or more embodiments of the present disclosure. Referring to FIG. 14, an electronic apparatus EA according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller. Data information necessary for the operation of the processor 12 or the display module 11 may be stored in the memory 13. If (e.g., when) the processor 12 executes an application stored in the memory 13, an image data signal and/or an input control signal are transmitted to the display module 11, and the display module 11 may process the received signal and output image information through a display screen.

The power module 14 may include a power supply module such as a power adapter or a battery device, and a power conversion module that converts the power supplied by the power supply module to generate power necessary for the operation of the electronic apparatus EA.

The display module 11 may include at least some configurations of the display devices DD, DD-TD, DD-a, DD-b, and DD-c, described with reference to FIGS. 1, 2, and 7 to 10. For example, in one or more embodiments, the display module 11 may include a base layer BS, a circuit layer DP-CL, and a display element layer DP-ED among the configurations of the display devices DD, DD-TD, DD-a, DD-b, and DD-c, described with reference to FIGS. 1, 2, and 7 to 10. In addition, the display module 11 may further include at least one of an optical layer PP (FIG. 2), a light control layer CCL (FIGS. 7 and 10), a color filter layer CFL (FIGS. 7 and 10), and an optical auxiliary layer PL (FIG. 10).

In one or more embodiments, the electronic apparatus EA may further include an input module 15, a non-image output module 16, and/or a communication module 17.

The input module 15 may provide input information to the processor 12 and/or the display module 11. The input module 15 may include one or more suitable sensor modules as well as physical buttons, a keyboard, and/or a microphone. Non-limiting examples of sensor module may include touch sensors, pressure sensors, distance sensors, position sensors, digitizers, motion recognition sensors, camera sensors, photodetector, photoelectric conversion sensors, temperature sensors, and biosensors such as blood pressure sensors, blood sugar sensors, electrocardiogram sensors, and heart rate sensors.

The non-image output module 16 may receive information other than images transmitted from the processor 12 and provide the information to a user. Non-limiting examples of the non-image output module 16 may include an audio module, a haptic module, a light emitting module, and/or the like, and may include other electronic device-specific functional modules (e.g., a cooling module of a refrigerator, and/or the like).

The communication module 17 is a module responsible for transmitting and receiving information between the electronic apparatus EA and an external device, and may include a receiving part and a transmitting part. The communication module 17 may include one or more suitable wireless communication modules such as a mobile communication module, a Wi-Fi module, and/or a Bluetooth module, or one or more suitable wired communication modules.

At least one of the configurations of the electronic apparatus EA described above may be included in the above-described display device (i.e., in at least one of DD, DD-TD, DD-a, DD-b, or DD-c, FIGS. 1, 2, and 7 to 10) according to one or more embodiments. In one or more embodiments, some of the individual modules functionally included in one module may be included in the display device, and other modules may be provided separately from the display device. For example, in one or more embodiments, the display device may include the display module 11 and the processor 12, and the memory 13 and the power module 14 may be provided in the form of other devices within the electronic apparatus EA other than the display device.

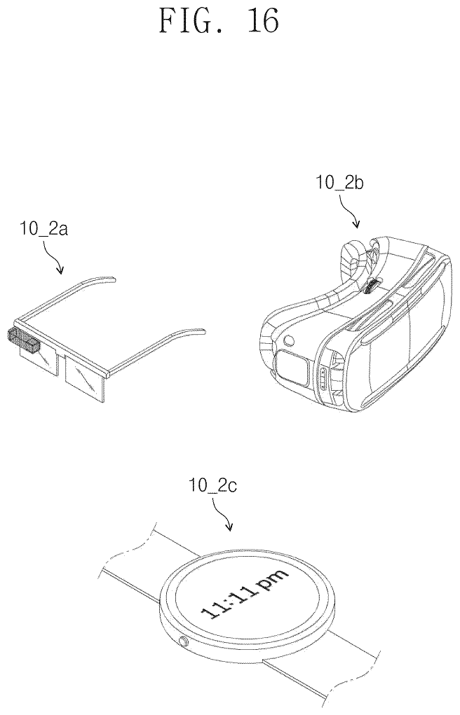

FIG. 15 and FIG. 16 are each a schematic diagram showing electronic apparatuses according to one or more embodiments of the present disclosure. Referring to FIG. 15 and FIG. 16, one or more suitable electronic apparatuses to which a display device (e.g., at least one of DD, DD-TD, DD-a, DD-b, or DD-c, FIGS. 1, 2, and 7 to 10) according to one or more embodiments is applied may include not only image display electronic apparatuses such as a smart phone 10_1a, a tablet PC 10_1b, a laptop 10_1c, a TV 10_1d, and a monitor for a desk 10_1e, but also wearable electronic apparatuses including display modules such as smart glasses 10_2a, a head-mounted display 10_2b, and a smart watch 10_2c. However, these are example embodiments, and the electronic apparatus according to one or more embodiments is not limited thereto.

Hereinafter, referring to Examples and Comparative Examples, the fused polycyclic compound according to one or more embodiments of the present disclosure and the light emitting element of one or more embodiments will be explained in particular. In addition, the Examples below are mere illustrations to assist the understanding of the present disclosure, but the scope of the disclosure is not limited thereto.

### EXAMPLES

### 1. Synthesis of Fused Polycyclic Compounds of Embodiments

The synthetic method of the fused polycyclic compound according to one or more embodiments will be explained in particular illustrating the synthetic methods of Fused Polycyclic Compounds 7, 41, 46, 91, 106, 120, 126, 138, and 142. In addition, the synthetic methods of the fused polycyclic compounds explained hereinafter are examples, and the synthetic method of the fused polycyclic compound according to one or more embodiments of the disclosure is not limited to the examples.

### (1) Synthesis of Fused Polycyclic Compound 7

Fused Polycyclic Compound 7 according to one or more embodiments may be synthesized according to, for example, Reaction Scheme 1.

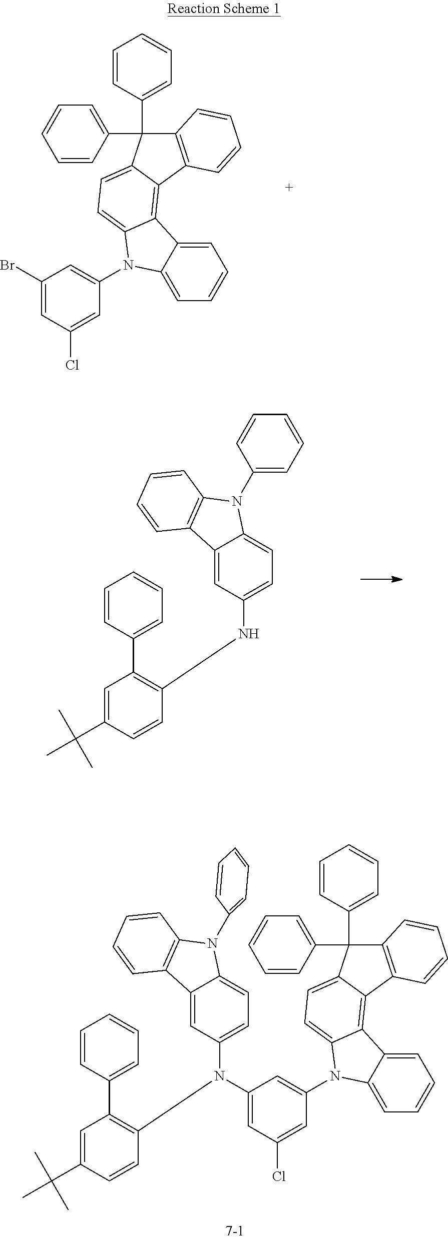 [SMILES: Clc1cc(Br)cc(-n2c3ccccc3c3c4c(ccc32)C(c2ccccc2)(c2ccccc2)c2ccccc2-4)c1 ; CC(C)(C)c1ccc(Nc2ccc3c(c2)c2ccccc2n3-c2ccccc2)c(-c2ccccc2)c1 ; CC(C)(C)c1ccc(N(c2cc(Cl)cc(-n3c4ccccc4c4c5c(ccc43)C(c3ccccc3)(c3ccccc3)c3ccccc3-5)c2)c2ccc3c(c2)c2ccccc2n3-c2ccccc2)c(-c2ccccc2)c1]

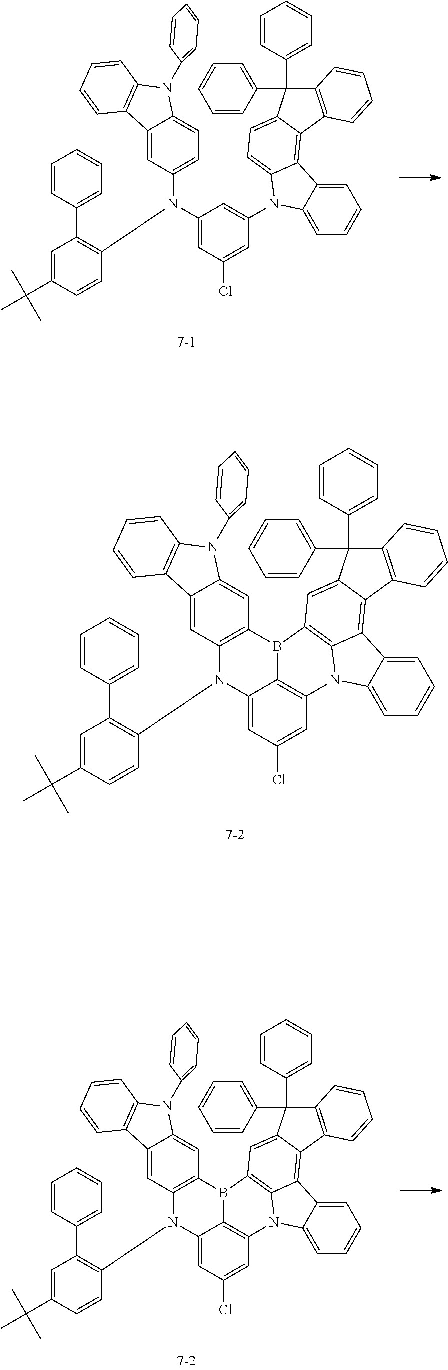 [SMILES: CC(C)(C)c1ccc(N(c2cc(Cl)cc(-n3c4ccccc4c4c5c(ccc43)C(c3ccccc3)(c3ccccc3)c3ccccc3-5)c2)c2ccc3c(c2)c2ccccc2n3-c2ccccc2)c(-c2ccccc2)c1 ; CC(C)(C)c1ccc(N2c3cc4c5ccccc5n(-c5ccccc5)c4cc3B3c4c2cc(Cl)cc4-n2c4ccccc4c4c5c(cc3c42)C(c2ccccc2)(c2ccccc2)c2ccccc2-5)c(-c2ccccc2)c1 ; CC(C)(C)c1ccc(N2c3cc4c5ccccc5n(-c5ccccc5)c4cc3B3c4c2cc(Cl)cc4-n2c4ccccc4c4c5c(cc3c42)C(c2ccccc2)(c2ccccc2)c2ccccc2-5)c(-c2ccccc2)c1]

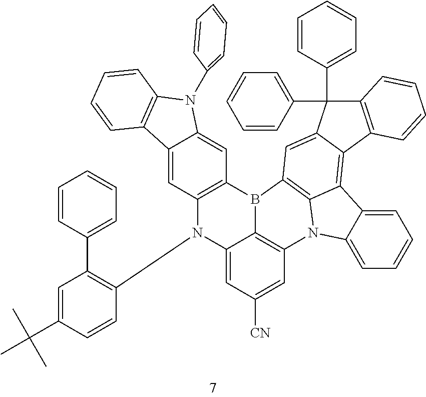 [SMILES: CC(C)(C)c1ccc(N2c3cc4c5ccccc5n(-c5ccccc5)c4cc3B3c4c2cc(C#N)cc4-n2c4ccccc4c4c5c(cc3c42)C(c2ccccc2)(c2ccccc2)c2ccccc2-5)c(-c2ccccc2)c1]

### Synthesis of Intermediate 7-1

5-(3-Bromo-5-chlorophenyl)-8,8-diphenyl-5,8-dihydroindeno[2,1-c]carbazole (1 eq), N-(5-(tert-butyl)-[1,1′-biphenyl]-2-yl)-9-phenyl-9H-carbazol-3-amine (1 eq), tris(dibenzylideneacetone)dipalladium(0) (0.05 eq), tri-tert-butylphosphine (0.1 eq), and sodium tert-butoxide (3 eq) were dissolved in toluene and stirred at about 80 degrees centigrade for about 12 hours. After cooling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using methylene chloride (MC) and n-hexane (as an eluent) to obtain Intermediate 7-1 (yield: 73%).

### Synthesis of Intermediate 7-2

Intermediate 7-1 (1 eq) was dissolved in o-dichlorobenzene and cooled to about 0 degrees centigrade, and under a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwise to a flask containing the reaction product to finish the reaction, and ethyl alcohol was added to the reaction product to precipitate. The precipitate was filtered to obtain a solid content. The solid content thus obtained was purified by column chromatography using MC and n-hexane and recrystallized using toluene and acetone to obtain Intermediate 7-2 (yield: 15%).

### Synthesis of Compound 7

Intermediate 7-2 (1 eq), potassium ferrocyanide (1 eq), di-tert-butyl(4-dimethylaminophenyl)phosphine (0.1 eq), and sodium carbonate (4 eq) were dissolved in dimethylformamide (DMF) and stirred at about 160 degrees centigrade for about 12 hours. After cooling, the reaction product was diluted with ethyl acetate and washed three times with water, and layer separation (e.g., extraction) was performed to obtain an organic layer. The organic layer thus obtained was dried over anhydrous MgSO₄ and then dried under a reduced pressure. The resultant was purified by column chromatography using MC and n-hexane to obtain Compound 7 (yield: 65%).

### (2) Synthesis of Fused Polycyclic Compound 41

Fused Polycyclic Compound 41 according to one or more embodiments may be synthesized according to, for example, Reaction Scheme 2.

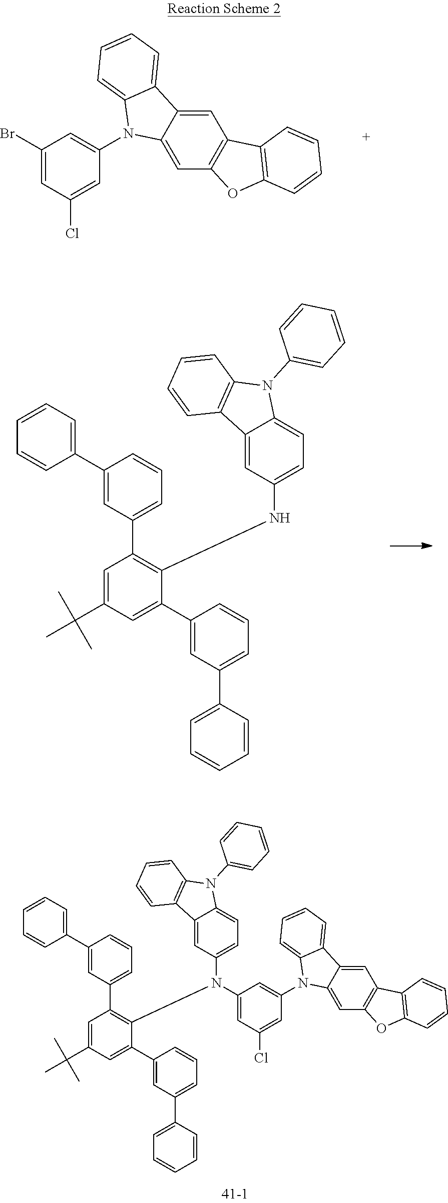 [SMILES: Clc1cc(Br)cc(-n2c3ccccc3c3cc4c(cc32)oc2ccccc24)c1 ; CC(C)(C)c1cc(-c2cccc(-c3ccccc3)c2)c(Nc2ccc3c(c2)c2ccccc2n3-c2ccccc2)c(-c2cccc(-c3ccccc3)c2)c1 ; CC(C)(C)c1cc(-c2cccc(-c3ccccc3)c2)c(N(c2cc(Cl)cc(-n3c4ccccc4c4cc5c(cc43)oc3ccccc35)c2)c2ccc3c(c2)c2ccccc2n3-c2ccccc2)c(-c2cccc(-c3ccccc3)c2)c1]

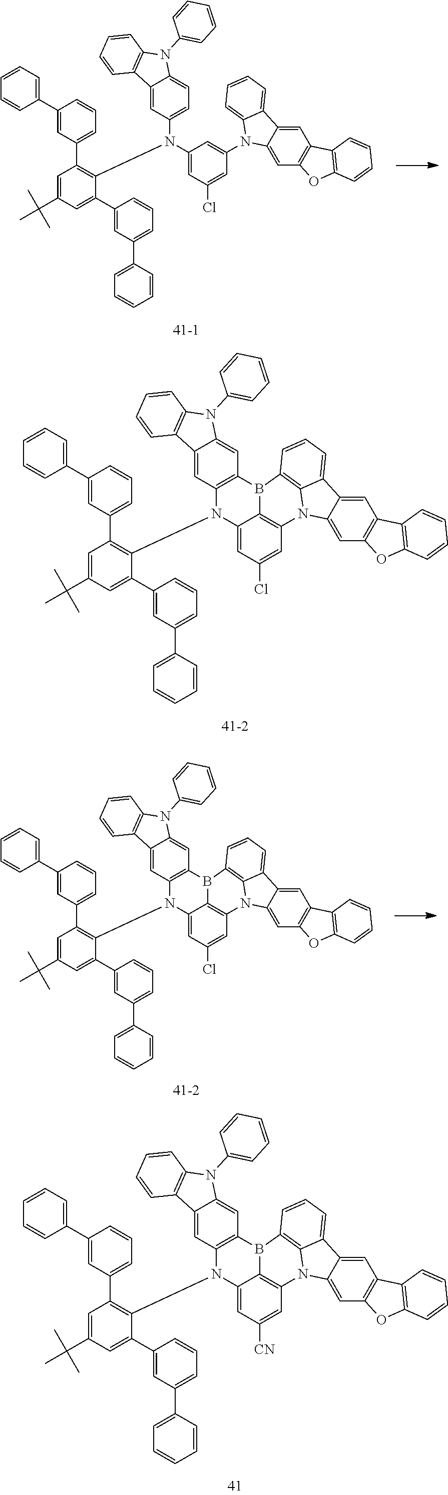

### Synthesis of Intermediate 41-1

7-(3-Bromo-5-chlorophenyl)-7H-benzofuro[2,3-b]carbazole (1 eq), N-(5″-(tert-butyl)-[1,1′:3′,1″:3″,1′″:3′″,1″″-quinquephenyl]-2′-yl)-9-phenyl-9H-carbazol-3-amine (1 eq), tris(dibenzylideneacetone)dipalladium(0) (0.05 eq), tri-tert-butylphosphine (0.1 eq), and sodium tert-butoxide (3 eq) were dissolved in toluene and stirred at about 80 degrees centigrade for about 12 hours. After cooling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Intermediate 41-(yield: 71%).

### Synthesis of Intermediate 41-2

Intermediate 41-1 (1 eq) was dissolved in o-dichlorobenzene and cooled to about 0 degrees centigrade, and under a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwise to a flask containing the reaction product to finish the reaction, and ethyl alcohol was added to the reaction product to precipitate. The precipitate was filtered to obtain a solid content. The solid content thus obtained was purified by column chromatography using MC and n-hexane and recrystallized using toluene and acetone to obtain Intermediate 41-2 (yield: 15%).

### Synthesis of Compound 41

Intermediate 41-2 (1 eq), potassium ferrocyanide (1 eq), di-tert-butyl(4-dimethylaminophenyl)phosphine (0.1 eq), and sodium carbonate (4 eq) were dissolved in DMF and stirred at about 160 degrees centigrade for about 12 hours. After cooling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Compound 41 (yield: 65%).

### (3) Synthesis of Fused Polycyclic Compound 46

Fused Polycyclic Compound 46 according to one or more embodiments may be synthesized according to, for example, Reaction Scheme 3.

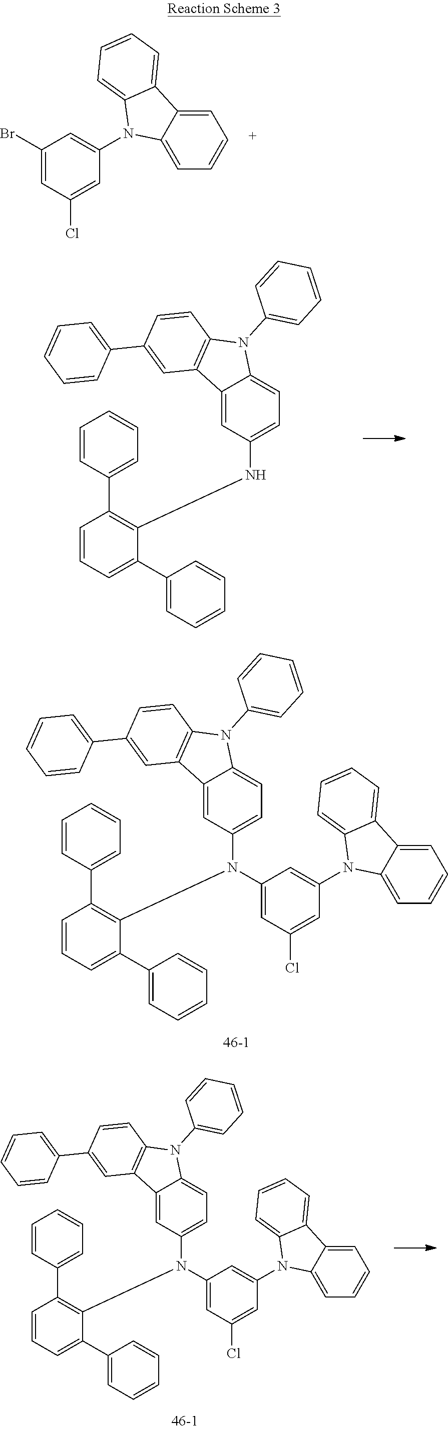 [SMILES: Clc1cc(Br)cc(-n2c3ccccc3c3ccccc32)c1 ; c1ccc(-c2ccc3c(c2)c2cc(Nc4c(-c5ccccc5)cccc4-c4ccccc4)ccc2n3-c2ccccc2)cc1 ; Clc1cc(N(c2ccc3c(c2)c2cc(-c4ccccc4)ccc2n3-c2ccccc2)c2c(-c3ccccc3)cccc2-c2ccccc2)cc(-n2c3ccccc3c3ccccc32)c1 ; Clc1cc(N(c2ccc3c(c2)c2cc(-c4ccccc4)ccc2n3-c2ccccc2)c2c(-c3ccccc3)cccc2-c2ccccc2)cc(-n2c3ccccc3c3ccccc32)c1]

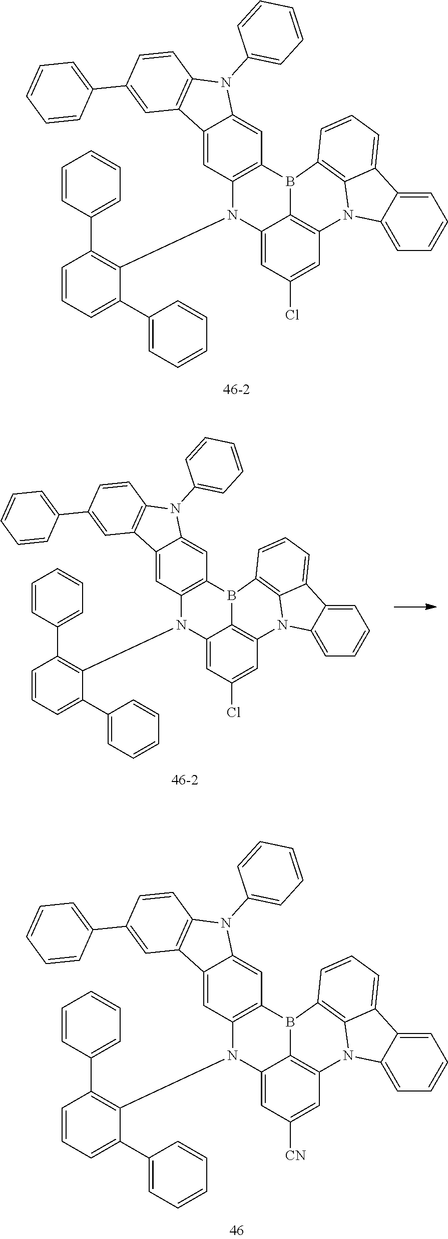 [SMILES: Clc1cc2c3c(c1)-n1c4ccccc4c4cccc(c41)B3c1cc3c(cc1N2c1c(-c2ccccc2)cccc1-c1ccccc1)c1cc(-c2ccccc2)ccc1n3-c1ccccc1 ; Clc1cc2c3c(c1)-n1c4ccccc4c4cccc(c41)B3c1cc3c(cc1N2c1c(-c2ccccc2)cccc1-c1ccccc1)c1cc(-c2ccccc2)ccc1n3-c1ccccc1 ; N#Cc1cc2c3c(c1)-n1c4ccccc4c4cccc(c41)B3c1cc3c(cc1N2c1c(-c2ccccc2)cccc1-c1ccccc1)c1cc(-c2ccccc2)ccc1n3-c1ccccc1]

### Synthesis of Intermediate 46-1

9-(3-Bromo-5-chlorophenyl)-9H-carbazole (1 eq), N-([1,1′:3′,1″terphenyl]-2′-yl)-6,9-diphenyl-9H-carbazol-3-amine (1 eq), tris(dibenzylideneacetone)dipalladium(0) (0.05 eq), tri-tert-butylphosphine (0.1 eq), and sodium tert-butoxide (3 eq) were dissolved in toluene and stirred at about 80 degrees centigrade for about 12 hours. After cooling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Intermediate 46-1 (yield: 77%).

### Synthesis of Intermediate 46-2

Intermediate 46-1 (1 eq) was dissolved in o-dichlorobenzene and cooled to about 0 degrees centigrade, and under a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwise to a flask containing the reaction product to finish the reaction, and ethyl alcohol was added to the reaction product to precipitate. The precipitate was filtered to obtain a solid content. The solid content thus obtained was purified by column chromatography using MC and n-hexane and recrystallized using toluene and acetone to obtain Intermediate 46-2 (yield: 13%).

### Synthesis of Compound 46

Intermediate 46-2 (1 eq), potassium ferrocyanide (1 eq), di-tert-butyl(4-dimethylaminophenyl)phosphine (0.1 eq), and sodium carbonate (4 eq) were dissolved in DMF and stirred at about 160 degrees centigrade for about 12 hours. After cooling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Compound 46 (yield: 60%).

### (4) Synthesis of Fused Polycyclic Compound 91

Fused Polycyclic Compound 91 according to one or more embodiments may be synthesized according to, for example, Reaction Scheme 4.

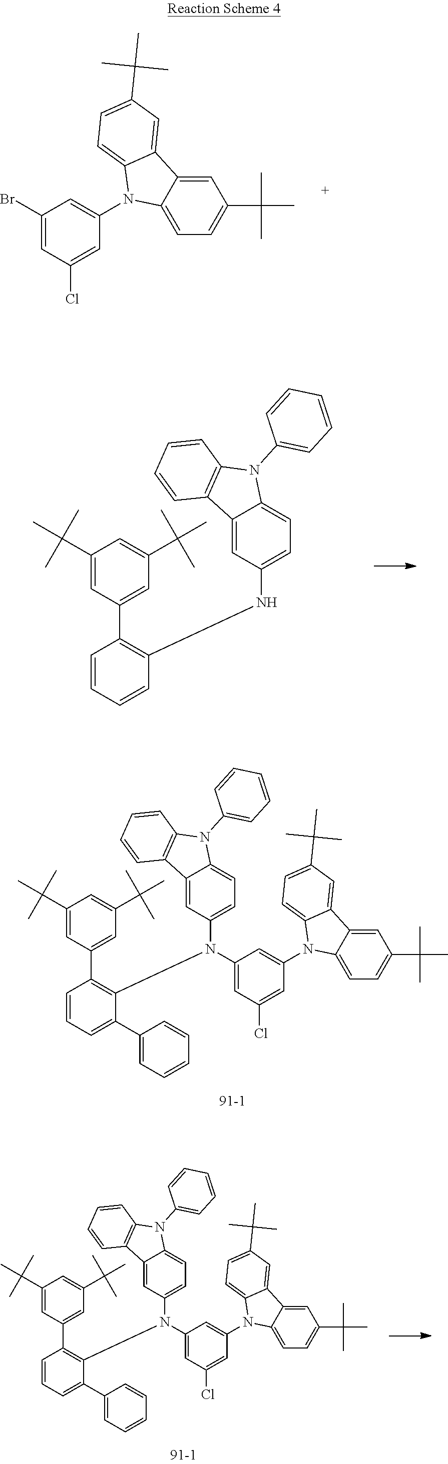

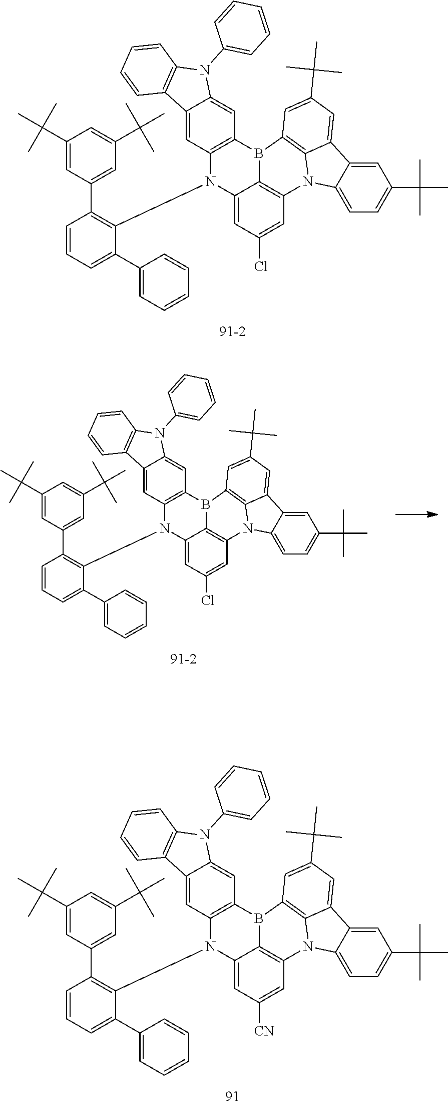

### Synthesis of Intermediate 91-1

9-(3-Bromo-5-chlorophenyl)-3,6-di-tert-butyl-9H-carbazole (1 eq), N-(3′,5′-di-tert-butyl-[1,1′-biphenyl]-2-yl)-9-phenyl-9H-carbazol-3-amine (1 eq), tris(dibenzylideneacetone)dipalladium(0) (0.05 eq), tri-tert-butylphosphine (0.1 eq), and sodium tert-butoxide (3 eq) were dissolved in toluene and stirred at about 80 degrees centigrade for about 12 hours. After coaling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Intermediate 91-1 (yield: 75%).

### Synthesis of Intermediate 91-2

Intermediate 91-1 (1 eq) was dissolved in o-dichlorobenzene and cooled to about 0 degrees centigrade, and under a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwise to a flask containing the reaction product to finish the reaction, and ethyl alcohol was added to the reaction product to precipitate. The precipitate was filtered to obtain a solid content. The solid content thus obtained was purified by column chromatography using MC and n-hexane and recrystallized using toluene and acetone to obtain Intermediate 91-2 (yield: 15%).

### Synthesis of Compound 91

Intermediate 91-2 (1 eq), potassium ferrocyanide (1 eq), di-tert-butyl(4-dimethylaminophenyl)phosphine (0.1 eq), and sodium carbonate (4 eq) were dissolved in DMF and stirred at about 160 degrees centigrade for about 12 hours. After cooling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Compound 91 (yield: 63%).

### (5) Synthesis of Fused Polycyclic Compound 106

Fused Polycyclic Compound 106 according to one or more embodiments may be synthesized according to, for example, Reaction Scheme 5.

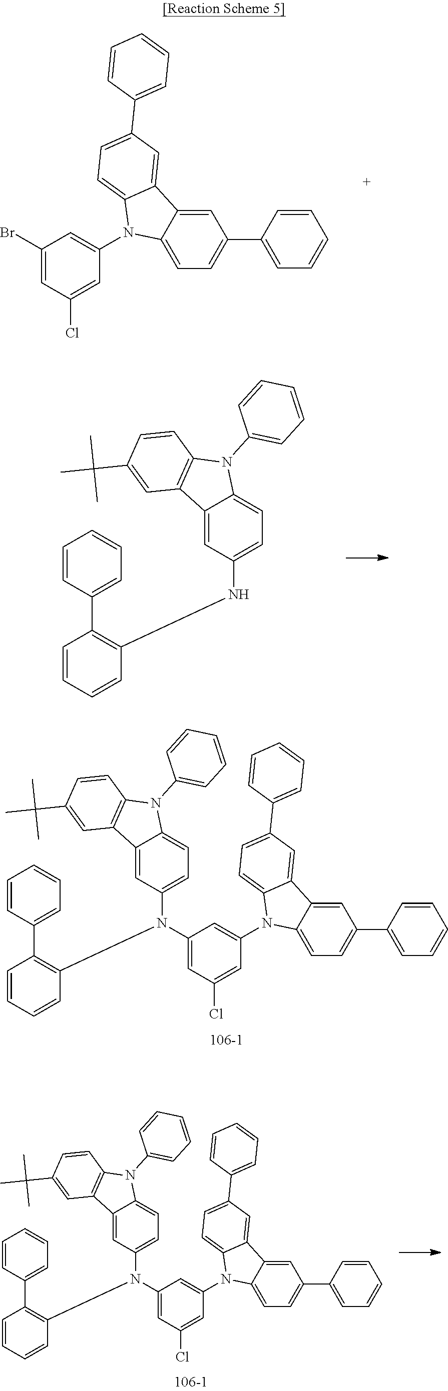 [SMILES: Clc1cc(Br)cc(-n2c3ccc(-c4ccccc4)cc3c3cc(-c4ccccc4)ccc32)c1 ; CC(C)(C)c1ccc2c(c1)c1cc(Nc3ccccc3-c3ccccc3)ccc1n2-c1ccccc1 ; CC(C)(C)c1ccc2c(c1)c1cc(N(c3cc(Cl)cc(-n4c5ccc(-c6ccccc6)cc5c5cc(-c6ccccc6)ccc54)c3)c3ccccc3-c3ccccc3)ccc1n2-c1ccccc1 ; CC(C)(C)c1ccc2c(c1)c1cc(N(c3cc(Cl)cc(-n4c5ccc(-c6ccccc6)cc5c5cc(-c6ccccc6)ccc54)c3)c3ccccc3-c3ccccc3)ccc1n2-c1ccccc1]

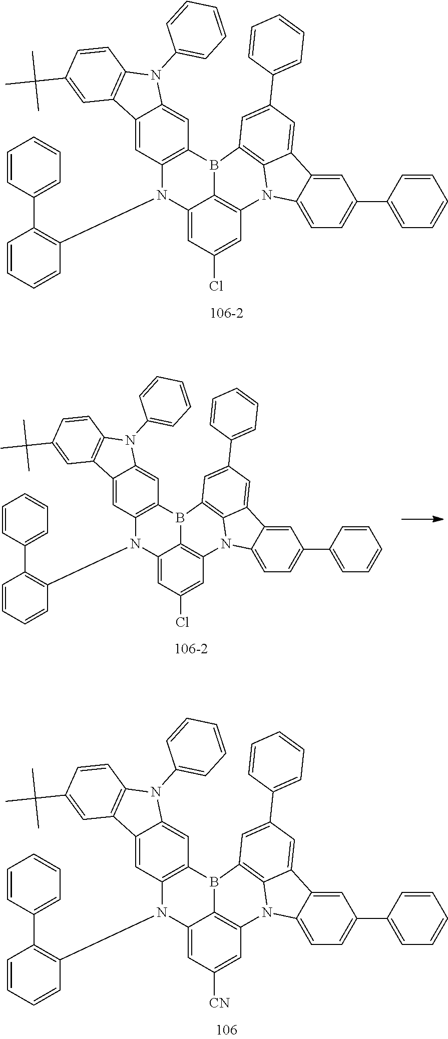 [SMILES: CC(C)(C)c1ccc2c(c1)c1cc3c(cc1n2-c1ccccc1)B1c2c(cc(Cl)cc2-n2c4ccc(-c5ccccc5)cc4c4cc(-c5ccccc5)cc1c42)N3c1ccccc1-c1ccccc1 ; CC(C)(C)c1ccc2c(c1)c1cc3c(cc1n2-c1ccccc1)B1c2c(cc(Cl)cc2-n2c4ccc(-c5ccccc5)cc4c4cc(-c5ccccc5)cc1c42)N3c1ccccc1-c1ccccc1 ; CC(C)(C)c1ccc2c(c1)c1cc3c(cc1n2-c1ccccc1)B1c2c(cc(C#N)cc2-n2c4ccc(-c5ccccc5)cc4c4cc(-c5ccccc5)cc1c42)N3c1ccccc1-c1ccccc1]

### Synthesis of Intermediate 106-1

9-(3-Bromo-5-chlorophenyl)-3,6-diphenyl-9H-carbazole (1 eq), N-([1,1′-biphenyl]-2-yl)-6-(tert-butyl)-9-phenyl-9H-carbazol-3-amine (1 eq), tris(dibenzylideneacetone)dipalladium(0) (0.05 eq), tri-tert-butylphosphine (0.1 eq), and sodium tert-butoxide (3 eq) were dissolved in toluene and stirred at about 80 degrees centigrade for about 12 hours. After cooling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Intermediate 106-1 (yield: 72%).

### Synthesis of Intermediate 106-2

Intermediate 106-1 (1 eq) was dissolved in o-dichlorobenzene and cooled to about 0 degrees centigrade, and under a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwise to a flask containing the reaction product to finish the reaction, and ethyl alcohol was added to the reaction product to precipitate. The precipitate was filtered to obtain a solid content. The solid content thus obtained was purified by column chromatography using MC and n-hexane and recrystallized using toluene and acetone to obtain Intermediate 106-2 (yield: 18%).

### Synthesis of Compound 106

Intermediate 106-2 (1 eq), potassium ferrocyanide (1 eq), di-tert-butyl(4-dimethylaminophenyl)phosphine (0.1 eq), and sodium carbonate (4 eq) were dissolved in DMF and stirred at about 160 degrees centigrade for about 12 hours. After cooling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Compound 106 (yield: 67%).

### (6) Synthesis of Fused Polycyclic Compound 120

Fused Polycyclic Compound 120 according to one or more embodiments may be synthesized according to, for example, Reaction Scheme 6.

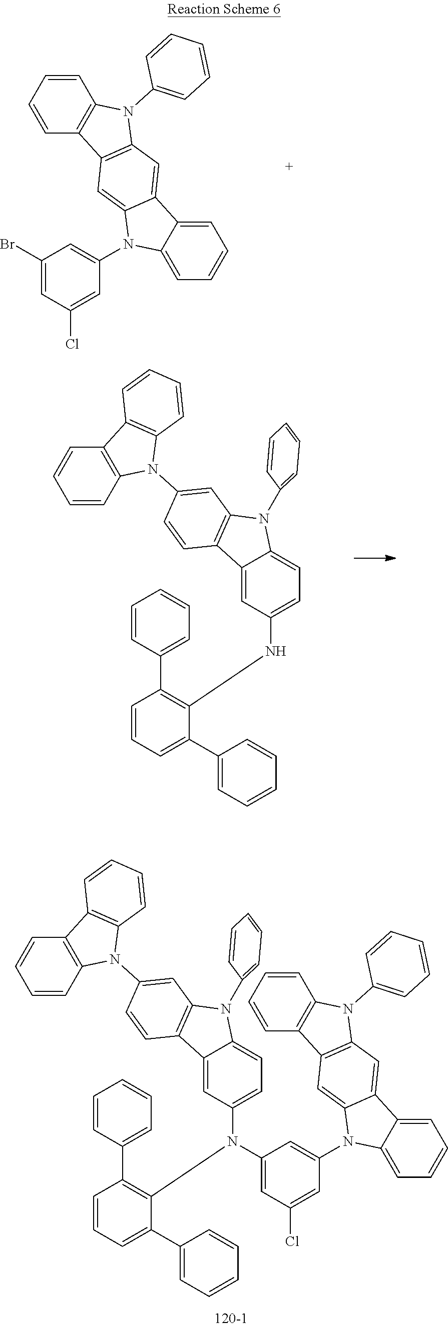 [SMILES: Clc1cc(Br)cc(-n2c3ccccc3c3cc4c(cc32)c2ccccc2n4-c2ccccc2)c1 ; c1ccc(-c2cccc(-c3ccccc3)c2Nc2ccc3c(c2)c2ccc(-n4c5ccccc5c5ccccc54)cc2n3-c2ccccc2)cc1 ; Clc1cc(N(c2ccc3c(c2)c2ccc(-n4c5ccccc5c5ccccc54)cc2n3-c2ccccc2)c2c(-c3ccccc3)cccc2-c2ccccc2)cc(-n2c3ccccc3c3cc4c(cc32)c2ccccc2n4-c2ccccc2)c1]

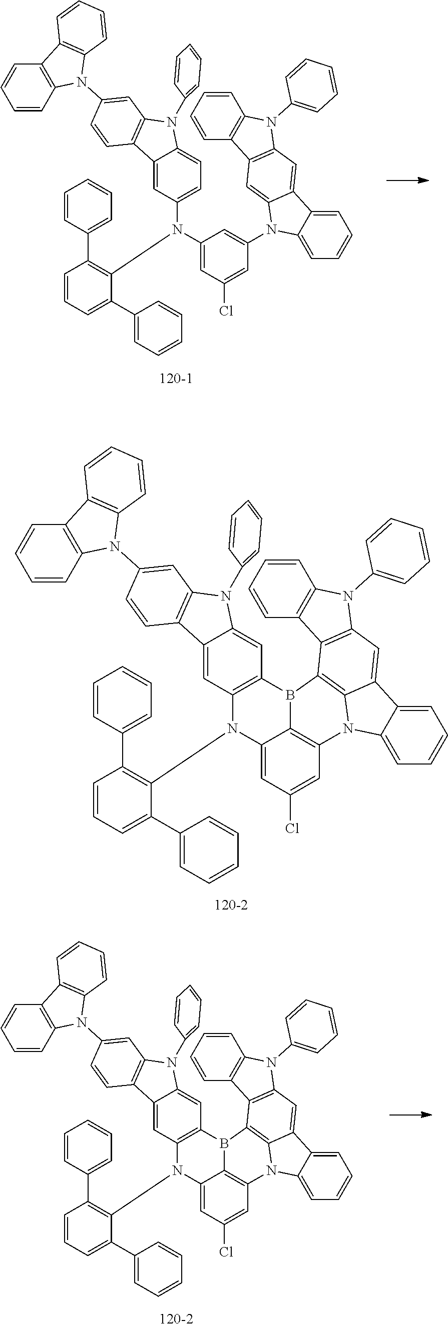 [SMILES: Clc1cc(N(c2ccc3c(c2)c2ccc(-n4c5ccccc5c5ccccc54)cc2n3-c2ccccc2)c2c(-c3ccccc3)cccc2-c2ccccc2)cc(-n2c3ccccc3c3cc4c(cc32)c2ccccc2n4-c2ccccc2)c1 ; Clc1cc2c3c(c1)-n1c4ccccc4c4cc5c(c(c41)B3c1cc3c(cc1N2c1c(-c2ccccc2)cccc1-c1ccccc1)c1ccc(-n2c4ccccc4c4ccccc42)cc1n3-c1ccccc1)c1ccccc1n5-c1ccccc1 ; Clc1cc2c3c(c1)-n1c4ccccc4c4cc5c(c(c41)B3c1cc3c(cc1N2c1c(-c2ccccc2)cccc1-c1ccccc1)c1ccc(-n2c4ccccc4c4ccccc42)cc1n3-c1ccccc1)c1ccccc1n5-c1ccccc1]

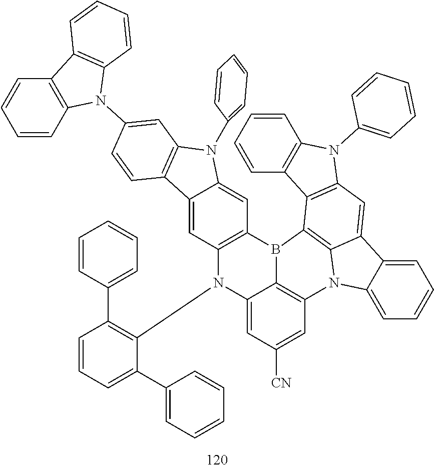 [SMILES: N#Cc1cc2c3c(c1)-n1c4ccccc4c4cc5c(c(c41)B3c1cc3c(cc1N2c1c(-c2ccccc2)cccc1-c1ccccc1)c1ccc(-n2c4ccccc4c4ccccc42)cc1n3-c1ccccc1)c1ccccc1n5-c1ccccc1]

### Synthesis of Intermediate 120-1

5-(3-Bromo-5-chlorophenyl)-11-phenyl-5,11-dihydroindolo[3,2-b]carbazole (1 eq), N-([1,1′:3′,1″-terphenyl]-2′-yl)-9-phenyl-9H-[2,9′-bicarbazol]-6-amine (1 eq), tris(dibenzylideneacetone)dipalladium(0) (0.05 eq), tri-tert-butylphosphine (0.1 eq), and sodium tert-butoxide (3 eq) were dissolved in toluene and stirred at about 80 degrees centigrade for about 12 hours. After cooling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Intermediate 120-1 (yield: 67%).

### Synthesis of Intermediate 120-2

Intermediate 120-1 (1 eq) was dissolved in o-dichlorobenzene and cooled to about 0 degrees centigrade, and under a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwise to a flask containing the reaction product to finish the reaction, and ethyl alcohol was added to the reaction product to precipitate. The precipitate was filtered to obtain a solid content. The solid content thus obtained was purified by column chromatography using MC and n-hexane and recrystallized using toluene and acetone to obtain Intermediate 120-2 (yield: 14%).

### Synthesis of Compound 120

Intermediate 120-2 (1 eq), potassium ferrocyanide (1 eq), di-tert-butyl(4-dimethylaminophenyl)phosphine (0.1 eq), and sodium carbonate (4 eq) were dissolved in DMF and stirred at about 160 degrees centigrade for about 12 hours. After cooling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Compound 120 (yield: 65%).

### (7) Synthesis of Fused Polycyclic Compound 126

Fused Polycyclic Compound 126 according to one or more embodiments may be synthesized according to, for example, Reaction Scheme 7.

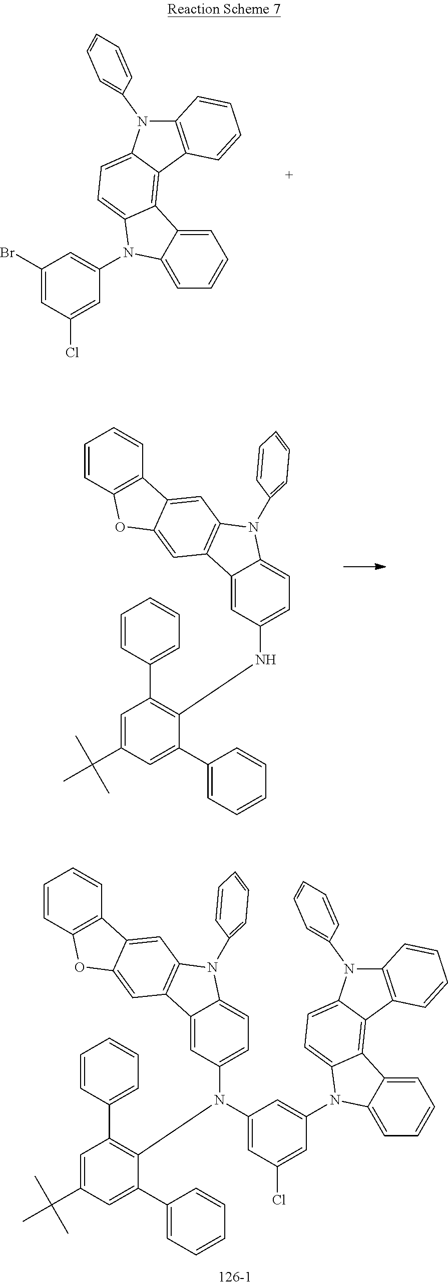 [SMILES: Clc1cc(Br)cc(-n2c3ccccc3c3c4c5ccccc5n(-c5ccccc5)c4ccc32)c1 ; CC(C)(C)c1cc(-c2ccccc2)c(Nc2ccc3c(c2)c2cc4oc5ccccc5c4cc2n3-c2ccccc2)c(-c2ccccc2)c1 ; CC(C)(C)c1cc(-c2ccccc2)c(N(c2cc(Cl)cc(-n3c4ccccc4c4c5c6ccccc6n(-c6ccccc6)c5ccc43)c2)c2ccc3c(c2)c2cc4oc5ccccc5c4cc2n3-c2ccccc2)c(-c2ccccc2)c1]

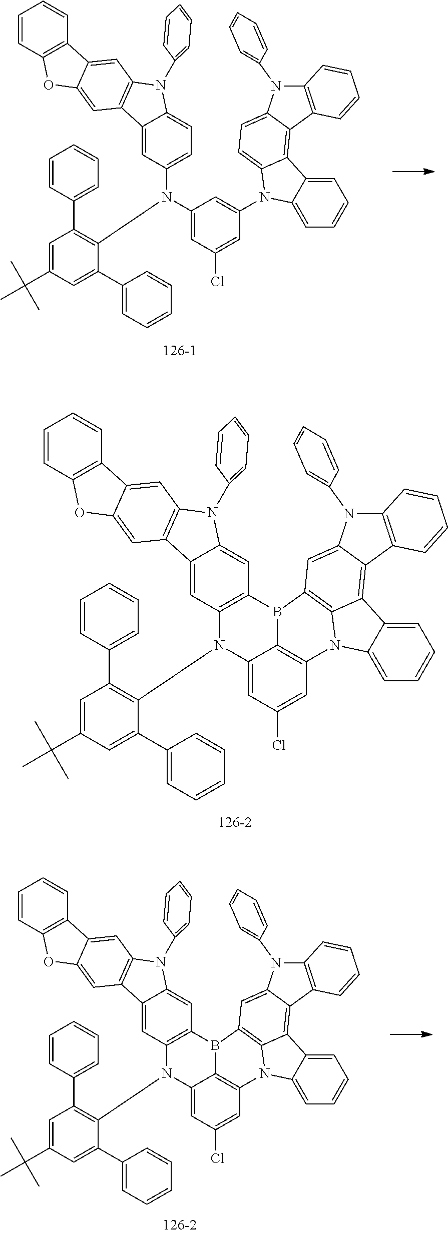 [SMILES: CC(C)(C)c1cc(-c2ccccc2)c(N(c2cc(Cl)cc(-n3c4ccccc4c4c5c6ccccc6n(-c6ccccc6)c5ccc43)c2)c2ccc3c(c2)c2cc4oc5ccccc5c4cc2n3-c2ccccc2)c(-c2ccccc2)c1 ; CC(C)(C)c1cc(-c2ccccc2)c(N2c3cc4c5cc6oc7ccccc7c6cc5n(-c5ccccc5)c4cc3B3c4c2cc(Cl)cc4-n2c4ccccc4c4c5c6ccccc6n(-c6ccccc6)c5cc3c42)c(-c2ccccc2)c1 ; CC(C)(C)c1cc(-c2ccccc2)c(N2c3cc4c5cc6oc7ccccc7c6cc5n(-c5ccccc5)c4cc3B3c4c2cc(Cl)cc4-n2c4ccccc4c4c5c6ccccc6n(-c6ccccc6)c5cc3c42)c(-c2ccccc2)c1]

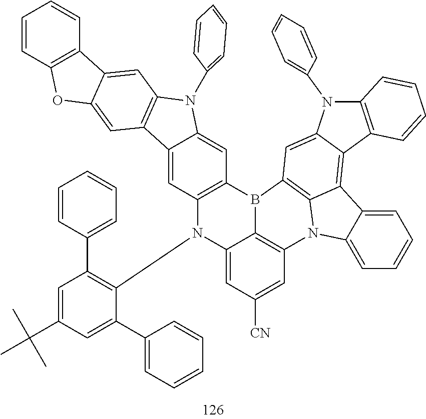 [SMILES: CC(C)(C)c1cc(-c2ccccc2)c(N2c3cc4c5cc6oc7ccccc7c6cc5n(-c5ccccc5)c4cc3B3c4c2cc(C#N)cc4-n2c4ccccc4c4c5c6ccccc6n(-c6ccccc6)c5cc3c42)c(-c2ccccc2)c1]

### Synthesis of Intermediate 126-1

5-(3-Bromo-5-chlorophenyl)-8-phenyl-5,8-dihydroindolo[2,3-c]carbazole (1 eq), N-(5′-(tert-butyl)-[1,1′:3′,1″-terphenyl]-2′-yl)-11-phenyl-11H-benzofuro[3,2-b]carbazol-8-amine (1 eq), tris(dibenzylideneacetone)dipalladium(0) (0.05 eq), tri-tert-butylphosphine (0.1 eq), and sodium tert-butoxide (3 eq) were dissolved in toluene and stirred at about 80 degrees centigrade for about 12 hours. After coaling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Intermediate 126-1 (yield: 71%).

### Synthesis of Intermediate 126-2

Intermediate 126-1 (1 eq) was dissolved in o-dichlorobenzene and cooled to about 0 degrees centigrade, and under a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwise to a flask containing the reaction product to finish the reaction, and ethyl alcohol was added to the reaction product to precipitate. The precipitate was filtered to obtain a solid content. The solid content thus obtained was purified by column chromatography using MC and n-hexane and recrystallized using toluene and acetone to obtain Intermediate 126-2 (yield: 17%).

### Synthesis of Compound 126

Intermediate 126-2 (1 eq), potassium ferrocyanide (1 eq), di-tert-butyl(4-dimethylaminophenyl)phosphine (0.1 eq), and sodium carbonate (4 eq) were dissolved in DMF and stirred at about 160 degrees centigrade for about 12 hours. After cooling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Compound 126 (yield: 63%).

### (8) Synthesis of Fused Polycyclic Compound 138

Fused Polycyclic Compound 138 according to one or more embodiments may be synthesized according to, for example, Reaction Scheme 8.

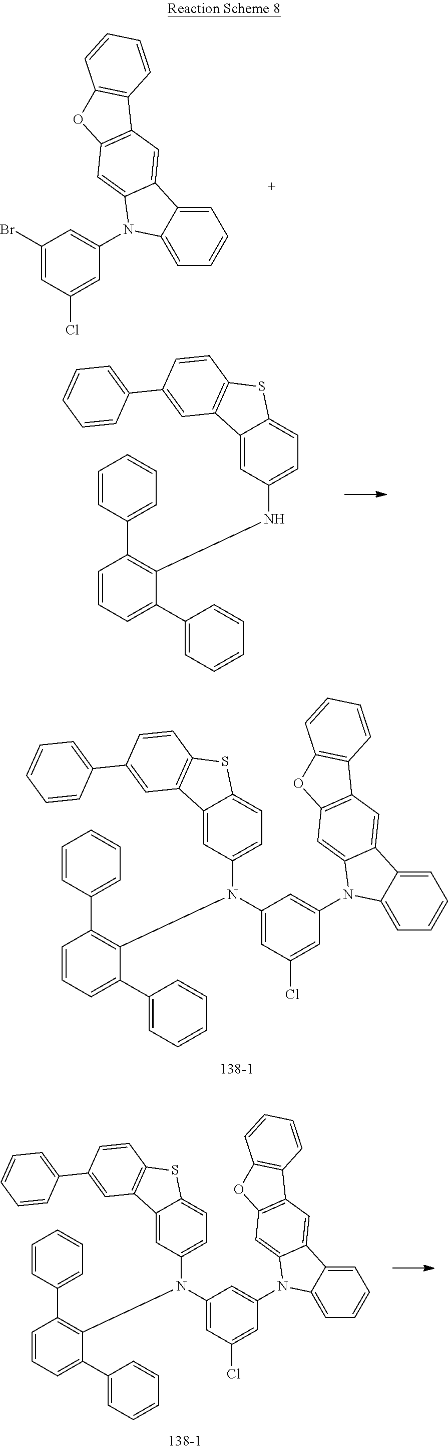

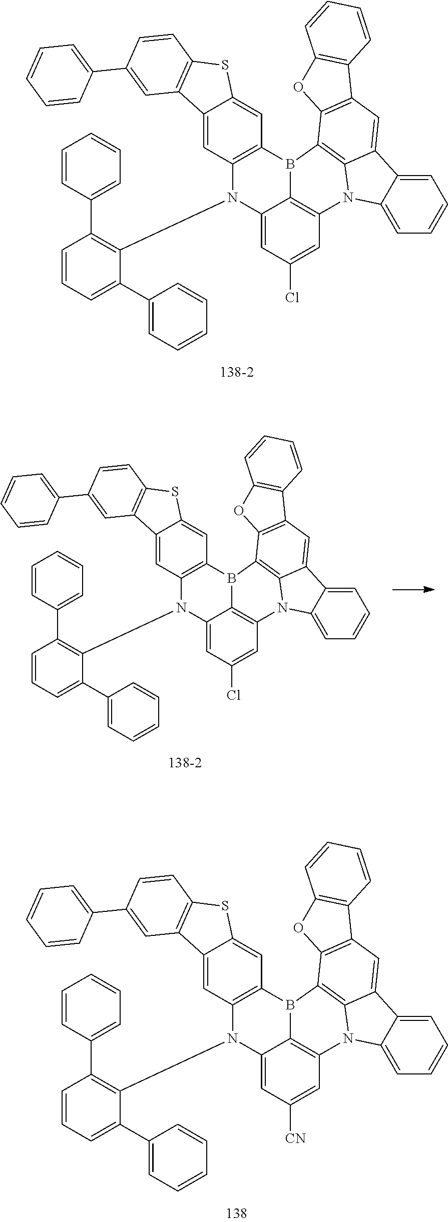 [SMILES: Clc1cc2c3c(c1)-n1c4ccccc4c4cc5c(oc6ccccc65)c(c41)B3c1cc3sc4ccc(-c5ccccc5)cc4c3cc1N2c1c(-c2ccccc2)cccc1-c1ccccc1 ; Clc1cc2c3c(c1)-n1c4ccccc4c4cc5c(oc6ccccc65)c(c41)B3c1cc3sc4ccc(-c5ccccc5)cc4c3cc1N2c1c(-c2ccccc2)cccc1-c1ccccc1 ; N#Cc1cc2c3c(c1)-n1c4ccccc4c4cc5c(oc6ccccc65)c(c41)B3c1cc3sc4ccc(-c5ccccc5)cc4c3cc1N2c1c(-c2ccccc2)cccc1-c1ccccc1]

### Synthesis of Intermediate 138-1

7-(3-Bromo-5-chlorophenyl)-7H-benzofuro[2,3-b]carbazole (1 eq), N-([1,1′:3′,1″-terphenyl]-2′-yl)-8-phenyldibenzo[b,d]thiophen-2-amine (1 eq), tris(dibenzylideneacetone)dipalladium(0) (0.05 eq), tri-tert-butylphosphine (0.1 eq), and sodium tert-butoxide (3 eq) were dissolved in toluene and stirred at about 80 degrees centigrade for about 12 hours. After cooling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Intermediate 138-1 (yield: 75%).

### Synthesis of Intermediate 138-2

Intermediate 138-1 (1 eq) was dissolved in o-dichlorobenzene and cooled to about 0 degrees centigrade, and under a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwise to a flask containing the reaction product to finish the reaction, and ethyl alcohol was added to the reaction product to precipitate. The precipitate was filtered to obtain a solid content. The solid content thus obtained was purified by column chromatography using MC and n-hexane and recrystallized using toluene and acetone to obtain Intermediate 138-2 (yield: 14%).

### Synthesis of Compound 138

Intermediate 138-2 (1 eq), potassium ferrocyanide (1 eq), di-tert-butyl(4-dimethylaminophenyl)phosphine (0.1 eq), and sodium carbonate (4 eq) were dissolved in DMF and stirred at about 160 degrees centigrade for about 12 hours. After cooling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Compound 138 (yield: 61%).

### (9) Synthesis of Fused Polycyclic Compound 142

Fused Polycyclic Compound 142 according to one or more embodiments may be synthesized according to, for example, Reaction Scheme 9.

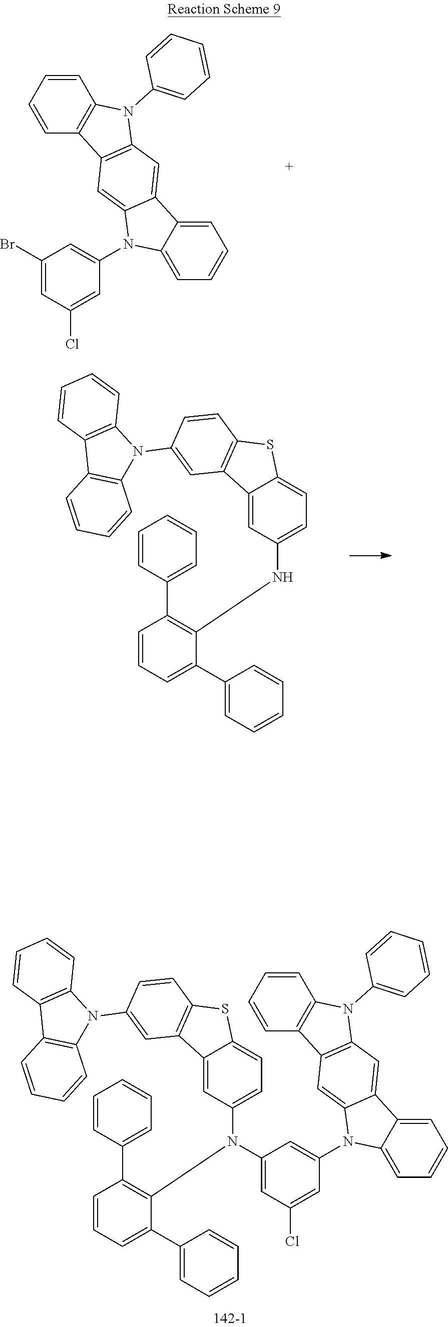

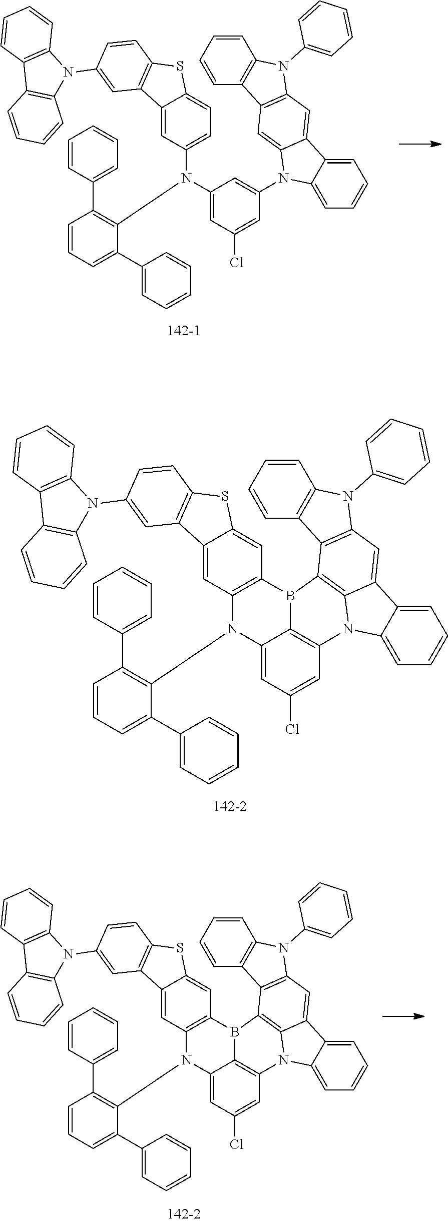 [SMILES: Clc1cc(N(c2ccc3sc4ccc(-n5c6ccccc6c6ccccc65)cc4c3c2)c2c(-c3ccccc3)cccc2-c2ccccc2)cc(-n2c3ccccc3c3cc4c(cc32)c2ccccc2n4-c2ccccc2)c1 ; Clc1cc2c3c(c1)-n1c4ccccc4c4cc5c(c(c41)B3c1cc3sc4ccc(-n6c7ccccc7c7ccccc76)cc4c3cc1N2c1c(-c2ccccc2)cccc1-c1ccccc1)c1ccccc1n5-c1ccccc1 ; Clc1cc2c3c(c1)-n1c4ccccc4c4cc5c(c(c41)B3c1cc3sc4ccc(-n6c7ccccc7c7ccccc76)cc4c3cc1N2c1c(-c2ccccc2)cccc1-c1ccccc1)c1ccccc1n5-c1ccccc1]

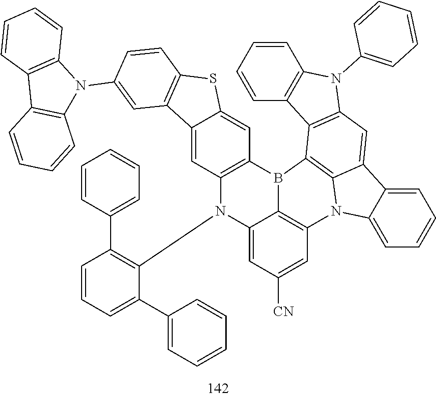 [SMILES: N#Cc1cc2c3c(c1)-n1c4ccccc4c4cc5c(c(c41)B3c1cc3sc4ccc(-n6c7ccccc7c7ccccc76)cc4c3cc1N2c1c(-c2ccccc2)cccc1-c1ccccc1)c1ccccc1n5-c1ccccc1]

### Synthesis of Intermediate 142-1

5-(3-Bromo-5-chlorophenyl)-11-phenyl-5,11-dihydroindolo[3,2-b]carbazole (1 eq), N-([1,1′:3′,1 terphenyl]-2′-yl)-8-(9H-carbazol-9-yl)dibenzo[b,d]thiophen-2-amine (1 eq), tris(dibenzylideneacetone)dipalladium(0) (0.05 eq), tri-tert-butylphosphine (0.1 eq), and sodium tert-butoxide (3 eq) were dissolved in toluene and stirred at about 80 degrees centigrade for about 12 hours. After coaling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Intermediate 142-1 (yield: 75%).

### Synthesis of Intermediate 142-2

Intermediate 142-1 (1 eq) was dissolved in o-dichlorobenzene and cooled to about 0 degrees centigrade, and under a nitrogen atmosphere, BBr₃ (3 eq) was slowly injected thereto. After finishing dropwise addition, the temperature was raised to about 180 degrees centigrade, and stirring was performed for about 48 hours. After cooling the reaction product, triethylamine was slowly added dropwise to a flask containing the reaction product to finish the reaction, and ethyl alcohol was added to the reaction product to precipitate. The precipitate was filtered to obtain a solid content. The solid content thus obtained was purified by column chromatography using MC and n-hexane and recrystallized using toluene and acetone to obtain Intermediate 142-2 (yield: 16%).

### Synthesis of Compound 142

Intermediate 142-2 (1 eq), potassium ferrocyanide (1 eq), di-tert-butyl(4-dimethylaminophenyl)phosphine (0.1 eq), and sodium carbonate (4 eq) were dissolved in DMF and stirred at about 160 degrees centigrade for about 12 hours. After cooling, the reaction product was diluted with ethyl acetate and washed three times with water, and layer separation was performed to obtain an organic layer. The organic layer thus obtained was dried over anhydrous MgSO₄ and then dried under a reduced pressure. The resultant was purified by column chromatography using MC and n-hexane to obtain Compound 142 (yield: 61%).

### 2. Manufacture and Evaluation of Light Emitting Elements

### (1) Manufacture of Light Emitting Elements

Light emitting elements including the Fused Polycyclic Compounds of embodiments or Comparative Compounds in emission layers were each manufactured by a method described herein. Light emitting elements of Examples 1 to 9 were manufactured by respectively using Compounds 7, 41, 46, 91, 106, 120, 126, 138 and 142, which are fused polycyclic compounds of embodiments, as the dopant materials of emission layers. Light emitting elements of Comparative Examples 1 to 7 were manufactured by respectively using Comparative Compounds CX1 to CX7 as the dopant materials of emission layers.

As a first electrode (anode), a glass substrate on which an ITO electrode of about 15 Ω/cm² (1200 Å) was formed (product of Corning Co.) was cut into a size of 50 mm×50 mm×0.7 mm, washed by ultrasonic waves with isopropyl alcohol and then distilled water for about 5 minutes each, and cleaned by irradiating ultraviolet rays for about 30 minutes and then, ozone. After that, the ITO glass substrate was installed in a vacuum deposition apparatus.

On the first electrode, a hole transport layer with a thickness of about 600 Å was formed by vacuum depositing H-1-1. On the hole transport layer, an electron blocking layer with a thickness of about 100 Å was formed by vacuum depositing H-1-20.

On the electron blocking layer, an emission layer with a thickness of about 300 Å was formed by co-depositing a host mixture, a sensitizer, and a dopant in a weight ratio of about 85:14:1. When forming the emission layer, the materials shown in Table 1 were respectively used as the host and the sensitizer, and the host mixture included a hole transporting (HT) host and an electron transporting (ET) host in a weight ratio of about 5:5.

On the emission layer, a hole blocking layer with a thickness of about 50 Å was formed by vacuum depositing ET37, and an electron transport layer with a thickness of about 300 Å was formed by depositing ET38:LiQ (weight ratio of about 5:5). On the electron transport layer, an electron injection layer with a thickness of about 10 Å was formed by depositing LiQ.

On the electron injection layer, Al was vacuum deposited to form a second electrode (cathode) with a thickness of about 1000 Å, to manufacture a light emitting element.

### Materials Used for the Manufacture of Light Emitting Elements

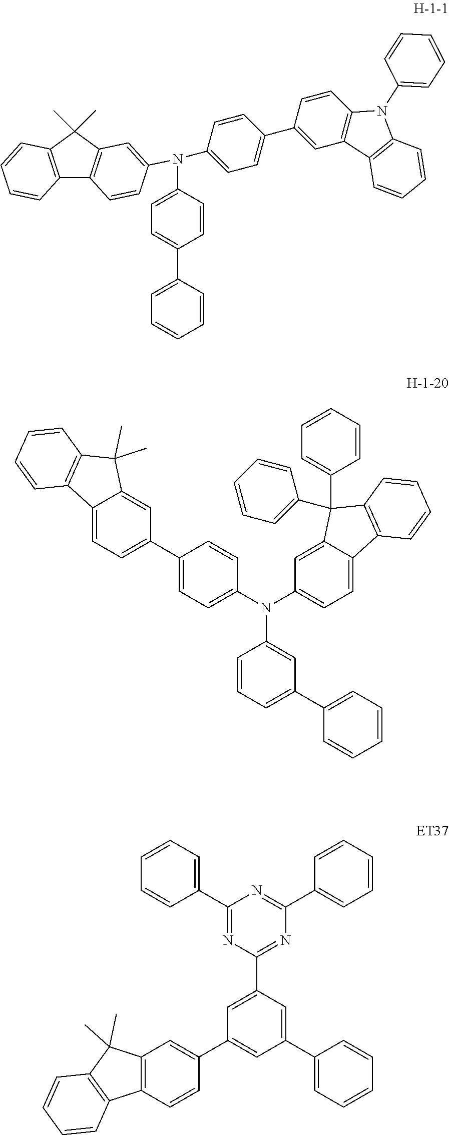 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(-c3ccc(N(c4cccc(-c5ccccc5)c4)c4ccc5c(c4)C(c4ccccc4)(c4ccccc4)c4ccccc4-5)cc3)cc21 ; CC1(C)c2ccccc2-c2ccc(-c3cc(-c4ccccc4)cc(-c4nc(-c5ccccc5)nc(-c5ccccc5)n4)c3)cc21]

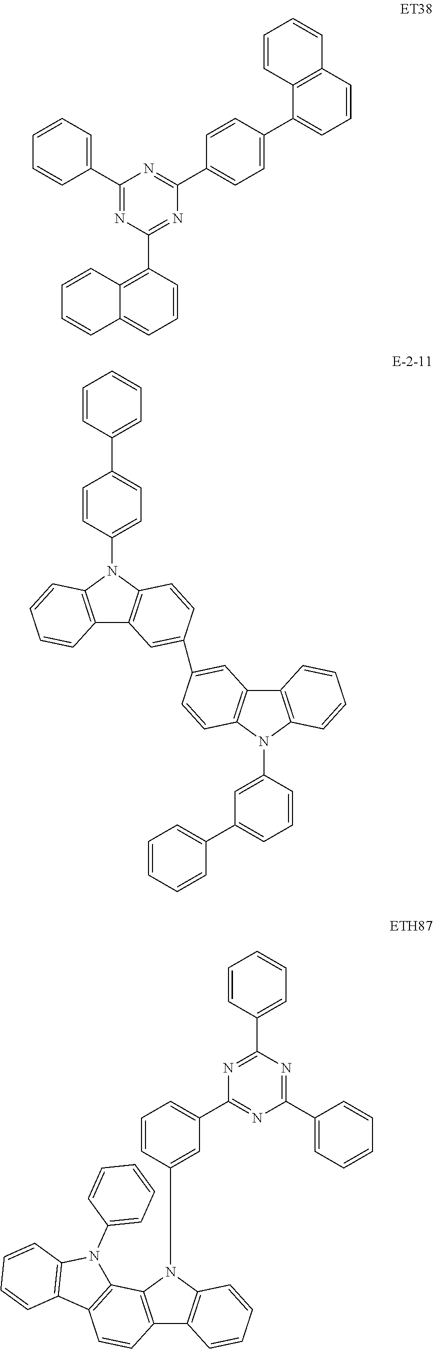

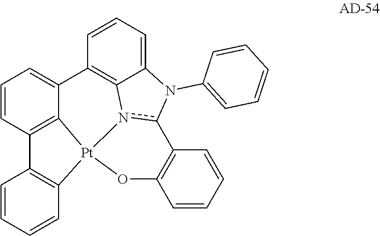

### Example Compounds

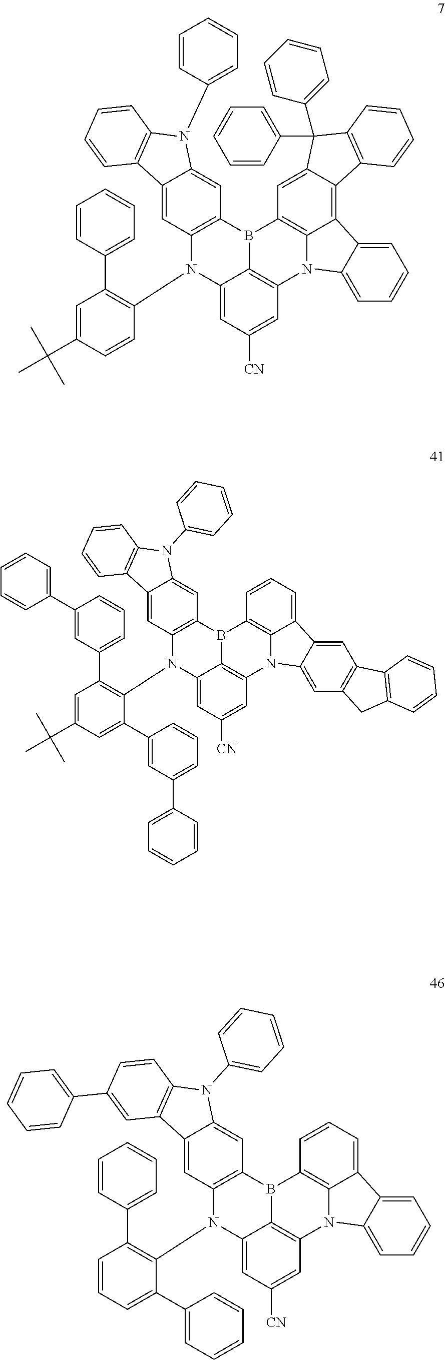 [SMILES: CC(C)(C)c1ccc(N2c3cc4c5ccccc5n(-c5ccccc5)c4cc3B3c4c2cc(C#N)cc4-n2c4ccccc4c4c5c(cc3c42)C(c2ccccc2)(c2ccccc2)c2ccccc2-5)c(-c2ccccc2)c1 ; CC(C)(C)c1cc(-c2cccc(-c3ccccc3)c2)c(N2c3cc4c5ccccc5n(-c5ccccc5)c4cc3B3c4c2cc(C#N)cc4-n2c4cc5c(cc4c4cccc3c42)-c2ccccc2C5)c(-c2cccc(-c3ccccc3)c2)c1 ; N#Cc1cc2c3c(c1)-n1c4ccccc4c4cccc(c41)B3c1cc3c(cc1N2c1c(-c2ccccc2)cccc1-c1ccccc1)c1cc(-c2ccccc2)ccc1n3-c1ccccc1]

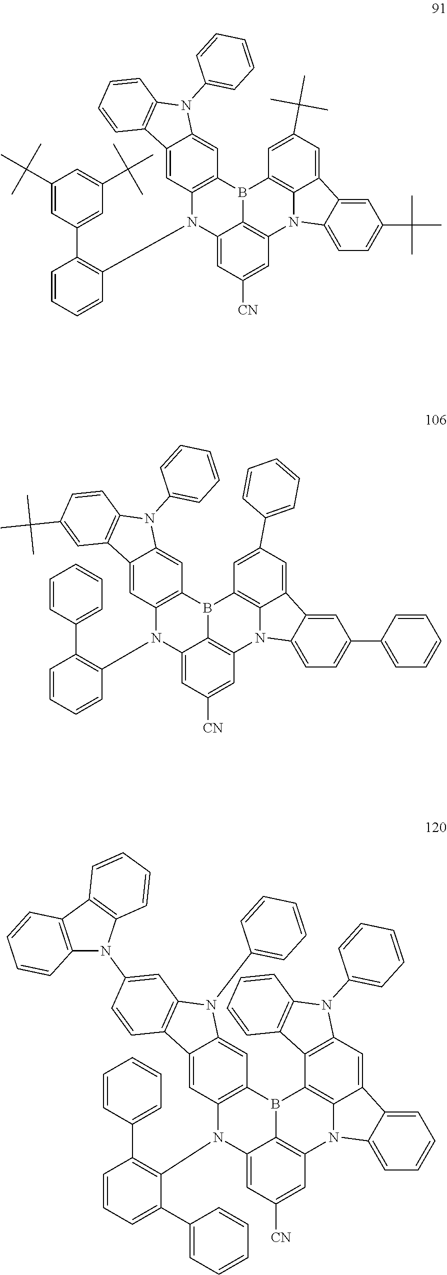

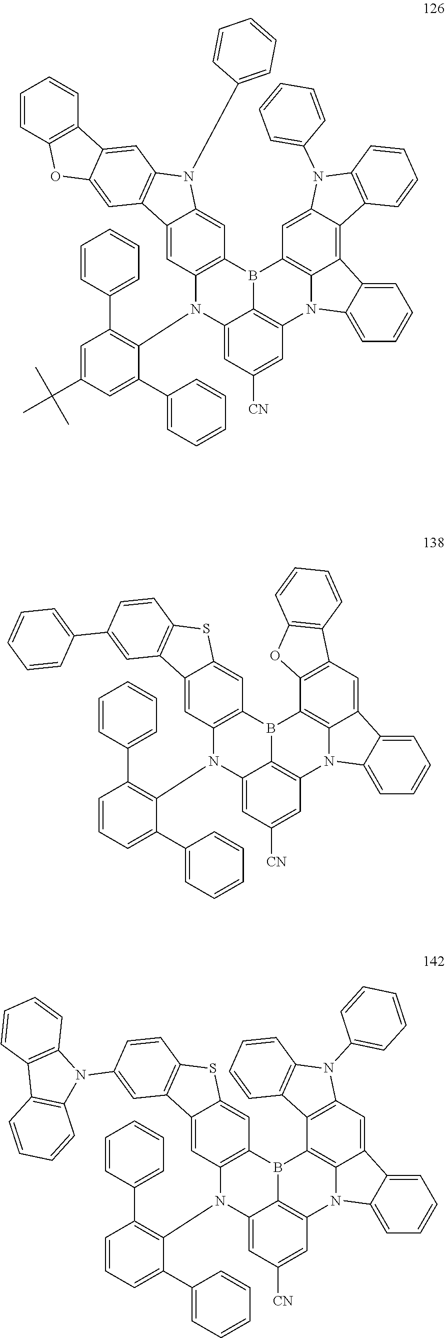 [SMILES: CC(C)(C)c1cc(-c2ccccc2)c(N2c3cc4c5cc6oc7ccccc7c6cc5n(-c5ccccc5)c4cc3B3c4c2cc(C#N)cc4-n2c4ccccc4c4c5c6ccccc6n(-c6ccccc6)c5cc3c42)c(-c2ccccc2)c1 ; N#Cc1cc2c3c(c1)-n1c4ccccc4c4cc5c(oc6ccccc65)c(c41)B3c1cc3sc4ccc(-c5ccccc5)cc4c3cc1N2c1c(-c2ccccc2)cccc1-c1ccccc1 ; N#Cc1cc2c3c(c1)-n1c4ccccc4c4cc5c(c(c41)B3c1cc3sc4ccc(-n6c7ccccc7c7ccccc76)cc4c3cc1N2c1c(-c2ccccc2)cccc1-c1ccccc1)c1ccccc1n5-c1ccccc1]

### Comparative Compounds

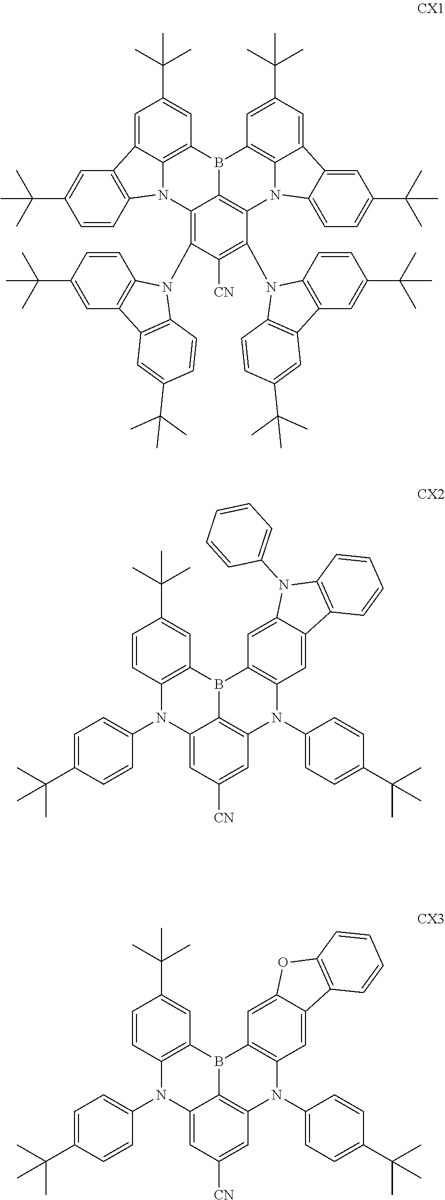

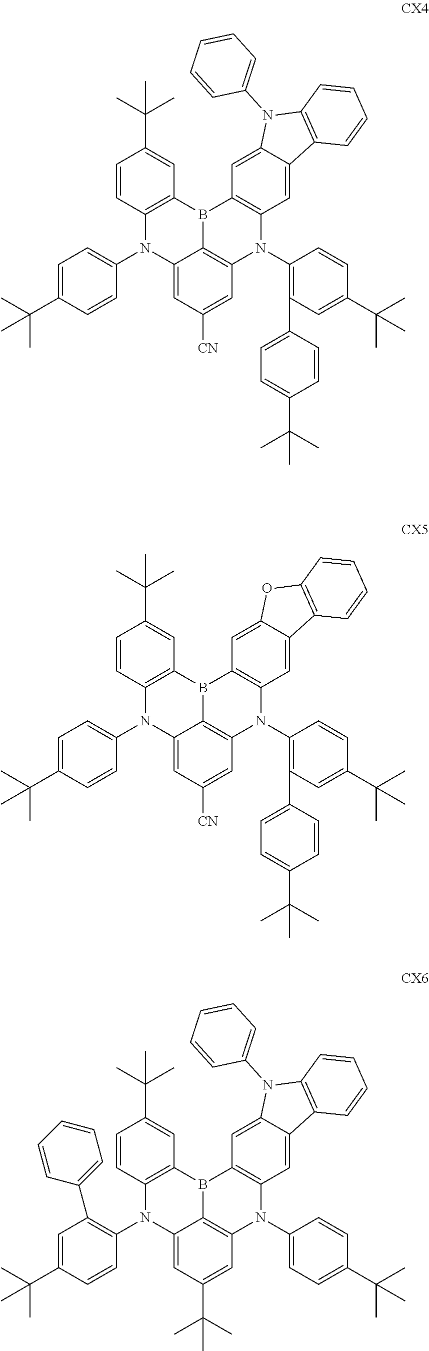

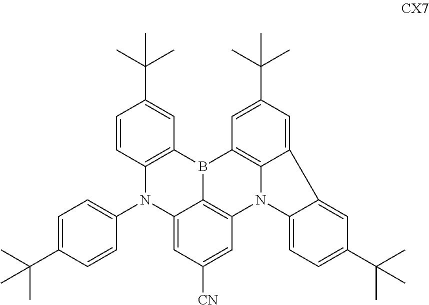 [SMILES: CC(C)(C)c1ccc(N2c3ccc(C(C)(C)C)cc3B3c4c2cc(C#N)cc4-n2c4ccc(C(C)(C)C)cc4c4cc(C(C)(C)C)cc3c42)cc1]

### (2) Evaluation of Light Emitting Elements

In Table 1, the light emitting elements of the Comparative Examples and the Examples are each evaluated and shown. The measurement results on driving voltages at a luminance of about 1000 cd/m², emission efficiency, lifespan and emission color that were measured using Keithley MU 236 and a luminance meter PR650, are shown in Table 1. The lifespan (T95) was obtained by measuring time taken for reducing an initial luminance of 100% to 95% thereof, and calculating relative lifespan based on Comparative Example 1, the driving voltage and emission efficiency of each of the light emitting elements were also each calculated as a relative value based on Comparative Example 1, and the results are shown.

TABLE 1

| | Host | | | Driving | | | |
|---|---|---|---|---|---|---|---|
| | (HT:ET = | | | voltage | Efficiency | Lifespan | Emission |
| | 5:5) | Sensitizer | Dopant | (V) | (cd/A) | (%) | color |
| Example 1 | E-2- | AD-54 | Compound 7 | 96% | 121 | 205% | Green |
| | 11/ETH87 | | | | | | |
| Example 2 | E-2- | AD-54 | Compound 41 | 93% | 142 | 225% | Green |
| | 11/ETH87 | | | | | | |
| Example 3 | E-2- | AD-54 | Compound 46 | 94% | 138 | 214% | Green |
| | 11/ETH87 | | | | | | |
| Example 4 | E-2- | AD-54 | Compound 91 | 94% | 135 | 209% | Green |
| | 11/ETH87 | | | | | | |
| Example 5 | E-2- | AD-54 | Compound 106 | 95% | 129 | 206% | Green |
| | 11/ETH87 | | | | | | |
| Example 6 | E-2- | AD-54 | Compound 120 | 98% | 110 | 194% | Green |
| | 11/ETH87 | | | | | | |
| Example 7 | E-2- | AD-54 | Compound 126 | 98% | 140 | 223% | Green |
| | 11/ETH87 | | | | | | |
| Example 8 | E-2- | AD-54 | Compound 138 | 94% | 139 | 218% | Green |
| | 11/ETH87 | | | | | | |
| Example 9 | E-2- | AD-54 | Compound 142 | 95% | 133 | 210% | Green |
| | 11/ETH87 | | | | | | |
| Comparative | E-2- | AD-54 | Comparative | 100% | 100 | 100% | Green |
| Example 1 | 11/ETH87 | | Compound CX1 | | | | |
| Comparative | E-2- | AD-54 | Comparative | 94% | 89 | 90% | Bluish |
| Example 2 | 11/ETH87 | | Compound CX2 | | | | green |
| Comparative | E-2- | AD-54 | Comparative | 94% | 84 | 86% | Bluish |
| Example 3 | 11/ETH87 | | Compound CX3 | | | | green |
| Comparative | E-2- | AD-54 | Comparative | 95% | 95 | 95% | Bluish |
| Example 4 | 11/ETH87 | | Compound CX4 | | | | green |
| Comparative | E-2- | AD-54 | Comparative | 95% | 90 | 91% | Bluish |
| Example 5 | 11/ETH87 | | Compound CX5 | | | | green |
| Comparative | E-2- | AD-54 | Comparative | 94% | 96 | 97% | Bluish |
| Example 6 | 11/ETH87 | | Compound CX6 | | | | green |
| Comparative | E-2- | AD-54 | Comparative | 95% | 70 | 68% | Bluish |
| Example 7 | 11/ETH87 | | Compound CX7 | | | | green |

Referring to Table 1, it can be found that the light emitting elements of Comparative Example 1 and Examples 1 to 9 each emit green light. It can be found that the light emitting elements of Comparative Examples 2 to 7 each emit bluish green light. Compared to the light emitting elements of Comparative Examples 1 to 7, it can be found that the light emitting elements of Examples 1 to 9 each exhibit excellent or suitable emission efficiency and long-life characteristics. In addition, compared to the light emitting element of Comparative Example 1, the light emitting elements of Examples I to 9 each exhibit a low driving voltage. The light emitting elements of Examples I to 9 include Compounds 7, 41, 46, 91, 106, 120, 126, 138 and 142, respectively, and Compounds 7, 41, 46, 91, 106, 120, 126, 138 and 142 are each the fused polycyclic compound according to one or more embodiments, which includes a biphenyl moiety and a cyano group, bonded to a fused ring with nine rings. The biphenyl moiety is bonded to a nitrogen atom that is a ring-forming atom in the fused ring with nine rings, and the cyano group is bonded at the para position of a benzene ring with respect to a boron atom that is a ring-forming atom in the fused ring with nine rings. Accordingly, it can be found that the fused polycyclic compound of one or more embodiments may improve the efficiency and lifespan of the light emitting element. In addition, it can be found that the fused polycyclic compound of one or more embodiments may reduce the driving voltage of the light emitting element.

The light emitting element of Comparative Example 1 includes Comparative Compound CX1, and Comparative Compound CX1 includes a fused ring with nine rings and a cyano group. The fused ring with nine rings included in Comparative Compound CX1 differs from the fused ring of nine rings included in the fused polycyclic compound of one or more embodiments. In addition, Comparative Compound CX1 differs from the fused polycyclic compound of one or more embodiments in not including a biphenyl moiety. Accordingly, the light emitting element of Comparative Example 1 exhibits relatively low emission efficiency and short lifespan.

The light emitting elements of Comparative Examples 2 and 3 include Comparative Compounds CX2 and CX3, respectively, and Comparative Compounds CX2 and CX3 each include a fused ring with seven rings as a central structure and include a cyano group bonded to the central structure. The fused ring with seven rings included in Comparative Compounds CX2 and CX3 differ from the fused ring with nine rings included in the fused polycyclic compound of one or more embodiments. In addition, Comparative Compounds CX2 and CX3 each differ from the fused polycyclic compound of one or more embodiments in not including a biphenyl moiety. Accordingly, the light emitting elements of Comparative Examples 2 and 3 each exhibit relatively low emission efficiency and short lifespan.

The light emitting elements of Comparative Examples 4 and 5 include Comparative Compounds CX4 and CX5, respectively, and Comparative Compounds CX4 and CX5 each include a fused ring with seven rings as a central structure and include a biphenyl moiety and a cyano group bonded to the central structure. The fused ring with seven rings included in Comparative Compounds CX4 and CX5 differ from the fused ring with nine rings included in the fused polycyclic compound of one or more embodiments. Accordingly, the light emitting elements of Comparative Examples 4 and 5 each exhibit relatively low emission efficiency and short lifespan.

The light emitting element of Comparative Example 6 includes Comparative Compound CX6, and Comparative Compound CX6 includes a fused ring with seven rings as a central structure and include a biphenyl moiety bonded to the central structure. The fused ring with seven rings included in Comparative Compound CX6 differs from the fused ring with nine rings included in the fused polycyclic compound of one or more embodiments. In addition, Comparative Compound CX6 differs from the fused polycyclic compound of one or more embodiments in not including a cyano group. Accordingly, the light emitting element of Comparative Example 6 exhibits relatively low emission efficiency and short lifespan.

The light emitting element of Comparative Example 7 includes Comparative Compound CX7, and Comparative Compound CX7 includes a fused ring with seven rings as a central structure and include a cyano group bonded to the central structure. The fused ring with seven rings included in Comparative Compound CX7 differs from the fused ring with nine rings included in the fused polycyclic compound of one or more embodiments. In addition, Comparative Compound CX7 differs from the fused polycyclic compound of one or more embodiments in not including a biphenyl moiety. Accordingly, the light emitting element of Comparative Example 7 exhibits relatively low emission efficiency and short lifespan.

A display device of one or more embodiments may include a light emitting element of one or more embodiments. The light emitting element of one or more embodiments may include a fused polycyclic compound of one or more embodiments. The fused polycyclic compound of one or more embodiments may include a fused ring with nine rings as a central structure and may include a biphenyl moiety and a cyano group, bonded to the central structure. The fused ring with nine rings may include two nitrogen atoms, one boron atom, and a fused heteroatom. The fused heteroatom may be a nitrogen atom, an oxygen atom, or a sulfur atom. The biphenyl moiety may be bonded to one nitrogen atom among two nitrogen atoms of the central structure, and the cyano group may be bonded at the para position of a benzene ring with respect to the boron atom. In other words, the fused polycyclic compound of one or more embodiments features a central structure with a fused ring consisting of nine rings. This structure includes a biphenyl moiety and a cyano group bonded to it. The fused ring with nine rings incorporates two nitrogen atoms, one boron atom, and a fused heteroatom, which may be a nitrogen, oxygen, or sulfur atom. The biphenyl moiety is attached to one of the nitrogen atoms in the central structure, while the cyano group is positioned at the para position of a benzene ring relative to the boron atom. Consequently, this configuration of the fused polycyclic compound may prevent or reduce intermolecular interactions and demonstrate excellent or suitable material stability. Accordingly, the fused polycyclic compound of one or more embodiments may prevent or reduce intermolecular interaction and may show excellent or suitable material stability. The light emitting element including the fused polycyclic compound of one or more embodiments may show excellent or suitable emission efficiency and long-life characteristics. The display device including the light emitting element of one or more embodiments may show excellent or suitable display quality. In addition, an electronic apparatus including the light emitting element of one or more embodiments may show excellent or suitable reliability.

The light emitting element of one or more embodiments and a display device including the same include the fused polycyclic compound of one or more embodiments and may show high emission efficiency and long-life characteristics.

The fused polycyclic compound of one or more embodiments may contribute to the increase of the emission efficiency and the lifespan of the light emitting element.

As utilized herein, the terms “substantially,” “abut,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

The light emitting element, the display apparatus/device, the electronic apparatus, a device for manufacturing the same, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

Although one or more embodiments of the disclosure have been described, it is understood that the disclosure should not be limited to these embodiments, but one or more suitable changes and modifications can be made by one ordinary skilled in the art within the spirit and scope of disclosure as hereinafter claimed.

Accordingly, the technical scope of the disclosure is not intended to be limited to the contents set forth in the detailed description of the disclosure, but is intended to be defined by the appended claims and equivalents thereof.

What is claimed is:

1. A light emitting element comprising:
a first electrode;
a second electrode on the first electrode; and
an emission layer between the first electrode and the second electrode and comprising a first compound represented by Formula 1: 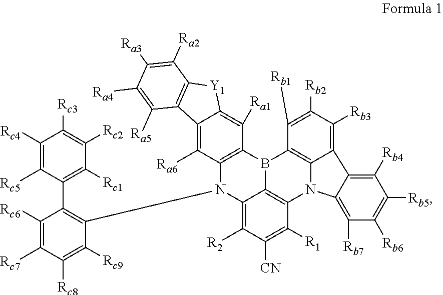
wherein, in Formula 1,
Y₁ is NR₃, O, or S,
R₁ to R₃ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms, and
Rₐ₁ to Rₐ₆, R_{b1} to R_{b7}, and R_{c1} to R_{c9} are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring.

2. The light emitting element of claim 1, wherein the emission layer further comprises at least one selected from among a second compound represented by Formula HT-1, a third compound represented by Formula ET-1, and a fourth compound represented by Formula D-1: 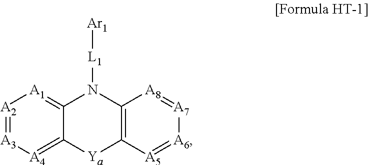
wherein, in Formula HT-1,
A₁ to A₈ are each independently N or CR₅₁,
L₁ is a direct linkage, a substituted or unsubstituted arylene group of 6 to 30 ring-forming carbon atoms, or a substituted or unsubstituted heteroarylene group of 2 to 30 ring-forming carbon atoms,
Yₐ is a direct linkage, CR₅₂R₅₃, or SiR₅₄R₅₅,
Ar₁ is a substituted or unsubstituted aryl group of 6 to 30 ring-forming carbon atoms or a substituted or unsubstituted heteroaryl group of 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group or 2 to 60 ring-forming carbon atoms, and/or combined with an adjacent group to form a ring, 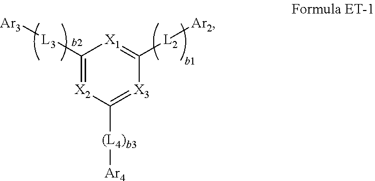
wherein, in Formula ET-1,
at least one selected from among X₁ to X₃ is N, and the remainder are CR₅₆,
R₅₆ is a hydrogen atom, a deuterium atom, a substituted or unsubstituted alkyl group of 1 to 20 carbon atoms, a substituted or unsubstituted aryl group of 6 to 60 ring-forming carbon atoms, or a substituted or unsubstituted heteroaryl group or 2 to 60 ring-forming carbon atoms,
b1 to b3 are each independently an integer of 0 to 10,
Ar₂ to Ar₄ are each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group or 2 to 30 ring-forming carbon atoms, and
L₂ to L₄ are each independently a direct linkage, a substituted or unsubstituted arylene group of 6 to 30 ring-forming carbon atoms, or a substituted or unsubstituted heteroarylene group or 2 to 30 ring-forming carbon atoms, and 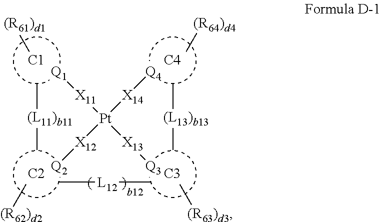
and
wherein, in Formula D-1,
Q₁ to Q₄ are each independently C or N,
C1 to C4 are each independently a substituted or unsubstituted hydrocarbon ring of 5 to 30 ring-forming carbon atoms, a substituted or unsubstituted aryl group of 6 to 30 ring-forming carbon atoms, or a substituted or unsubstituted heterocycle of 2 to 30 ring-forming carbon atoms,
X₁₁ to X₁₄ are each independently a direct linkage or *—O—*,
L₁₁ to L₁₃ are each independently a direct linkage, 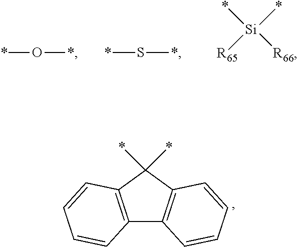
a substituted or unsubstituted alkylene group of 1 to 20 carbon atoms, a substituted or unsubstituted arylene group of 6 to 30 ring-forming carbon atoms, or a substituted or unsubstituted heteroarylene group of 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group of 1 to 20 carbon atoms, a substituted or unsubstituted alkenyl group of 2 to 20 carbon atoms, a substituted or unsubstituted aryl group of 6 to 60 ring-forming carbon atoms, or a substituted or unsubstituted heteroaryl group of 2 to 60 ring-forming carbon atoms, and
d1 to d4 are each independently an integer of 0 to 4.

3. The light emitting element of claim 1, wherein the first compound represented by Formula 1 is represented by any one selected from among Formula 1-1 to Formula 1-3: 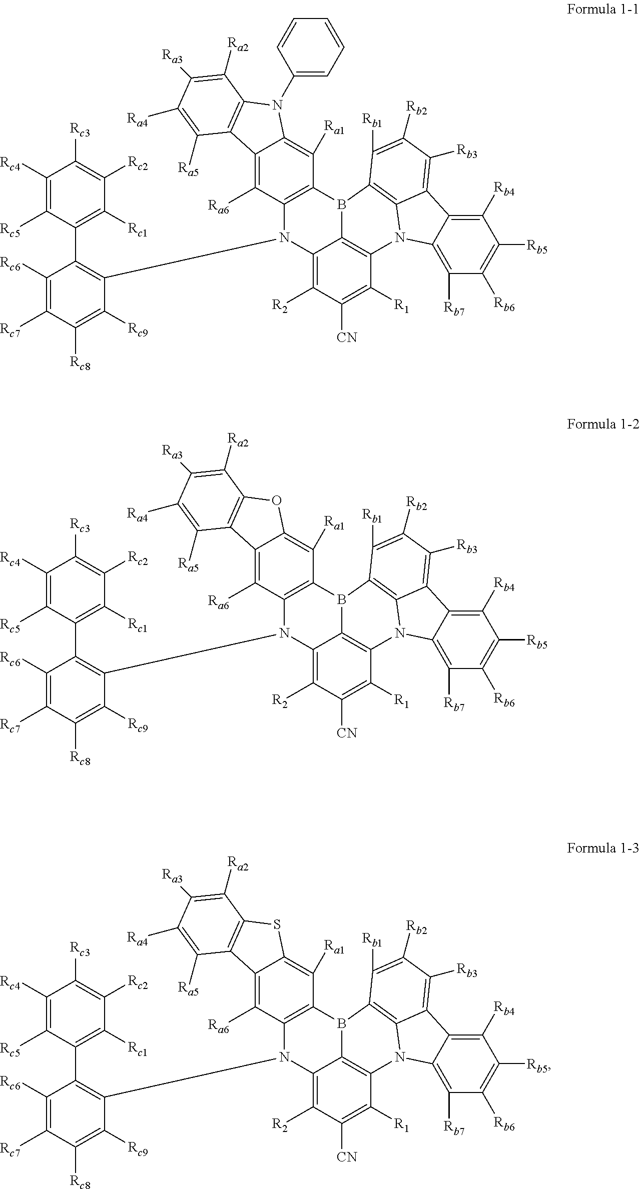
in Formula 1-1 to Formula 1-3,
R₁, R₂, Rₐ₁ to Rₐ₆, R_{b1} to R_{b7}, and R_{c1} to R_{c9} being the same as defined in Formula 1.

4. The light emitting element of claim 1, wherein the first compound represented by Formula 1 is represented by any one selected from among Formula 1-A1 to Formula 1-A3: 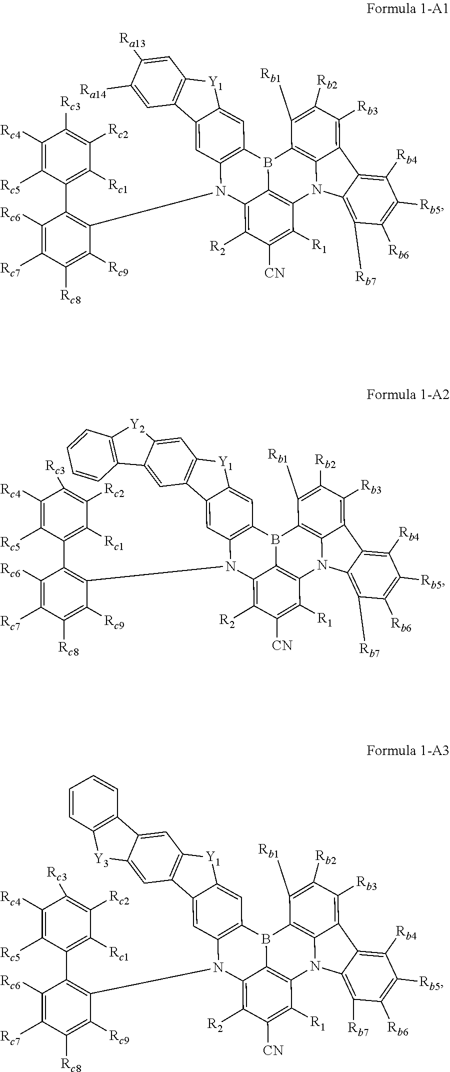
in Formula 1-A1,
Rₐ₁₃ and Rₐ₁₄ being each independently a hydrogen atom, a deuterium atom, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, and
in Formula 1-A2 and Formula 1-A3,
Y₂ and Y₃ being each independently CR₄R₅, O, or S,
R₄ and R₅ being each independently a hydrogen atom, a deuterium atom, a substituted or unsubstituted alkyl group of 1 to 30 carbon atoms, or a substituted or unsubstituted aryl group of 6 to 30 ring-forming carbon atoms, and
in Formula 1-A1 to Formula 1-A3, Y₁, R₁, R₂, R_{b1} to R_{b7}, and R_{c1} to R_{c9} being the same as defined in Formula 1.

5. The light emitting element of claim 1, wherein the first compound represented by Formula 1 is represented by any one selected from among Formula 1-B1 to Formula 1-B8: 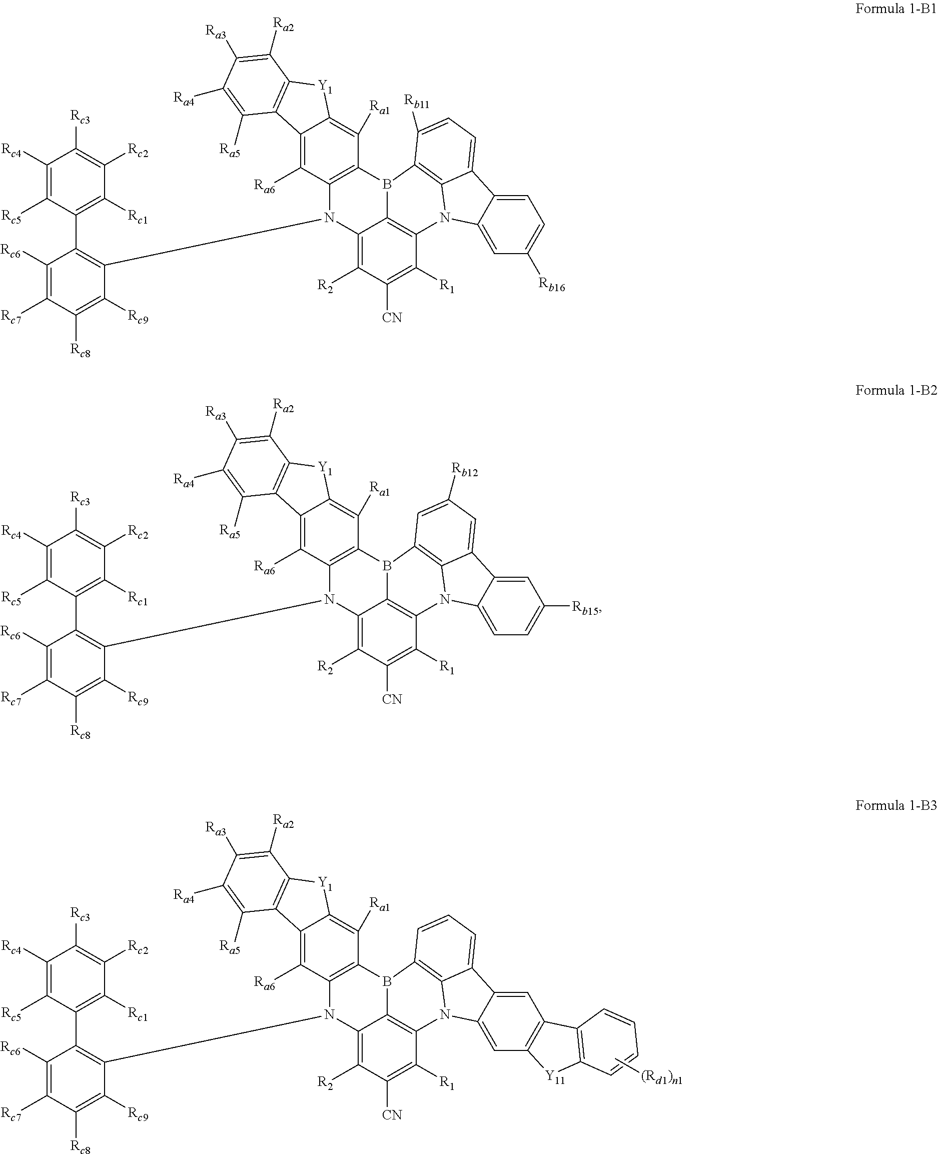 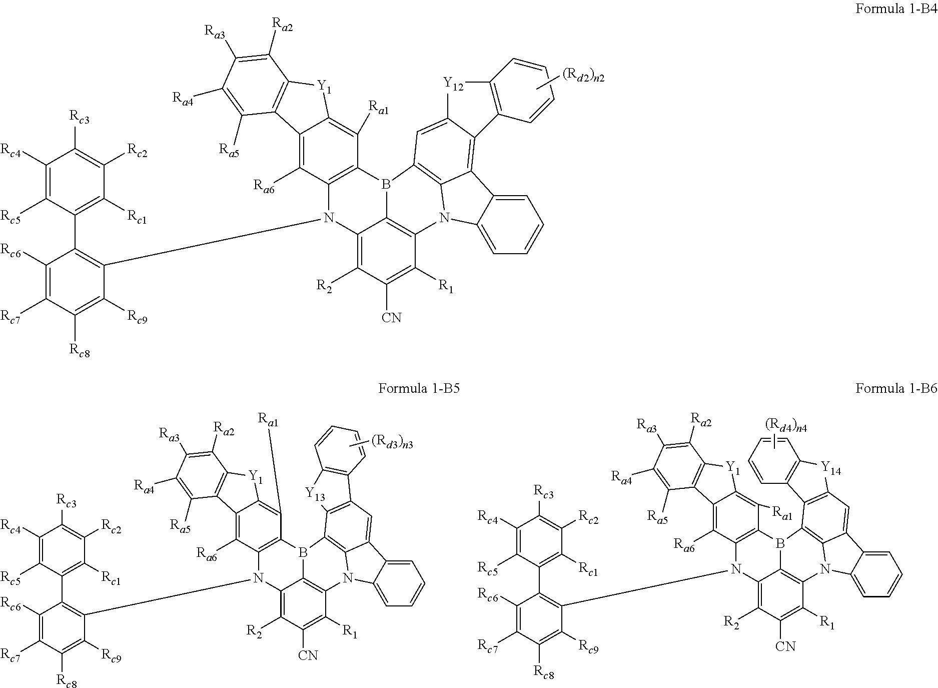 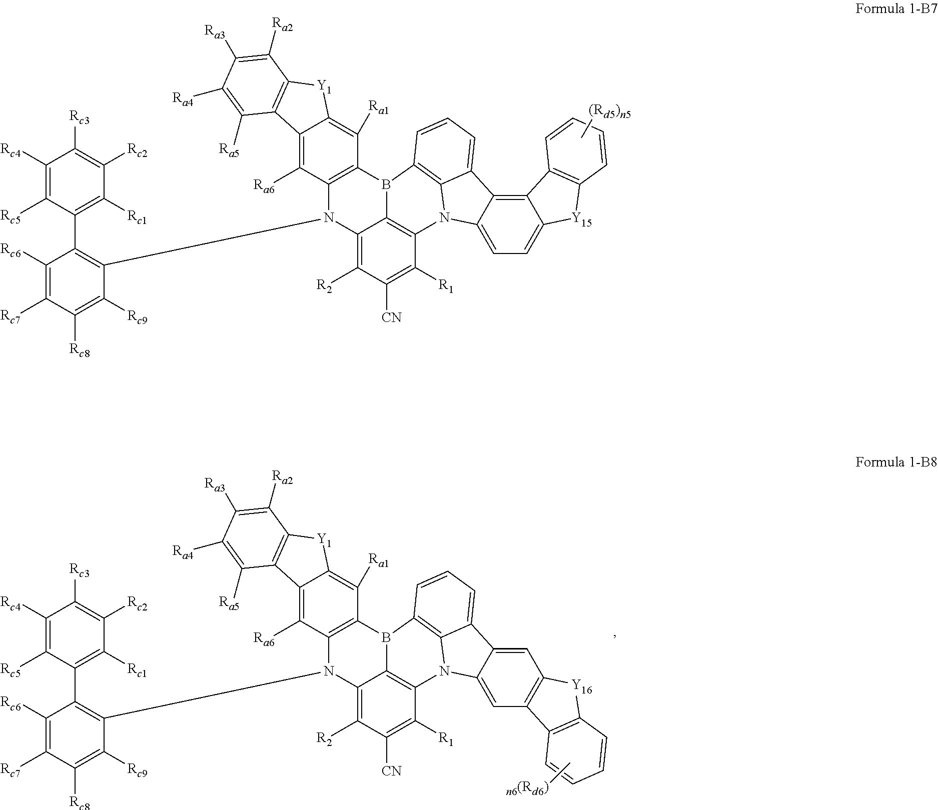
in Formula 1-B1 and Formula 1-B2,
R_{b11}, R_{b12}, R_{b15}, and R_{b16} being each independently a hydrogen atom, a deuterium atom, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms, and
in Formula 1-B3 to Formula 1-B8,
Y₁₁ to Y₁₆ being each independently CR₁₁R₁₂, NR₁₃, O, or S,
n1 to n6 being each independently an integer of 0 to 4,
R₁₁ to R₁₃ and R_{d1} to R_{d6} being each independently a hydrogen atom, a deuterium atom, or a substituted or unsubstituted aryl group of 6 to 60 ring-forming carbon atoms, and
in Formula 1-B1 to Formula 1-B8, Y₁, R₁, R₂, Rₐ₁ to Rₐ₆, and R_{c1} to R_{c9} being the same as defined in Formula 1.

6. The light emitting element of claim 1, wherein,
in Formula 1, at least one selected from among R_{b1} to R_{b7} is combined with an adjacent group to form a fused ring, and
the fused ring is a substituted or unsubstituted aryl group of 6 to 30 ring-forming carbon atoms or a substituted or unsubstituted heteroaryl group comprising N, O, or S as a ring-forming atom and having 2 to 30 ring-forming carbon atoms.

7. The light emitting element of claim 1, wherein, in Formula 1, a biphenyl moiety comprising R_{c1} to R_{c9} is represented by any one selected from among RC-1 to RC-18:

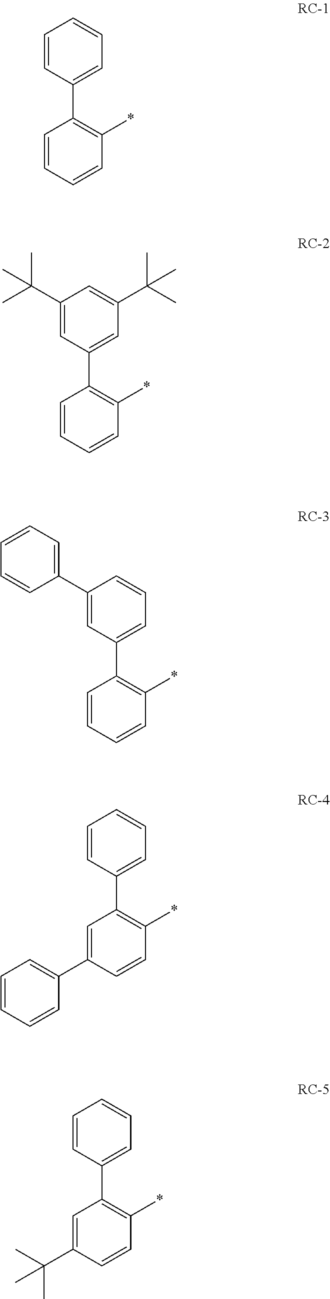

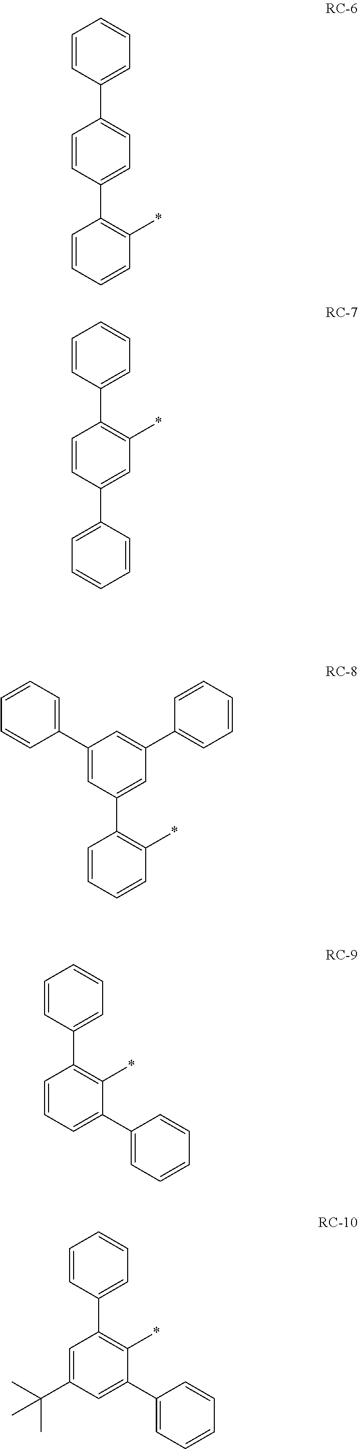

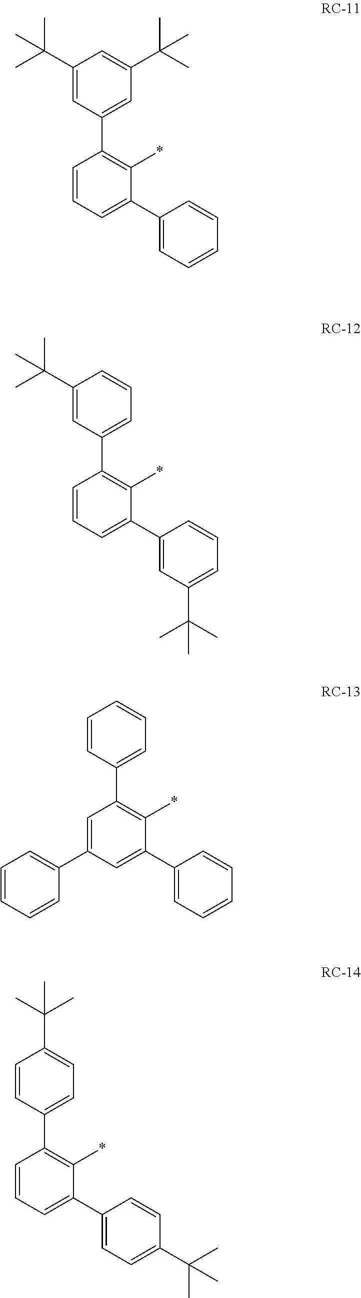 [SMILES: *c1c(-c2ccccc2)cccc1-c1cc(C(C)(C)C)cc(C(C)(C)C)c1 ; *c1c(-c2cccc(C(C)(C)C)c2)cccc1-c1cccc(C(C)(C)C)c1 ; *c1c(-c2ccccc2)cc(-c2ccccc2)cc1-c1ccccc1 ; *c1c(-c2ccc(C(C)(C)C)cc2)cccc1-c1ccc(C(C)(C)C)cc1]

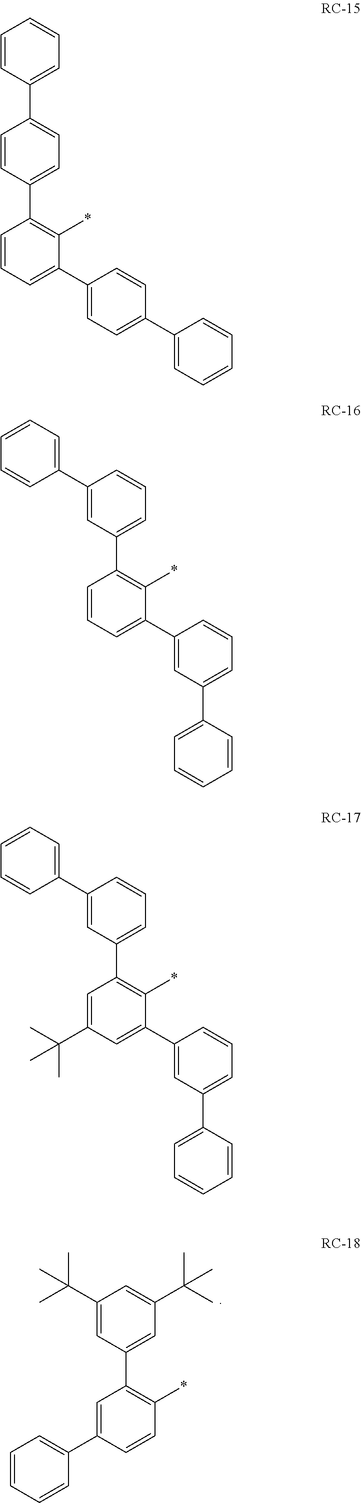 [SMILES: *c1c(-c2ccc(-c3ccccc3)cc2)cccc1-c1ccc(-c2ccccc2)cc1 ; *c1c(-c2cccc(-c3ccccc3)c2)cccc1-c1cccc(-c2ccccc2)c1 ; *c1c(-c2cccc(-c3ccccc3)c2)cc(C(C)(C)C)cc1-c1cccc(-c2ccccc2)c1 ; *c1ccc(-c2ccccc2)cc1-c1cc(C(C)(C)C)cc(C(C)(C)C)c1]

8. The light emitting element of claim 1, wherein, in Formula 1, R_{c1} to R_{c9} are each independently a hydrogen atom, a deuterium atom, a substituted or unsubstituted t-butyl group, a substituted or unsubstituted phenyl group, or a substituted or unsubstituted biphenyl group.

9. The light emitting element of claim 1, wherein the first compound is any one selected from among compounds in Compound Group 1:

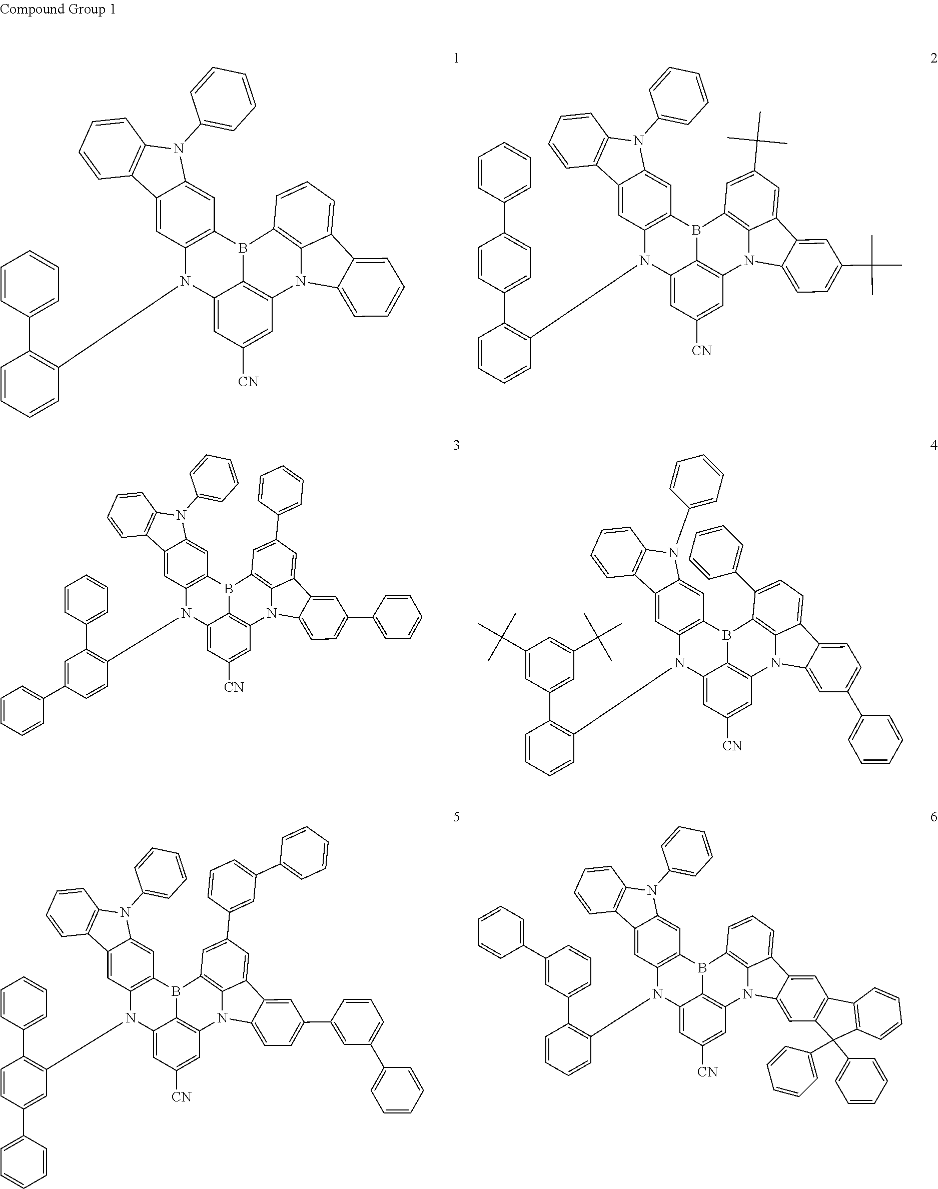

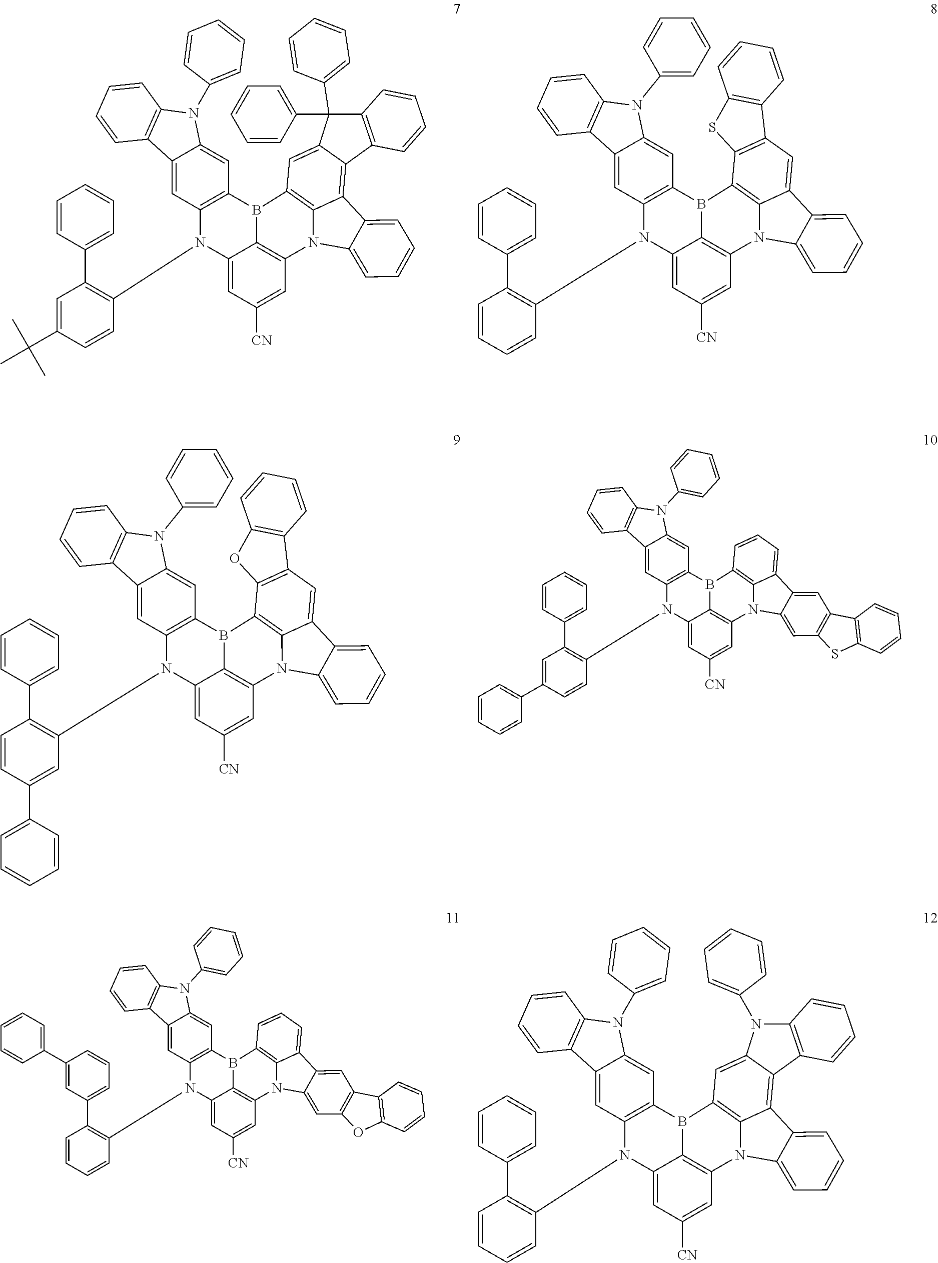

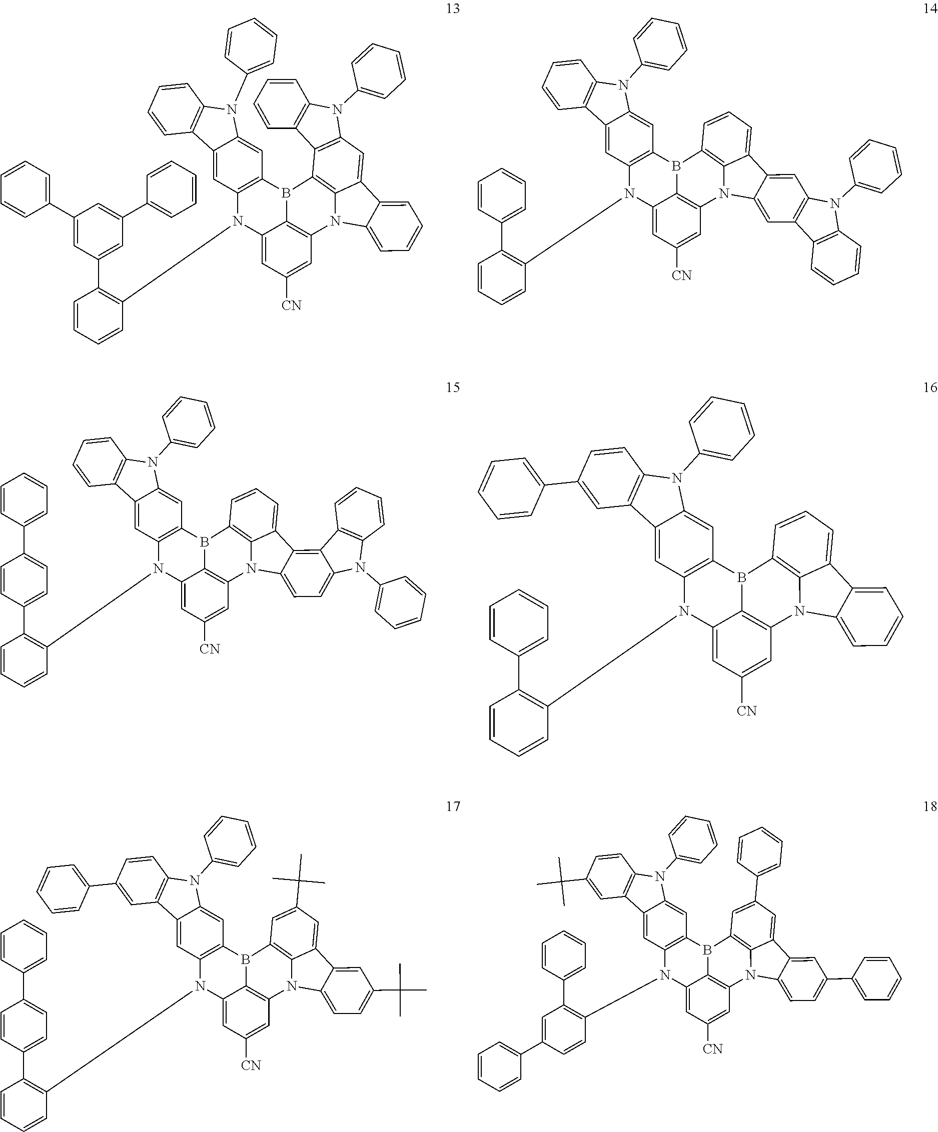

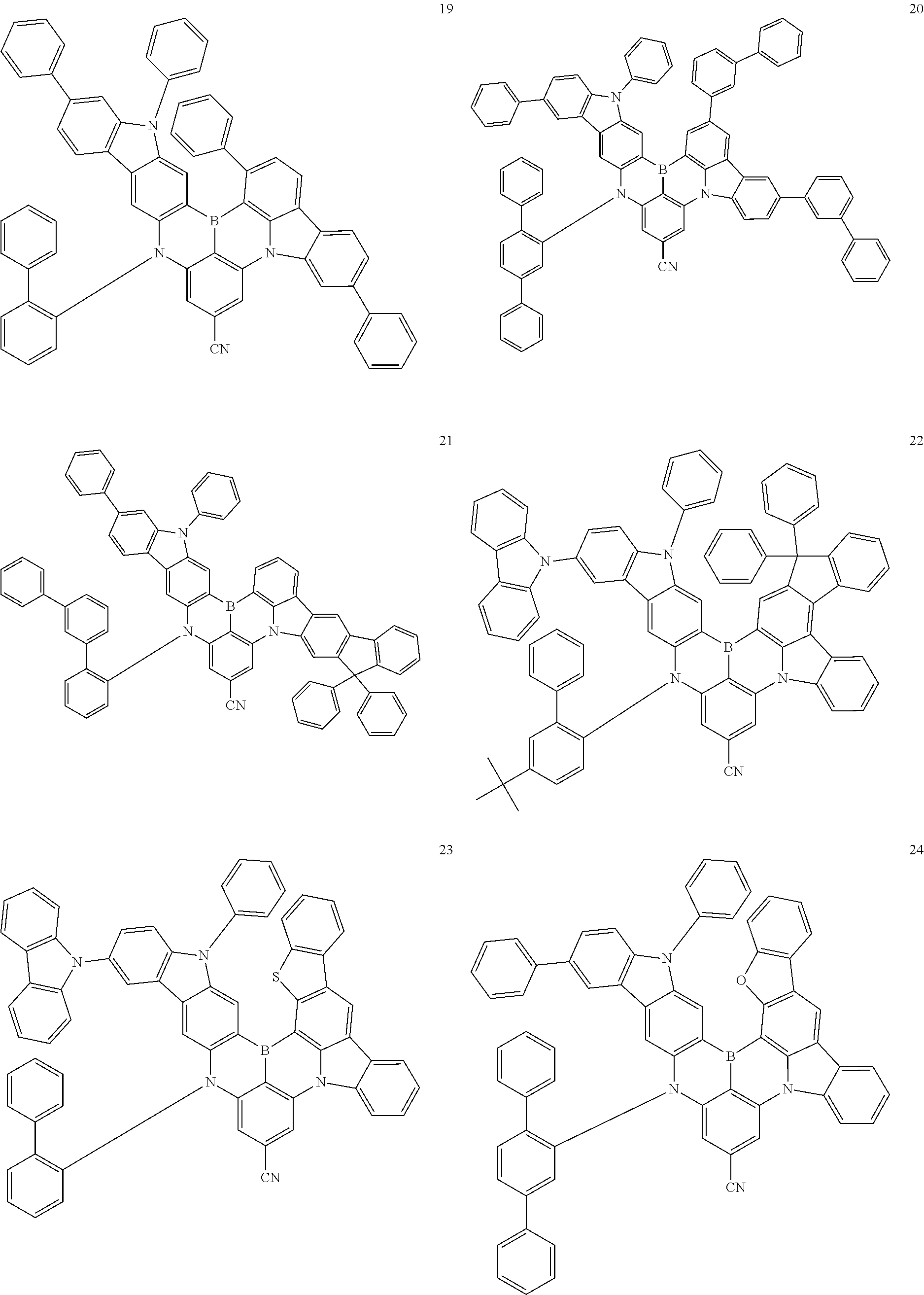

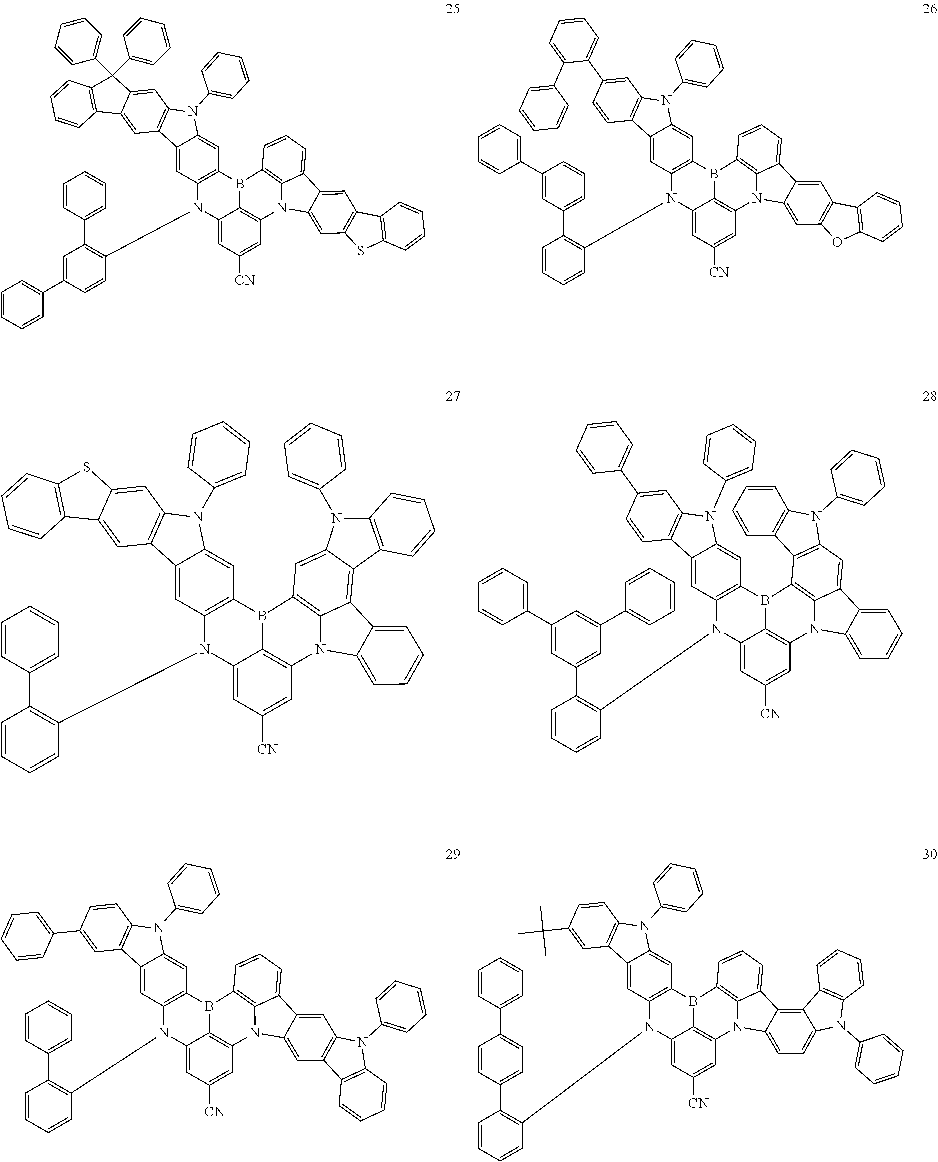

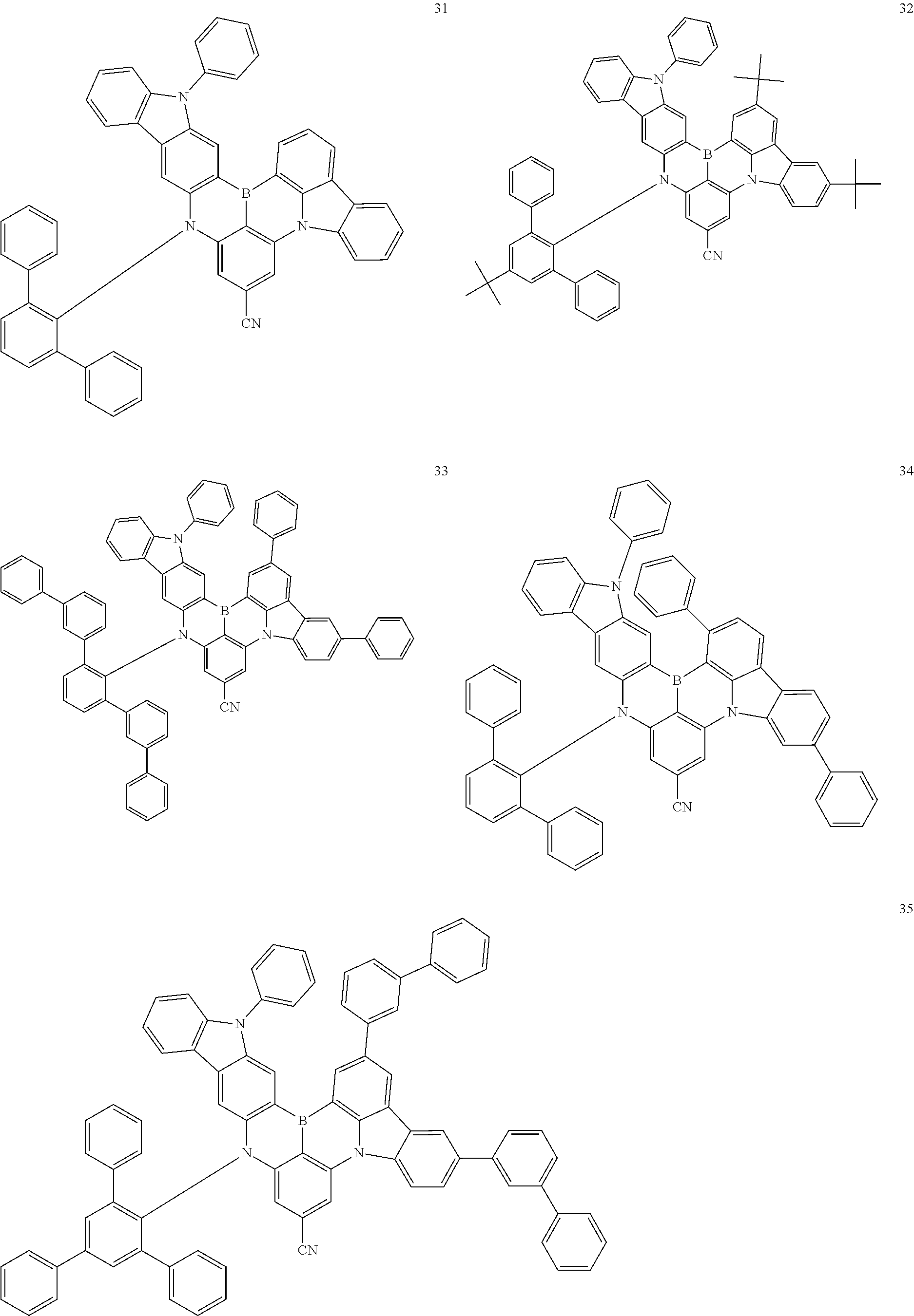

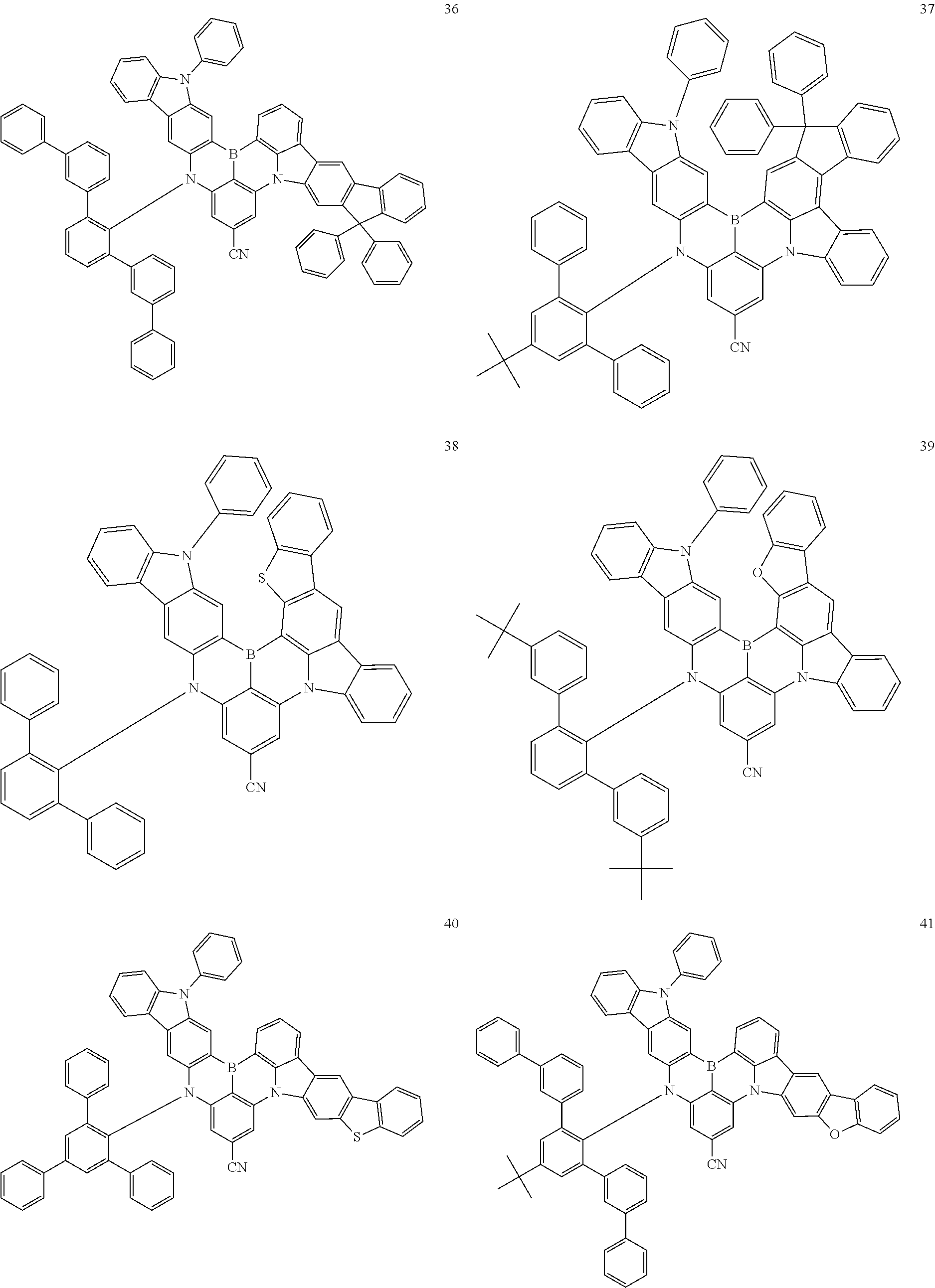

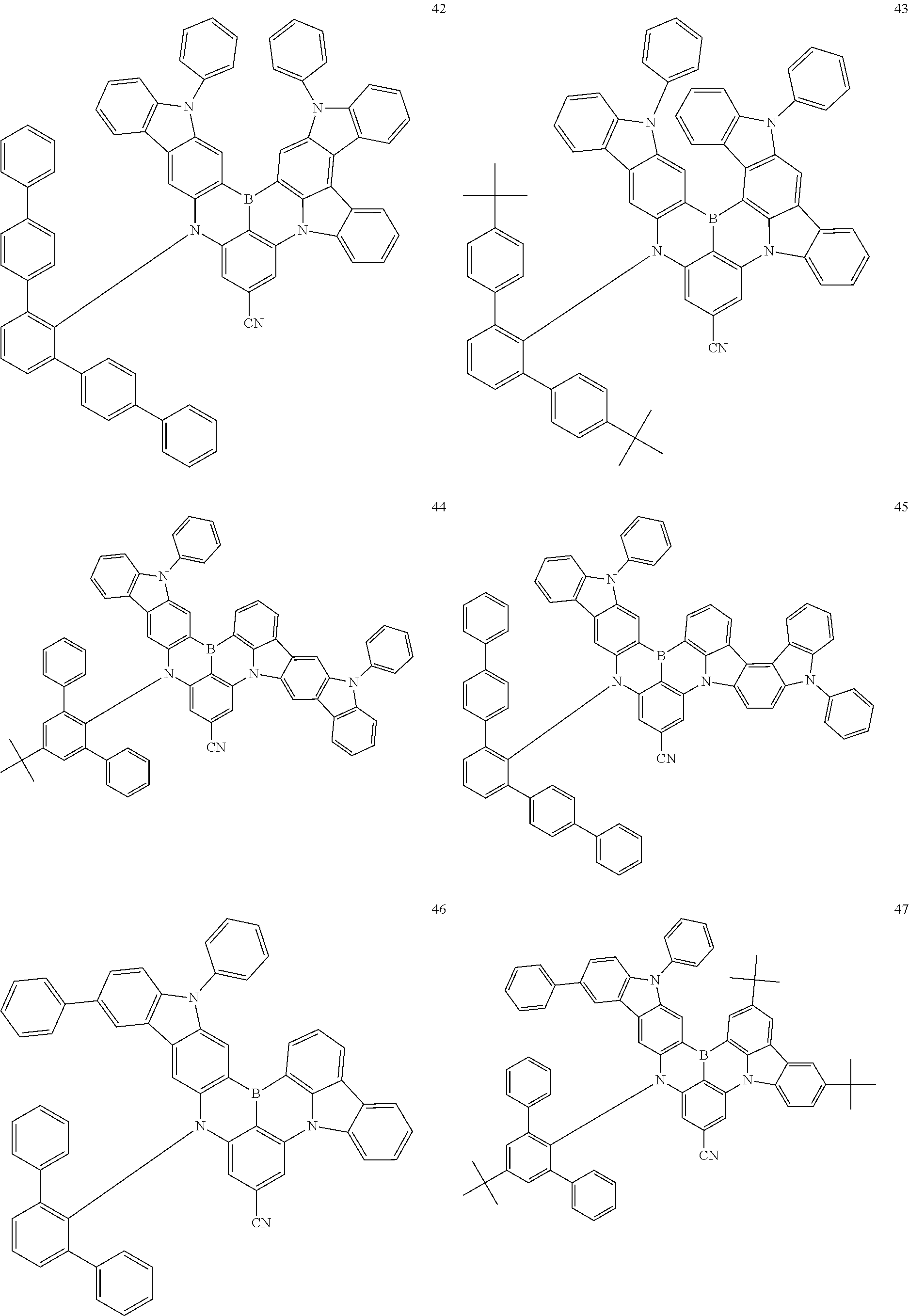

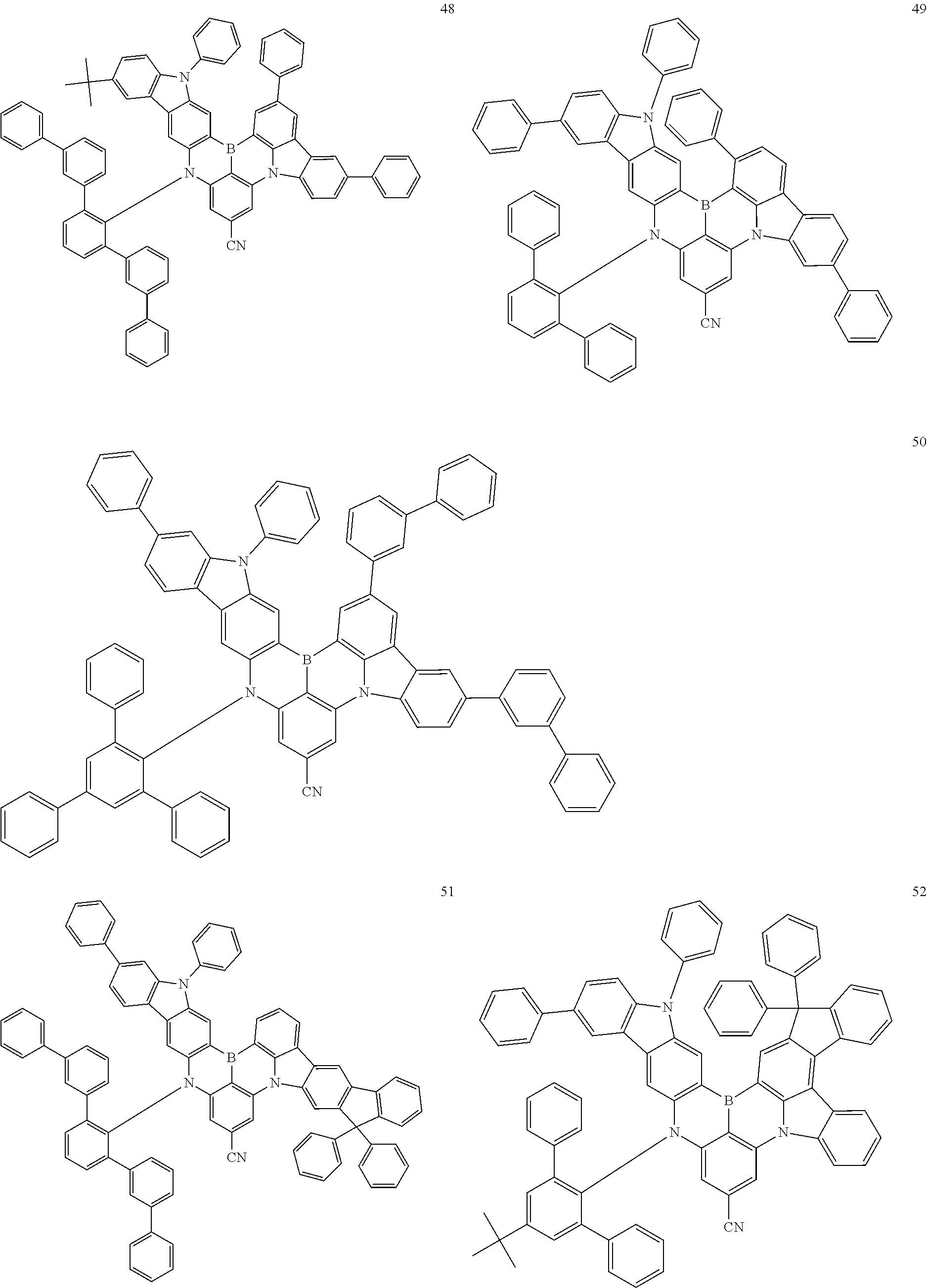

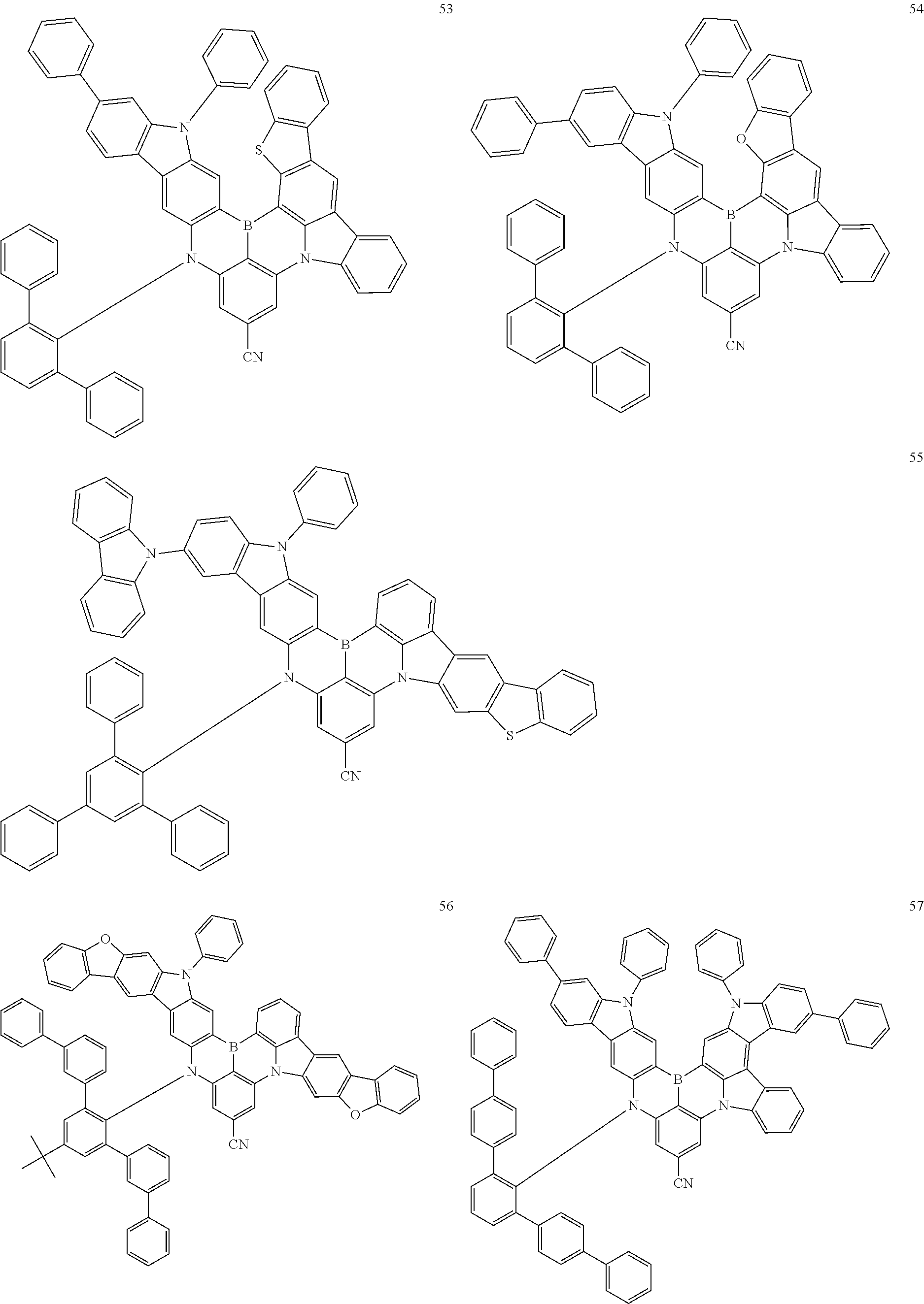

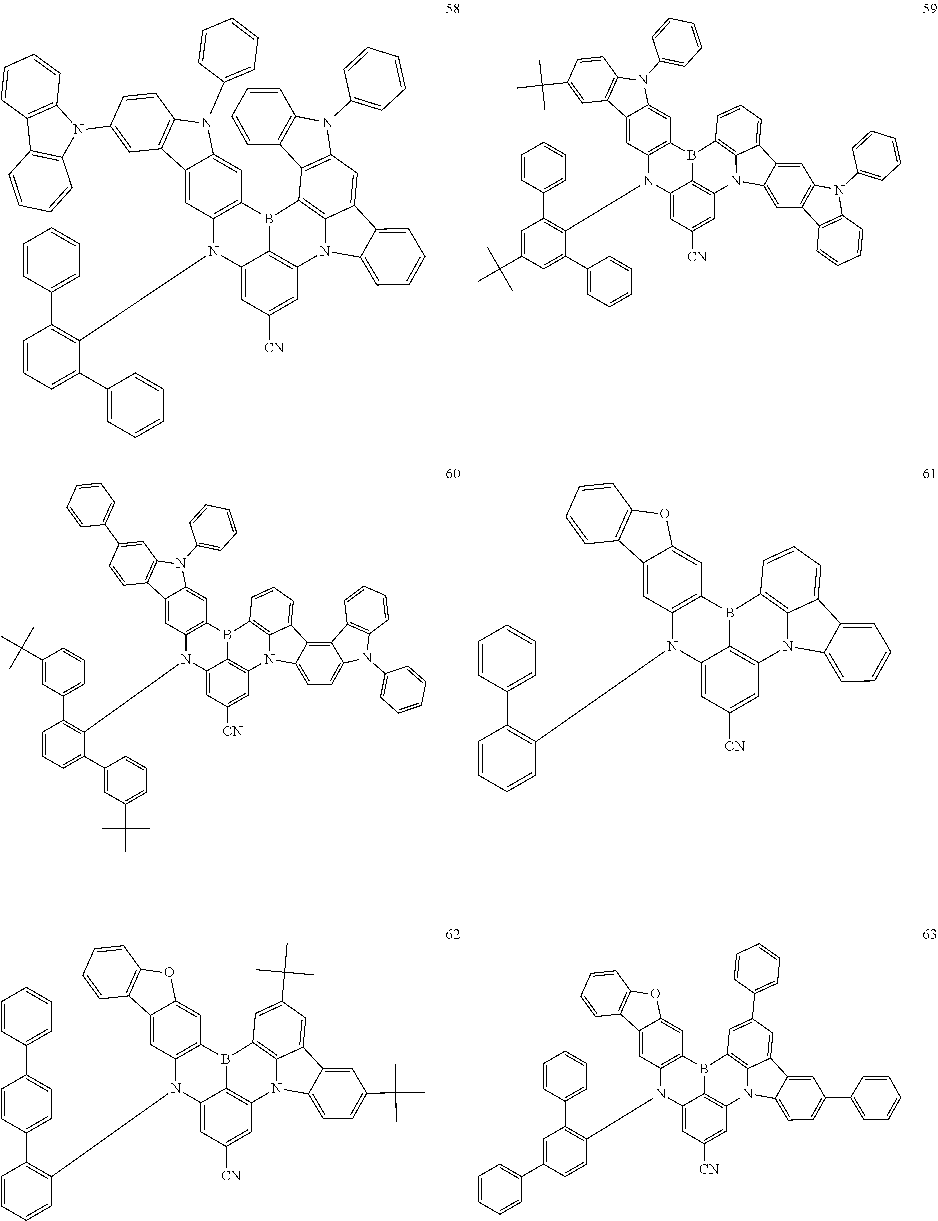

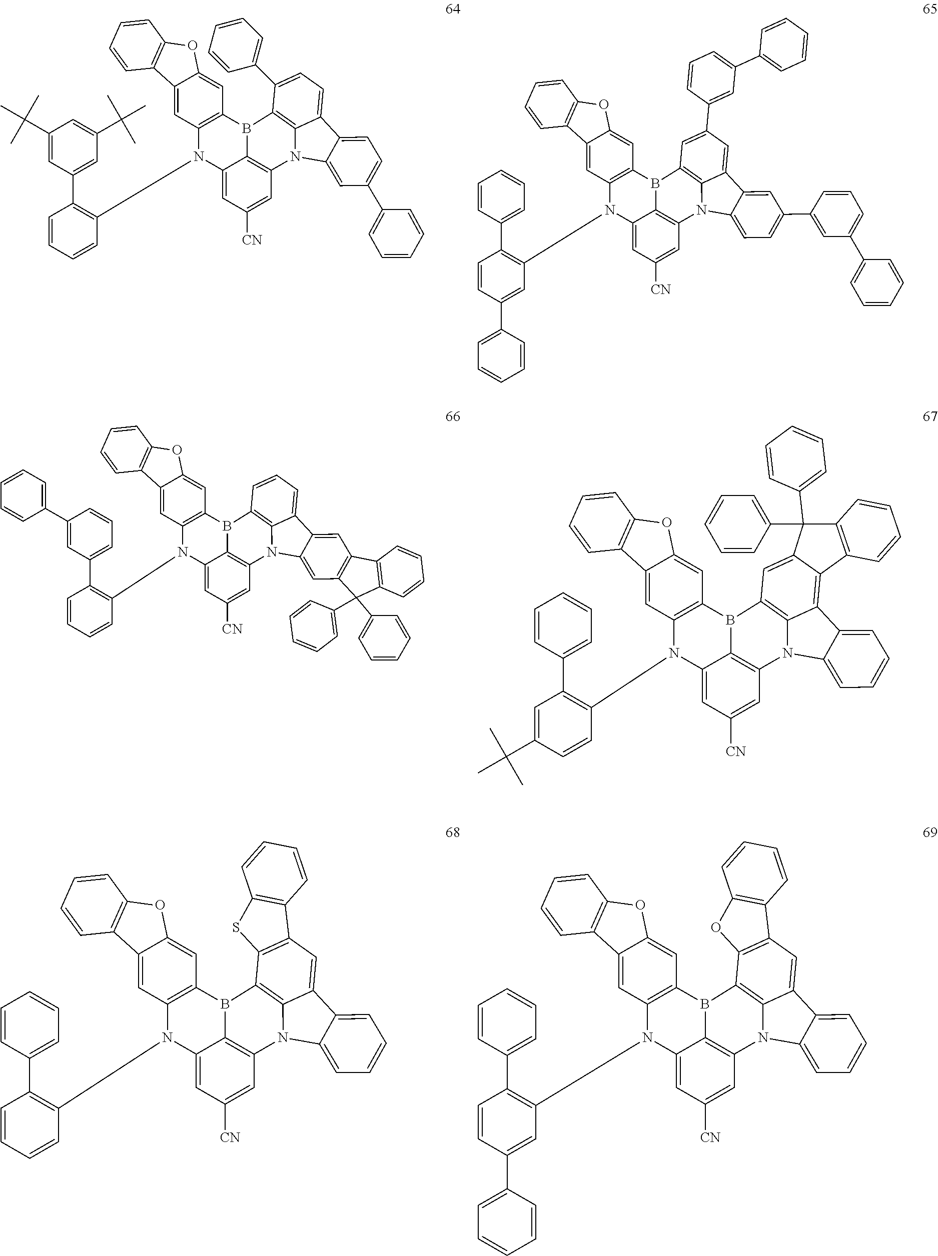

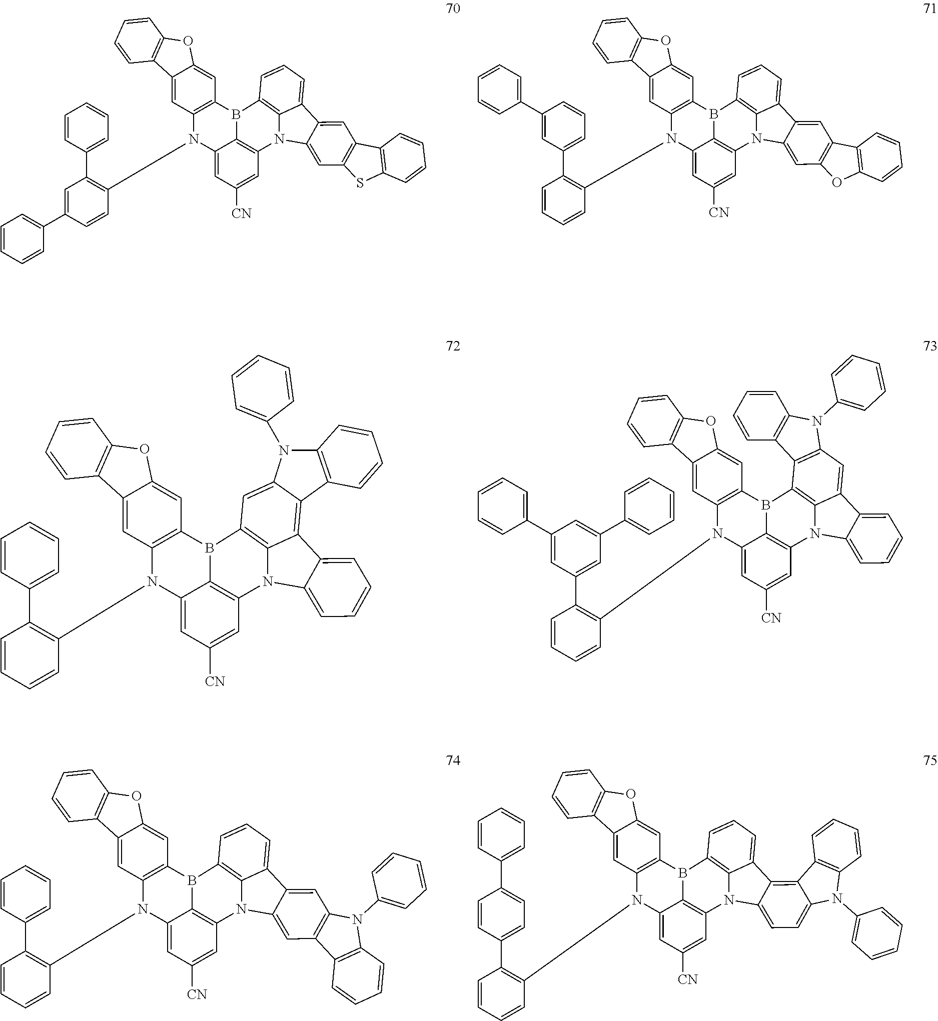

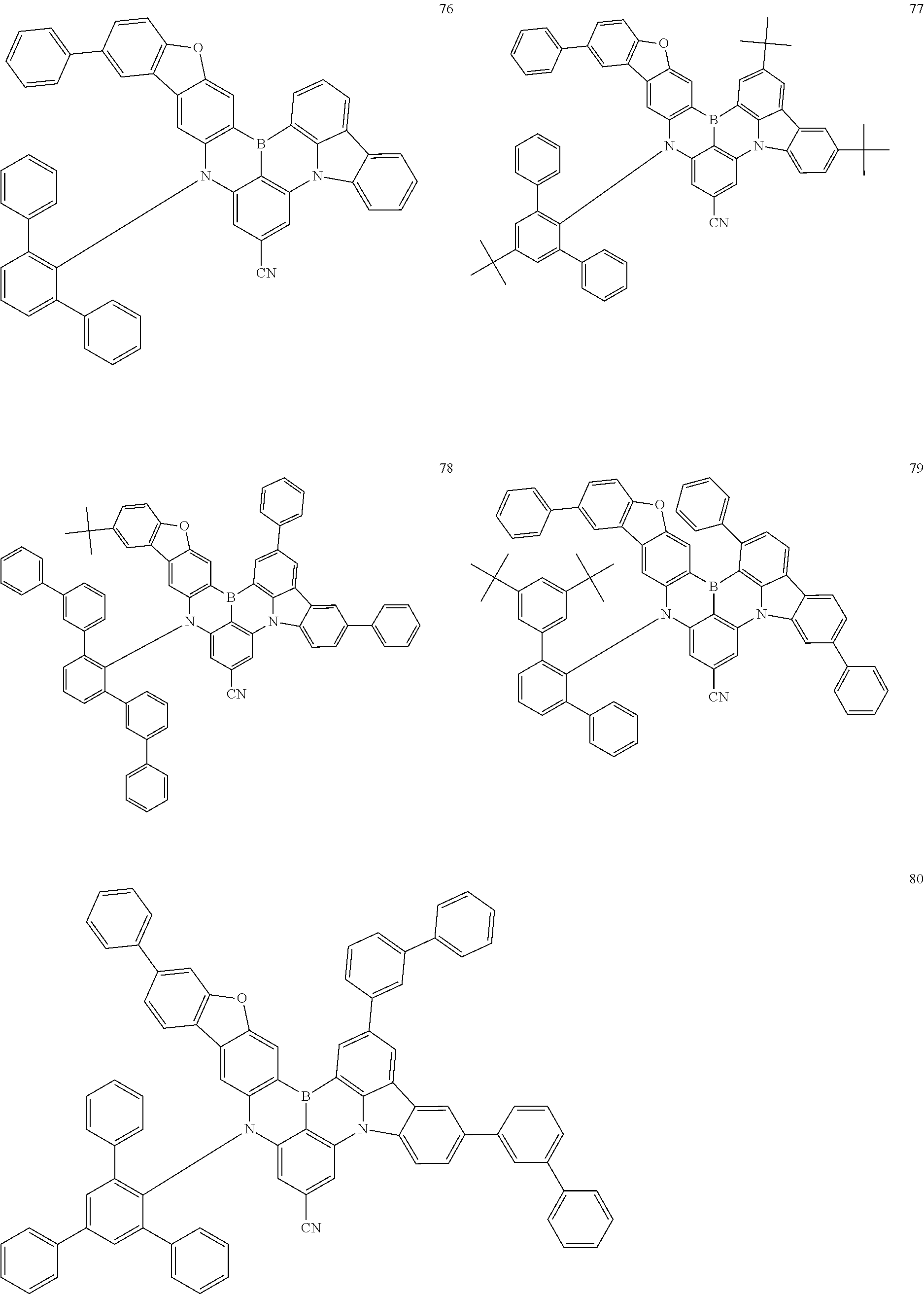

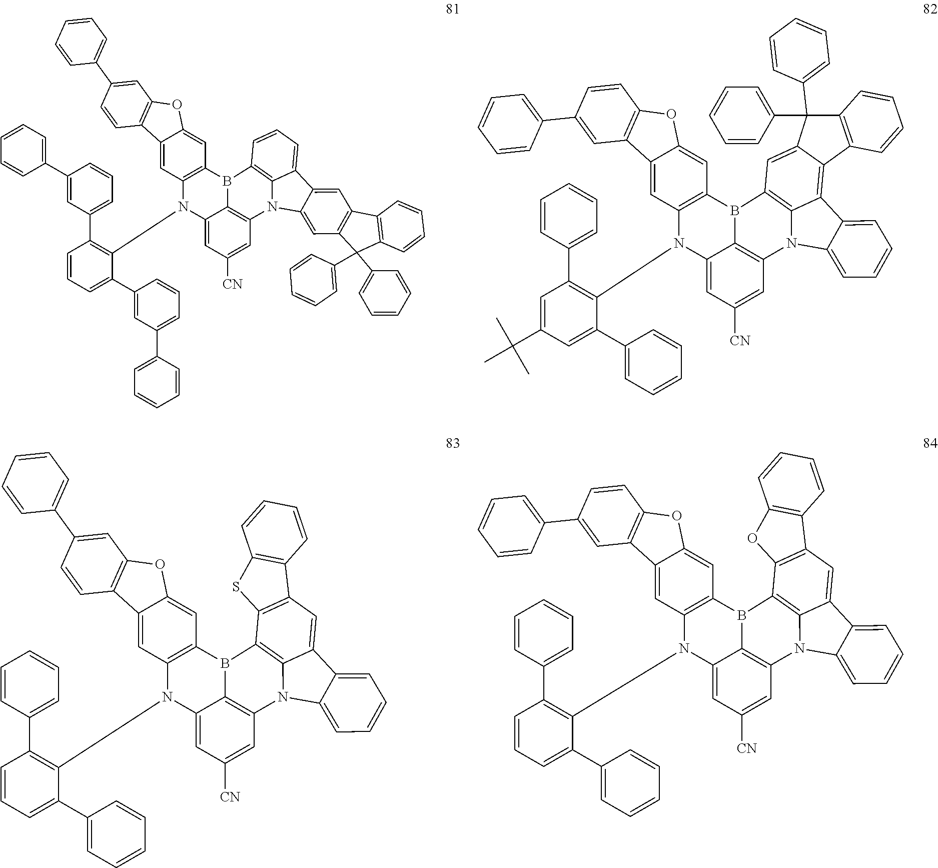

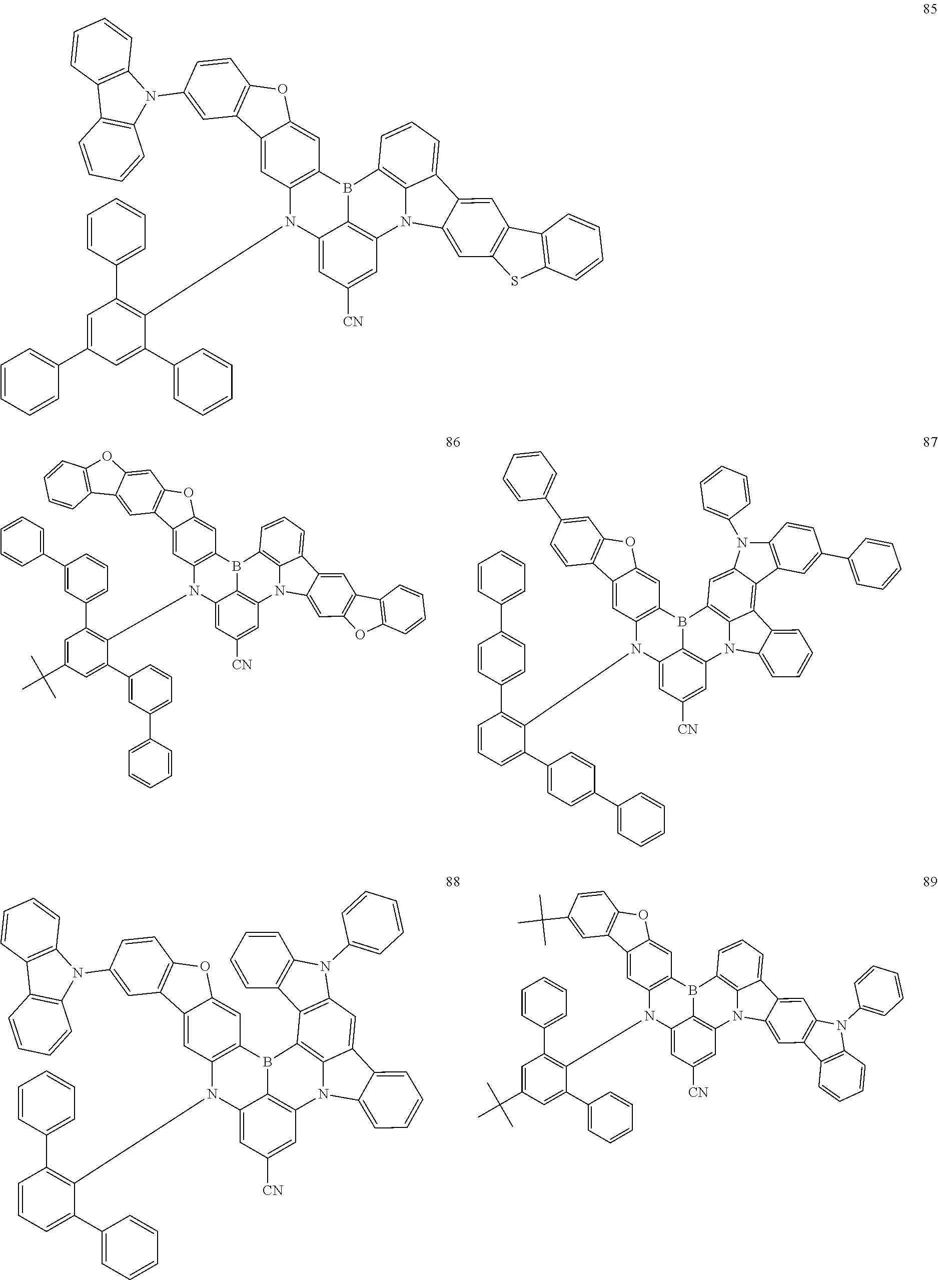

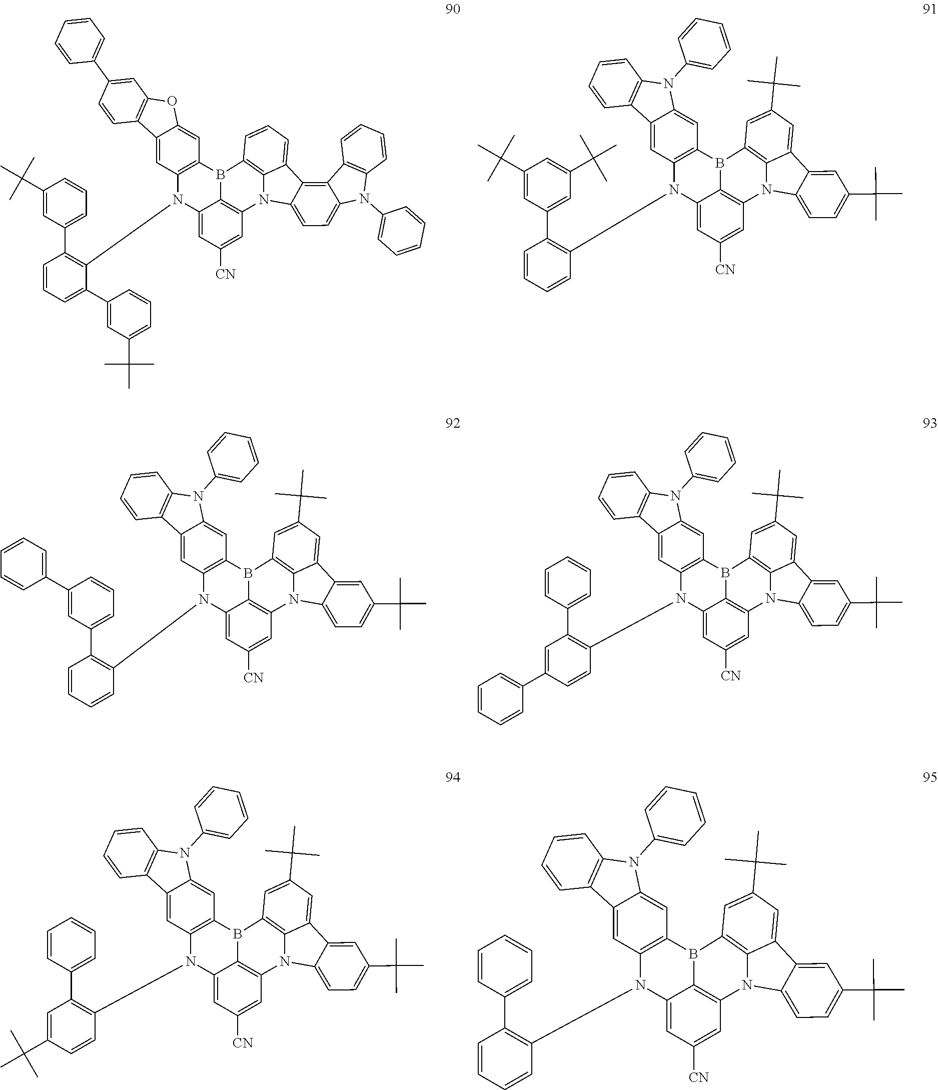

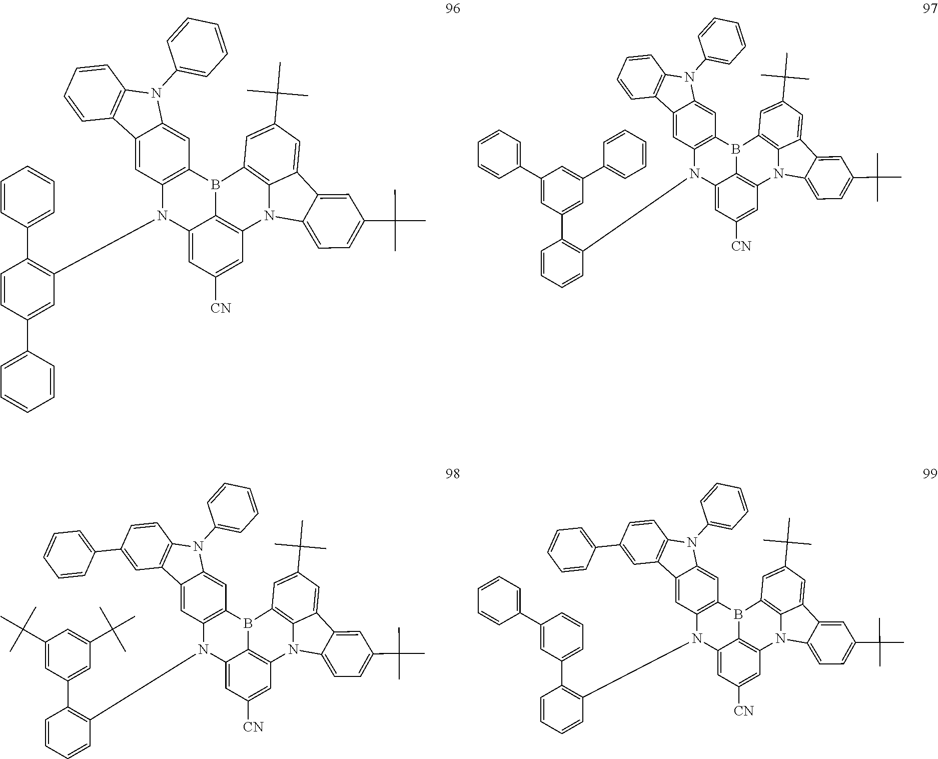

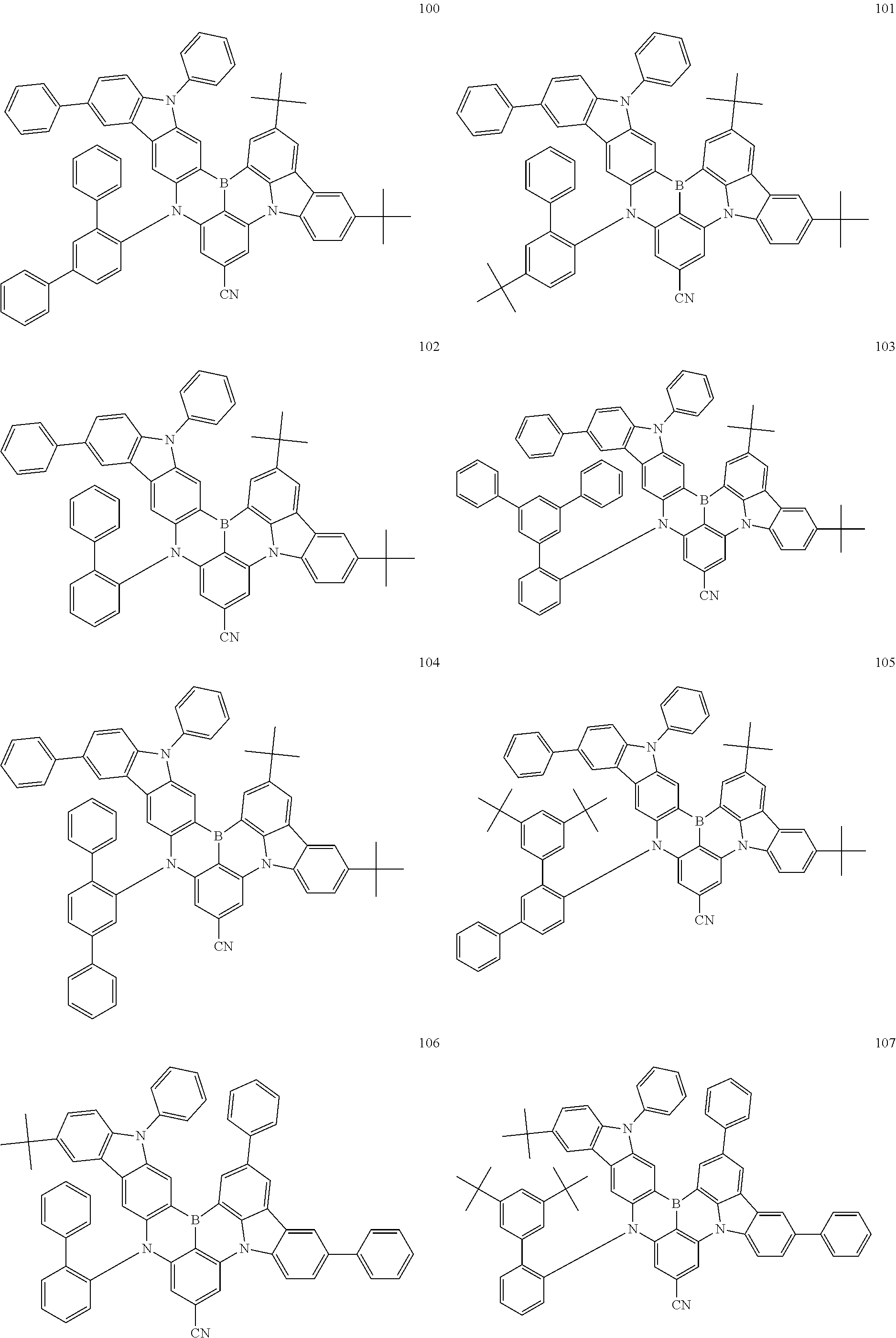

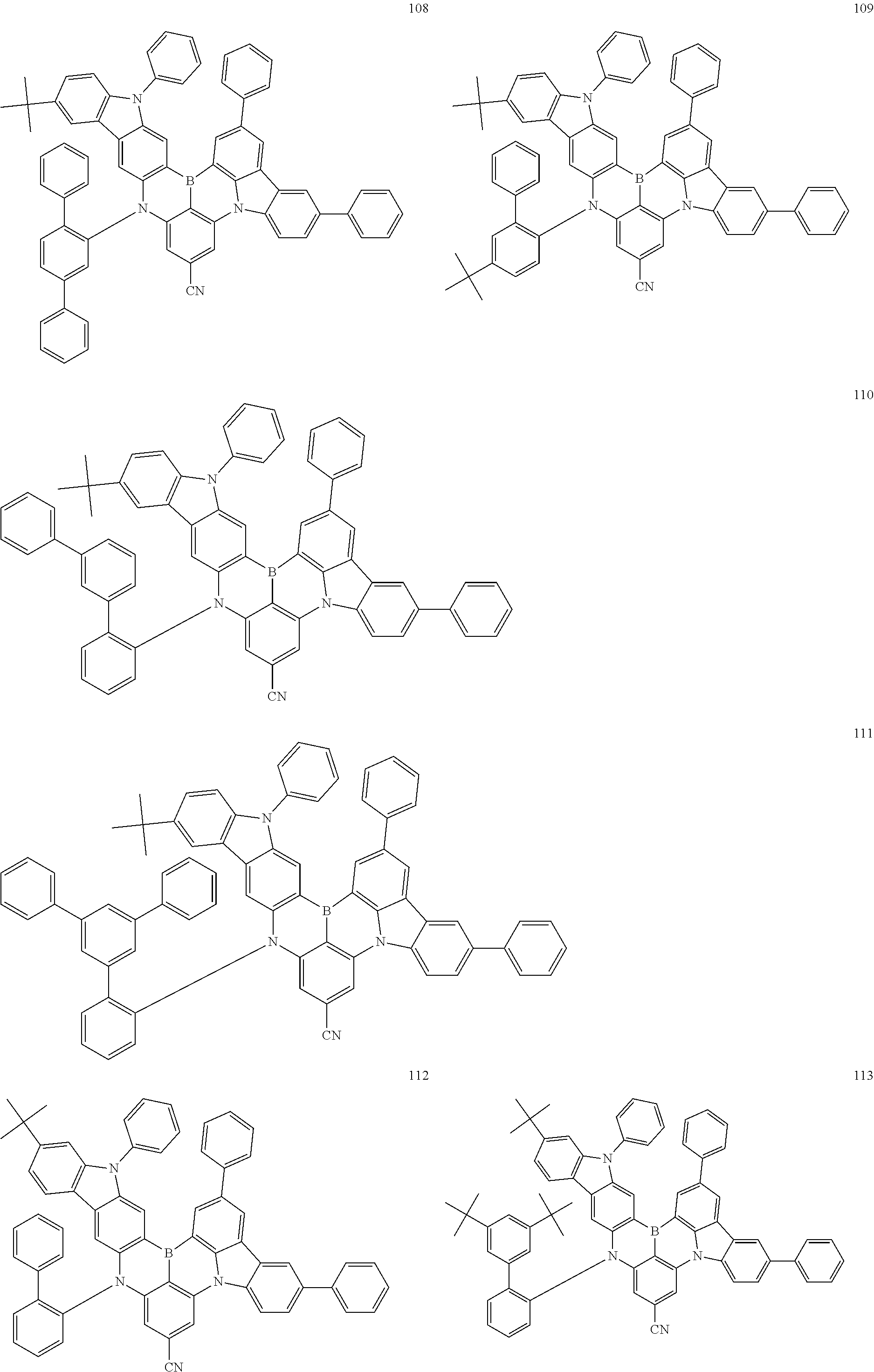

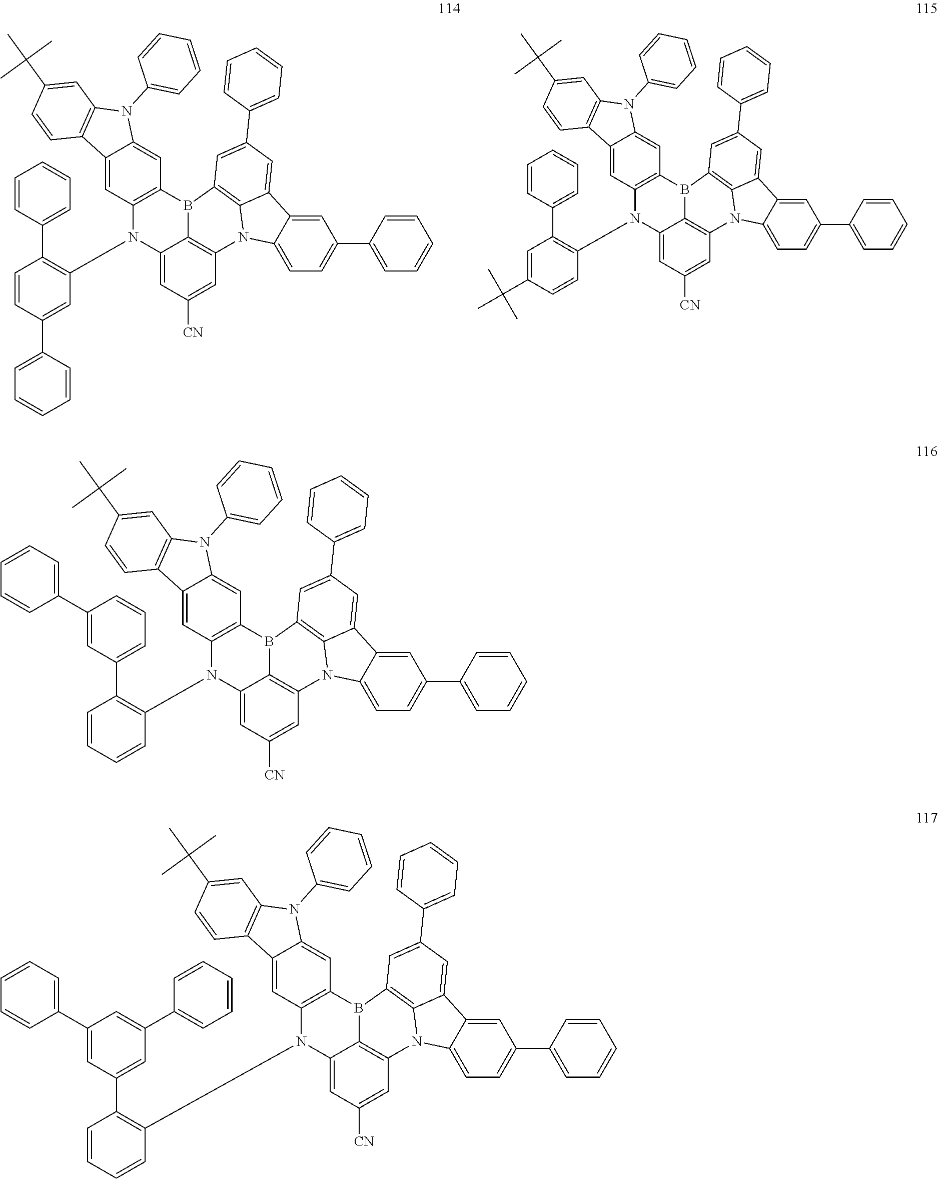

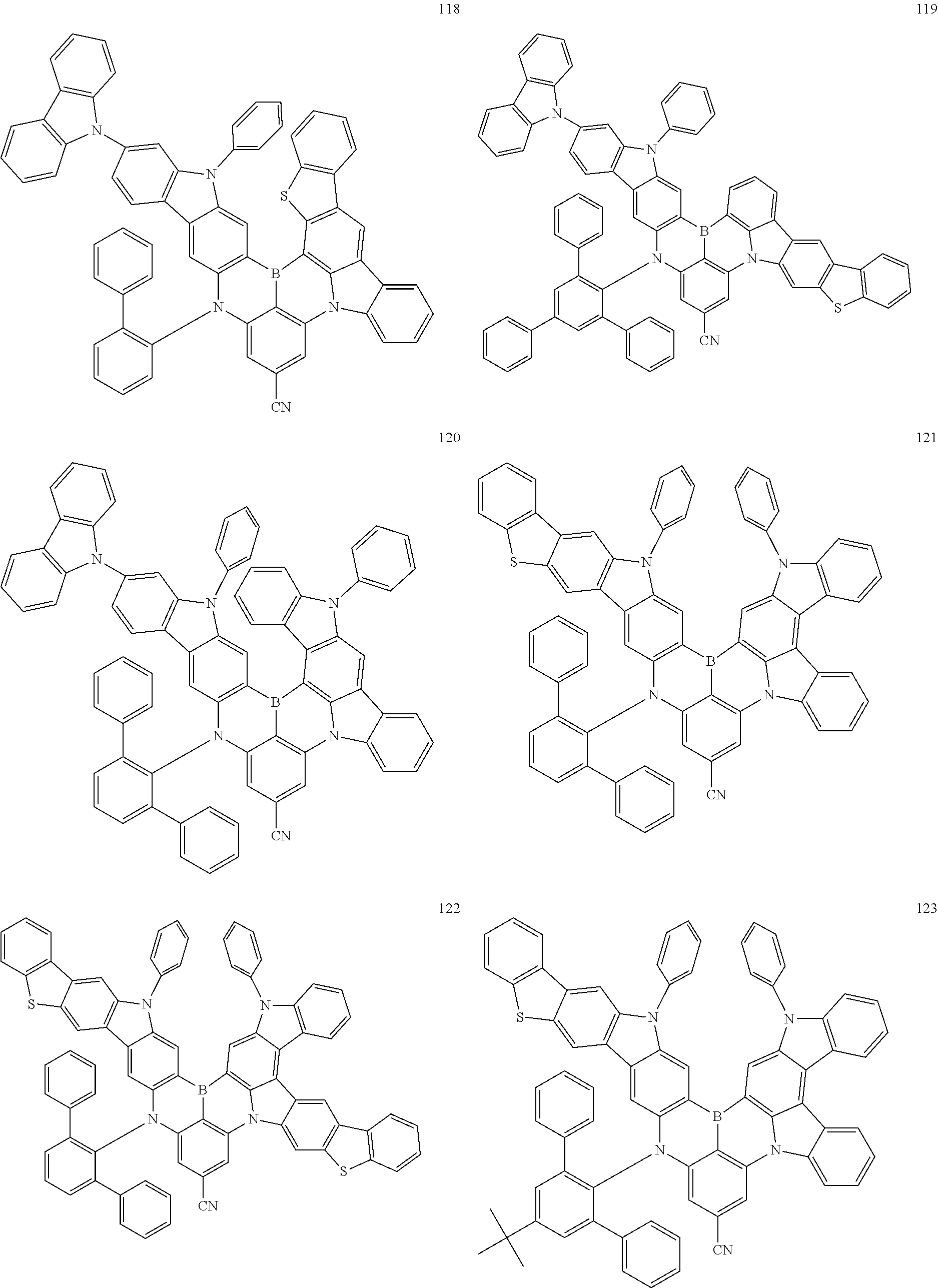

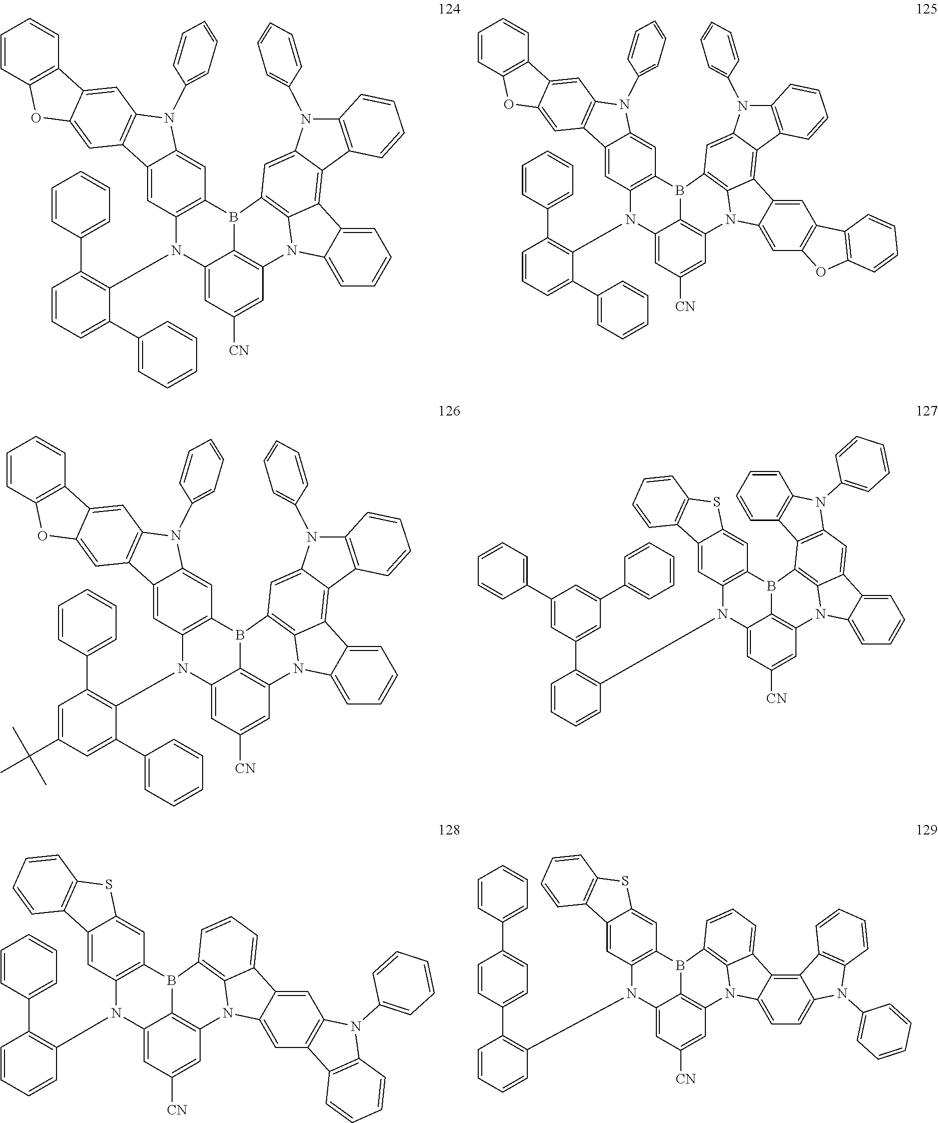

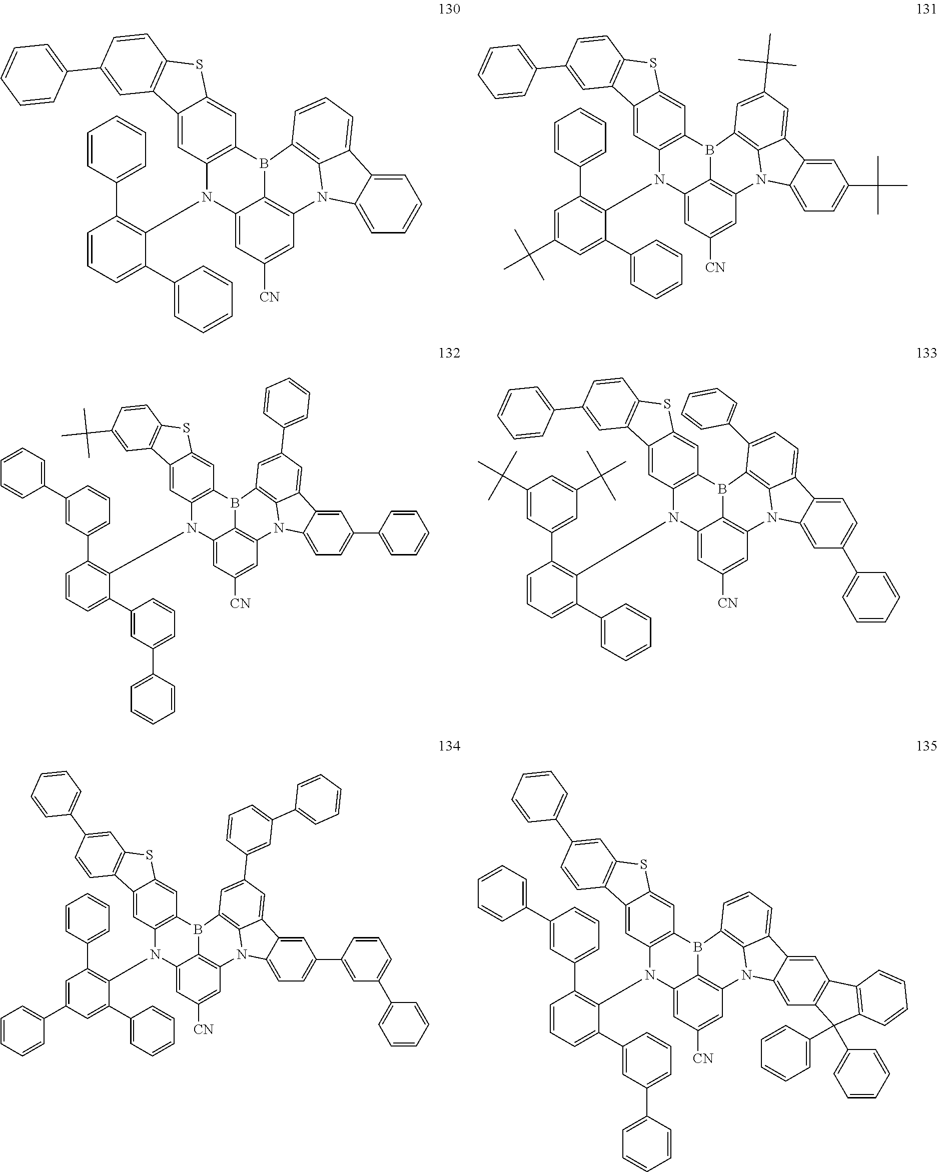

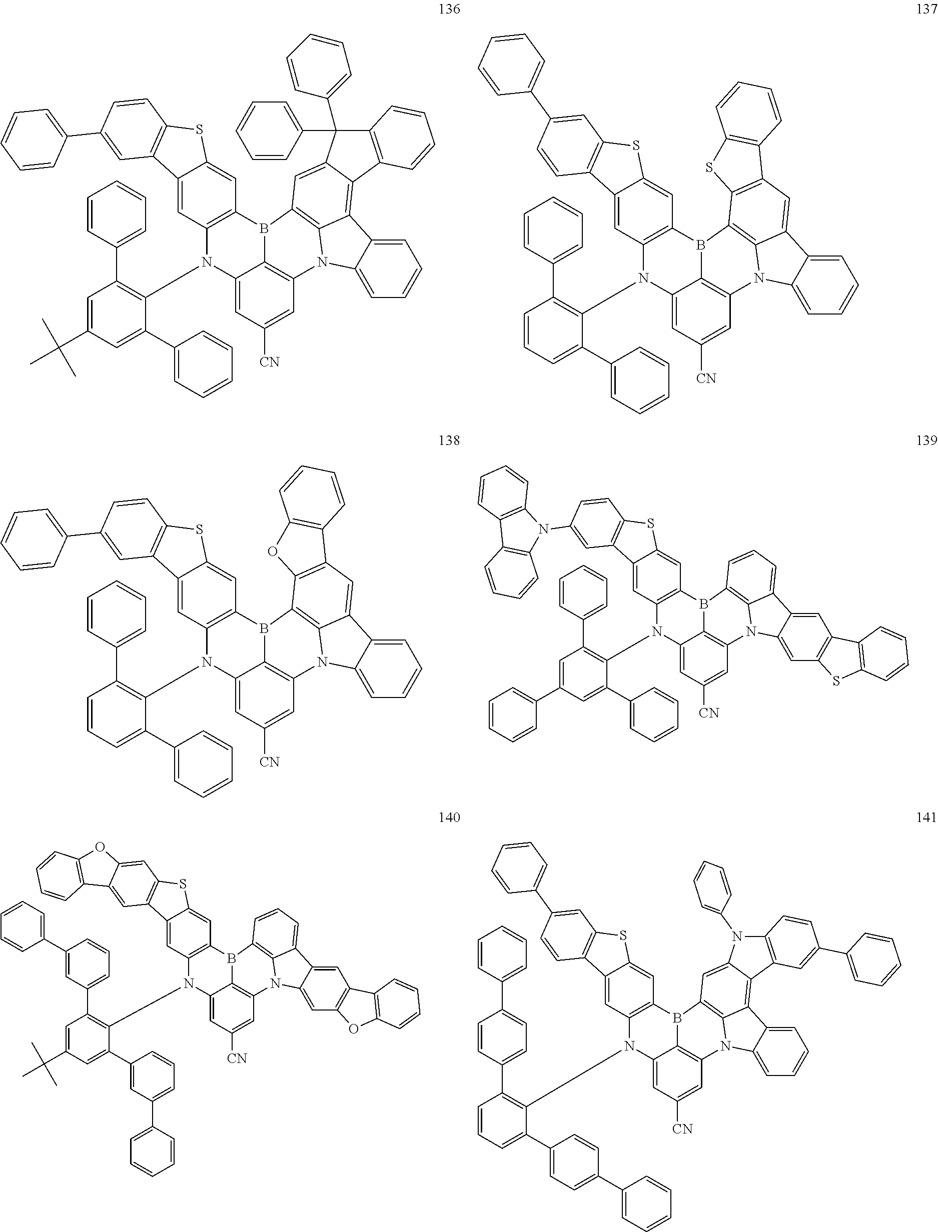

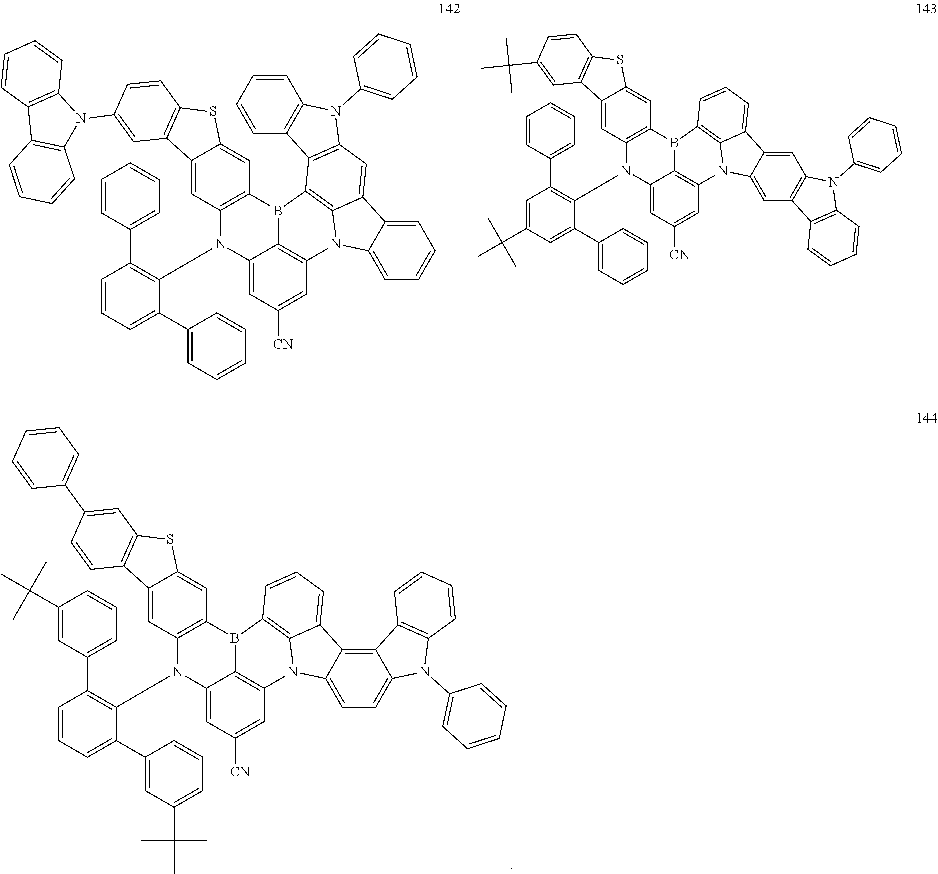

10. A fused polycyclic compound represented by Formula 1: 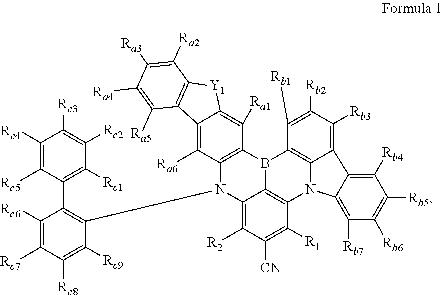
wherein, in Formula 1,
Y₁ is NR₃, O, or S,
R₁ to R₃ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms, and
Rₐ₁ to Rₐ₆, R_{b1} to R_{b7}, and R_{c1} to R_{c9} are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring.

11. The fused polycyclic compound of claim 10, wherein the fused polycyclic compound represented by Formula 1 is represented by any one selected from among Formula 1-1 to Formula 1-3: 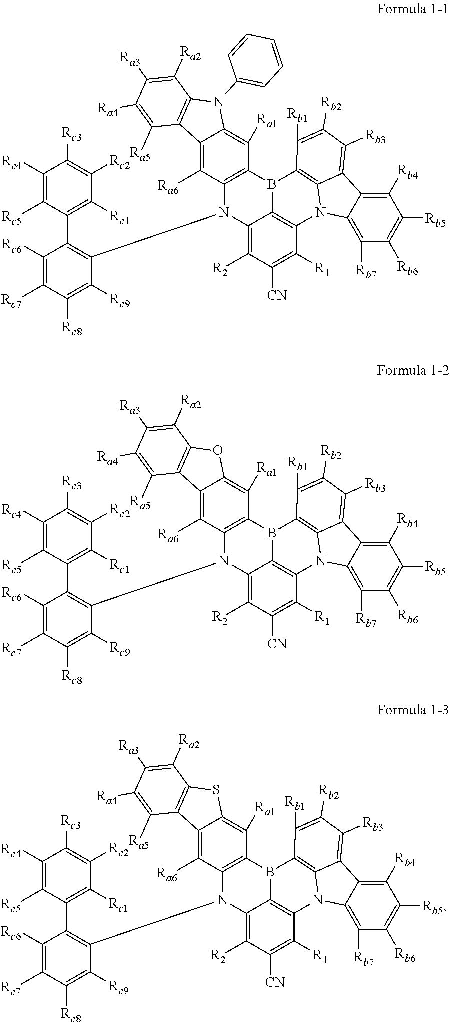
in Formula 1-1 to Formula 1-3,
R₁, R₂, Rₐ₁ to Rₐ₆, R_{b1} to R_{b7}, and R_{c1} to R_{c9} being the same as defined in Formula 1.

12. The fused polycyclic compound of claim 10, wherein the fused polycyclic compound represented by Formula 1 is represented by any one selected from among Formula 1-A1 to Formula 1-A3: 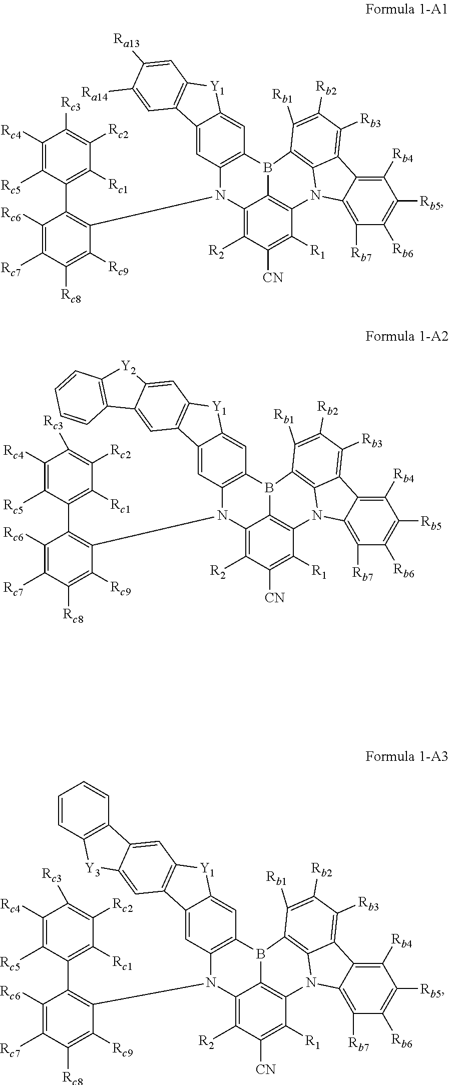
in Formula 1-A1,
Rₐ₁₃ and Rₐ₁₄ being each independently a hydrogen atom, a deuterium atom, a substituted or unsubstituted alkyl group of 1 to 30 carbon atoms, a substituted or unsubstituted aryl group of 6 to 30 ring-forming carbon atoms, or a substituted or unsubstituted heteroaryl group of 2 to 30 ring-forming carbon atoms, and
in Formula 1-A2 and Formula 1-A3,
Y₂ and Y₃ being each independently CR₄R₅, O, or S,
R₄ and R₅ being each independently a hydrogen atom, a deuterium atom, a substituted or unsubstituted alkyl group of 1 to 30 carbon atoms, or a substituted or unsubstituted aryl group of 6 to 30 ring-forming carbon atoms, and
in Formula 1-A1 to Formula 1-A3, Y₁, R₁, R₂, R_{b1} to R_{b7}, and R_{c1} to R_{c9} being the same as defined in Formula 1.

13. The fused polycyclic compound of claim 10, wherein the fused polycyclic compound represented by Formula 1 is represented by any one selected from among Formula 1-B1 to Formula 1-B8: 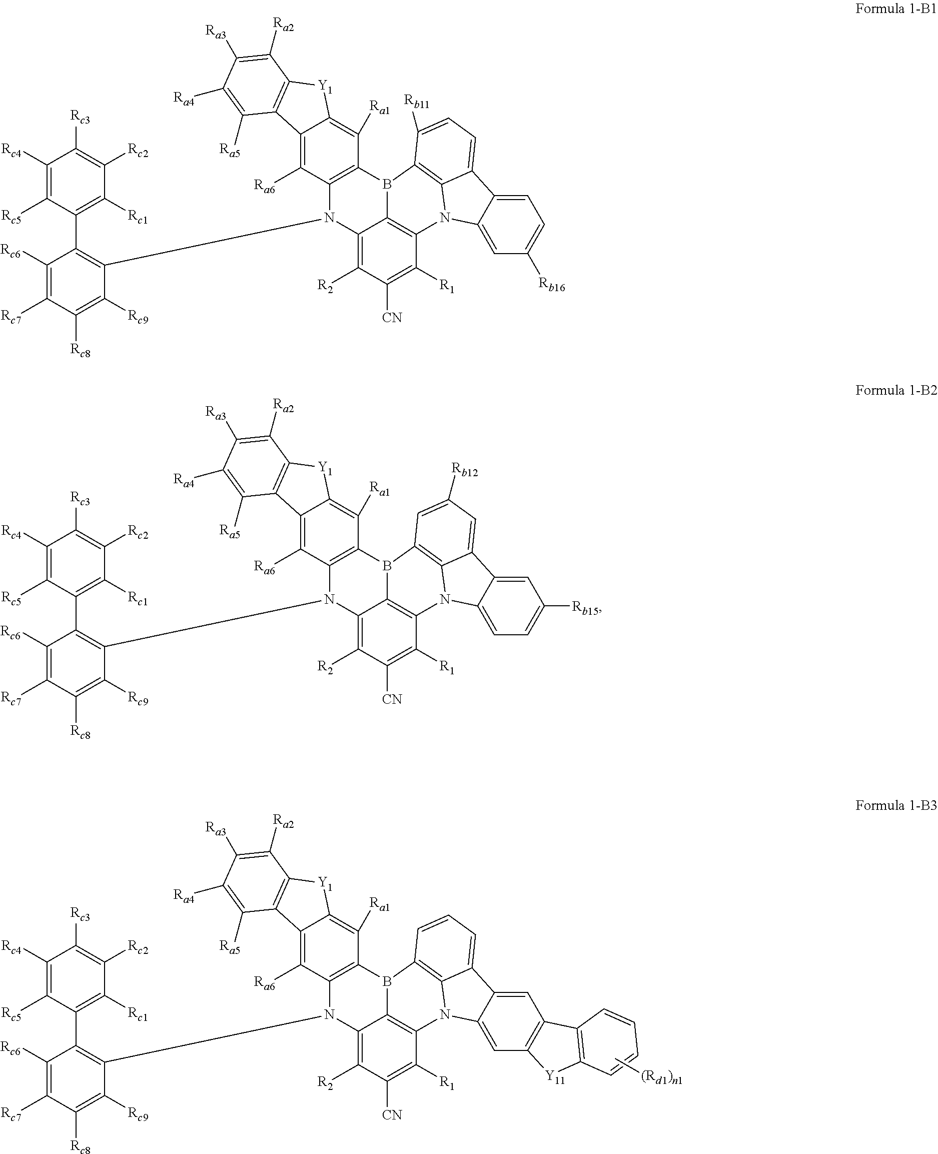 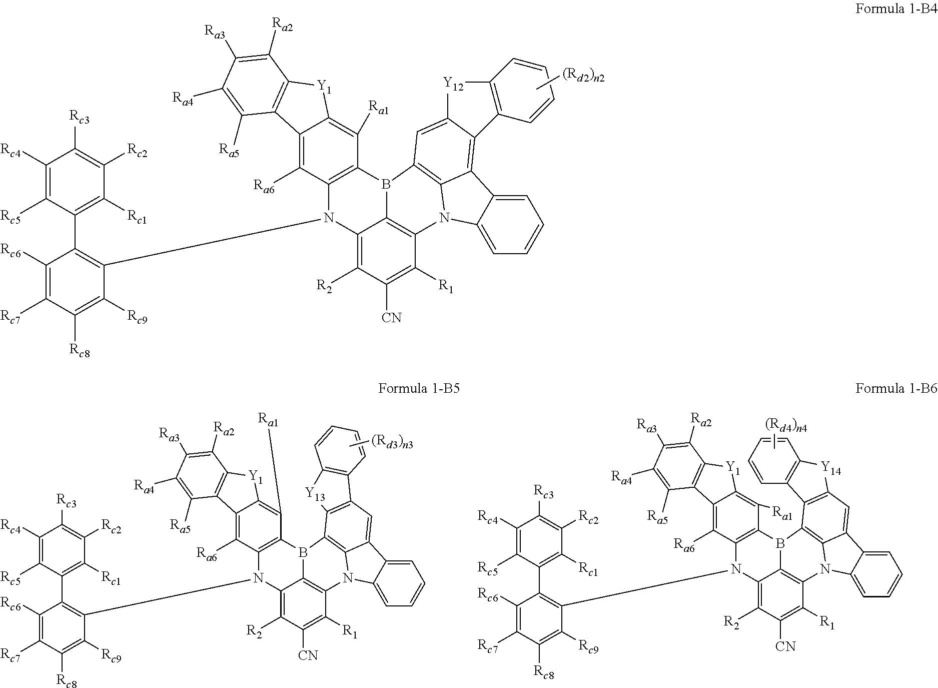 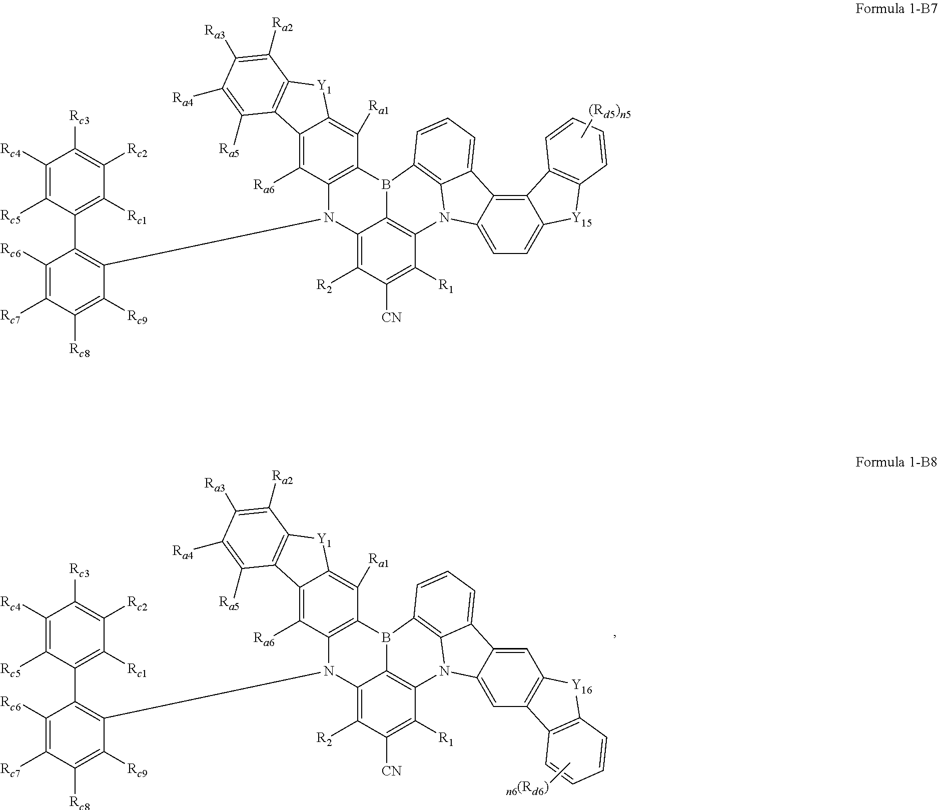
in Formula 1-B1 and Formula 1-B2,
R_{b11}, R_{b12}, R_{b15}, and R_{b16} being each independently a hydrogen atom, a deuterium atom, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms, and
in Formula 1-B3 to Formula 1-B8,
Y₁₁ to Y₁₆ being each independently CR₁₁R₁₂, NR₁₃, O, or S,
n1 to n6 being each independently an integer of 0 to 4,
R₁₁ to R₁₃ and R_{d1} to R_{d6} being each independently a hydrogen atom, a deuterium atom, or a substituted or unsubstituted aryl group of 6 to 60 ring-forming carbon atoms, and
in Formula 1-B1 to Formula 1-B8, Y₁, R₁, R₂, Rₐ₁ to Rₐ₆, and R_{c1} to R_{c9} being the same as defined in Formula 1.

14. The fused polycyclic compound of claim 10, wherein,
in Formula 1, at least one selected from among R_{b1} to R_{b7} is combined with an adjacent group to form a fused ring, and
the fused ring is a substituted or unsubstituted aryl group having 6 to 30 ring-forming carbon atoms or a substituted or unsubstituted heteroaryl group comprising N, O, or S as a ring-forming atom and having 2 to 30 ring-forming carbon atoms.

15. The fused polycyclic compound of claim 10, wherein, in Formula 1, a biphenyl moiety comprising R_{c1} to R_{c9} is represented by any one selected from among RC-1 to RC-18:

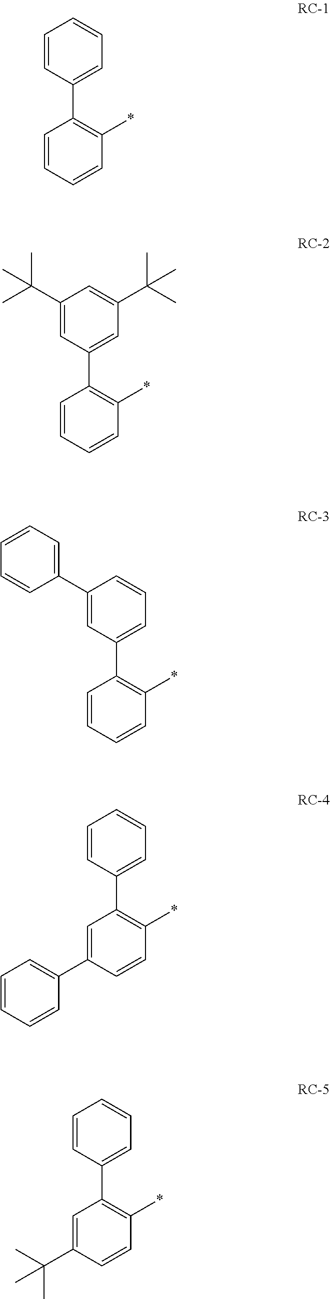

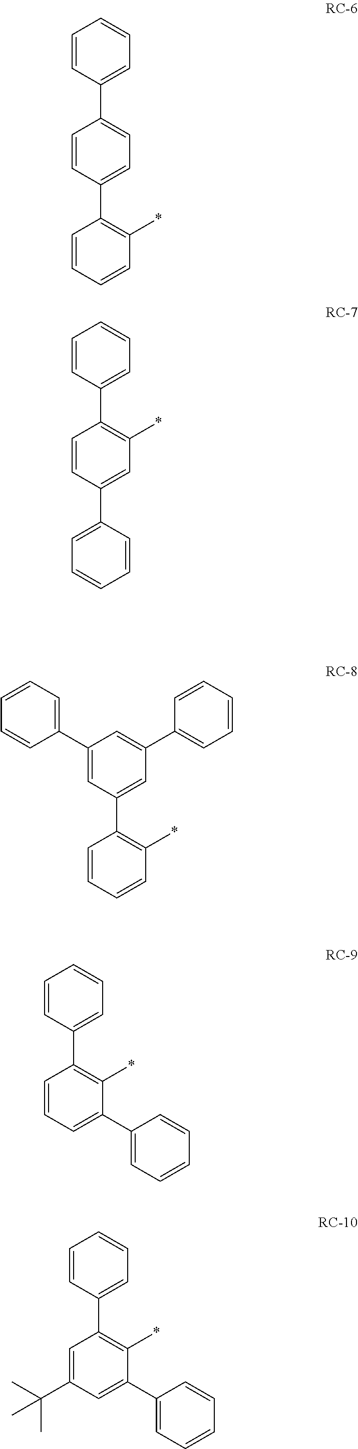

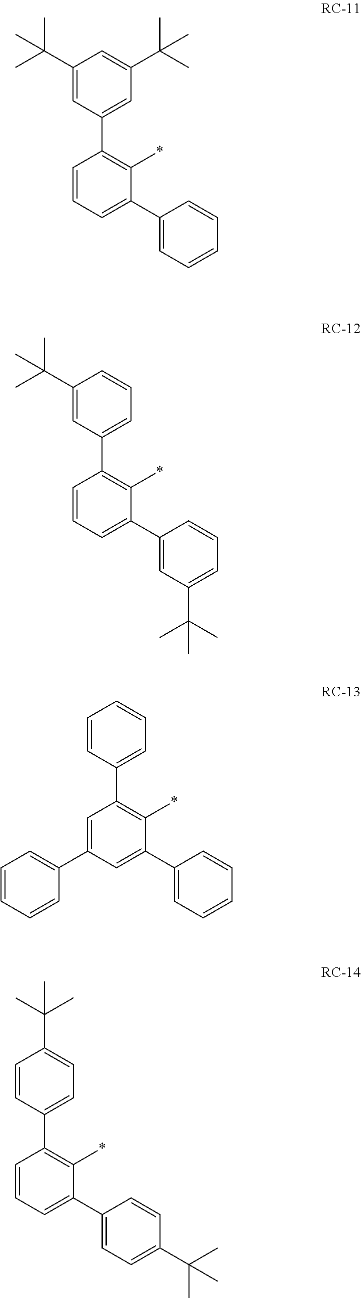 [SMILES: *c1c(-c2ccccc2)cccc1-c1cc(C(C)(C)C)cc(C(C)(C)C)c1 ; *c1c(-c2cccc(C(C)(C)C)c2)cccc1-c1cccc(C(C)(C)C)c1 ; *c1c(-c2ccccc2)cc(-c2ccccc2)cc1-c1ccccc1 ; *c1c(-c2ccc(C(C)(C)C)cc2)cccc1-c1ccc(C(C)(C)C)cc1]

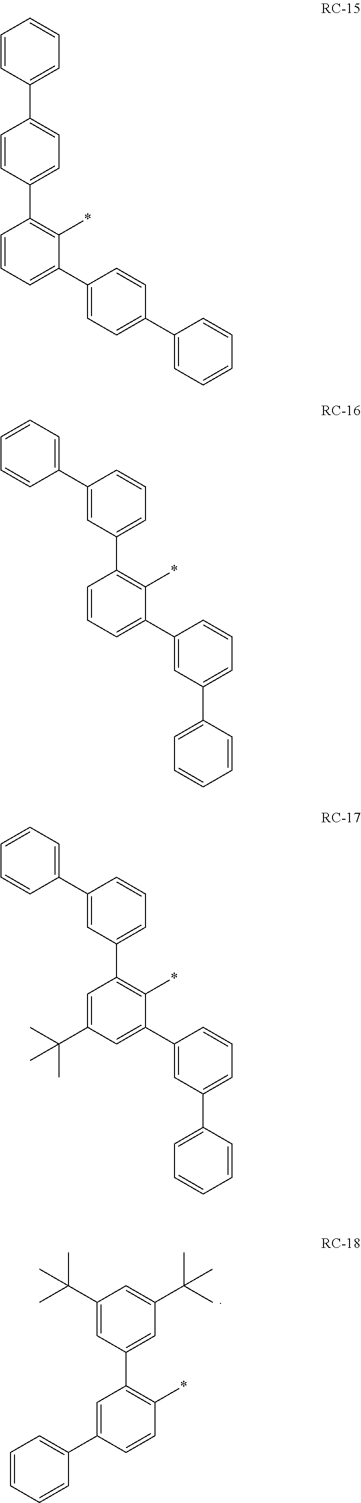 [SMILES: *c1c(-c2ccc(-c3ccccc3)cc2)cccc1-c1ccc(-c2ccccc2)cc1 ; *c1c(-c2cccc(-c3ccccc3)c2)cccc1-c1cccc(-c2ccccc2)c1 ; *c1c(-c2cccc(-c3ccccc3)c2)cc(C(C)(C)C)cc1-c1cccc(-c2ccccc2)c1 ; *c1ccc(-c2ccccc2)cc1-c1cc(C(C)(C)C)cc(C(C)(C)C)c1]

16. The fused polycyclic compound of claim 10, wherein, in Formula 1, R_{c1} to R_{c9} are each independently a hydrogen atom, a deuterium atom, a substituted or unsubstituted t-butyl group, a substituted or unsubstituted phenyl group, or a substituted or unsubstituted biphenyl group.

17. The fused polycyclic compound of claim 10, wherein the fused polycyclic compound represented by Formula 1 is any one selected from among compounds in Compound Group 1:

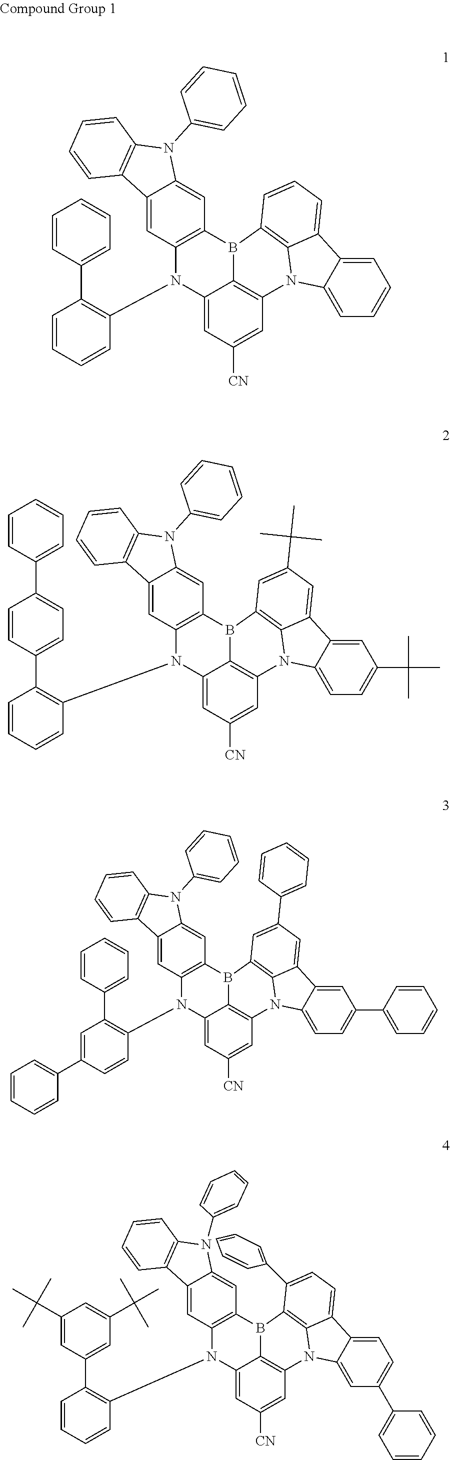

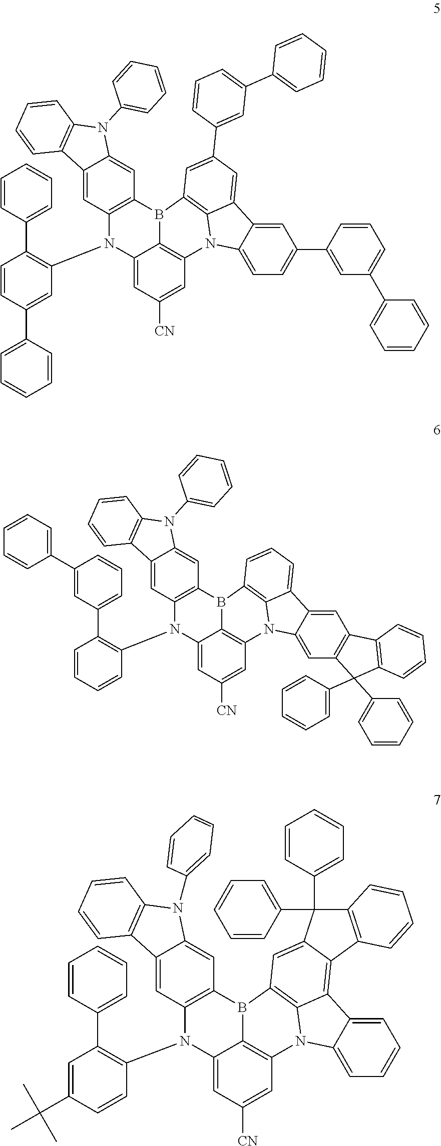 [SMILES: N#Cc1cc2c3c(c1)-n1c4ccc(-c5cccc(-c6ccccc6)c5)cc4c4cc(-c5cccc(-c6ccccc6)c5)cc(c41)B3c1cc3c(cc1N2c1cc(-c2ccccc2)ccc1-c1ccccc1)c1ccccc1n3-c1ccccc1 ; N#Cc1cc2c3c(c1)-n1c4cc5c(cc4c4cccc(c41)B3c1cc3c(cc1N2c1ccccc1-c1cccc(-c2ccccc2)c1)c1ccccc1n3-c1ccccc1)-c1ccccc1C5(c1ccccc1)c1ccccc1 ; CC(C)(C)c1ccc(N2c3cc4c5ccccc5n(-c5ccccc5)c4cc3B3c4c2cc(C#N)cc4-n2c4ccccc4c4c5c(cc3c42)C(c2ccccc2)(c2ccccc2)c2ccccc2-5)c(-c2ccccc2)c1]

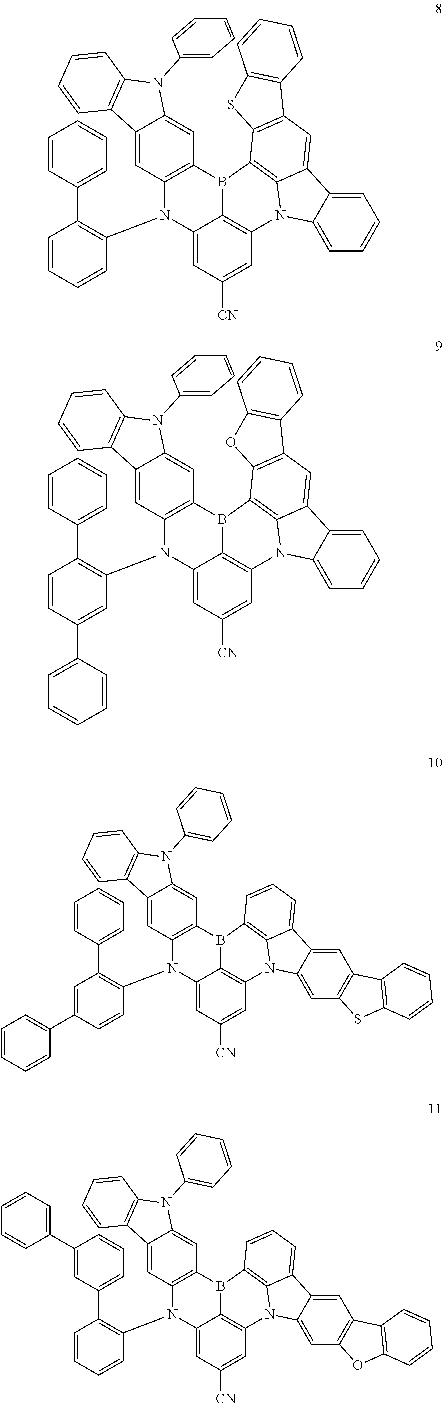 [SMILES: N#Cc1cc2c3c(c1)-n1c4ccccc4c4cc5c(sc6ccccc65)c(c41)B3c1cc3c(cc1N2c1ccccc1-c1ccccc1)c1ccccc1n3-c1ccccc1 ; N#Cc1cc2c3c(c1)-n1c4ccccc4c4cc5c(oc6ccccc65)c(c41)B3c1cc3c(cc1N2c1cc(-c2ccccc2)ccc1-c1ccccc1)c1ccccc1n3-c1ccccc1 ; N#Cc1cc2c3c(c1)-n1c4cc5sc6ccccc6c5cc4c4cccc(c41)B3c1cc3c(cc1N2c1ccc(-c2ccccc2)cc1-c1ccccc1)c1ccccc1n3-c1ccccc1 ; N#Cc1cc2c3c(c1)-n1c4cc5oc6ccccc6c5cc4c4cccc(c41)B3c1cc3c(cc1N2c1ccccc1-c1cccc(-c2ccccc2)c1)c1ccccc1n3-c1ccccc1]

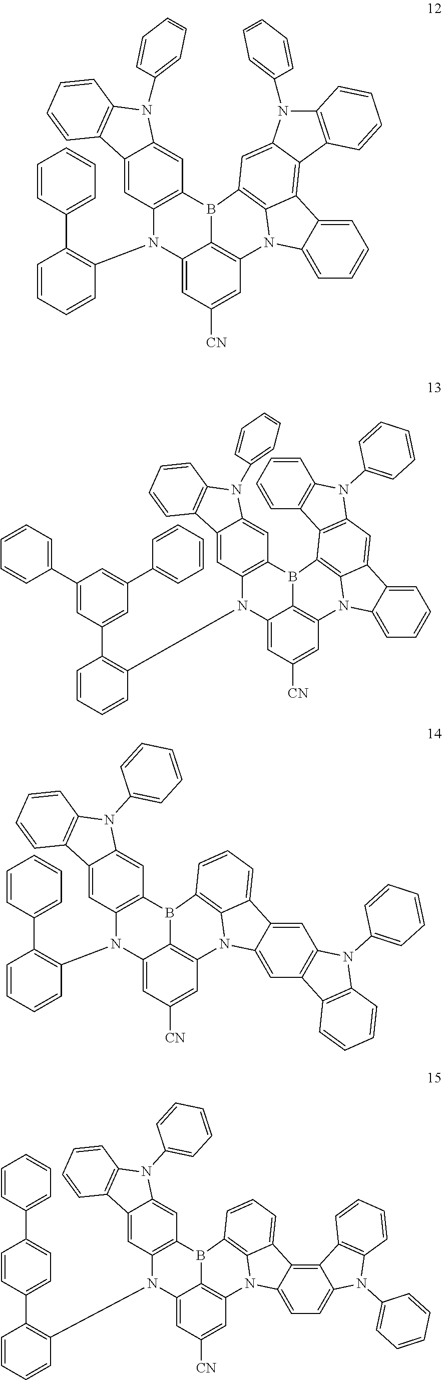 [SMILES: N#Cc1cc2c3c(c1)-n1c4ccccc4c4c5c6ccccc6n(-c6ccccc6)c5cc(c41)B3c1cc3c(cc1N2c1ccccc1-c1ccccc1)c1ccccc1n3-c1ccccc1 ; N#Cc1cc2c3c(c1)-n1c4ccccc4c4cc5c(c(c41)B3c1cc3c(cc1N2c1ccccc1-c1cc(-c2ccccc2)cc(-c2ccccc2)c1)c1ccccc1n3-c1ccccc1)c1ccccc1n5-c1ccccc1 ; N#Cc1cc2c3c(c1)-n1c4cc5c6ccccc6n(-c6ccccc6)c5cc4c4cccc(c41)B3c1cc3c(cc1N2c1ccccc1-c1ccccc1)c1ccccc1n3-c1ccccc1 ; N#Cc1cc2c3c(c1)-n1c4ccc5c(c6ccccc6n5-c5ccccc5)c4c4cccc(c41)B3c1cc3c(cc1N2c1ccccc1-c1ccc(-c2ccccc2)cc1)c1ccccc1n3-c1ccccc1]

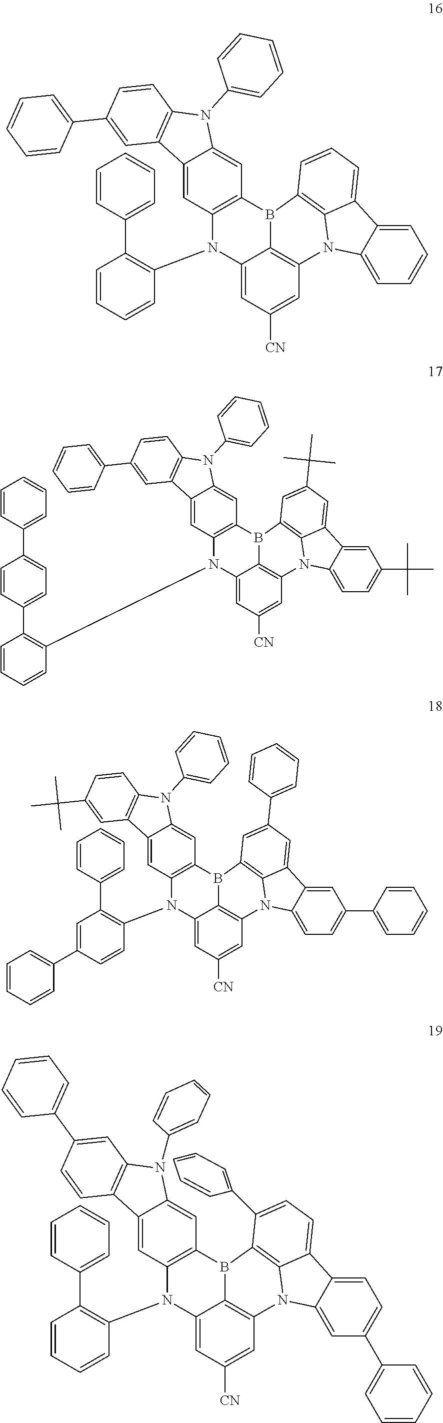 [SMILES: N#Cc1cc2c3c(c1)-n1c4ccccc4c4cccc(c41)B3c1cc3c(cc1N2c1ccccc1-c1ccccc1)c1cc(-c2ccccc2)ccc1n3-c1ccccc1 ; CC(C)(C)c1ccc2c(c1)c1cc(C(C)(C)C)cc3c1n2-c1cc(C#N)cc2c1B3c1cc3c(cc1N2c1ccccc1-c1ccc(-c2ccccc2)cc1)c1cc(-c2ccccc2)ccc1n3-c1ccccc1 ; CC(C)(C)c1ccc2c(c1)c1cc3c(cc1n2-c1ccccc1)B1c2c(cc(C#N)cc2-n2c4ccc(-c5ccccc5)cc4c4cc(-c5ccccc5)cc1c42)N3c1ccc(-c2ccccc2)cc1-c1ccccc1 ; N#Cc1cc2c3c(c1)-n1c4cc(-c5ccccc5)ccc4c4ccc(-c5ccccc5)c(c41)B3c1cc3c(cc1N2c1ccccc1-c1ccccc1)c1ccc(-c2ccccc2)cc1n3-c1ccccc1]

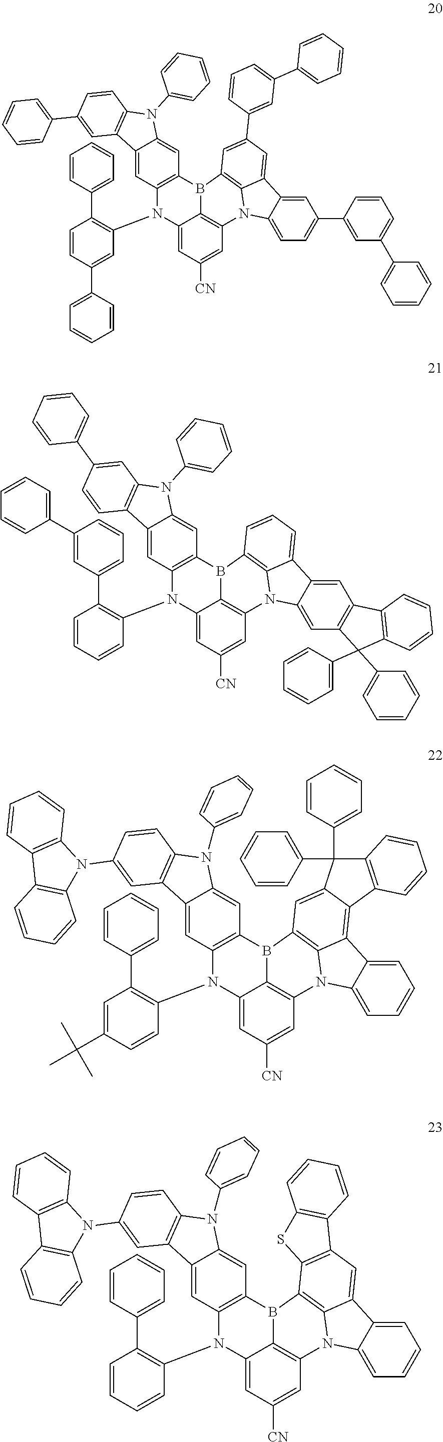

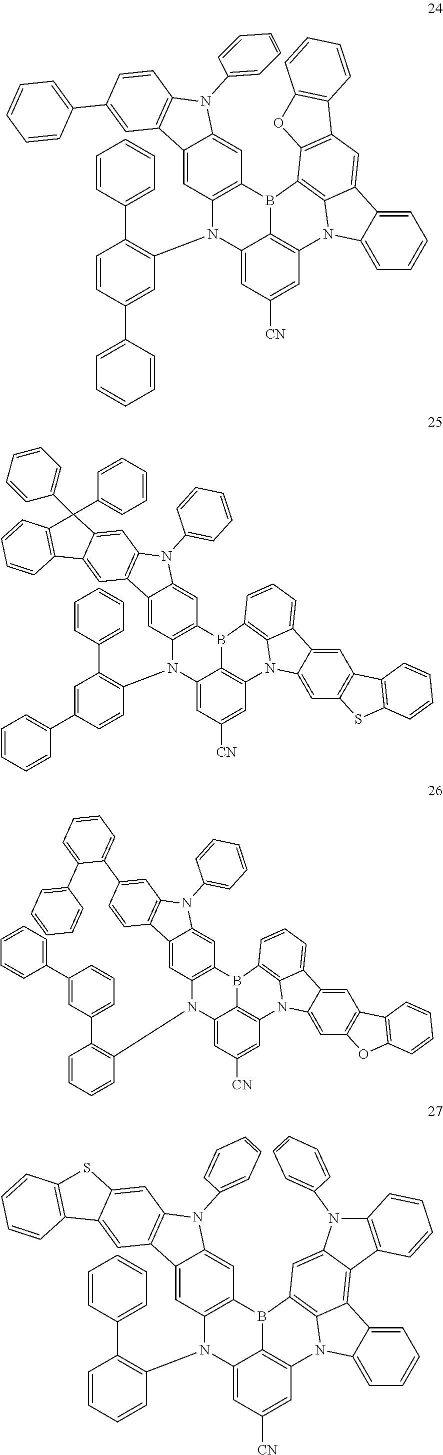

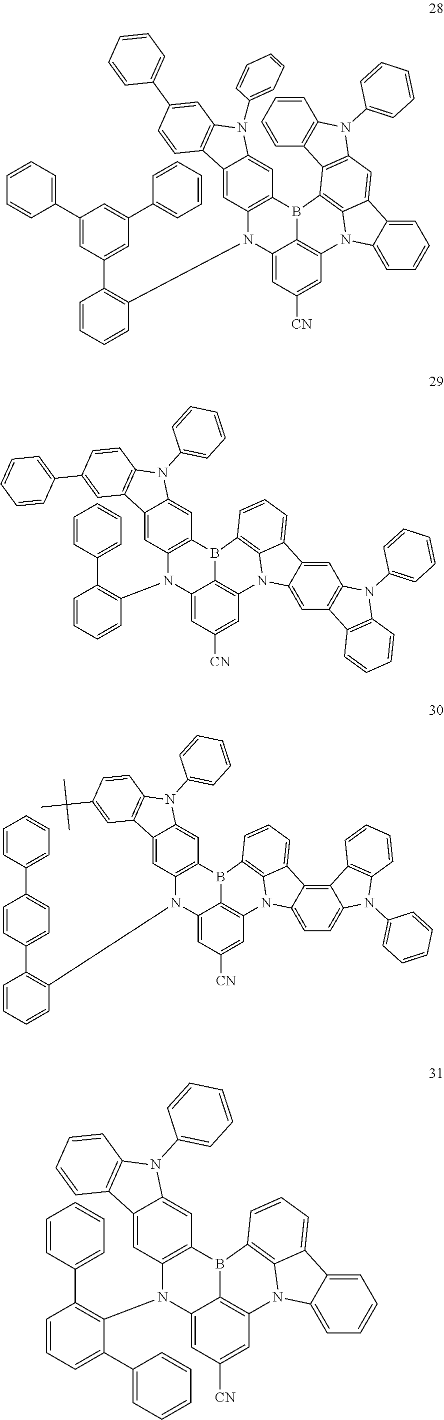

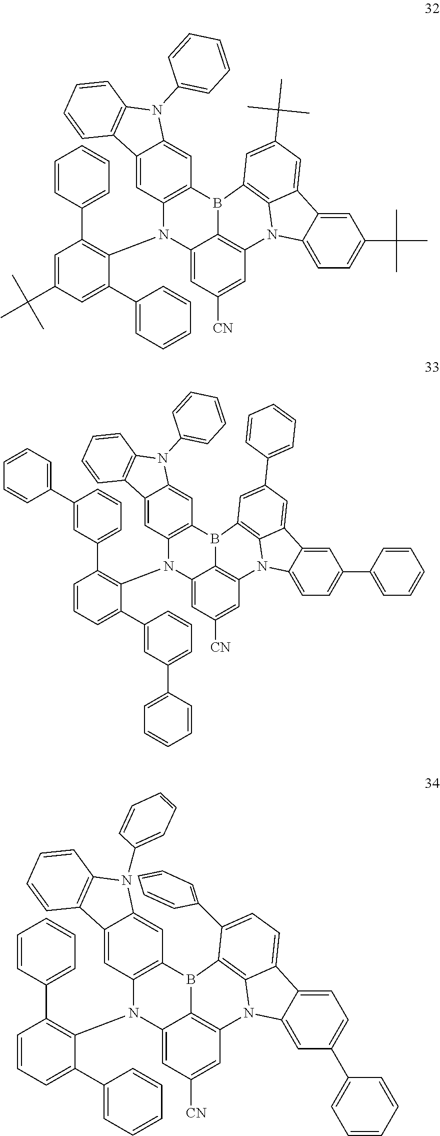 [SMILES: CC(C)(C)c1cc(-c2ccccc2)c(N2c3cc4c5ccccc5n(-c5ccccc5)c4cc3B3c4c2cc(C#N)cc4-n2c4ccc(C(C)(C)C)cc4c4cc(C(C)(C)C)cc3c42)c(-c2ccccc2)c1 ; N#Cc1cc2c3c(c1)-n1c4ccc(-c5ccccc5)cc4c4cc(-c5ccccc5)cc(c41)B3c1cc3c(cc1N2c1c(-c2cccc(-c4ccccc4)c2)cccc1-c1cccc(-c2ccccc2)c1)c1ccccc1n3-c1ccccc1 ; N#Cc1cc2c3c(c1)-n1c4cc(-c5ccccc5)ccc4c4ccc(-c5ccccc5)c(c41)B3c1cc3c(cc1N2c1c(-c2ccccc2)cccc1-c1ccccc1)c1ccccc1n3-c1ccccc1]

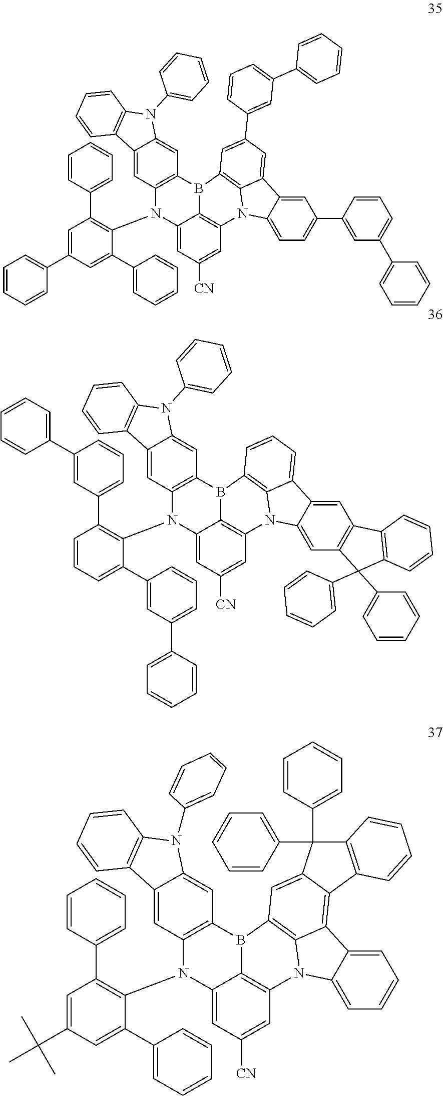 [SMILES: N#Cc1cc2c3c(c1)-n1c4ccc(-c5cccc(-c6ccccc6)c5)cc4c4cc(-c5cccc(-c6ccccc6)c5)cc(c41)B3c1cc3c(cc1N2c1c(-c2ccccc2)cc(-c2ccccc2)cc1-c1ccccc1)c1ccccc1n3-c1ccccc1 ; N#Cc1cc2c3c(c1)-n1c4cc5c(cc4c4cccc(c41)B3c1cc3c(cc1N2c1c(-c2cccc(-c4ccccc4)c2)cccc1-c1cccc(-c2ccccc2)c1)c1ccccc1n3-c1ccccc1)-c1ccccc1C5(c1ccccc1)c1ccccc1 ; CC(C)(C)c1cc(-c2ccccc2)c(N2c3cc4c5ccccc5n(-c5ccccc5)c4cc3B3c4c2cc(C#N)cc4-n2c4ccccc4c4c5c(cc3c42)C(c2ccccc2)(c2ccccc2)c2ccccc2-5)c(-c2ccccc2)c1]

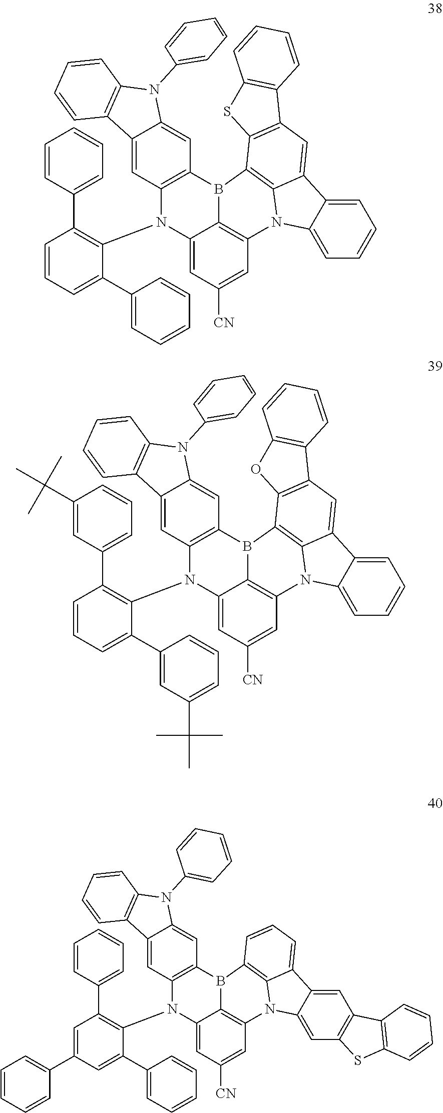 [SMILES: N#Cc1cc2c3c(c1)-n1c4ccccc4c4cc5c(sc6ccccc65)c(c41)B3c1cc3c(cc1N2c1c(-c2ccccc2)cccc1-c1ccccc1)c1ccccc1n3-c1ccccc1 ; CC(C)(C)c1cccc(-c2cccc(-c3cccc(C(C)(C)C)c3)c2N2c3cc4c5ccccc5n(-c5ccccc5)c4cc3B3c4c2cc(C#N)cc4-n2c4ccccc4c4cc5c(oc6ccccc65)c3c42)c1 ; N#Cc1cc2c3c(c1)-n1c4cc5sc6ccccc6c5cc4c4cccc(c41)B3c1cc3c(cc1N2c1c(-c2ccccc2)cc(-c2ccccc2)cc1-c1ccccc1)c1ccccc1n3-c1ccccc1]

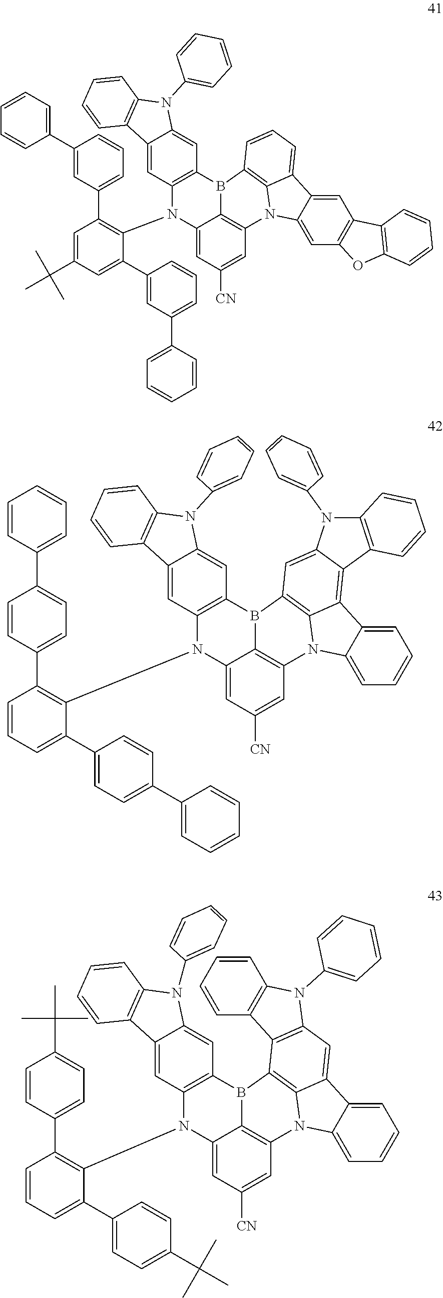 [SMILES: CC(C)(C)c1cc(-c2cccc(-c3ccccc3)c2)c(N2c3cc4c5ccccc5n(-c5ccccc5)c4cc3B3c4c2cc(C#N)cc4-n2c4cc5oc6ccccc6c5cc4c4cccc3c42)c(-c2cccc(-c3ccccc3)c2)c1 ; N#Cc1cc2c3c(c1)-n1c4ccccc4c4c5c6ccccc6n(-c6ccccc6)c5cc(c41)B3c1cc3c(cc1N2c1c(-c2ccc(-c4ccccc4)cc2)cccc1-c1ccc(-c2ccccc2)cc1)c1ccccc1n3-c1ccccc1 ; CC(C)(C)c1ccc(-c2cccc(-c3ccc(C(C)(C)C)cc3)c2N2c3cc4c5ccccc5n(-c5ccccc5)c4cc3B3c4c2cc(C#N)cc4-n2c4ccccc4c4cc5c(c3c42)c2ccccc2n5-c2ccccc2)cc1]

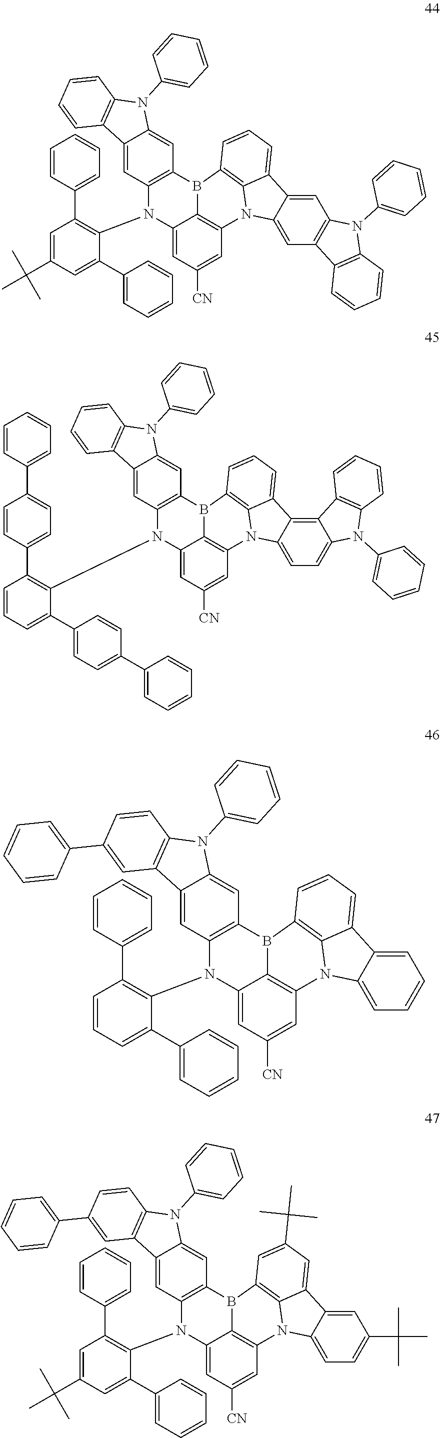

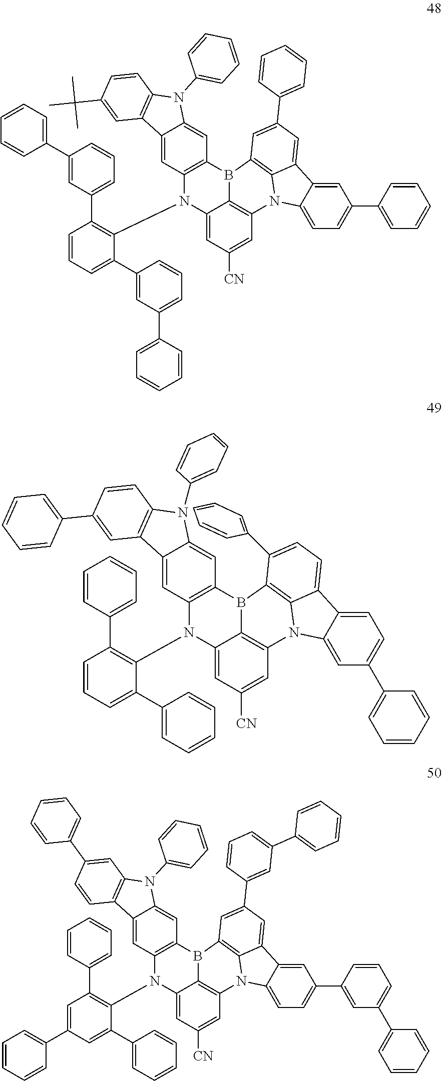 [SMILES: CC(C)(C)c1ccc2c(c1)c1cc3c(cc1n2-c1ccccc1)B1c2c(cc(C#N)cc2-n2c4ccc(-c5ccccc5)cc4c4cc(-c5ccccc5)cc1c42)N3c1c(-c2cccc(-c3ccccc3)c2)cccc1-c1cccc(-c2ccccc2)c1 ; N#Cc1cc2c3c(c1)-n1c4cc(-c5ccccc5)ccc4c4ccc(-c5ccccc5)c(c41)B3c1cc3c(cc1N2c1c(-c2ccccc2)cccc1-c1ccccc1)c1cc(-c2ccccc2)ccc1n3-c1ccccc1 ; N#Cc1cc2c3c(c1)-n1c4ccc(-c5cccc(-c6ccccc6)c5)cc4c4cc(-c5cccc(-c6ccccc6)c5)cc(c41)B3c1cc3c(cc1N2c1c(-c2ccccc2)cc(-c2ccccc2)cc1-c1ccccc1)c1ccc(-c2ccccc2)cc1n3-c1ccccc1]

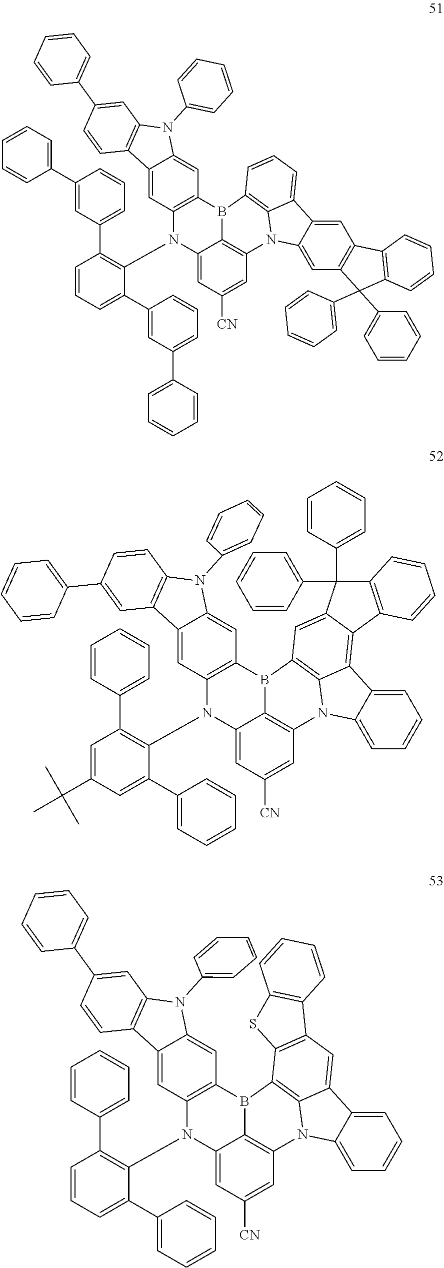 [SMILES: N#Cc1cc2c3c(c1)-n1c4cc5c(cc4c4cccc(c41)B3c1cc3c(cc1N2c1c(-c2cccc(-c4ccccc4)c2)cccc1-c1cccc(-c2ccccc2)c1)c1ccc(-c2ccccc2)cc1n3-c1ccccc1)-c1ccccc1C5(c1ccccc1)c1ccccc1 ; CC(C)(C)c1cc(-c2ccccc2)c(N2c3cc4c5cc(-c6ccccc6)ccc5n(-c5ccccc5)c4cc3B3c4c2cc(C#N)cc4-n2c4ccccc4c4c5c(cc3c42)C(c2ccccc2)(c2ccccc2)c2ccccc2-5)c(-c2ccccc2)c1 ; N#Cc1cc2c3c(c1)-n1c4ccccc4c4cc5c(sc6ccccc65)c(c41)B3c1cc3c(cc1N2c1c(-c2ccccc2)cccc1-c1ccccc1)c1ccc(-c2ccccc2)cc1n3-c1ccccc1]

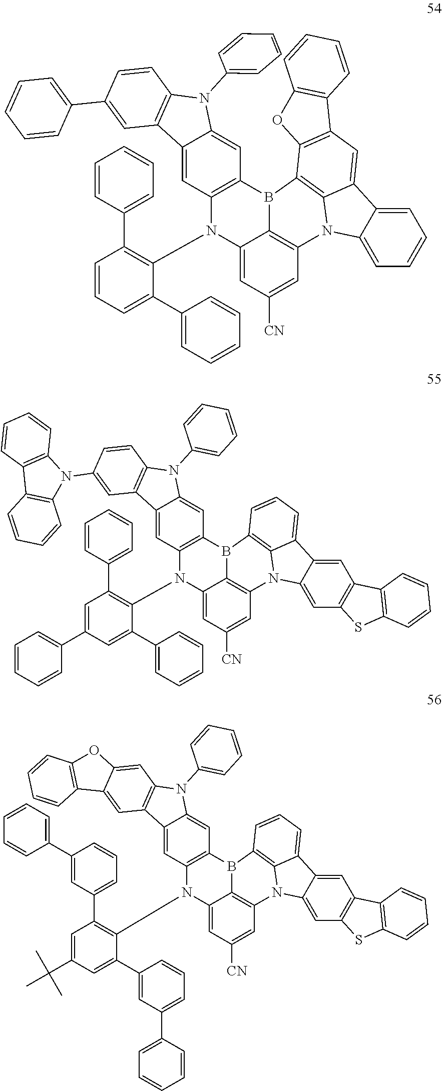 [SMILES: N#Cc1cc2c3c(c1)-n1c4ccccc4c4cc5c(oc6ccccc65)c(c41)B3c1cc3c(cc1N2c1c(-c2ccccc2)cccc1-c1ccccc1)c1cc(-c2ccccc2)ccc1n3-c1ccccc1 ; N#Cc1cc2c3c(c1)-n1c4cc5sc6ccccc6c5cc4c4cccc(c41)B3c1cc3c(cc1N2c1c(-c2ccccc2)cc(-c2ccccc2)cc1-c1ccccc1)c1cc(-n2c4ccccc4c4ccccc42)ccc1n3-c1ccccc1 ; CC(C)(C)c1cc(-c2cccc(-c3ccccc3)c2)c(N2c3cc4c5cc6c(cc5n(-c5ccccc5)c4cc3B3c4c2cc(C#N)cc4-n2c4cc5sc7ccccc7c5cc4c4cccc3c42)oc2ccccc26)c(-c2cccc(-c3ccccc3)c2)c1]

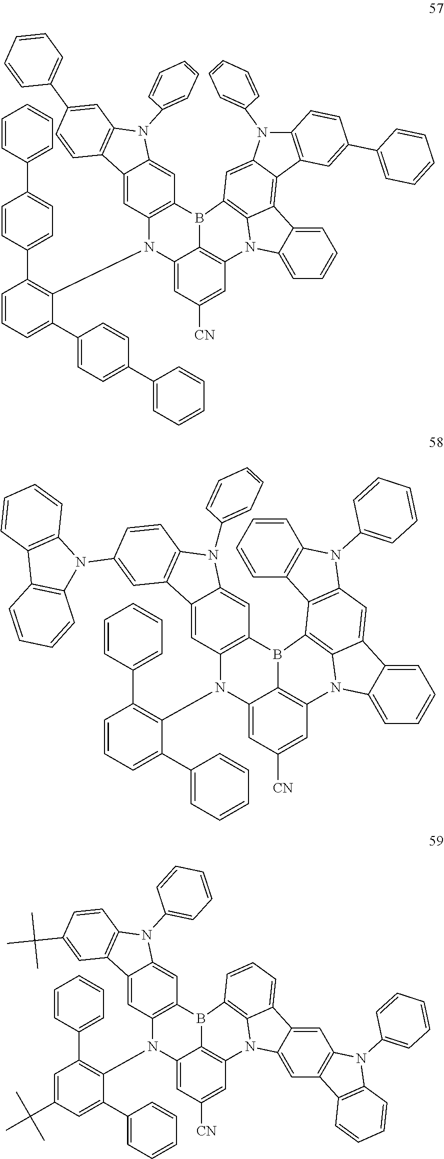 [SMILES: N#Cc1cc2c3c(c1)-n1c4ccccc4c4c5c6cc(-c7ccccc7)ccc6n(-c6ccccc6)c5cc(c41)B3c1cc3c(cc1N2c1c(-c2ccc(-c4ccccc4)cc2)cccc1-c1ccc(-c2ccccc2)cc1)c1ccc(-c2ccccc2)cc1n3-c1ccccc1 ; N#Cc1cc2c3c(c1)-n1c4ccccc4c4cc5c(c(c41)B3c1cc3c(cc1N2c1c(-c2ccccc2)cccc1-c1ccccc1)c1cc(-n2c4ccccc4c4ccccc42)ccc1n3-c1ccccc1)c1ccccc1n5-c1ccccc1 ; CC(C)(C)c1cc(-c2ccccc2)c(N2c3cc4c5cc(C(C)(C)C)ccc5n(-c5ccccc5)c4cc3B3c4c2cc(C#N)cc4-n2c4cc5c6ccccc6n(-c6ccccc6)c5cc4c4cccc3c42)c(-c2ccccc2)c1]

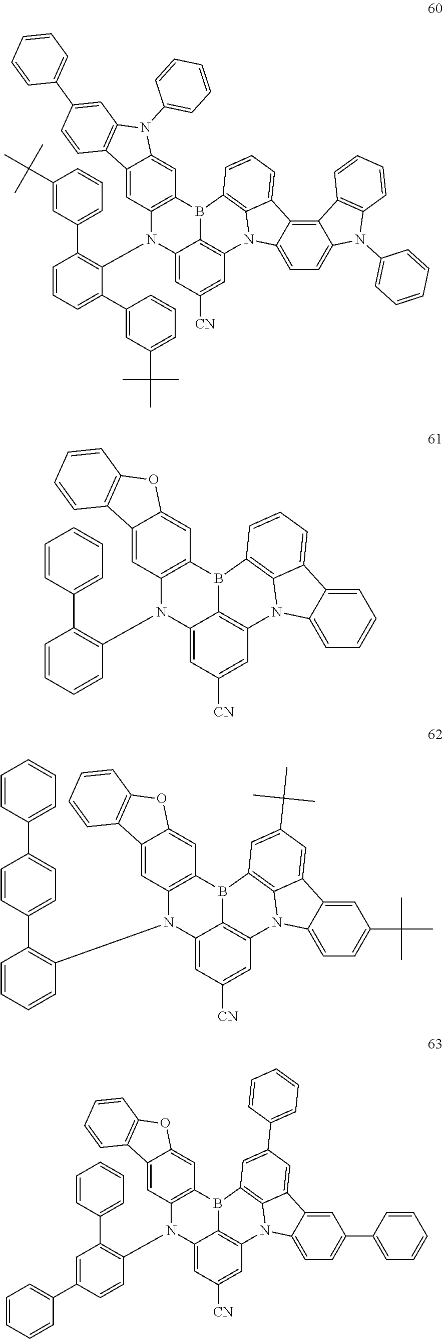 [SMILES: CC(C)(C)c1cccc(-c2cccc(-c3cccc(C(C)(C)C)c3)c2N2c3cc4c5ccc(-c6ccccc6)cc5n(-c5ccccc5)c4cc3B3c4c2cc(C#N)cc4-n2c4ccc5c(c6ccccc6n5-c5ccccc5)c4c4cccc3c42)c1 ; N#Cc1cc2c3c(c1)-n1c4ccccc4c4cccc(c41)B3c1cc3oc4ccccc4c3cc1N2c1ccccc1-c1ccccc1 ; CC(C)(C)c1ccc2c(c1)c1cc(C(C)(C)C)cc3c1n2-c1cc(C#N)cc2c1B3c1cc3oc4ccccc4c3cc1N2c1ccccc1-c1ccc(-c2ccccc2)cc1 ; N#Cc1cc2c3c(c1)-n1c4ccc(-c5ccccc5)cc4c4cc(-c5ccccc5)cc(c41)B3c1cc3oc4ccccc4c3cc1N2c1ccc(-c2ccccc2)cc1-c1ccccc1]

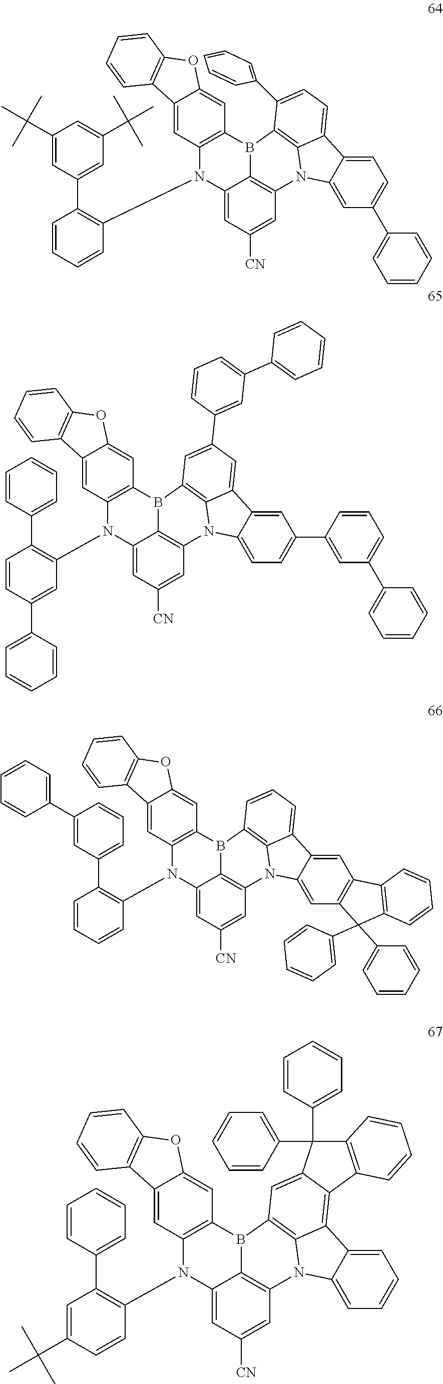

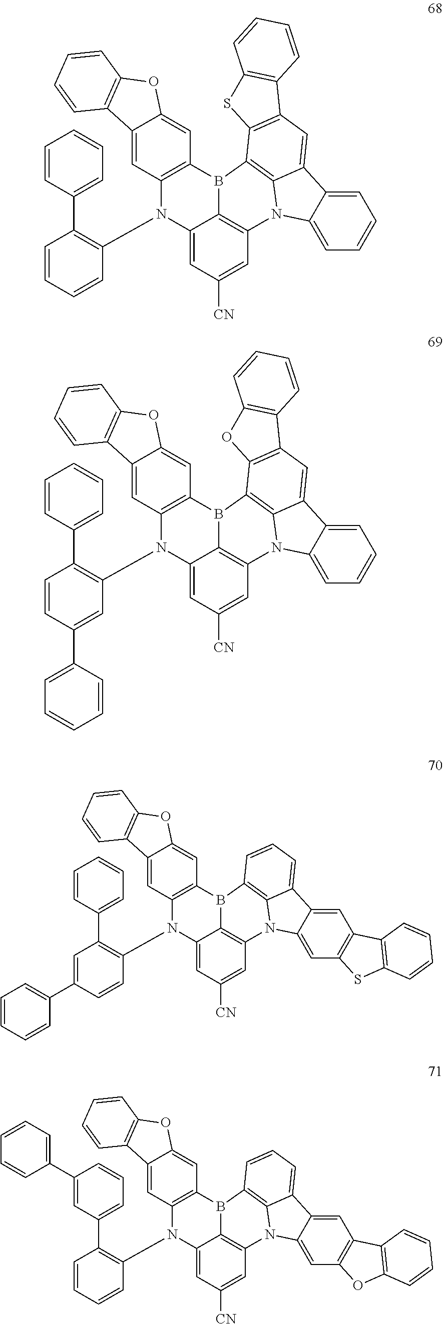 [SMILES: N#Cc1cc2c3c(c1)-n1c4ccccc4c4cc5c(sc6ccccc65)c(c41)B3c1cc3oc4ccccc4c3cc1N2c1ccccc1-c1ccccc1 ; N#Cc1cc2c3c(c1)-n1c4ccccc4c4cc5c(oc6ccccc65)c(c41)B3c1cc3oc4ccccc4c3cc1N2c1cc(-c2ccccc2)ccc1-c1ccccc1 ; N#Cc1cc2c3c(c1)-n1c4cc5sc6ccccc6c5cc4c4cccc(c41)B3c1cc3oc4ccccc4c3cc1N2c1ccc(-c2ccccc2)cc1-c1ccccc1 ; N#Cc1cc2c3c(c1)-n1c4cc5oc6ccccc6c5cc4c4cccc(c41)B3c1cc3oc4ccccc4c3cc1N2c1ccccc1-c1cccc(-c2ccccc2)c1]

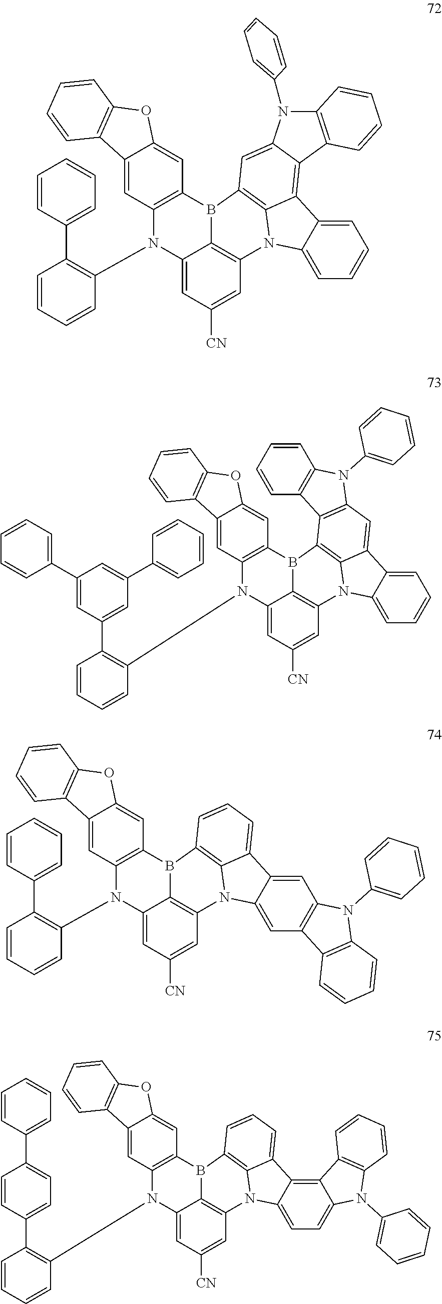 [SMILES: N#Cc1cc2c3c(c1)-n1c4ccccc4c4c5c6ccccc6n(-c6ccccc6)c5cc(c41)B3c1cc3oc4ccccc4c3cc1N2c1ccccc1-c1ccccc1 ; N#Cc1cc2c3c(c1)-n1c4ccccc4c4cc5c(c(c41)B3c1cc3oc4ccccc4c3cc1N2c1ccccc1-c1cc(-c2ccccc2)cc(-c2ccccc2)c1)c1ccccc1n5-c1ccccc1 ; N#Cc1cc2c3c(c1)-n1c4cc5c6ccccc6n(-c6ccccc6)c5cc4c4cccc(c41)B3c1cc3oc4ccccc4c3cc1N2c1ccccc1-c1ccccc1 ; N#Cc1cc2c3c(c1)-n1c4ccc5c(c6ccccc6n5-c5ccccc5)c4c4cccc(c41)B3c1cc3oc4ccccc4c3cc1N2c1ccccc1-c1ccc(-c2ccccc2)cc1]

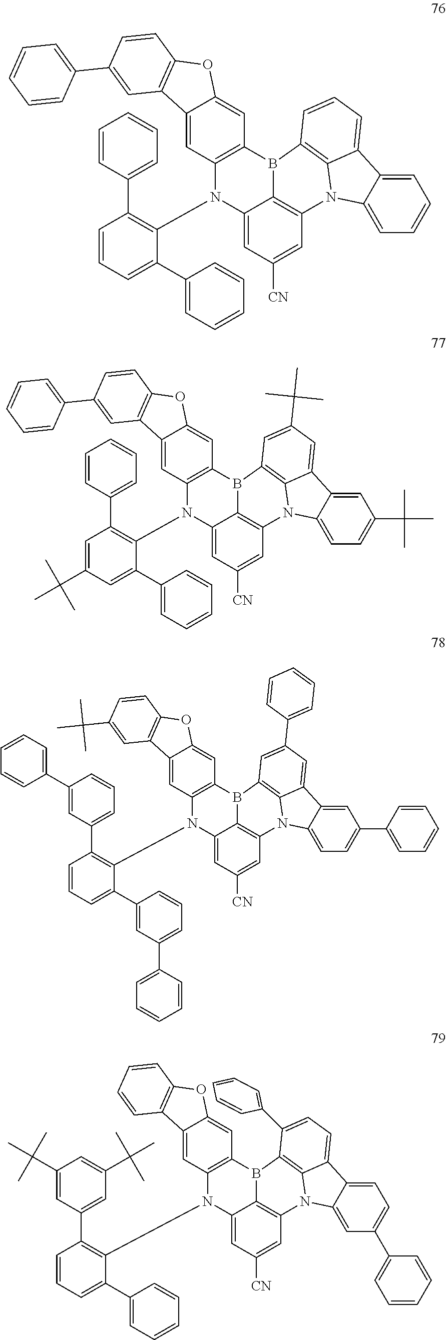

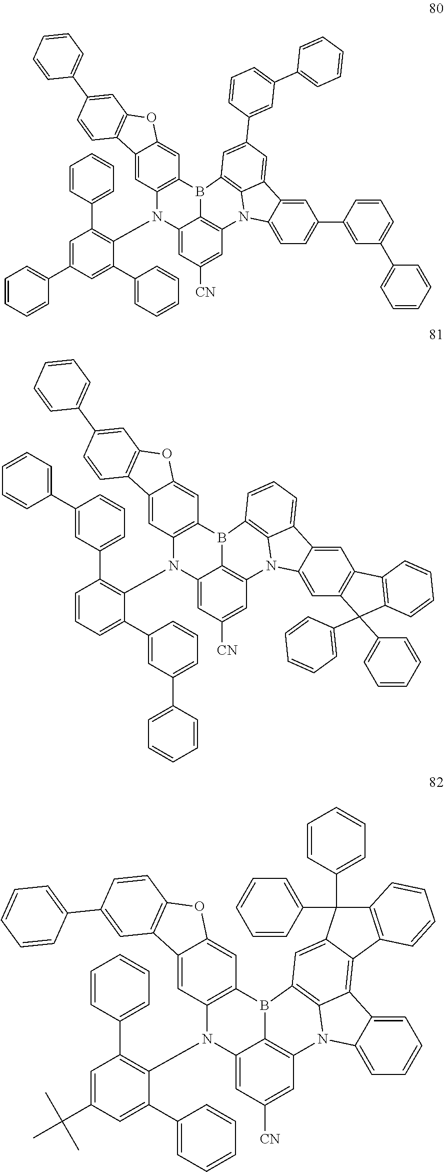 [SMILES: N#Cc1cc2c3c(c1)-n1c4ccc(-c5cccc(-c6ccccc6)c5)cc4c4cc(-c5cccc(-c6ccccc6)c5)cc(c41)B3c1cc3oc4cc(-c5ccccc5)ccc4c3cc1N2c1c(-c2ccccc2)cc(-c2ccccc2)cc1-c1ccccc1 ; N#Cc1cc2c3c(c1)-n1c4cc5c(cc4c4cccc(c41)B3c1cc3oc4cc(-c6ccccc6)ccc4c3cc1N2c1c(-c2cccc(-c3ccccc3)c2)cccc1-c1cccc(-c2ccccc2)c1)-c1ccccc1C5(c1ccccc1)c1ccccc1 ; CC(C)(C)c1cc(-c2ccccc2)c(N2c3cc4c(cc3B3c5c2cc(C#N)cc5-n2c5ccccc5c5c6c(cc3c52)C(c2ccccc2)(c2ccccc2)c2ccccc2-6)oc2ccc(-c3ccccc3)cc24)c(-c2ccccc2)c1]

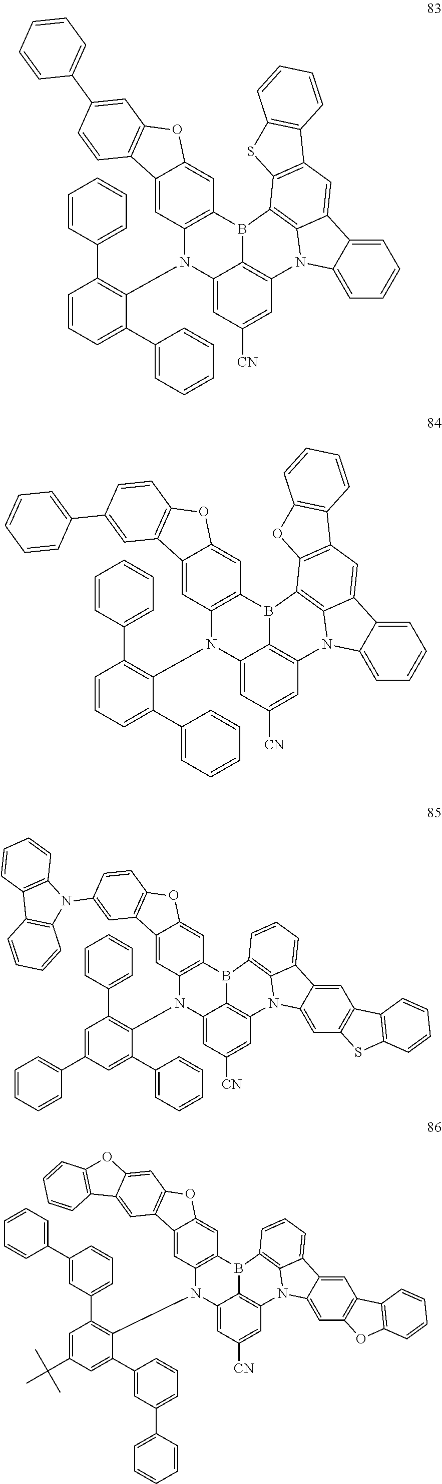

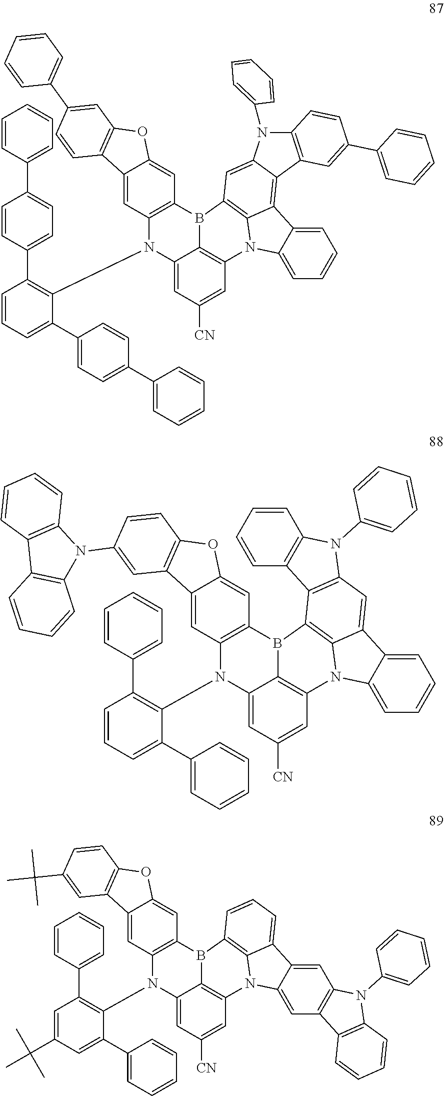 [SMILES: N#Cc1cc2c3c(c1)-n1c4ccccc4c4c5c6cc(-c7ccccc7)ccc6n(-c6ccccc6)c5cc(c41)B3c1cc3oc4cc(-c5ccccc5)ccc4c3cc1N2c1c(-c2ccc(-c3ccccc3)cc2)cccc1-c1ccc(-c2ccccc2)cc1 ; N#Cc1cc2c3c(c1)-n1c4ccccc4c4cc5c(c(c41)B3c1cc3oc4ccc(-n6c7ccccc7c7ccccc76)cc4c3cc1N2c1c(-c2ccccc2)cccc1-c1ccccc1)c1ccccc1n5-c1ccccc1 ; CC(C)(C)c1cc(-c2ccccc2)c(N2c3cc4c(cc3B3c5c2cc(C#N)cc5-n2c5cc6c7ccccc7n(-c7ccccc7)c6cc5c5cccc3c52)oc2ccc(C(C)(C)C)cc24)c(-c2ccccc2)c1]

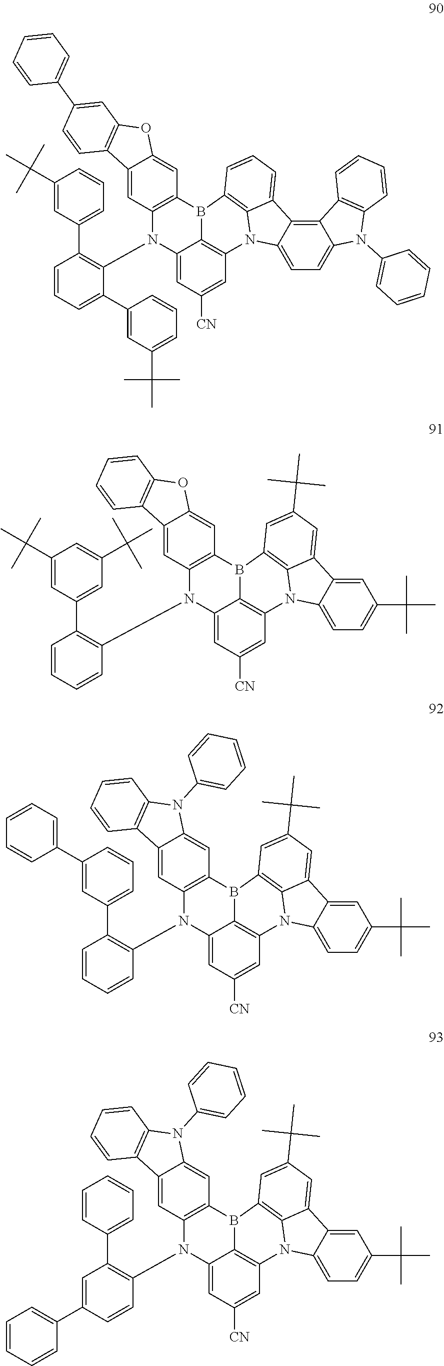

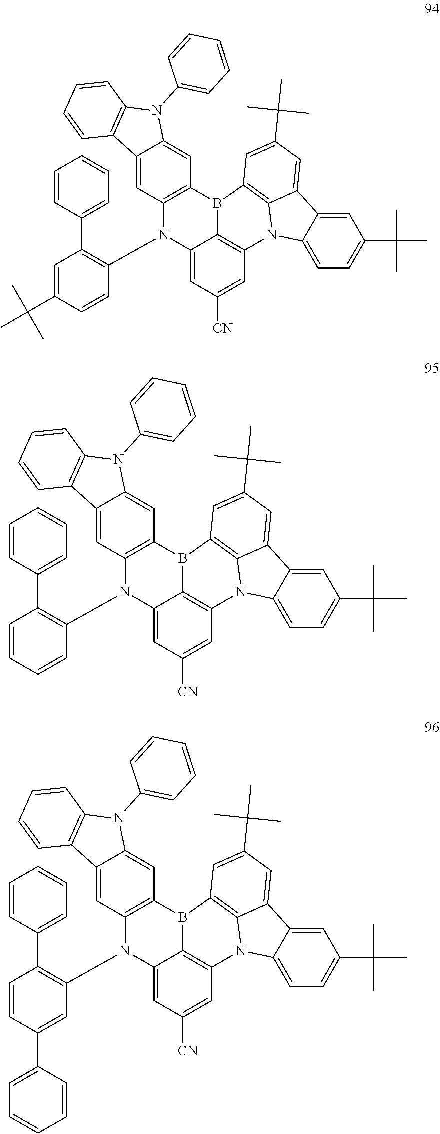 [SMILES: CC(C)(C)c1ccc(N2c3cc4c5ccccc5n(-c5ccccc5)c4cc3B3c4c2cc(C#N)cc4-n2c4ccc(C(C)(C)C)cc4c4cc(C(C)(C)C)cc3c42)c(-c2ccccc2)c1 ; CC(C)(C)c1ccc2c(c1)c1cc(C(C)(C)C)cc3c1n2-c1cc(C#N)cc2c1B3c1cc3c(cc1N2c1ccccc1-c1ccccc1)c1ccccc1n3-c1ccccc1 ; CC(C)(C)c1ccc2c(c1)c1cc(C(C)(C)C)cc3c1n2-c1cc(C#N)cc2c1B3c1cc3c(cc1N2c1cc(-c2ccccc2)ccc1-c1ccccc1)c1ccccc1n3-c1ccccc1]

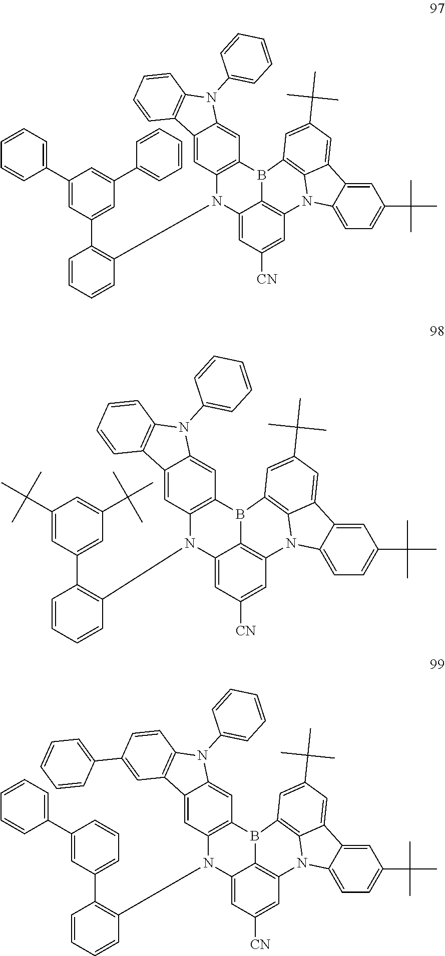

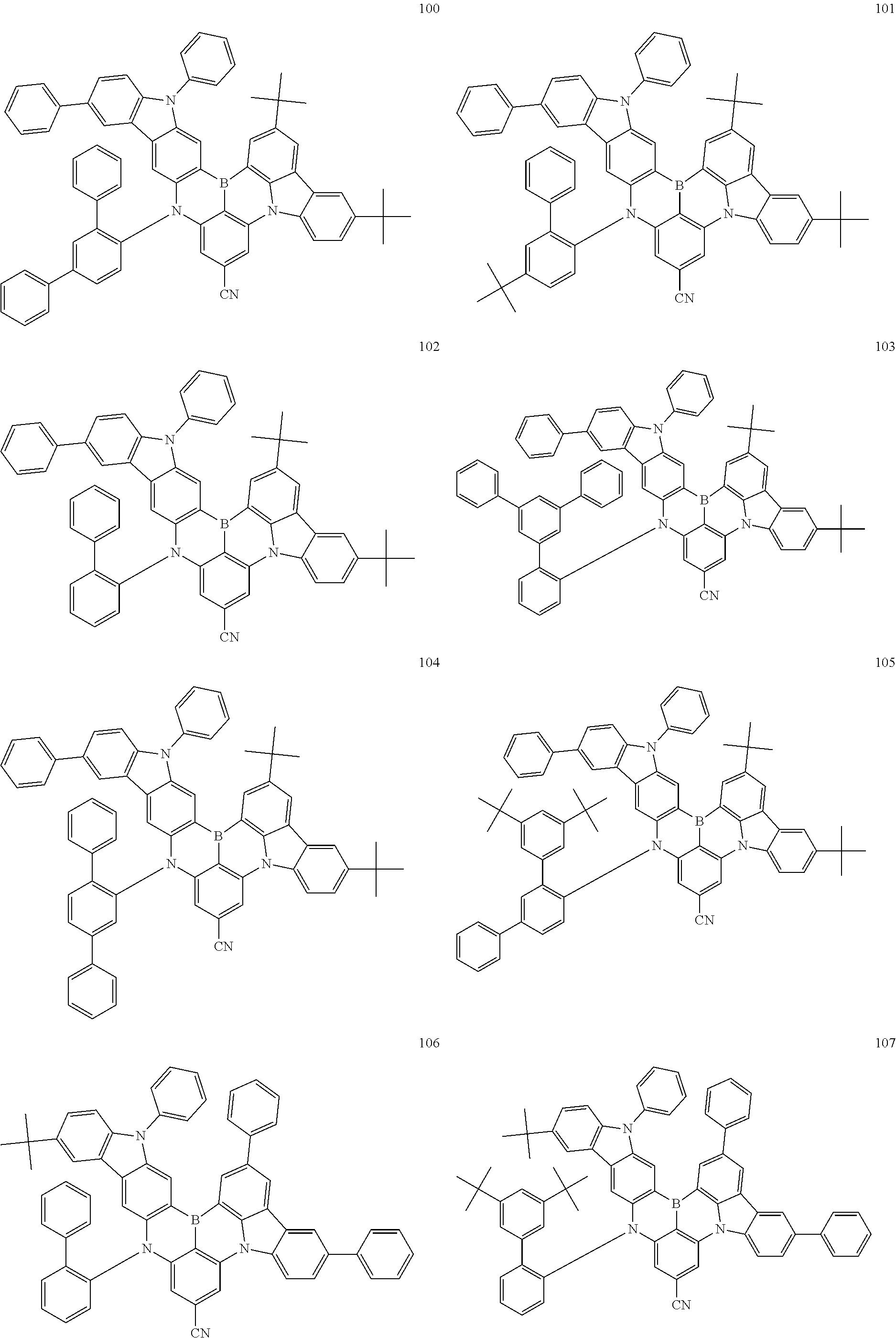

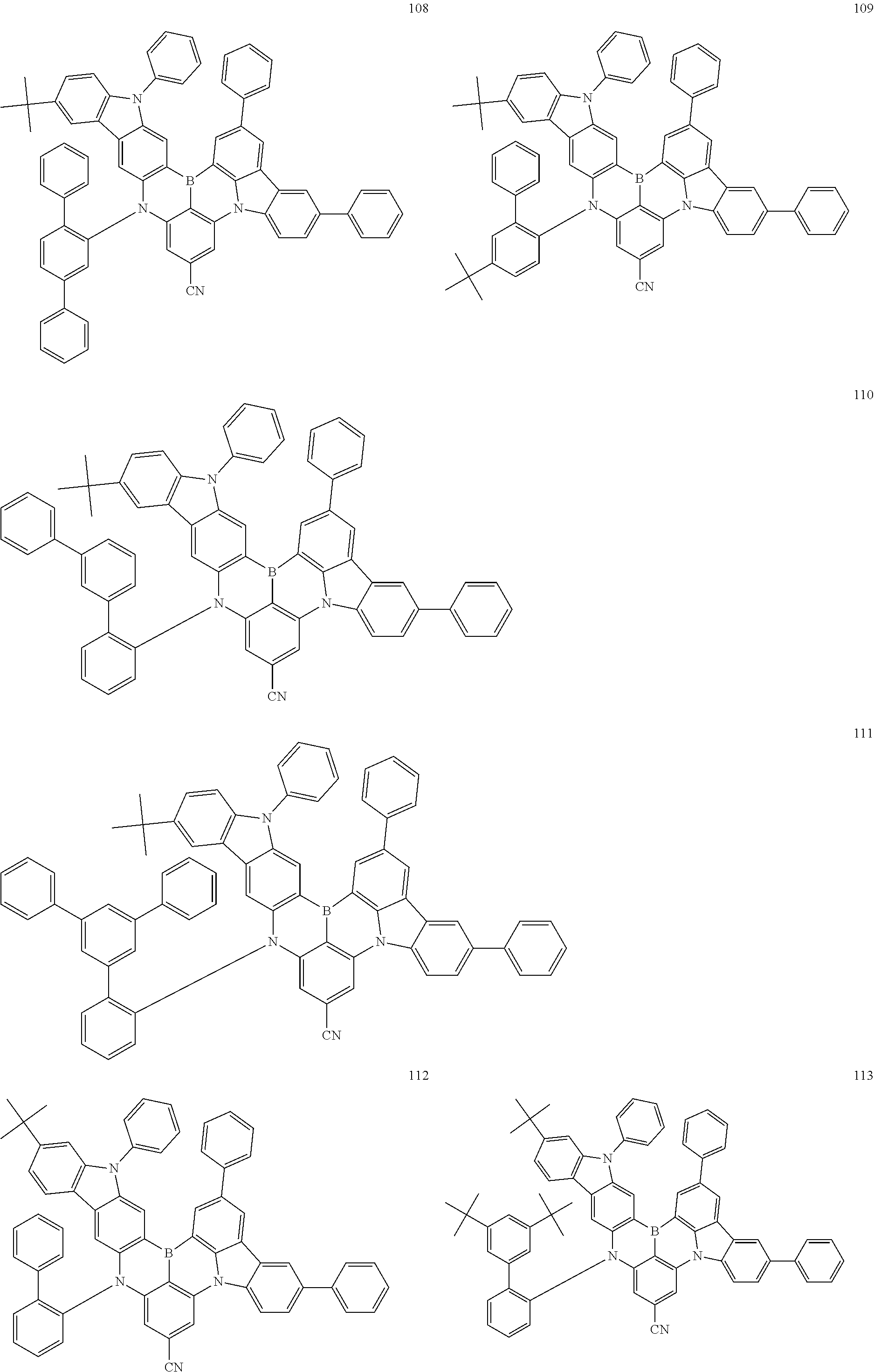

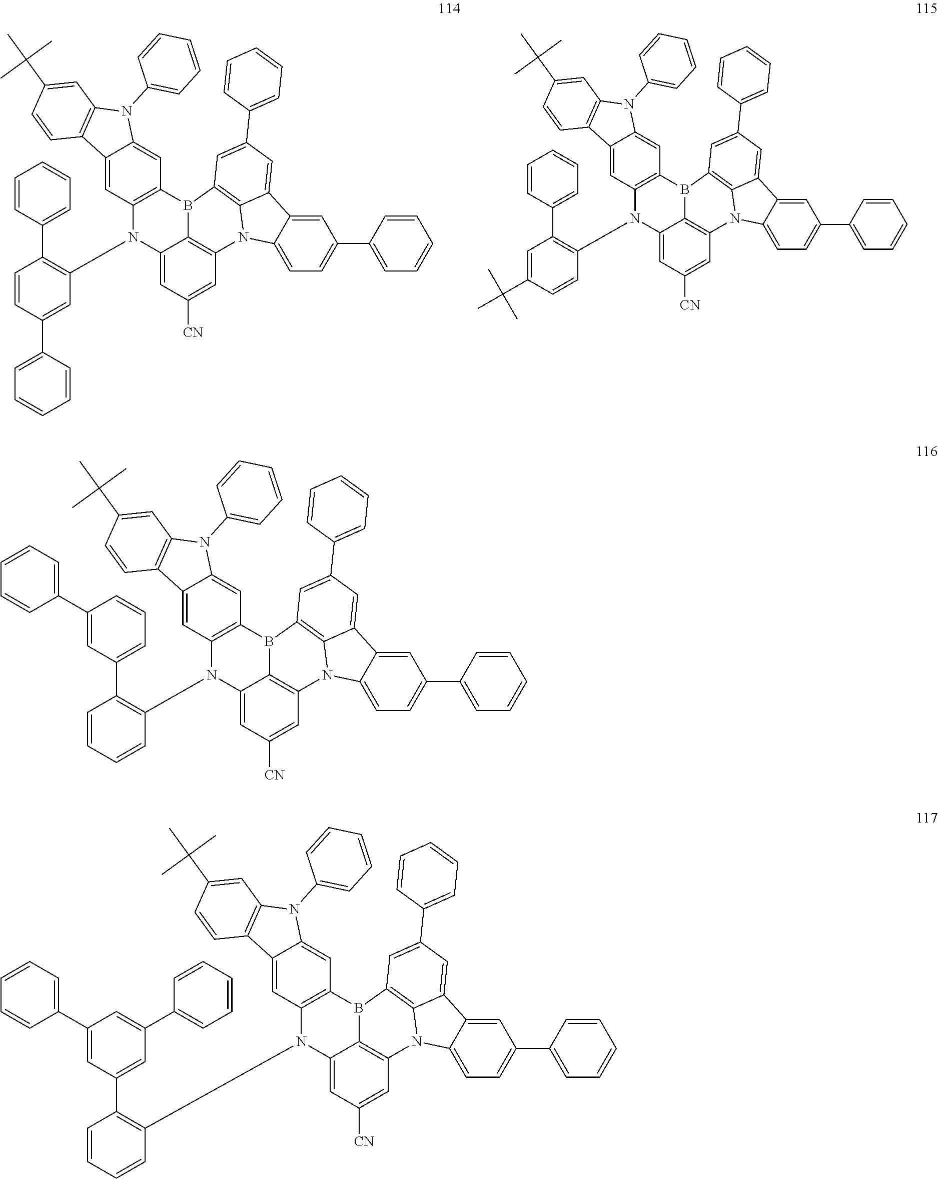

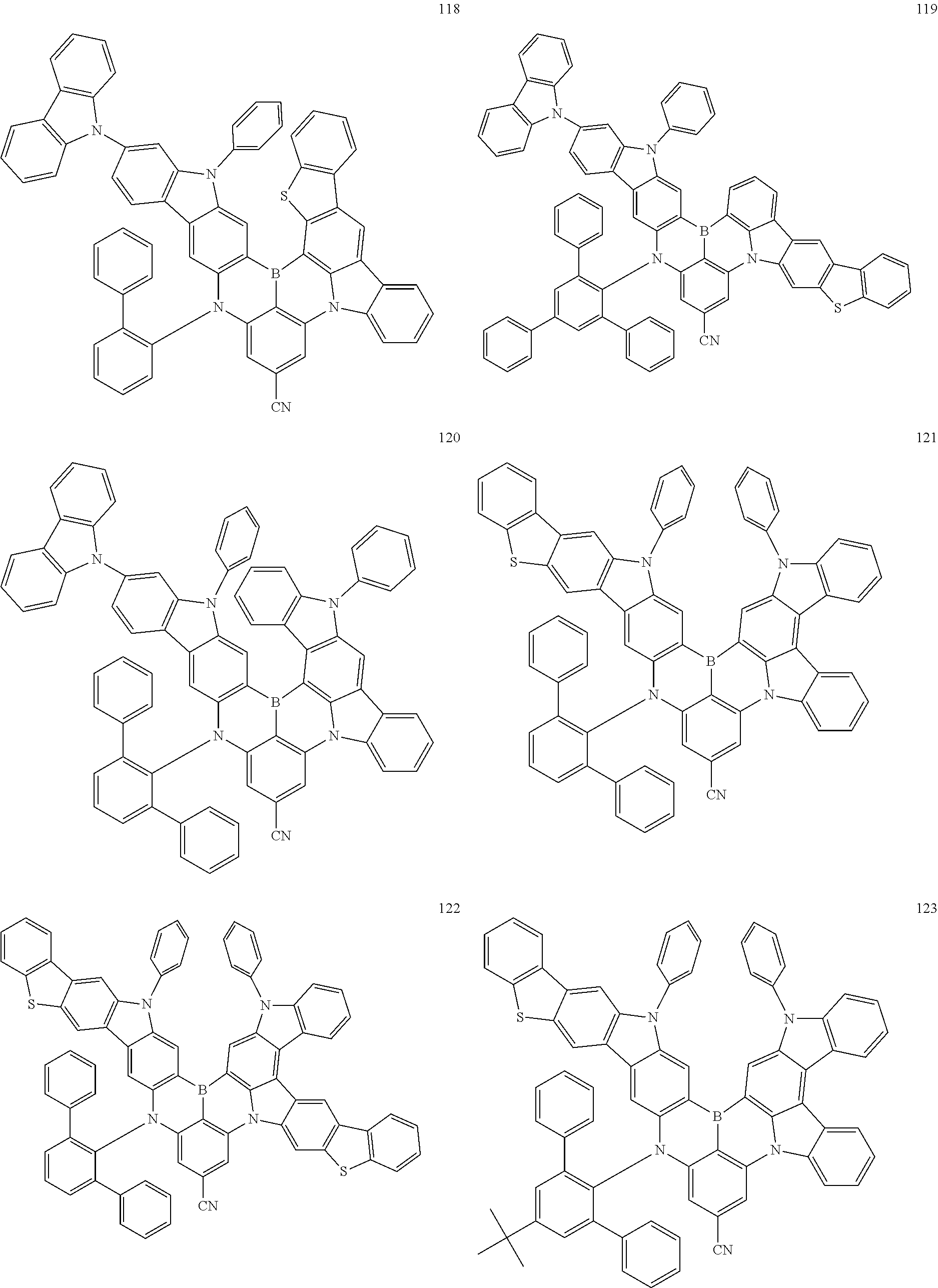

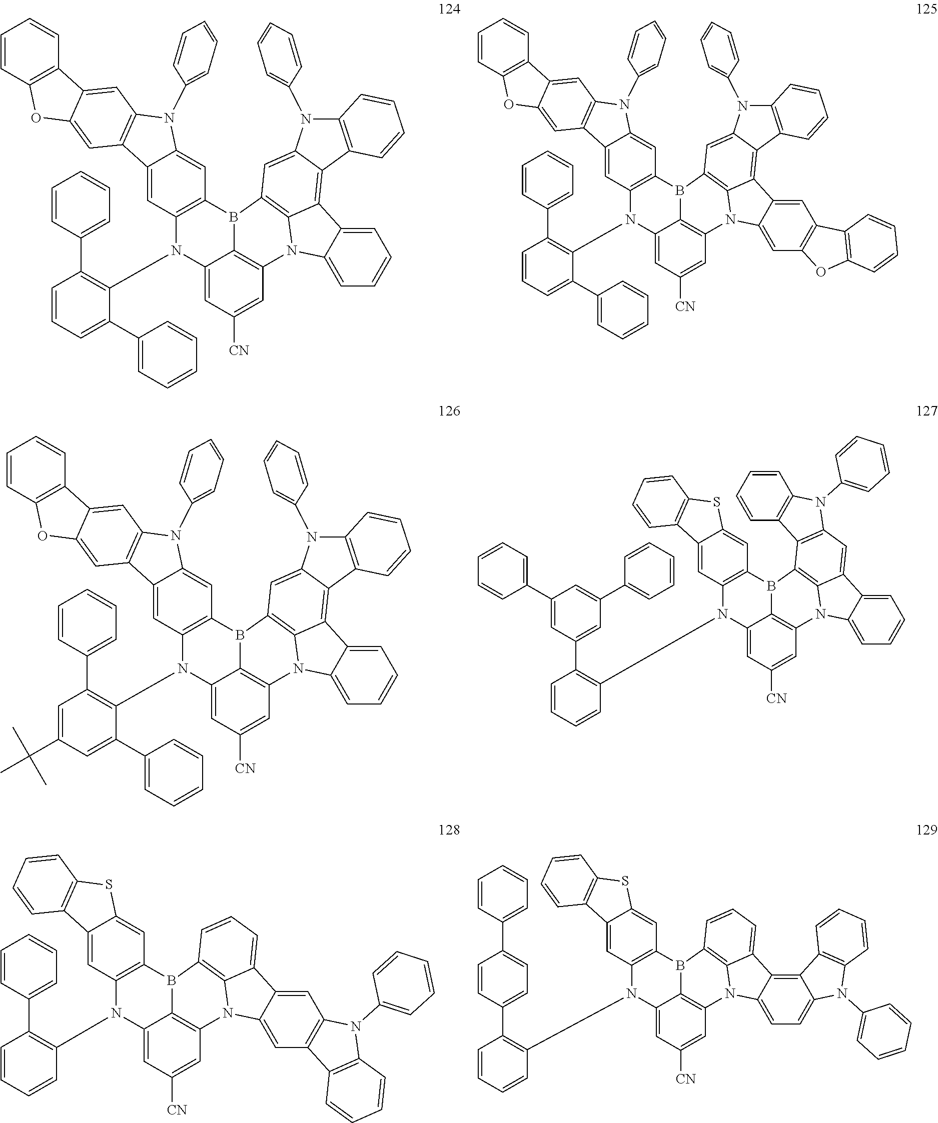

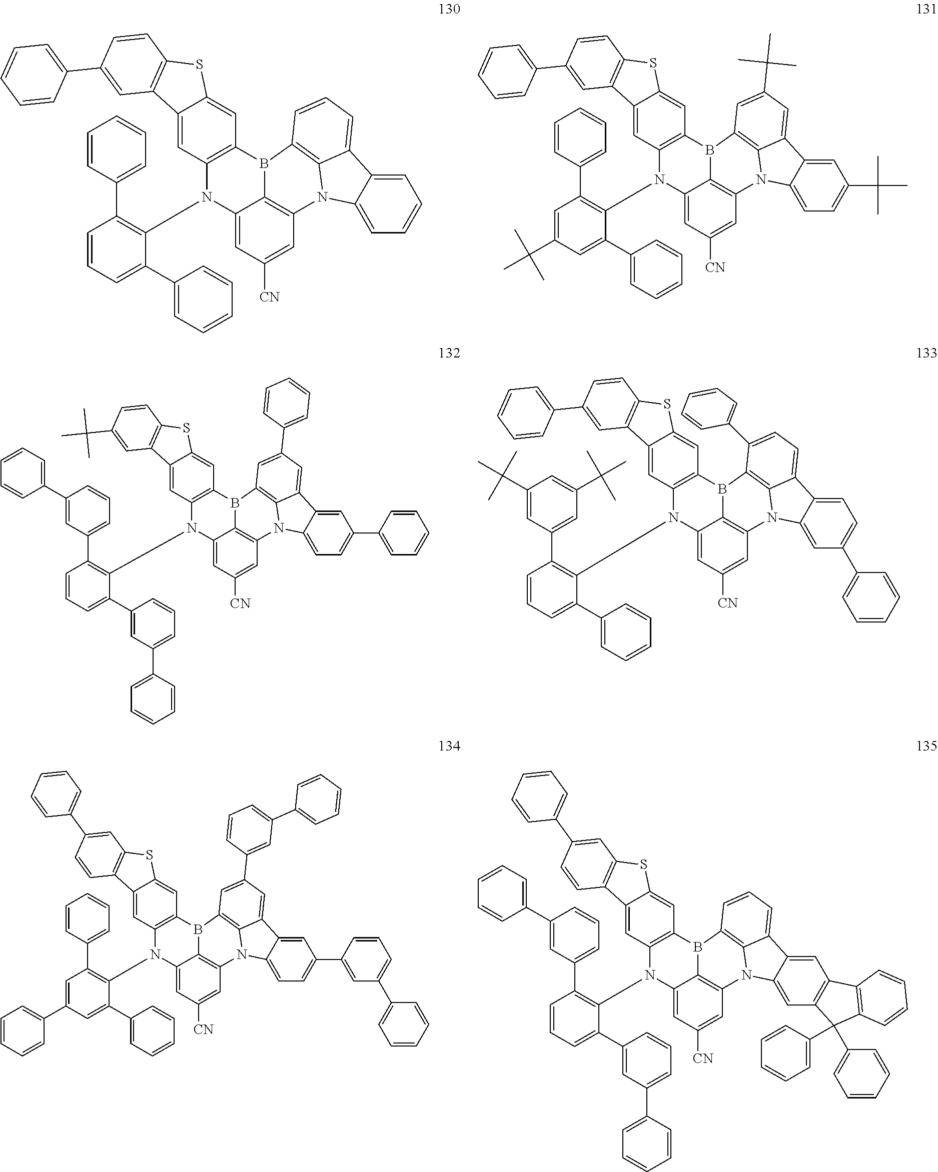

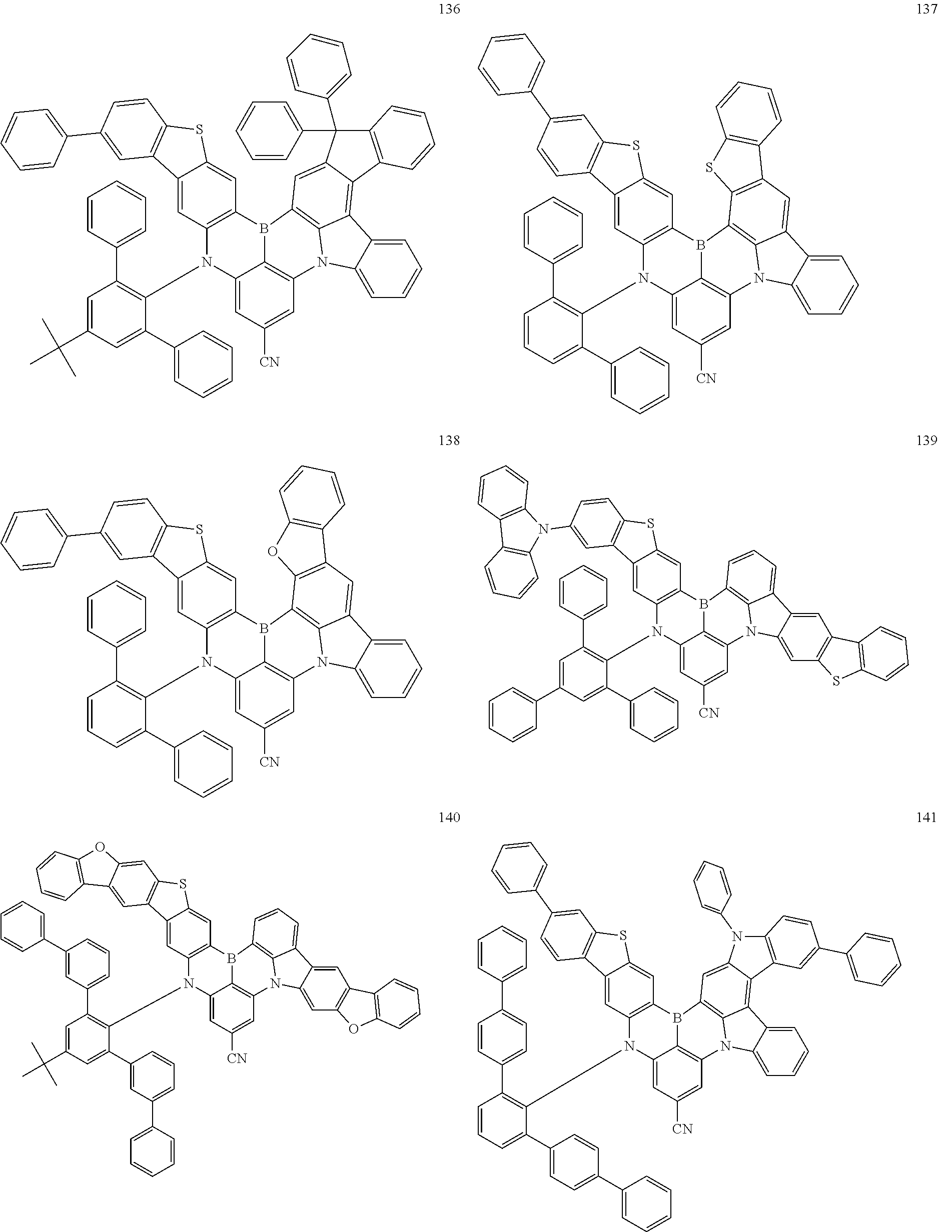

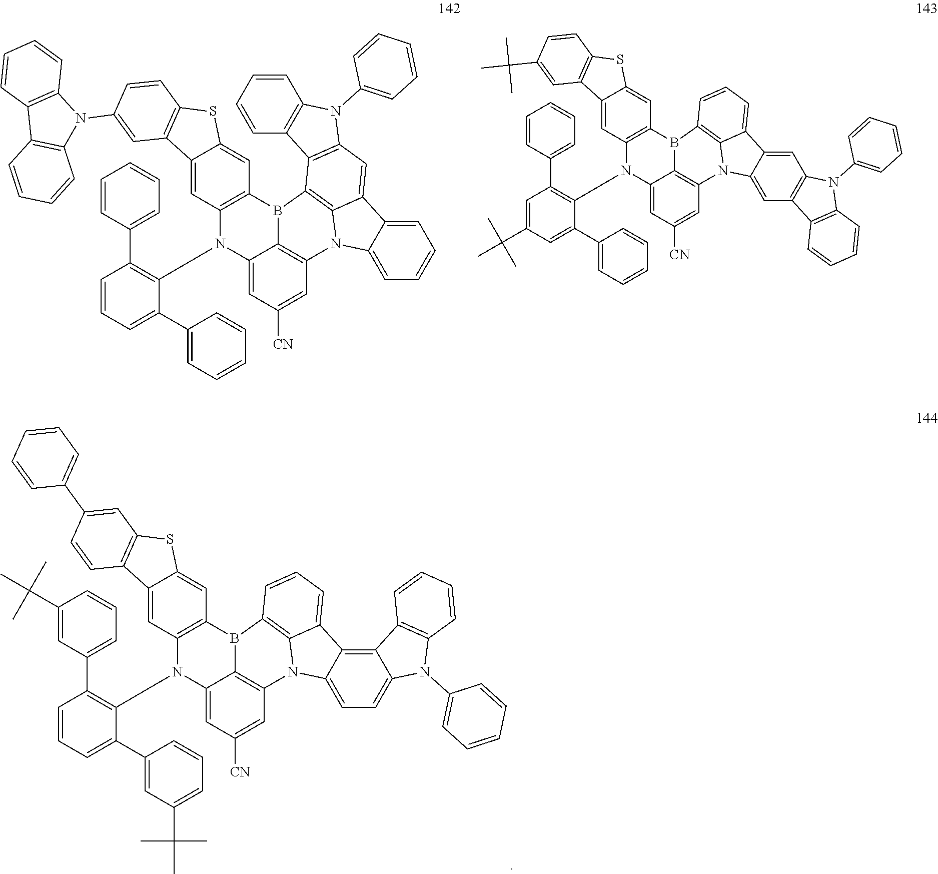

18. An electronic apparatus comprising:
a base layer;
a circuit layer on the base layer; and
a display element layer on the circuit layer and comprising a light emitting element,
wherein the light emitting element comprises a first electrode, a second electrode on the first electrode, and an emission layer between the first electrode and the second electrode and comprising a fused polycyclic compound represented by Formula 1: 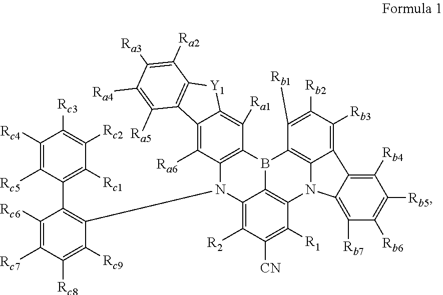
and
wherein, in Formula 1,
Y₁ is NR₃, O, or S,
R₁ to R₃ are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted alkyl group of 1 to 60 carbon atoms, a substituted or unsubstituted aryl group of 6 to 60 ring-forming carbon atoms, or a substituted or unsubstituted heteroaryl group of 2 to 60 ring-forming carbon atoms, and
Rₐ₁ to Rₐ₆, R_{b1} to R_{b7}, and R_{c1} to R_{c9} are each independently a hydrogen atom, a deuterium atom, a halogen atom, a cyano group, a nitro group, a substituted or unsubstituted silyl group, a substituted or unsubstituted amine group, a substituted or unsubstituted oxy group, a substituted or unsubstituted thio group, a substituted or unsubstituted alkyl group of 1 to 60 carbon atoms, a substituted or unsubstituted alkenyl group of 2 to 60 carbon atoms, a substituted or unsubstituted aryl group of 6 to 60 ring-forming carbon atoms, or a substituted or unsubstituted heteroaryl group of 2 to 60 ring-forming carbon atoms, and/or combined with an adjacent group to form a ring.

19. The electronic apparatus of claim 18, wherein the light emitting element comprises a first light emitting element configured to emit red light, a second light emitting element configured to emit green light, and a third light emitting element configured to emit blue light, and
the second light emitting element comprises the fused polycyclic compound.

20. The electronic apparatus of claim 18, further comprising a light control layer on the display element layer and comprising a quantum dot.
